(19) United States
(12) Patent Application Publication
(10) Pub. No.: US 2015/0086912 A1
(43) Pub. Date: Mar. 26, 2015

(54) ACTINIC RAY-SENSITIVE OR RADIATION-SENSITIVE RESIN COMPOSITION, RESIST FILM AND PATTERN FORMING METHOD USING THE SAME, MANUFACTURING METHOD OF SEMICONDUCTOR DEVICE, AND SEMICONDUCTOR DEVICE

(71) Applicant: FUJIFILM CORPORATION, Tokyo (JP)

(72) Inventors: Takeshi KAWABATA, Haibara-gun (JP); Hideaki TSUBAKI, Haibara-gun (JP); Hiroo TAKIZAWA, Haibara-gun (JP); Natsumi YOKOKAWA, Haibara-gun (JP)

(73) Assignee: FUJIFILM CORPORATION, Tokyo (JP)

(21) Appl. No.: 14/554,344

(22) Filed: Nov. 26, 2014

Related U.S. Application Data
(63) Continuation of application No. PCT/JP2013/065770, filed on May 31, 2013.

(30) Foreign Application Priority Data
May 31, 2012 (JP) 2012-124854
Apr. 30, 2013 (JP) 2013-096041

(51) Int. Cl. G03F 7/038; C08F 216/10; C08F 220/30; C08F 216/14

(52) U.S. Cl. CPC G03F 7/0388; C08F 216/1416; C08F 216/10; C08F 220/30; C08F 216/14; C08F 2220/301
USPC 430/18; 430/325; 430/319; 526/243; 526/256; 526/270; 526/287

(57) ABSTRACT

There is provided an actinic ray-sensitive or radiation-sensitive resin composition comprising (P) a resin having a repeating unit (A) represented by the specific formula (I) capable of generating an acid on the side chain of the resin upon irradiation with an actinic ray or radiation, and a resist film formed with the actinic ray-sensitive or radiation-sensitive resin composition, and a pattern forming method comprising: exposing the resist film, and developing the exposed resist film, and a method for manufacturing a semiconductor device, containing the pattern forming method, and a semiconductor device manufactured by the manufacturing method of the semiconductor device.

### CROSS REFERENCE TO RELATED APPLICATION

This is a continuation of International Application No. PCT/JP2013/065770 filed on May 31, 2013, and claims priority from Japanese Patent Application No. 2012-124854 filed on May 31, 2012, and Japanese Patent Application No. 2013-096041 filed on Apr. 30, 2013 the entire disclosures of which are incorporated therein by reference.

### TECHNICAL FIELD

The present invention relates to an actinic ray-sensitive or radiation-sensitive resin composition suitably used in microlithography process such as the manufacture of super LSI and high capacity microchips and other photo-fabrication processes, a resist film and a pattern forming method using the same, a method for manufacturing a semiconductor device, and a semiconductor device.

### BACKGROUND ART

In the manufacturing processes of semiconductor devices such as IC and LSI, fine process by lithography using a photo-resist composition has been conventionally performed. In recent years, ultrafine pattern formation of a sub-micron region and a quarter micron region has been required with higher integration of integrated circuits. In such a circumstance, exposure wavelength also shows a tendency to become shorter such as from g-rays to i-rays, and further to KrF excimer laser rays. Further, other than excimer laser rays, development of lithography using electron beams, X-rays or EUV rays is also now progressing.

In particular, electron beam lithography is positioned as a pattern forming technique of the next generation or the next of the next generation, and a positive resist of high sensitivity and high resolution is desired. In particular, for shortening the processing time of a wafer, increase of sensitivity is a very important subject. However, in positive resists for electron beam, pursuit of higher sensitization is accompanied by not only lowering of resolving power but also deterioration of line edge roughness, accordingly development of a resist satisfying these characteristics at the same time is strongly desired. The edge on the interface of the resist pattern and the substrate irregularly fluctuates in the direction vertical to the line direction due to the properties of the resist. Therefore, when the pattern is viewed from directly above, the edge is seen to be irregular, this is what is called line edge roughness. The irregularity is transferred in the etching process in which the resist is used as a mask, and electrical properties are deteriorated to thereby decrease the yield. Improvement of line edge roughness is a very important subject in particular in an ultrafine region of 0.25 μm or less. High sensitivity, high resolution, good pattern profile, and good line edge roughness are in a tradeoff relationship, and to satisfy these properties at the same time is a very important subject.

To satisfy high sensitivity, high resolution, good pattern profile and good line edge roughness at the same time is also an important subject in lithography using X-ray or EUV ray.

Further, in the case where EUV ray is used as a light source, since the wavelength of light belongs to an extreme ultraviolet region and has high energy, different from conventional light sources, a problem of outgas becomes conspicuous such that the compound in a resist film is broken by fragmentation and volatilizes as a low molecular component during exposure to contaminate the environment in the exposing apparatus.

As one method of solving these problems, use of a resin having a photo-acid generator on the main chain or side chain of a polymer has been examined (JP-A-9-325497 (The term “JP-A” as used herein refers to an “unexamined published Japanese patent application”.), JP-A-10-221852, JP-A-2006-178317, JP-A-2007-197718, WO 06/121096, U.S. Patent Application Publication 2006/121390, WO 08/056796, and JP-A-2010-250290).

However, since the technique in JP-A-9-325497 uses a mixed system of a resin having a photo-acid generator and a dissolution inhibiting compound capable of increasing the solubility in an alkali developer by acid decomposition, it has been difficult to obtain a good pattern profile and line edge roughness ascribable to inhomogeneous mixing properties of these materials.

Further, there are described in JP-A-10-221852, JP-A-2006-178317, JP-A-2007-197718, WO 06/121096, U.S. Patent Application Publication 2006/121390, WO 08/056796, and JP-A-2010-250290 resins having a photo-acid generating group and a group capable of increasing the solubility in an alkali developer by acid decomposition in the same molecule. However, these resins cannot be said to be sufficient in sensitivity to electron beams, X-rays or EUV rays.

In the case where an acid generating site corresponding to an acid generator is included in the resin as in the techniques in JP-A-9-325497, JP-A-10-221852, JP-A-2006-178317, JP-A-2007-197718, WO 06/121096, U.S. Patent Application Publication 2006/121390, WO 08/056796, and JP-A-2010-250290, such problems tend to be reduced that resolution is damaged by insufficient miscibility of an acid generator and a resin or by diffusion of an acid generated from an acid generator by exposure even to an unintended region (e.g., an unexposed area). Further, for example, in the case where EUV ray is irradiated, generation of outgas resulting from a low molecular component tends to be the more reduced due to the absence of a low molecular acid generator. However, even in these techniques, there is yet room for improvement as to sensitivity particularly to electron beams, X-rays or EUV rays.

In particular, in electron beam, X-ray or EUV ray lithography, further improvement is required as to resolution and outgas characteristics and, in addition, at the same time, further improvement is demanded in sensitivity, line edge roughness and pattern profile, as is the present situation.

### SUMMARY OF INVENTION

An object of the invention is to provide an actinic ray-sensitive or radiation-sensitive resin composition capable of satisfying high sensitivity, high resolution, good pattern profile, and good line edge roughness on a high level at the same time, controlled in pattern collapse in a rinsing process, and having sufficiently satisfactory outgas properties at the time of exposure.

Further objects of the invention are to provide a resist film using the same composition, a pattern forming method, a manufacturing method of a semiconductor device, and a semiconductor device.

That is, the invention is as follows.

[1] An actinic ray-sensitive or radiation-sensitive resin composition comprising:

(P) a resin having a repeating unit (A) represented by the following formula (I) capable of generating an acid on the side chain of the resin upon irradiation with an actinic ray or radiation:

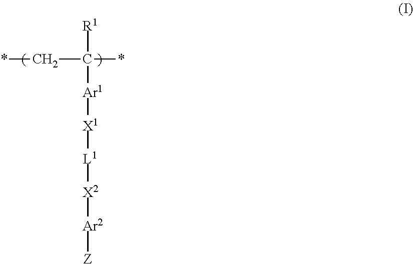

wherein R¹ represents a hydrogen atom, an alkyl group, a monovalent aliphatic hydrocarbon cyclic group, a halogen atom, a cyano group, or an alkoxycarbonyl group,

each of Ar¹ and Ar² independently represents a divalent aromatic cyclic group, or a group formed by combining a divalent aromatic cyclic group and an alkylene group,

each of X¹ and X² independently represents —O— or —S—,

L¹ represents an alkylene group, an alkenylene group, a divalent aliphatic hydrocarbon cyclic group, a divalent aromatic cyclic group, or a group formed by combining two or more of these groups, two or more groups combined in the group formed by combining two or more of these groups may be the same with or different from each other, and two or more groups combined may be linked via —O— or —S— as a linking group; and

Z represents a site capable of becoming a sulfonic acid group, an imidic acid group or a methide acid group upon irradiation with an actinic ray or radiation.

[2] The actinic ray-sensitive or radiation-sensitive resin composition as described in [1], wherein each of X¹ and X² is —O—.
[3] The actinic ray-sensitive or radiation-sensitive resin composition as described in [1] or [2],

wherein in formula (I), the number of atoms for constituting the main structure of the alkylene group, the ankenylene group, the divalent aliphatic hydrocarbon cyclic group, the divalent aromatic cyclic group, or the group formed by combining two or more of these groups represented by L₁ in formula (I) is 2 to 7.

[4] The actinic ray-sensitive or radiation-sensitive resin composition as described in any one of [1] to [3],

wherein the resin (P) is a resin further having (B) a repeating unit having a group capable of decomposing by an action of an acid to generate a polar group.

[5] The actinic ray-sensitive or radiation-sensitive resin composition as described in [4],

wherein the repeating unit (B) is a repeating unit represented by the following formula (b):

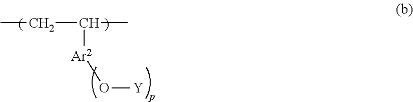

wherein Ar₂ represents a (p+1)-valent aromatic cyclic group,

Y represents a hydrogen atom or a group capable of leaving by an action of an acid, and when a plurality of Y are present, the plurality of Y may be the same with or different from every other Y, provided that at least one of Y's represents a group capable of leaving by the action of an acid, and

p represents an integer of 1 or more.

[6] The actinic ray-sensitive or radiation-sensitive resin composition as described in [5],

wherein Y in formula (b) is a group represented by the following formula (c):

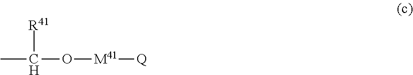

wherein R⁴¹ represents a hydrogen atom, an alkyl group, a cycloalkyl group, an aryl group, or an aralkyl group,
M⁴¹ represents a single bond or a divalent linking group,

Q represents an alkyl group, an alicyclic group, or an aromatic cyclic group which may contain a heteroatom, and at least two of R⁴¹, M⁴¹ and Q may be bonded to each other to form a ring.

[7] The actinic ray-sensitive or radiation-sensitive resin composition as described in [4],

wherein the repeating unit (B) is a repeating unit represented by the following formula (II):

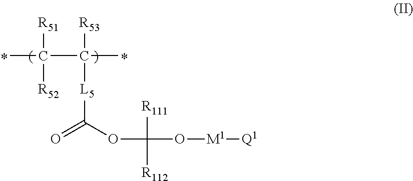

wherein each of R₅₁, R₅₂ and R₅₃ independently represents a hydrogen atom, an alkyl group, a cycloalkyl group, a halogen atom, a cyano group, or an alkoxycarbonyl group,

R₅₂ and L₅ may be bonded to each other to form a ring, and R₅₂ represents an alkylene group in that case,

L₅ represents a single bond or a divalent linking group, and L₅ represents a trivalent linking group when L₅ is bonded to R₅₂ to form a ring,

R₁₁₁ represents a hydrogen atom or an alkyl group,

R₁₁₂ represents a hydrogen atom, an alkyl group, a cycloalkyl group, an aryl group, an aralkyl group, an alkoxy group, an acyl group, or a heterocyclic group,

M¹ represents a single bond or a divalent linking group,

Q¹ represents an alkyl group, a cycloalkyl group, an aryl group, or a heterocyclic group, Q¹, M¹ and R₁₁₂ may be bonded to each other to form a ring,

when M¹ represents a divalent linking group, Q¹ may be bonded to M¹ via a single bond or a different linking group to form a ring.

[8] The actinic ray-sensitive or radiation-sensitive resin composition as described in any one of [1] to [7], which is exposed with an electron beam or an extreme ultraviolet ray.
[9] A resist film formed with the actinic ray-sensitive or radiation-sensitive resin composition as described in any one of [1] to [8].
[10] A pattern forming method comprising:

exposing the resist film described in [9], and

developing the exposed resist film.

[11] The pattern forming method as described in [10],

wherein, as the development, development by using a developer containing an organic solvent is performed to form a negative pattern.

[12] The pattern forming method as described in [10] or [11],

wherein the exposure is performed by electron beam or extreme ultraviolet ray.

[13] A method for manufacturing a semiconductor device, containing the pattern forming method as described in any one of [10] to [12].
[14] A semiconductor device manufactured by the manufacturing method of the semiconductor device as described in [13].

According to the invention, it is possible to provide an actinic ray-sensitive or radiation-sensitive resin composition capable of satisfying high sensitivity, high resolution, good pattern profile, and good line edge roughness on a high level at the same time, controlled in pattern collapse in a rinsing process, and having sufficiently satisfactory outgas properties at the time of exposure. According to the invention, it is also possible to provide a resist film using the same composition, a pattern forming method, a manufacturing method of a semiconductor device, and a semiconductor device.

### DESCRIPTION OF EMBODIMENTS

The mode for carrying out the invention is described in detail below.

In the description of the invention, a group and an atomic group not being specified whether substituted or unsubstituted encompass both a group having no substituent and a group having a substituent. For example, “an alkyl group” not specifying whether substituted or unsubstituted encompasses not only an alkyl group having no substituent (an unsubstituted alkyl group) but also an alkyl group having a substituent (a substituted alkyl group).

Also, in the specification of the invention, the “actinic ray” or “radiation” means, for example, a bright line spectrum of a mercury lamp, a far ultraviolet ray typified by excimer laser, an X-ray, a soft X-ray such as an extreme ultraviolet ray (EUV ray), or an electron beam (EB). The “light” means an actinic ray or radiation. The “exposure” encompasses not only irradiation with a mercury lamp, a far ultraviolet ray, an X-ray, an EUV ray or the like but also lithography with a corpuscular beam, such as electron beam and ion beam, unless otherwise indicated.

The actinic ray-sensitive or radiation-sensitive resin composition according to the invention contains a resin (P), which is described later. By adopting such a constitution, it becomes possible to form a pattern satisfying high sensitivity, high resolution, good pattern profile, and good line edge roughness on a high level at the same time, control pattern collapse in a rinsing process, and achieve sufficiently satisfactory outgas properties. The reasons for these facts are not clearly known but presumably as follows.

First of all, the resin (P) contained in the actinic ray-sensitive or radiation-sensitive resin composition of the invention has a repeating unit (A) capable of decomposing upon irradiation with an actinic ray or radiation to generate an acid on the side chain of the resin. By containing the repeating unit (A), it is presumed that diffusion and volatilization of an acid generated during exposure are reduced, resolution and outgas performance at pattern forming time are improved, and the formed pattern has a better form.

Further, in the repeating unit (A) of the resin (P) contained in the actinic ray-sensitive or radiation-sensitive resin composition according to the invention, a site which becomes a sulfonic acid group, an imidic acid group, or a methide acid group upon irradiation with an actinic ray or radiation and the main chain of repeating unit (A) are linked through a long linking group, accordingly the site which becomes a sulfonic acid group, an imidic acid group, or a methide acid group upon irradiation with an actinic ray or radiation is stretched out to the outside of the main chain of the polymer, and the solubility of the exposed area in an alkali developer is presumably improved. It is considered that sensitivity of the actinic ray-sensitive or radiation-sensitive resin composition in the invention is improved and line edge roughness of the formed pattern is bettered by such a constitution.

In addition, since the linking group L₁ in the repeating unit (A) of the resin (P) contained in the actinic ray-sensitive or radiation-sensitive resin composition in the invention is a linking group having low polarity, the contact angle of water on the surface of the resist film increases and pattern collapse in a rinsing process can be probably controlled.

The actinic ray-sensitive or radiation-sensitive resin composition according to the invention may be used in negative development (development in which the exposed area remains as a pattern and the unexposed area is removed) or may be used in positive development (development in which the exposed area is removed and the unexposed area remains as a pattern). That is, the actinic ray-sensitive or radiation-sensitive resin composition according to the invention may be an actinic ray-sensitive or radiation-sensitive resin composition for organic solvent development used in development using a developer containing an organic solvent (negative type development), or may be an actinic ray-sensitive or radiation-sensitive resin composition for alkali development used in development using an alkali developer (positive type development). Here, “for organic solvent development” means to be used in a process of development using a developer containing at least an organic developer, and “for alkali development” means to be used in a process of development using at least an alkali developer.

The actinic ray-sensitive or radiation-sensitive resin composition according to the invention is typified by a chemically amplified resist composition.

The composition according to the invention is preferably exposed with an electron beam or an extreme ultraviolet ray (that is, a composition for electron beam or extreme ultraviolet ray).

The constitution of the composition is described below.

### [1] Resin (P)

The resin (P) contains a repeating unit (A) represented by the following formula (I) capable of decomposing upon irradiation with an actinic ray or radiation to generate an acid on the side chain of the resin. The resin (P) may further contain a repeating unit other than the repeating unit (A).

### [Repeating Unit (A)]

The repeating unit (A) is preferably a repeating unit having an ionic structural site capable of decomposing upon irradiation with an actinic ray or radiation to generate an acid on the side chain of the resin.

The repeating unit (A) is a repeating unit represented by the following formula (I).

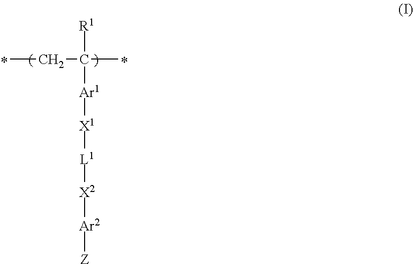

In formula (I), R¹ represents a hydrogen atom, an alkyl group, a monovalent aliphatic hydrocarbon cyclic group, a halogen atom, a cyano group, or an alkoxycarbonyl group.

Each of Ar¹ and Ar² independently represents a divalent aromatic cyclic group, or a group formed by combining a divalent aromatic cyclic group and an alkylene group.

Each of X¹ and X² independently represents —O— or —S—.

L¹ represents an alkylene group, an alkenylene group, a divalent aliphatic hydrocarbon cyclic group, a divalent aromatic cyclic group, or a group formed by combining two or more of these groups. Two or more groups combined in the group formed by combining two or more of these groups may be the same with or different from each other, and two or more groups to be combined may be linked via —O— or —S— as a linking group.

Z represents a site capable of becoming a sulfonic acid group, an imidic acid group or a methide acid group upon irradiation with an actinic ray or radiation.

The alkyl group represented by R¹ is, for example, an alkyl group having 20 or less carbon atoms, preferably a methyl group, an ethyl group, a propyl group, an isopropyl group, an n-butyl group, a sec-butyl group, a hexyl group, a 2-ethylhexyl group, an octyl group, or a dodecyl group, and more preferably these alkyl groups are alkyl groups having 8 or less carbon atoms. These alkyl groups may have a substituent.

The alkyl group contained in the alkoxycarbonyl group is preferably the same as the alkyl group in R¹.

The monovalent aliphatic hydrocarbon cyclic group may be monocyclic or polycyclic, and preferred examples include monocyclic aliphatic hydrocarbon cyclic groups having 3 to 8 carbon atoms, e.g., a cyclopropyl group, a cyclopentyl group and a cyclohexyl group. These aliphatic hydrocarbon cyclic groups may have a substituent.

The halogen atom is a fluorine atom, a chlorine atom, a bromine atom or an iodine atom, and preferably a fluorine atom.

R¹ preferably represents a hydrogen atom or an alkyl group, and more preferably a hydrogen atom.

Each of the divalent aromatic cyclic group represented by Ar¹ and Ar² may have a substituent, for example, an arylene group having 6 to 18 carbon atoms, such as a phenylene group, a tolylene group, and a naphthylene group, and a divalent aromatic cyclic group containing a heterocyclic ring, for example, thiophene, furan, pyrrole, benzothiophene, benzofuran, benzopyrrole, triazine, imidazole, benzimidazole, triazole, thiadiazole, or thiazole, are exemplified as preferred examples.

The group formed by combining a divalent aromatic cyclic group and an alkylene group is preferably an aralkylene group obtained by combining the above-described divalent aromatic cyclic group and an alkylene group (which may be linear or branched) having 1 to 8 carbon atoms, e.g., a methylene group, an ethylene group, a propylene group, a butylene group, a hexylene group, or an octylene group.

Ar¹ is more preferably an arylene group having 6 to 18 carbon atoms which may have a substituent, or an aralkylene group having 7 to 22 carbon atoms which may have a substituent, and especially preferably a phenylene group, a benzylene group, or a naphthylene group.

Ar² is more preferably an arylene group having 6 to 18 carbon atoms which may have a substituent, and especially preferably a phenylene group or a phenylene group substituted with a fluorine atom.

Each of X¹ and X² preferably represents —O— or —S—, and especially preferably —O—.

The alkylene group represented by L¹ may have a substituent and may be linear or branched, and preferred examples include an alkylene group having 1 to 8 carbon atoms, such as a methylene group, an ethylene group, a propylene group, a butylene group, a hexylene group, and an octylene group. An alkylene group having 2 to 8 carbon atoms is more preferred, and an alkylene group having 2 to 6 carbon atoms is especially preferred.

As the alkenylene group, a group having a double bond on an arbitrary position of the alkylene group described above in L¹ is exemplified.

The divalent aliphatic hydrocarbon cyclic group may be monocyclic or polycyclic, and preferred examples thereof include divalent aliphatic hydrocarbon cyclic groups each having 3 to 17 carbon atoms, such as a cyclobutylene group, a cyclopentylene group, a cyclohexylene group, a norbornanylene group, an adamantylene group, and a diamantanylene group. A divalent aliphatic hydrocarbon cyclic group having 5 to 12 carbon atoms is more preferred, and a divalent aliphatic hydrocarbon cyclic group having 6 to 10 carbon atoms is especially preferred.

As the divalent aromatic cyclic group, an arylene group having 6 to 14 carbon atoms which may have a substituent, such as a phenylene group, a tolylene group, and a naphthylene group, and a divalent aromatic cyclic group containing a heterocyclic ring, for example, thiophene, furan, pyrrole, benzothiophene, benzofuran, benzopyrrole, triazine, imidazole, benzimidazole, triazole, thiadiazole, or thiazole, are exemplified.

L¹ is more preferably an alkylene group or a divalent aliphatic hydrocarbon cyclic group, and especially preferably an alkylene group.

The preferred examples of the substituents for above each group include the alkyl groups exemplified in R¹, the halogen groups exemplified in R¹, alkoxy groups such as a methoxy group, an ethoxy group, a hydroxyethoxy group, a propoxy group, a hydroxypropoxy group, and a butoxy group, and an aryl group such as a phenyl group, and a fluorine atom is especially preferred.

The number of atoms for constituting the main structure of the group represented by L¹ is preferably 1 to 20, more preferably 1 to 10, and still more preferably 2 to 7. Incidentally, “the main structure of the linking group” in the invention indicates atoms or atomic groups used only for linking X¹ and X² in formula (I), and particularly when there are a plurality of linking routes, the terminology indicates the atoms or atomic groups for constituting the route requiring the least number of atoms used. By bringing the number of atoms for constituting the main structure of the group represented by L¹ into the above range, the pattern collapse in a rinsing process is inhibited the more.

The structures of the repeating units represented by formula (I) are shown below, and the number of atoms for constituting the main structure of the linking group represented by L′ in the structure and the computing method thereof are also shown.

### Number of Atoms for Forming the Main Structure of Linking Group

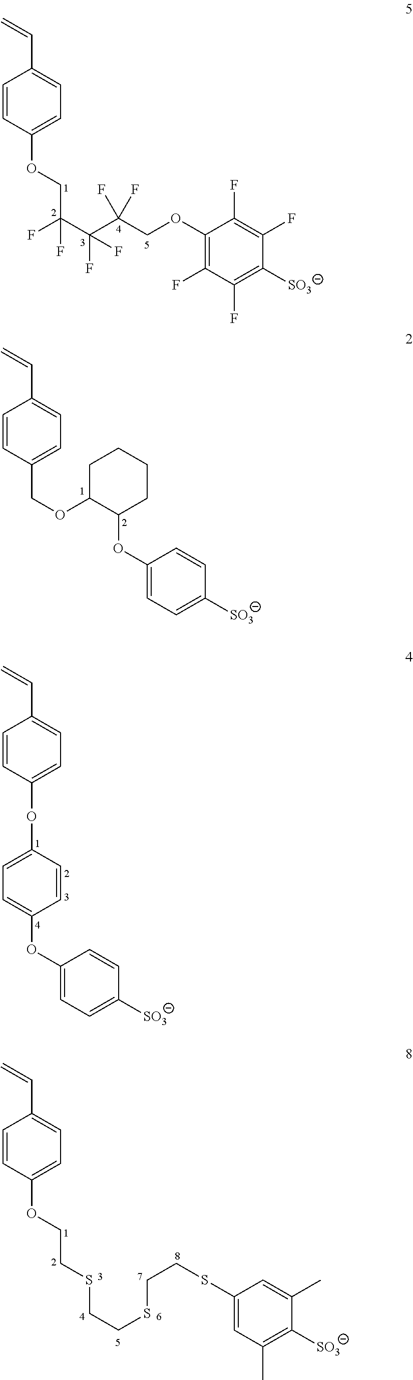

Z represents a site capable of becoming a sulfonic acid group, an imidic acid group or a methide acid group upon irradiation with an actinic ray or radiation. As the site represented by Z, an onium salt is preferred. The onium salt is preferably a sulfonium salt or an iodonium salt, and especially preferably the structure represented by any of the following formulae (ZI), (ZII) and (ZIII).

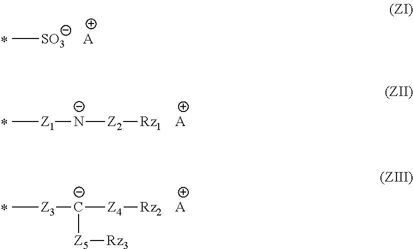

In formulae (ZII) and (ZIII), each of Z₁, Z₂, Z₃, Z₄ and Z₅ independently represents —CO— or —SO₂—, and more preferably —SO₂—.

Each of Rz₁, Rz₂ and Rz₃ independently represents an alkyl group, a monovalent aliphatic hydrocarbon cyclic group, an aryl group, or an aralkyl group. An embodiment in which a part or all of the hydrogen atoms of these groups are substituted with a fluorine atom or a fluoroalkyl group (more preferably a perfluoroalkyl group) is more preferable, and an embodiment in which 30% to 100% of the number of the hydrogen atoms are substituted with fluorine atoms is especially preferable.

* represents a bonding position to Ar² in formula (I).

The above alkyl group may be linear or branched, and the preferred examples thereof include an alkyl group having 1 to 8 carbon atoms, e.g., a methyl group, an ethyl group, a propyl group, a butyl group, a hexyl group and an octyl group, more preferably an alkyl group having 1 to 6 carbon atoms, and especially preferably an alkyl group having 1 to 4 carbon atoms.

The monovalent aliphatic hydrocarbon cyclic group is preferably a cycloalkyl group, more preferably a monovalent cycloalkyl group having 3 to 10 carbon atoms, e.g., a cyclobutyl group, a cyclopentyl group, or a cyclohexyl group, and still more preferably a cycloalkyl group having 3 to 6 carbon atoms.

The aryl group is preferably an aryl group having 6 to 18 carbon atoms, more preferably an aryl group having 6 to 10 carbon atoms, and especially preferably a phenyl group.

The aralkyl group is preferably an aralkyl group obtained by bonding an alkylene group having 1 to 8 carbon atoms and the above aryl group, more preferably an aralkyl group obtained by bonding an alkylene group having 1 to 6 carbon atoms and the above aryl group, and especially preferably an aralkyl group obtained by bonding an alkylene group having 1 to 4 carbon atoms and the above aryl group.

Each of Rz₁, Rz₂ and Rz₃ is preferably an alkyl group in which a part or all of the hydrogen atoms are substituted with a fluorine atom or a fluoroalkyl group (more preferably a perfluoroalkyl group), and especially preferably an alkyl group in which 30% to 100% of the number of the hydrogen atoms are substituted with fluorine atoms.

In the above formulae (ZI) to (ZIII), A⁺ represents a sulfonium cation or an iodonium cation, and the structure represented by the following formula (ZA-1) or (ZA-2) is preferred.

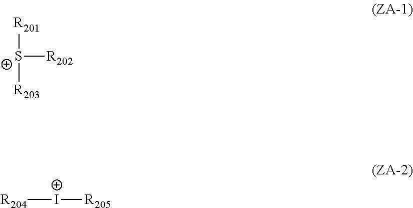

In formula (ZA-1), each of R₂₀₁, R₂₀₂ and R₂₀₃ independently represents an organic group. The number of carbon atoms of the organic group as R₂₀₁, R₂₀₂ and R₂₀₃ is generally 1 to 30, and preferably 1 to 20.

Any two of R₂₀₁ to R₂₀₃ may be bonded to form a cyclic structure (including a condensed ring), and an oxygen atom, a sulfur atom, an ester bond, an amido bond, or a carbonyl group may further be contained in the ring other than the sulfur atom in the formula. As the group formed by bonding two of R₂₀₁ to R₂₀₃, an alkylene group (e.g., a butylene group or a pentylene group) can be exemplified.

As the organic group represented by R₂₀₁, R₂₀₂ and R₂₀₃, the corresponding groups in the groups represented by formula (ZA-1-1), (ZA-1-2) or (ZA-1-3) described later as the preferred group of the groups represented by formula (ZA-1) can be exemplified, and the especially preferred organic groups are the corresponding groups in the groups represented by formula (ZA-1-1) or (ZA-1-3).

In the first place, the group represented by formula (ZA-1-1) is described.

The group (ZA-1-1) is such a group that at least one of R₂₀₁ to R₂₀₃ in formula (ZA-1) is an aryl group, that is, a group having arylsulfonium as a cation.

All of R₂₀₁ to R₂₀₃ may be aryl groups, or a part of R₂₀₁ to R₂₀₃ is an aryl group and the remainder may be an alkyl group or a monovalent aliphatic hydrocarbon cyclic group.

For example, a group corresponding to triarylsulfonium, diarylalkylsulfonium, aryldialkylsulfonium, diarylcycloalkylsulfonium, or aryldicycloalkylsulfonium can be exemplified.

The aryl group in the arylsulfonium is preferably a phenyl group or a naphthyl group. The aryl group may be an aryl group having a heterocyclic structure having an oxygen atom, a nitrogen atom, a sulfur atom or the like. As the heterocyclic structure, structures such as pyrrole, furan, thiophene, indole, benzofuran and benzothiophene are exemplified.

When the arylsulfonium has two or aryl groups, the two or more aryl groups may be the same with or different from every other aryl group.

The alkyl group or monovalent aliphatic hydrocarbon cyclic group that the arylsulfonium contains according to necessity is preferably a linear or branched alkyl group having 1 to 15 carbon atoms or a monovalent aliphatic hydrocarbon cyclic group having 3 to 15 carbon atoms, and the examples thereof include a methyl group, an ethyl group, a propyl group, an n-butyl group, a sec-butyl group, a t-butyl group, a cyclopropyl group, a cyclobutyl group and a cyclohexyl group. The monovalent aliphatic hydrocarbon cyclic group is preferably a cycloalkyl group.

The aryl group, alkyl group and monovalent aliphatic hydrocarbon cyclic group of R₂₀₁ to R₂₀₃ may have, as a substituent, an alkyl group (e.g., having 1 to 15 carbon atoms), a monovalent aliphatic hydrocarbon cyclic group (e.g., having 3 to 15 carbon atoms, preferably a cycloalkyl group having 3 to 15 carbon atoms), an aryl group (e.g., having 6 to 14 carbon atoms), an alkoxy group (e.g., having 1 to 15 carbon atoms), a halogen atom, a hydroxyl group, or a phenylthio group. The substituents are preferably a linear or branched alkyl group having 1 to 12 carbon atoms, a monovalent aliphatic hydrocarbon cyclic group having 3 to 12 carbon atoms (preferably a cycloalkyl group having 3 to 12 carbon atoms), and a linear, branched or cyclic alkoxy group having 1 to 12 carbon atoms, and more preferably an alkyl group having 1 to 4 carbon atoms, and an alkoxy group having 1 to 4 carbon atoms. The substituent may be substituted on any one of three R₂₀₁ to R₂₀₃, or may be substituted on all of three. Further, when R₂₀₁ to R₂₀₃ is an aryl group, it is preferred that the substituent is substituted on the p-position of the aryl group.

As more preferred groups represented by formula (ZA-1-1), triarylsulfonium and the structure represented by the following formula (ZA-1-1A) or (ZA-1-1B) are exemplified.

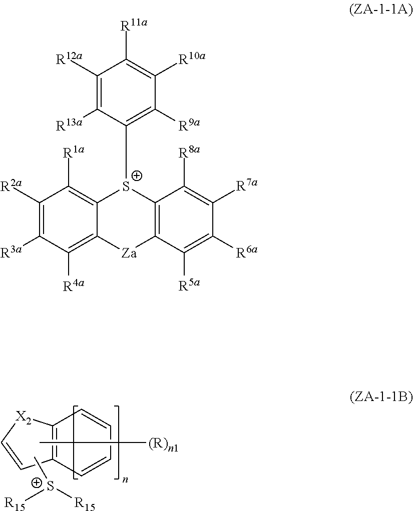

In formula (ZA-1-1A), each of R^{1a} to R^{13a} independently represents a hydrogen atom or a substituent.

Za represents a single bond or a divalent linking group.

The alcoholic hydroxyl group in the invention means a hydroxyl group bonded to the carbon atom of a chain-like or cyclic alkyl group.

It is preferred that at least one of R^{1a} to R^{13a} represents a substituent containing an alcoholic hydroxyl group, and more preferably at least one of R^{9a} to R^{13a} contains an alcoholic hydroxyl group.

When each of R^{1a} to R^{13a} represents a substituent containing an alcoholic hydroxyl group, each of R^{1a} to R^{13a} is represented by —W—Y, provided that Y is a chain-like or cyclic alkyl group substituted with a hydroxyl group, and W is a single bond or a divalent linking group.

The examples of the chain-like or cyclic alkyl group of Y include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, a cyclopropyl group, a cyclopentyl group, a cyclohexyl group, an adamantyl group, a norbonyl group, and a boronyl group, preferably an ethyl group, a propyl group, an isopropyl group, an n-butyl group, an isobutyl group, and a sec-butyl group, and more preferably an ethyl group, a propyl group, and an isopropyl group. Especially preferably Y contains a —CH₂CH₂OH structure.

W preferably represents a single bond, or a divalent group obtained by substituting a single bond for an arbitrary hydrogen atom of an alkoxy group, an acyloxy group, an acylamino group, an alkylsulfonylamino group, an arylsulfonylamino group, an alkylthio group, an alkylsulfonyl group, an acyl group, an alkoxycarbonyl group, or a carbamoyl group, and more preferably represents a single bond, or a divalent group obtained by substituting a single bond for an arbitrary hydrogen atom of an acyloxy group, an alkylsulfonyl group, an acyl group, or an alkoxycarbonyl group.

When each of R^{1a} to R^{13a} represents a substituent containing an alcoholic hydroxyl group, the number of carbon atoms contained is preferably 2 to 10, more preferably 2 to 6, and especially preferably 2 to 4.

The substituent containing an alcoholic hydroxyl group as R^{1a} to R^{13a} may contain two or more alcoholic hydroxyl groups. The number of the alcoholic hydroxyl groups in the substituent containing an alcoholic hydroxyl group as R^{1a} to R^{13a} is 1 to 6, preferably 1 to 3, and more preferably 1.

The number of the alcoholic hydroxyl groups contained in the compound represented by formula (ZA-1-1A) is preferably 1 to 10 in total of R^{1a} to R^{13a}, more preferably 1 to 6, and still more preferably 1 to 3.

When each of R^{1a} to R^{13a} does not contain an alcoholic hydroxyl group, each of R^{1a} to R^{13a} preferably represents a hydrogen atom, a halogen atom, an alkyl group, a monovalent aliphatic hydrocarbon cyclic group (preferably a cycloalkyl group), an alkenyl group (including a cycloalkenyl group and a bicycloalkenyl group), an alkynyl group, an aryl group, a cyano group, a carboxyl group, an alkoxy group, an aryloxy group, an acyloxy group, a carbamoyloxy group, an acylamino group, an aminocarbonylamino group, an alkoxycarbonylamino group, an aryloxycarbonylamino group, a sulfamoylamino group, an alkylsulfonylamino group, an arylsulfonylamino group, an alkylthio group, an arylthio group, a sulfamoyl group, an alkylsulfonyl group, an arylsulfonyl group, an aryloxycarbonyl group, an alkoxycarbonyl group, a carbamoyl group, an imido group, a silyl group, or a ureido group.

When each of R^{1a} to R^{13a} does not contain an alcoholic hydroxyl group, each of R^{1a} to R^{13a} more preferably represents a hydrogen atom, a halogen atom, an alkyl group, a monovalent aliphatic hydrocarbon cyclic group (preferably a cycloalkyl group), a cyano group, an alkoxy group, an acyloxy group, an acylamino group, an aminocarbonylamino group, an alkoxycarbonylamino group, an alkylsulfonylamino group, an arylsulfonylamino group, an alkylthio group, a sulfamoyl group, an alkylsulfonyl group, an arylsulfonyl group, an alkoxycarbonyl group, or a carbamoyl group.

Further, when each of R^{1a} to R^{13a} does not contain an alcoholic hydroxyl group, each of R^{1a} to R^{13a} especially preferably represents a hydrogen atom, an alkyl group, a monovalent aliphatic hydrocarbon cyclic group (preferably a cycloalkyl group), a halogen atom, or an alkoxy group.

Contiguous two of R^{1a} to R^{13a} can also form a ring together (e.g., aromatic or non-aromatic hydrocarbon rings or heterocyclic rings, and these rings may be combined to form polycyclic condensed rings, e.g., a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxthine ring, a phenothiazine ring, and a phenazine ring are exemplified).

Za represents a single bond or a divalent linking group. The examples of the divalent linking groups include an alkylene group, an arylene group, a carbonyl group, a sulfonyl group, a carbonyloxy group, a carbonylamino group, a sulfonylamido group, an ether group, a thioether group, an amino group, a disulfide group, an acyl group, an alkylsulfonyl group, —CH═CH—, —C≡C—, an aminocarbonylamino group and an aminosulfonylamino group, which groups may have a substituent. The substituents of these groups are the same as those as described in R^{1a} to R^{13a}. Za preferably represents a single bond, or a substituent not having an electron-withdrawing property, such as an alkylene group, an arylene group, an ether group, a thioether group, an amino group, —CH═CH—, —C≡C—, an aminocarbonylamino group, or an aminosulfonylamino group, more preferably a single bond, an ether group, or a thioether group, and especially preferably a single bond.

In the next place, formula (ZA-1-1B) is described.

In formula (ZA-1-1B), each of R₁₅ independently represents an alkyl group, a monovalent aliphatic hydrocarbon cyclic group (preferably a cycloalkyl group), or an aryl group. Two R₁₅ may be bonded to each other to form a ring.

X₂ represents any of —CR₂₁═CR₂₂—, —NR₂₃—, —S—, and —O—, where each of R₂₁ and R₂₂ independently represents a hydrogen atom, an alkyl group, a monovalent aliphatic hydrocarbon cyclic group (preferably a cycloalkyl group), or an aryl group. R₂₃ represents a hydrogen atom, an alkyl group, a monovalent aliphatic hydrocarbon cyclic group (preferably a cycloalkyl group), an aryl group, or an acyl group.

When two or more R's are present, each of R independently represents a substituent. As the substituents for R, for example, corresponding groups in formulae (ZI-1) to (ZI-3), which are described below as preferred embodiments of formula (ZA-1-1B).

n represents an integer of 0 to 3.

n1 represents an integer of 0 to 11.

The alkyl group in R₁₅, R₂₁ to R₂₃ may have a substituent, preferably a linear or branched alkyl group having 1 to 20 carbon atoms, and may have an oxygen atom, a sulfur atom or a nitrogen atom in the alkyl chain.

As the alkyl group having a substituent, in particular, a group wherein a linear or branched alkyl group is substituted with a monovalent aliphatic hydrocarbon cyclic group (preferably a cycloalkyl group) (e.g., an adamantylmethyl group, an adamantylethyl group, a cyclohexylethyl group, and a camphor residue) can be exemplified.

The monovalent aliphatic hydrocarbon cyclic group in R₁₅, R₂₁ to R₂₃ may have a substituent, preferably a cycloalkyl group, and more preferably a cycloalkyl group having 3 to 20 carbon atoms, and may have an oxygen atom in the ring.

The aryl group in R₁₅, R₂₁ to R₂₃ may have a substituent, preferably an aryl group having 6 to 14 carbon atoms.

The specific examples and preferred range of the alkyl group in the acyl group in R²³ are the same as those in the alkyl group as described above.

As the examples of the substituents that the above groups may have, for example, a halogen atom, a hydroxyl group, a nitro group, a cyano group, a carboxyl group, a carbonyl group, an alkyl group (preferably having 1 to 10 carbon atoms), a monovalent aliphatic hydrocarbon cyclic group (preferably having 3 to 10 carbon atoms, and more preferably a cycloalkyl group having 3 to 10 carbon atoms), an aryl group (preferably having 6 to 14 carbon atoms), an alkoxy group (preferably having 1 to 10 carbon atoms), an aryloxy group (preferably having 6 to 14 carbon atoms), an acyl group (preferably having 2 to 20 carbon atoms), an acyloxy group (preferably having 2 to 10 carbon atoms), an alkoxycarbonyl group (preferably having 2 to 20 carbon atoms), an aminoacyl group (preferably having 2 to 20 carbon atoms), an alkylthio group (preferably having 1 to 10 carbon atoms), and an arylthio group (preferably having 6 to 14 carbon atoms) are exemplified. The cyclic structure in the aryl group and monovalent aliphatic hydrocarbon cyclic group, and aminoacyl group may further have an alkyl group (preferably having 1 to 20 carbon atoms) as a substituent.

The ring formed by bonding two R₁₅ to each other is a cyclic structure formed together with —S⁺ shown in formula (ZA-1-1B), and is preferably a 5-membered ring containing one sulfur atom or a condensed ring containing the 5-membered ring. In the case of a condensed ring, it is preferred to contain 1 sulfur atom and 18 or less carbon atoms, and more preferably a cyclic structure represented by any of the following formulae (IV-1) to (IV-3).

In the formulae, * represents a bond. R represents an arbitrary substituent, for example, the same substituent as the one that each group in R₁₅, R₂₁ to R₂₃ may have is exemplified. n represents an integer of 0 to 4.

n2 represents an integer of 0 to 3.

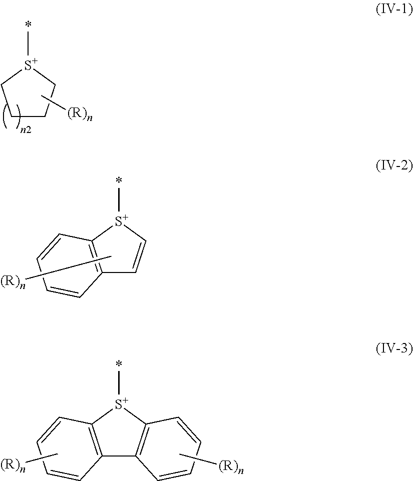

Of the compounds represented by formula (ZA-1-1B), the following cationic structures (ZI-1) to (ZI-3) are exemplified as preferred cationic structures.

The cationic structure (ZI-1) is a structure represented by the following formula (ZI-1).

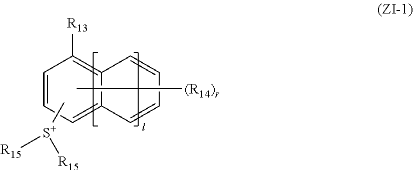

In formula (ZI-1), R₁₃ represents a hydrogen atom, a fluorine atom, a hydroxyl group, an alkyl group, a monovalent aliphatic hydrocarbon cyclic group, an alkoxy group, an alkoxycarbonyl group, or a group having a monocyclic or polycyclic cycloalkyl skeleton.

When two or more R₁₄ are present, each R₁₄ independently represents an alkyl group, a monovalent aliphatic hydrocarbon cyclic group, an alkoxy group, an alkylsulfonyl group, a cycloalkylsulfonyl group, a hydroxyl group, or a group having a monocyclic or polycyclic cycloalkyl skeleton.

Each R₁₅ independently represents an alkyl group, a monovalent aliphatic hydrocarbon cyclic group, or an aryl group. Two R₁₅ may be bonded to each other to form a ring.

l represents an integer of 0 to 2.

r represents an integer of 0 to 8.

In formula (ZI-1), the alkyl group of R₁₃, R₁₄ and R₁₅ is a linear or branched alkyl group preferably having 1 to 10 carbon atoms, and the examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group and an n-decyl group. Of these alkyl groups, a methyl group, an ethyl group, an n-butyl group, and a t-butyl group are more preferred.

The monovalent aliphatic hydrocarbon cyclic group of R₁₃, R₁₄ and R₁₅ may be monocyclic or polycyclic and preferably having 3 to 12 carbon atoms, and the examples include cyclopropyl, cyclobutyl, cyclopentyl, cyclohexyl, cycloheptyl, cyclooctyl, cyclododecanyl, cyclopentenyl, cyclohexenyl, cyclooctadienyl, bicycloheptyl (norbornyl), and adamantyl, and more preferably cyclopropyl, cyclopentyl, cyclohexyl, and cyclooctyl. The monovalent aliphatic hydrocarbon cyclic group is preferably a cycloalkyl group.

The aryl group of R₁₅ is preferably an aryl group having 6 to 14 carbon atoms, and more preferably a phenyl group or a naphthyl group.

The alkoxy group of R₁₃ and R₁₄ is linear or branched, preferably having 1 to 10 carbon atoms, and the examples include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group. Of these alkoxy groups, a methoxy group, an ethoxy group, an n-propoxy group, and an n-butoxy group are preferred.

The alkoxycarbonyl group of R₁₃ is linear or branched, preferably having 2 to 11 carbon atoms, and those obtained by substituting the alkyl group in R₁₃, R₁₄ and R₁₅ with a carbonyl group are exemplified. The examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, and an n-decyloxycarbonyl group. Of these alkoxycarbonyl groups, a methoxycarbonyl group, an ethoxycarbonyl group, and an n-butoxycarbonyl group are more preferred.

As the group having a monocyclic or polycyclic cycloalkyl skeleton of R₁₃ and R₁₄, for example, a monocyclic or polycyclic cycloalkyloxy group and an alkoxy group having a monocyclic or polycyclic cycloalkyl skeleton are exemplified, each of which groups may further have a substituent.

The monocyclic or polycyclic cycloalkyloxy group of R₁₃ and R₁₄ preferably has a total carbon atom number of 7 or more, more preferably a total carbon atom number of 7 to 15, and preferably has a monocyclic cycloalkyl skeleton. The monocyclic cycloalkyloxy group having a total carbon atom number of 7 or more is a monocyclic cycloalkyloxy group having an arbitrary substituent such as an alkyl group, e.g., a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, or an isoamyl group, a hydroxyl group, a halogen atom (e.g., fluorine, chlorine, bromine, iodine), a nitro group, a cyano group, an amido group, a sulfonamido group, an alkoxy group, e.g., a methoxy group, an ethoxy group, a hydroxyethoxy group, a propoxy group, a hydroxypropoxy group, or a butoxy group, an alkoxycarbonyl group, e.g., a methoxycarbonyl group, or an ethoxycarbonyl group, an acyl group, e.g., a formyl group, an acetyl group, or a benzoyl group, an acyloxy group, e.g., an acetoxy group, or a butyryl group, or a carboxy group on a cycloalkyloxy group, such as a cyclopropyloxy group, a cyclobutyloxy group, a cyclopentyloxy group, a cyclohexyloxy group, a cycloheptyloxy group, a cyclooctyloxy group, or a cyclododecanyloxy group. The total carbon atom number of the monocyclic cycloalkyloxy group is 7 or more in total of the arbitrary substituent on the cycloalkyl group.

The examples of the polycyclic cycloalkyloxy group having a total carbon atom number of 7 or more include a norbornyloxy group, a tricyclodecanyloxy group, a tetracyclodecanyloxy group, and an adamantyloxy group.

The total carbon atom number of the alkoxy group having a monocyclic or polycyclic cycloalkyl skeleton of R₁₃ and R₁₄ is preferably 7 or more, more preferably 7 to 15, and preferably an alkoxy group having a monocyclic cycloalkyl skeleton. The alkoxy group having a monocyclic cycloalkyl skeleton and a total carbon atom number of 7 or more is an alkoxy group substituted with the above-described monocyclic cycloalkyl group which may have a substituent, on an alkoxy group, such as a methoxy group, an ethoxy group, a propoxy group, a butoxy group, a pentyloxy group, a hexyloxy group, a heptoxy group, an octyloxy group, a dodecyloxy group, a 2-ethylhexyloxy group, an isopropoxy group, a sec-butoxy group, a t-butoxy group, or an isoamyloxy group, and the carbon atom number in total of 7 or more including the substituent. The examples thereof include a cyclohexylmethoxy group, a cyclopentylethoxy group, and a cyclohexylethoxy group, and a cyclohexylmethoxy group is preferred.

As the alkoxy group having a polycyclic cycloalkyl structure and a total carbon atom number of 7 or more, a norbornylmethoxy group, a norbornylethoxy group, a tricyclodecanylmethoxy group, a tricyclodecanylethoxy group, a tetracyclodecanylmethoxy group, tetracyclodecanylethoxy group, an adamantantylmethoxy group, and an adamantantylethoxy group are exemplified, and a norbornylmethoxy group and a norbornylethoxy group are preferred.

The alkylsulfonyl group and cycloalkylsulfonyl group of R₁₄ is linear, branched or cyclic, preferably having 1 to 10 carbon atoms. For example, the groups obtained by substituting the alkyl groups in R₁₃, R₁₄ and R₁₅ with a sulfonyl group are exemplified. The examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, and a cyclohexanesulfonyl group. Of these alkylsulfonyl groups and cycloalkylsulfonyl groups, a methanesulfonyl group, an ethanesulfonyl group, an n-propanesulfonyl group, an n-butanesulfonyl group, a cyclopentanesulfonyl group, and a cyclohexanesulfonyl group are more preferred.

l is preferably 0 or 1, and more preferably 1.

r is preferably 0 to 2.

Each group of R₁₃, R₁₄ and R₁₅ may further have a substituent, and the examples of such substituents include an alkyl group, e.g., a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, and an iso-amyl group, a monovalent aliphatic hydrocarbon cyclic group (which may be monocyclic or polycyclic, preferably having 3 to 20 carbon atoms, more preferably 5 to 8 carbon atoms), a hydroxyl group, a halogen atom (e.g., fluorine, chlorine, bromine, iodine), a nitro group, a cyano group, an amido group, a sulfonamide group, an alkoxy group, an alkoxyalkyl group, an alkoxycarbonyl group, an alkoxycarbonyloxy group, a formyl group, an acetyl group, an acyl group, e.g., a benzoyl group, an acyloxy group, e.g., an acetoxy group, a butyryloxy group, and a carboxyl group.

As the alkoxy group, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group are exemplified.

As the alkoxyalkyl group, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group are exemplified.

As the alkoxycarbonyl group, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, and a cyclopentyloxycarbonyl group, a cyclohexyloxycarbonyl group are exemplified.

As the alkoxycarbonyloxy group, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxy-carbonyloxy group, an n-butoxycarbonyloxy group, a t-butoxycarbonyloxy group, a cyclopentyloxycarbonyloxy group, and a cyclohexyloxycarbonyloxy group are exemplified.

The cyclic structure which may be formed by bonding two of R₁₅ to each other is a 5- or 6-membered ring formed by a divalent group formed by bonding two of R₁₅ together with the sulfur atom in formula (ZI-1), especially preferably a 5-membered ring (i.e., a tetrahydrothiophene ring), and the ring may be condensed with an aryl group or an aliphatic hydrocarbon cyclic group (preferably a cycloalkyl group). The divalent group may have a substituent, and the examples of the substituents include an alkyl group, a cycloalkyl group, a hydroxyl group, a carboxyl group, a cyano group, a nitro group, an alkoxy group, an alkoxyalkyl group, an alkoxycarbonyl group, and an alkoxycarbonyloxy group.

R₁₅ in formula (ZI-1) is preferably a methyl group, an ethyl group, a naphthyl group, or a divalent group in the case of forming a tetrahydrothiophene cyclic structure by bonding two of R₁₅ and together with the sulfur atom.

The alkyl group, the monovalent aliphatic hydrocarbon cyclic group, the alkoxy group, and the alkoxycarbonyl group in R₁₃, and the alkyl group, the monovalent aliphatic hydrocarbon cyclic group, the alkoxy group, the alkylsulfonyl group, the cycloalkylsulfonyl group in R₁₄ may be substituted as described above, and as the substituents, a hydroxyl group, an alkoxy group, an alkoxycarbonyl group, and a halogen atom (in particular, a fluorine atom) are preferred.

Preferred specific examples of the cationic structures represented by formula (ZI-1) are shown below.

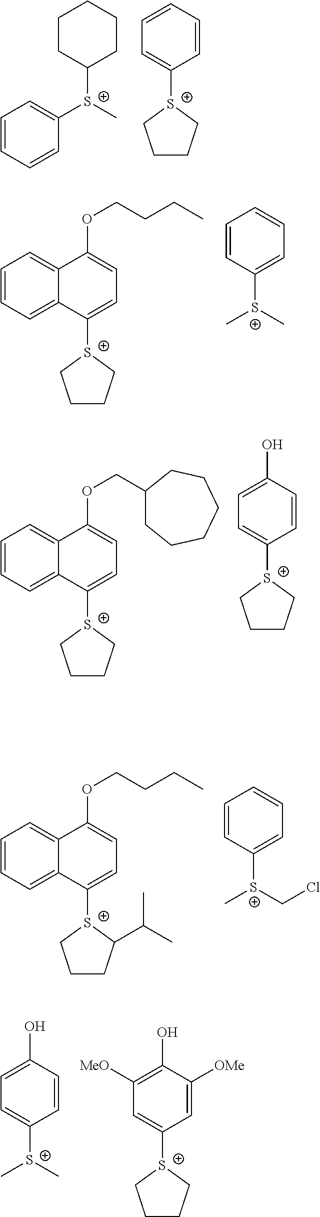

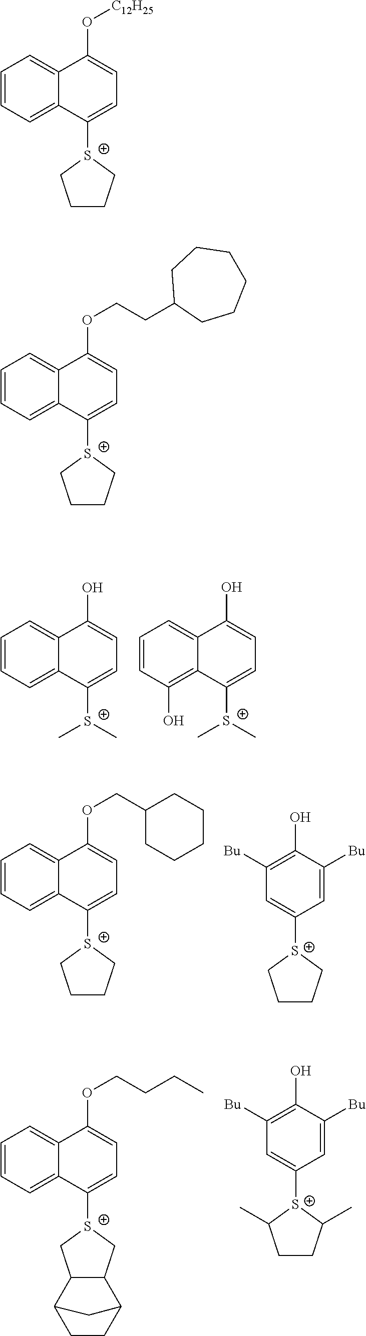

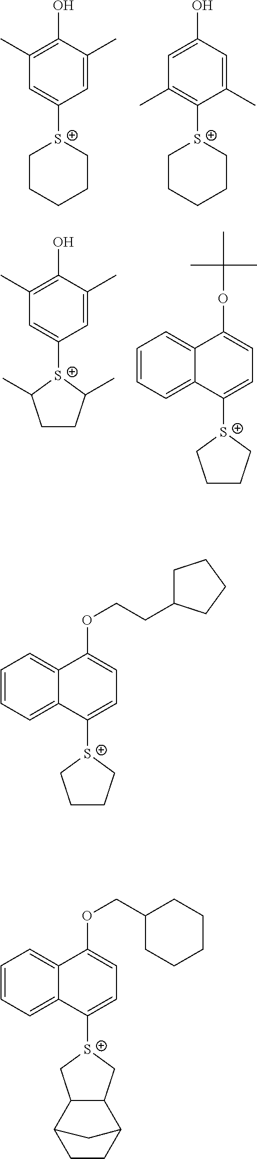

The cationic structure (ZI-2) is a structure represented by the following formula (ZI-2).

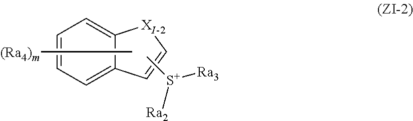

In formula (ZI-2), X_{I-2} represents an oxygen atom, a sulfur atom, or an —NRa₁— group, and Ra₁ represents a hydrogen atom, an alkyl group, a monovalent aliphatic hydrocarbon cyclic group, an aryl group, or an acyl group.

Each of Ra₂ and Ra₃ independently represents an alkyl group, a monovalent aliphatic hydrocarbon cyclic group, an alkenyl group, or an aryl group. Ra₂ and Ra₃ may be bonded to each other to form a ring.

In the case where two or more Ra₄ are present, each Ra₄ independently represents a monovalent group.

m represents an integer of 0 to 3.

The alkyl group of Ra₁ to Ra₃ is preferably a linear or branched alkyl group having 1 to 20 carbon atoms, e.g., a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, a undecyl group, a dodecyl group, a tridecyl group, a tetradecyl group, a pentadecyl group, a hexadecyl group, a heptadecyl group, an octadecyl group, a nonadecyl group, and an eicosyl group can be exemplified.

The monovalent aliphatic hydrocarbon cyclic group of Ra₁ to Ra₃ is preferably a monovalent aliphatic hydrocarbon cyclic group having 3 to 20 carbon atoms, e.g., a cyclopropyl group, a cyclobutyl group, a cyclopentyl group, a cyclohexyl group, a cyclooctyl group, an adamantyl group, a norbornyl group, an isoboronyl group, a camphanyl group, a dicyclopentyl group, an α-pinel group, a tricyclodecanyl group, a tetracyclododecyl group, and an androstanyl group can be exemplified. The monovalent aliphatic hydrocarbon cyclic group is preferably a cycloalkyl group.

The aryl group of Ra₁ to Ra₃ is preferably an aryl group having 6 to 10 carbon atoms, e.g., a phenyl group and a naphthyl group can be exemplified.

The acyl group of Ra₁ is preferably an acyl group having 2 to 20 carbon atoms, e.g., a formyl group, an acetyl group, a propanoyl group, a butanoyl group, a pivaloyl group, and a benzoyl group can be exemplified.

The alkenyl group of Ra₂ and Ra₃ is preferably an alkenyl group having 2 to 15 carbon atoms, e.g., a vinyl group, an allyl group, a butenyl group, and a cyclohexenyl group can be exemplified.

As the cyclic structure which may be formed by bonding Ra₂ and Ra₃ to each other, a group for forming a 5- or 6-membered ring together with the sulfur atom in formula (ZI-2), especially preferably a 5-membered ring (i.e., a tetrahydrothiophene ring), is preferred, which group may contain an oxygen atom. Specifically, the same ring with the ring which may be formed by bonding R₁₅ in formula (ZI-1) to each other is exemplified.

As the monovalent group of Ra₄, for example, an alkyl group (preferably having 1 to 20 carbon atoms), a monovalent aliphatic hydrocarbon cyclic group (preferably having 3 to 20 carbon atoms, and more preferably a cycloalkyl group having 3 to 20 carbon atoms), an aryl group (preferably having 6 to 10 carbon atoms), an alkoxy group (preferably having 1 to 20 carbon atoms), an acyl group (preferably having 2 to 20 carbon atoms), an acyloxy group (preferably having 2 to 20 carbon atoms), a fluorine atom, a chlorine atom, a bromine atom, an iodine atom, a hydroxyl group, a carboxyl group, a nitro group, a cyano group, an alkoxycarbonyl group, an alkylsolfonyl group, an arylsulfonyl group, an arylcarbonyl group, an alkylcarbonyl group, and an alkenylcarbonyl group can be exemplified.

Ra₁ is more preferably an alkyl group, and still more preferably an alkyl group having 1 to 4 carbon atoms.

Ra₂ and Ra₃ are more preferably linked to each other to form a 5- or 6-membered ring.

Each group in Ra₁ to Ra₄ may further have a substituent. As such further substituents, the same substituents with the further substituents that each group of R₁₃ to R₁₅ in (ZI-1) may have are exemplified.

The preferred specific examples of the cations in the compound represented by formula (ZI-2) are shown below.

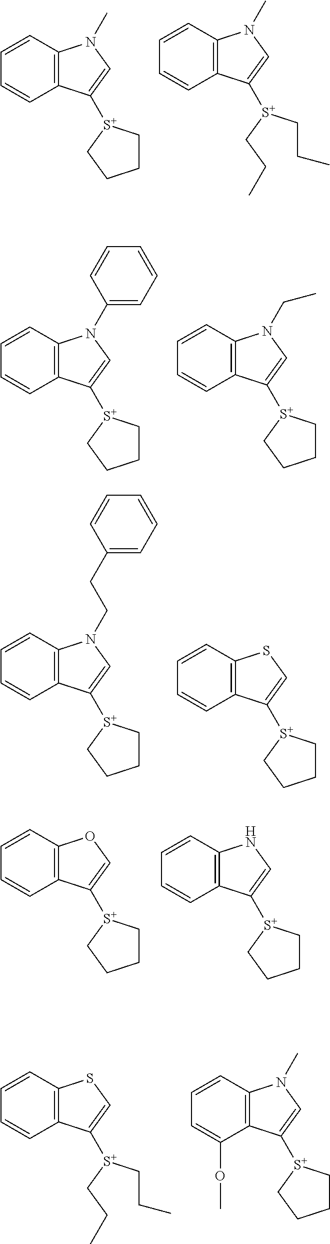

The cationic structure (ZI-3) is a structure represented by the following formula (ZI-3).

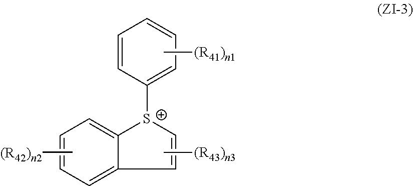

In formula (ZI-3), each of R₄₁ to R₄₃ independently represents an alkyl group, an acetyl group, an alkoxy group, a carboxyl group, a halogen atom, a hydroxyl group, or a hydroxyalkyl group. The alkyl group and alkoxy group as R₄₁ to R₄₃ are the same with those of R₁₃ to R₁₅ in formula (ZI-1).

The hydroxyalkyl group is preferably a hydroxyalkyl group in which one or two or more hydrogen atoms are substituted with a hydroxyl group, and a hydroxymethyl group, a hydroxyethyl group, and a hydroxypropyl group are exemplified.

n1 is an integer of 0 to 3, preferably 1 or 2, and more preferably 1.

n2 is an integer of 0 to 3, preferably 0 or 1, and more preferably 0.

n3 is an integer of 0 to 2, preferably 0 or 1, and more preferably 1.

Each group in R₄₁ to R₄₃ may further have a substituent, and as the substituents, the same substituents with the substituents that each group of R₁₃ to R₁₅ in formula (ZI-1) may have are exemplified.

Preferred specific examples of the cations in the compound represented by formula (ZI-3) are shown below.

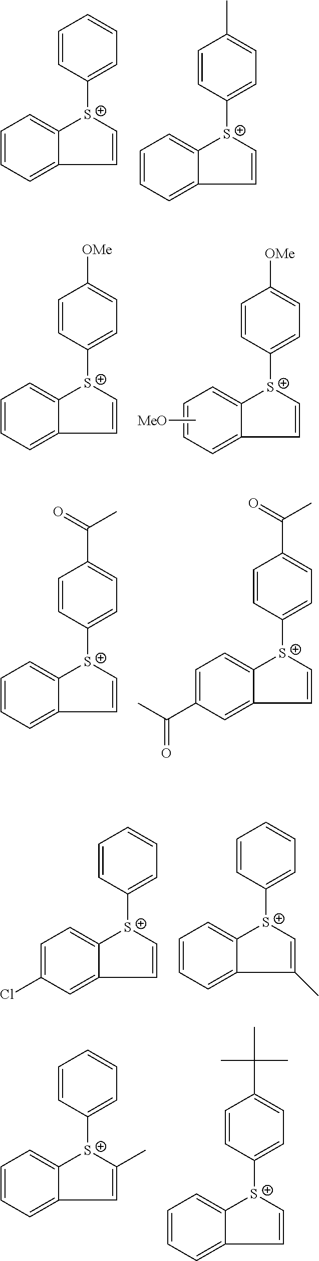

Of the cationic structures represented by formulae (ZI-1) to (ZI-3), preferred are (ZI-1) and (ZI-2), and more preferred is (ZI-1).

In the next place, (ZA-1-2) is described.

(ZA-1-2) represents an organic group in which each of R₂₀₁ to R₂₀₃ in (ZI-1) independently represents an organic group not having an aromatic ring. The aromatic ring here means to include an aromatic ring containing a heteroatom.

The organic group not containing an aromatic ring as R₂₀₁ to R₂₀₃ is generally an organic group having 1 to 30 carbon atoms, and preferably 1 to 20 carbon atoms.

Each of R₂₀₁ to R₂₀₃ independently preferably represents an alkyl group, a monovalent aliphatic hydrocarbon cyclic group, an allyl group, or a vinyl group, more preferably a linear or branched 2-oxoalkyl group, 2-oxo aliphatic hydrocarbon cyclic group, or alkoxycarbonylmethyl group, and especially preferably a linear or branched 2-oxo aliphatic hydrocarbon cyclic group.

As the alkyl group and aliphatic hydrocarbon cyclic group of R₂₀₁ to R₂₀₃, a linear or branched alkyl group having 1 to 10 carbon atoms (e.g., a methyl group, an ethyl group, a propyl group, a butyl group, a pentyl group), and an aliphatic hydrocarbon cyclic group having 3 to 10 carbon atoms (e.g., a cyclopentyl group, a cyclohexyl group, a norbonyl group) can be preferably exemplified. The alkyl group is more preferably a 2-oxoalkyl group and an alkoxycarbonylmethyl group. The aliphatic hydrocarbon cyclic group is more preferably a 2-oxo aliphatic hydrocarbon cyclic group. The aliphatic hydrocarbon cyclic group is preferably a cycloalkyl group.

The 2-oxoalkyl group may be either linear or branched, and is preferably a group having >C═O at the 2-position of the above alkyl group.

The 2-oxo aliphatic hydrocarbon cyclic group is preferably a group having >C═O at the 2-position of the above aliphatic hydrocarbon cyclic group. The 2-oxo aliphatic hydrocarbon cyclic group is preferably a 2-oxocycloalkyl group.

The alkoxy group in the alkoxycarbonylmethyl group is preferably an alkoxy group having 1 to 5 carbon atoms (e.g., a methoxy group, an ethoxy group, a propoxy group, a butoxy group, a pentoxy group).

R₂₀₁ to R₂₀₃ may further be substituted with a halogen atom, an alkoxy group (e.g., having 1 to 5 carbon atoms), a hydroxyl group, a cyano group, or a nitro group.

(ZA-1-3) is described in the next place.

(ZA-1-3) is a group represented by the following formula, and is a group having a phenacylsulfonium salt structure.

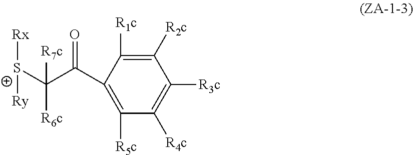

In formula (ZA-1-3), each of R₁c to R₅c independently represents a hydrogen atom, an alkyl group, a monovalent aliphatic hydrocarbon cyclic group, an alkoxy group, a phenylthio group, or a halogen atom.

Each of R₆c and R₇c independently represents a hydrogen atom, an alkyl group, or a monovalent aliphatic hydrocarbon cyclic group.

Each of Rx and Ry independently represents an alkyl group, a monovalent aliphatic hydrocarbon cyclic group, an allyl group, or a vinyl group.

Any two or more of R₁c to R₅c, R₆c and R₇c, and Rx and Ry may be bonded to each other to form a ring, and the ring may contain an oxygen atom, a sulfur atom, an ester bond, or an amido bond. As the group formed by bonding any two or more of R₁c to R₅c, R₆c and R₇c, and Rx and Ry, a butylene group and a pentylene group can be exemplified.

The alkyl group as R₁c to R₇c may be either linear or branched, and the examples thereof include an alkyl group having 1 to 20 carbon atoms, and preferably a linear or branched alkyl group having 1 to 12 carbon atoms (e.g., a methyl group, an ethyl group, a linear or branched propyl group, a linear or branched butyl group, and a linear or branched pentyl group).

The monovalent aliphatic hydrocarbon cyclic group as R₁c to R₇c may be either monocyclic or polycyclic, and the examples thereof include a monovalent aliphatic hydrocarbon cyclic group having 3 to 8 carbon atoms (e.g., a cyclopentyl group and a cyclohexyl group). The monovalent aliphatic hydrocarbon cyclic group is preferably a cycloalkyl group.

The alkoxy group as R₁c to R₅c may be linear, branched or cyclic, and the examples thereof include an alkoxy group having 1 to 10 carbon atoms, and preferably a linear or branched alkoxy group having 1 to 5 carbon atoms (e.g., a methoxy group, an ethoxy group, a linear or branched propoxy group, a linear or branched butoxy group, and a linear or branched pentoxy group), a cyclic alkoxy group having 3 to 8 carbon atoms (e.g., a cyclopentyloxy group and a cyclohexyloxy group).

Preferably any of R₁c to R₅c is a linear or branched alkyl group, a monovalent aliphatic hydrocarbon cyclic group, or a linear, branched or cyclic alkoxy group, and more preferably the sum total of the carbon atoms of R₁c to R₅c is 2 to 15, by which the solubility of solvent is improved and the generation of particles during preservation is controlled.

As the alkyl group and monovalent aliphatic hydrocarbon cyclic group as Rx and Ry, the same alkyl group and monovalent aliphatic hydrocarbon cyclic group as in R₁c to R₇c can be exemplified, and more preferably a 2-oxoalkyl group, a 2-oxo aliphatic hydrocarbon cyclic group, and an alkoxycarbonylmethyl group.

As the 2-oxoalkyl group and 2-oxo aliphatic hydrocarbon cyclic group, the alkyl group and the group having >C═O at the 2-position of the aliphatic hydrocarbon cyclic group as R₁c to R₇c can be exemplified.

As for the alkoxy group in the alkoxycarbonylmethyl group, the alkoxy group same as those in R₁c to R₅c can be exemplified.

Each of Rx and Ry preferably represents an alkyl group having 4 or more carbon atoms or a monovalent aliphatic hydrocarbon cyclic group, more preferably an alkyl group having 6 or more carbon atoms, and still more preferably an alkyl group having 8 or more carbon atoms or a monovalent aliphatic hydrocarbon cyclic group.

As the cyclic structure which may be formed by bonding Rx and Ry to each other, a 5- or 6-membered ring formed by divalent groups Rx and Ry (e.g., a methylene group, an ethylene group, a propylene group, and the like) together with the sulfur atom in formula (ZA-1-3), especially preferably a 5-membered ring (i.e., a tetrahydrothiophene ring), is exemplified.

Formula (ZA-2) is described.

In formula (ZA-2), each of R₂₀₄ and R₂₀₅ independently represents an aryl group, an alkyl group, or a monovalent aliphatic hydrocarbon cyclic group.

The aryl group of R₂₀₄ and R₂₀₅ is preferably a phenyl group or a naphthyl group, and more preferably a phenyl group. The aryl group of R₂₀₄ and R₂₀₅ may be an aryl group having a heterocyclic structure containing an oxygen atom, a nitrogen atom, a sulfur atom or the like. As the aryl group having a heterocyclic structure, a pyrrole residue (a group formed by depriving pyrrole of one hydrogen atom), a furan residue (a group formed by depriving furan of one hydrogen atom), a thiophene residue (a group formed by depriving thiophene of one hydrogen atom), an indole residue (a group formed by depriving indole of one hydrogen atom), a benzofuran residue (a group formed by depriving benzofuran of one hydrogen atom), and a benzothiophene residue (a group formed by depriving benzothiophene of one hydrogen atom) can be exemplified.

As the alkyl group and the monovalent aliphatic hydrocarbon cyclic group in R₂₀₄ and R₂₀₅, preferably a linear or branched alkyl group having 1 to 10 carbon atoms (e.g., a methyl group, an ethyl group, a propyl group, a butyl group, a pentyl group), and a monovalent aliphatic hydrocarbon cyclic group having 3 to 10 carbon atoms (e.g., a cyclopentyl group, a cyclohexyl group, a norbonyl group) can be exemplified. The monovalent aliphatic hydrocarbon cyclic group is preferably a cycloalkyl group.

The aryl group, alkyl group, and monovalent aliphatic hydrocarbon cyclic group of R₂₀₄ and R₂₀₅ may have a substituent. As the examples of the substituents that the aryl group, alkyl group, and monovalent aliphatic hydrocarbon cyclic group of R₂₀₄ and R₂₀₅ may have, for example, an alkyl group (e.g., having 1 to 15 carbon atoms), a monovalent aliphatic hydrocarbon cyclic group (e.g., having 3 to 15 carbon atoms, preferably a cycloalkyl group having 3 to 15 carbon atoms), an aryl group (e.g., having 6 to 15 carbon atoms), an alkoxy group (e.g., having 1 to 15 carbon atoms), a halogen atom, a hydroxyl group, and a phenylthio group can be exemplified.

The specific examples of the cations for constituting a suitable onium salt as Z in formula (I) are shown below.

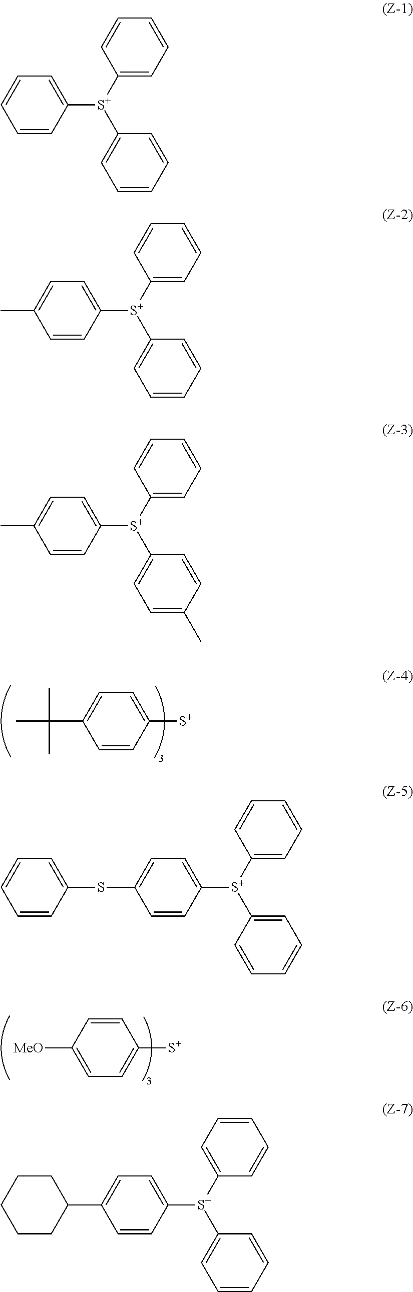

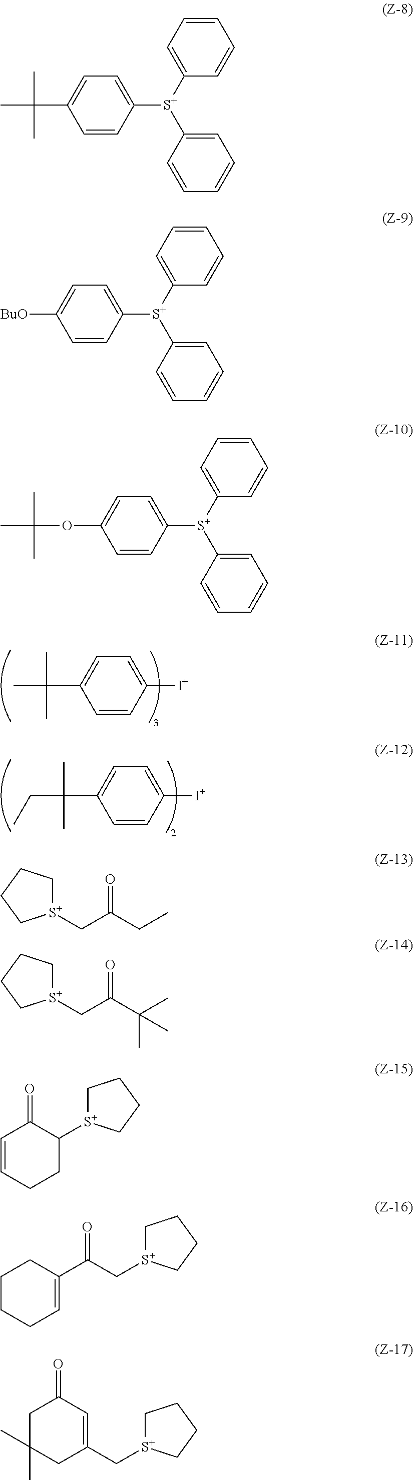

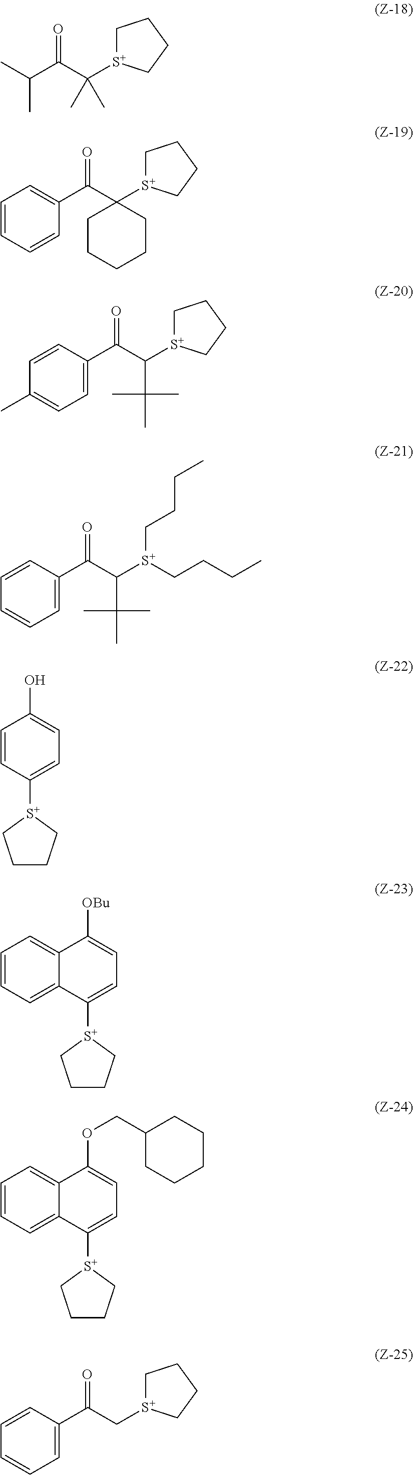

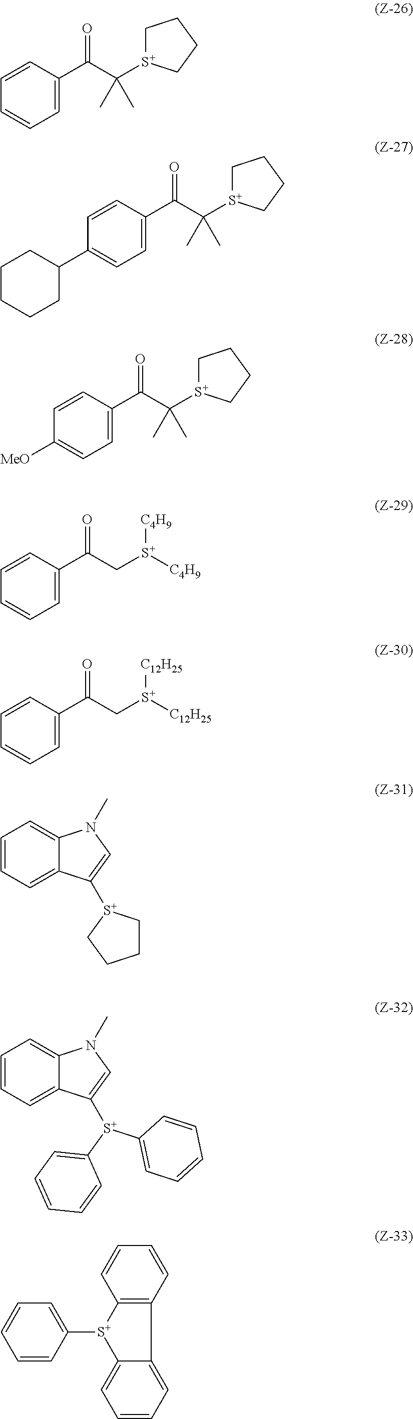

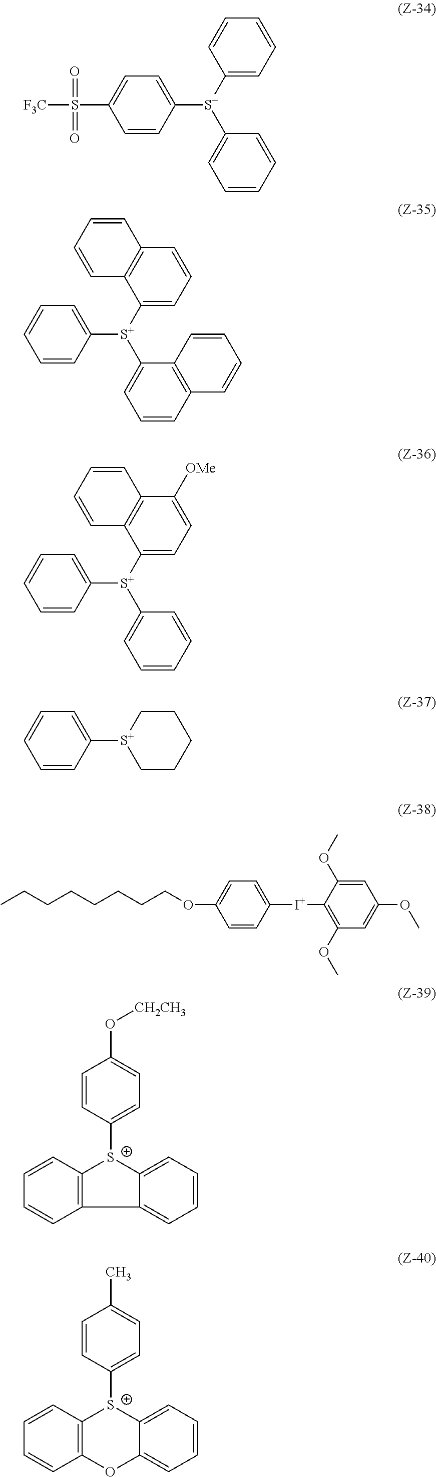

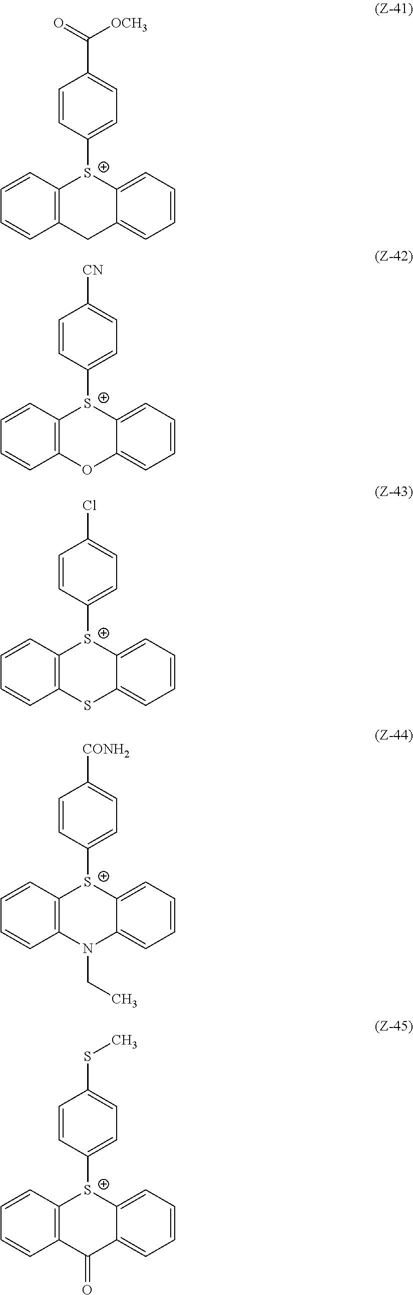 [SMILES: COC(=O)c1ccc([S+]2c3ccccc3Cc3ccccc32)cc1 ; N#Cc1ccc([S+]2c3ccccc3Oc3ccccc32)cc1 ; Clc1ccc([S+]2c3ccccc3Sc3ccccc32)cc1 ; CCN1c2ccccc2[S+](c2ccc(C(N)=O)cc2)c2ccccc21 ; CSc1ccc(-[s+]2c3ccccc3c(=O)c3ccccc32)cc1]

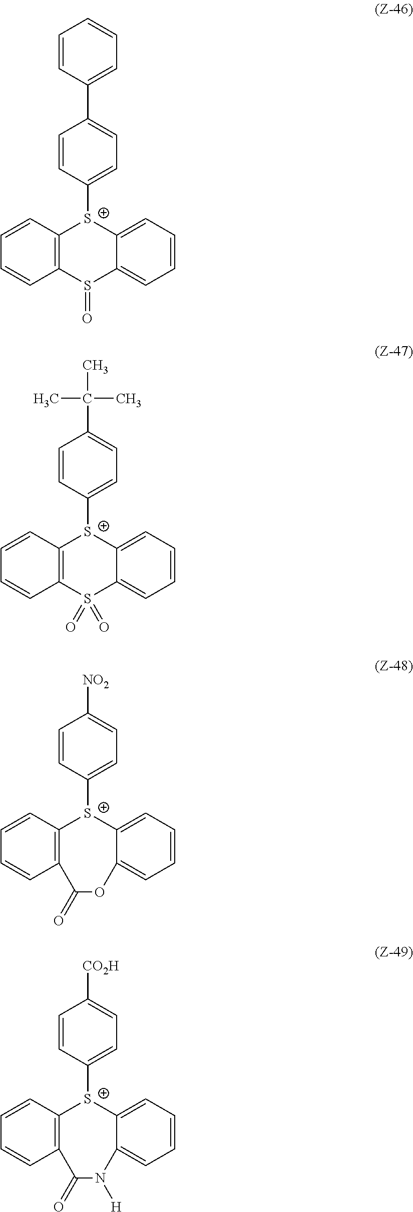 [SMILES: O=S1c2ccccc2[S+](c2ccc(-c3ccccc3)cc2)c2ccccc21 ; CC(C)(C)c1ccc([S+]2c3ccccc3S(=O)(=O)c3ccccc32)cc1 ; O=C1Oc2ccccc2[S+](c2ccc([N+](=O)[O-])cc2)c2ccccc21 ; O=C(O)c1ccc([S+]2c3ccccc3NC(=O)c3ccccc32)cc1]

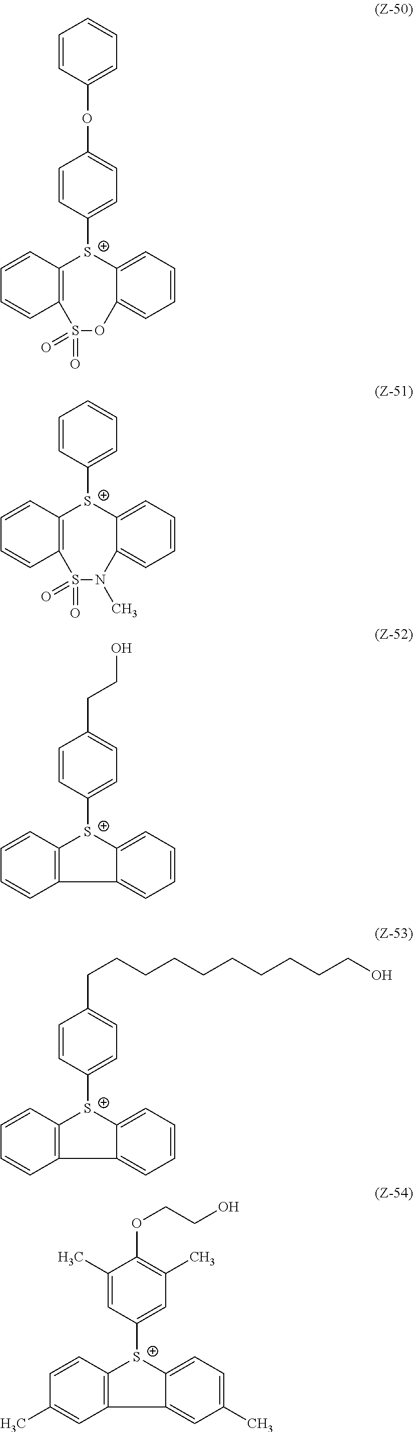

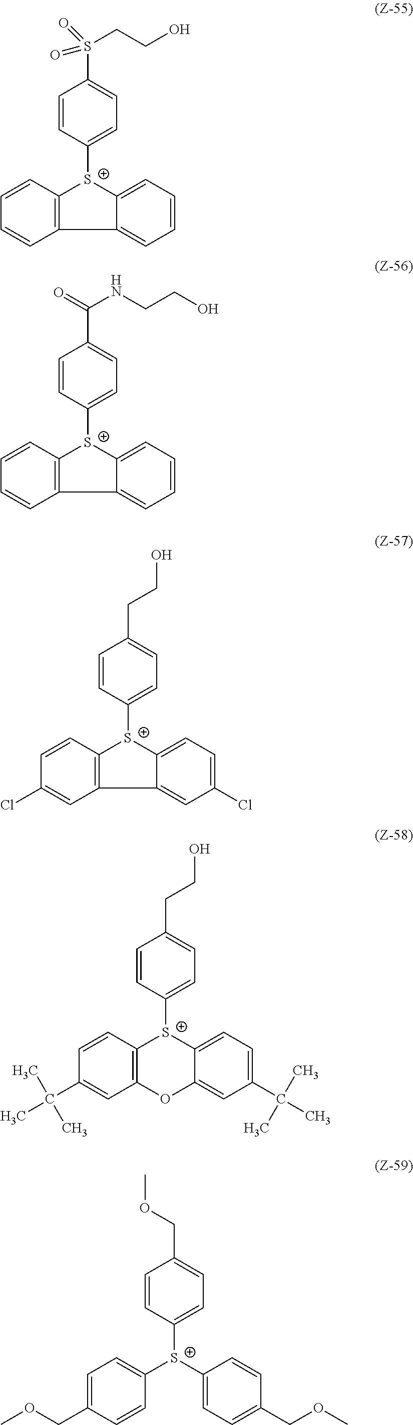

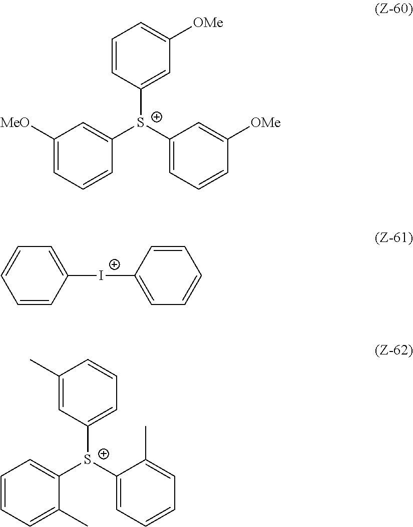 [SMILES: COc1cccc([S+](c2cccc(OC)c2)c2cccc(OC)c2)c1 ; c1ccc([I+]c2ccccc2)cc1 ; Cc1cccc([S+](c2ccccc2C)c2ccccc2C)c1]

As for the repeating unit represented by formula (I), the specific examples of the monomers corresponding to acid anions formed by leaving of cations upon irradiation with an actinic ray or radiation are shown below.

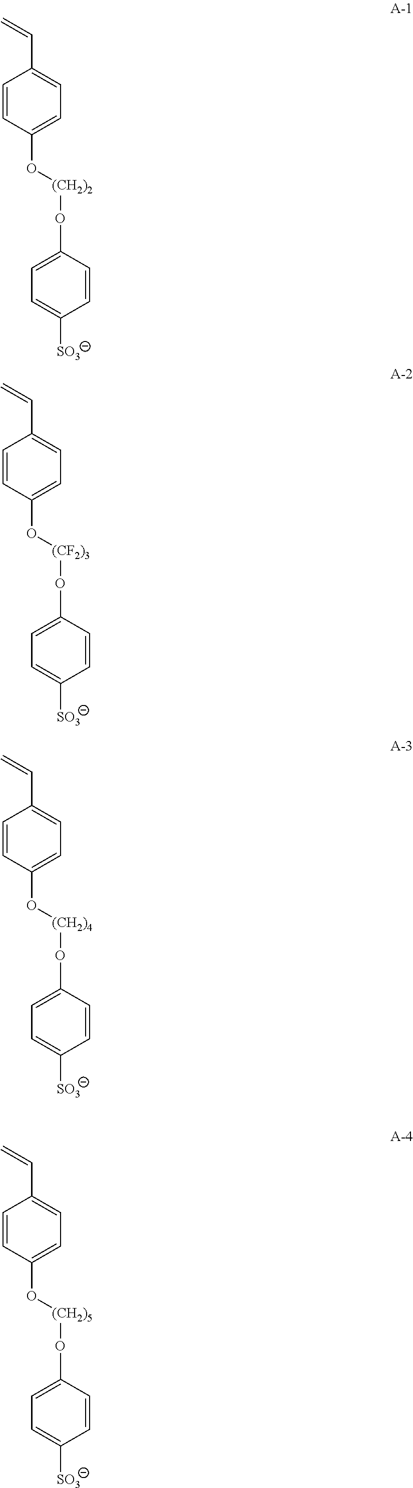

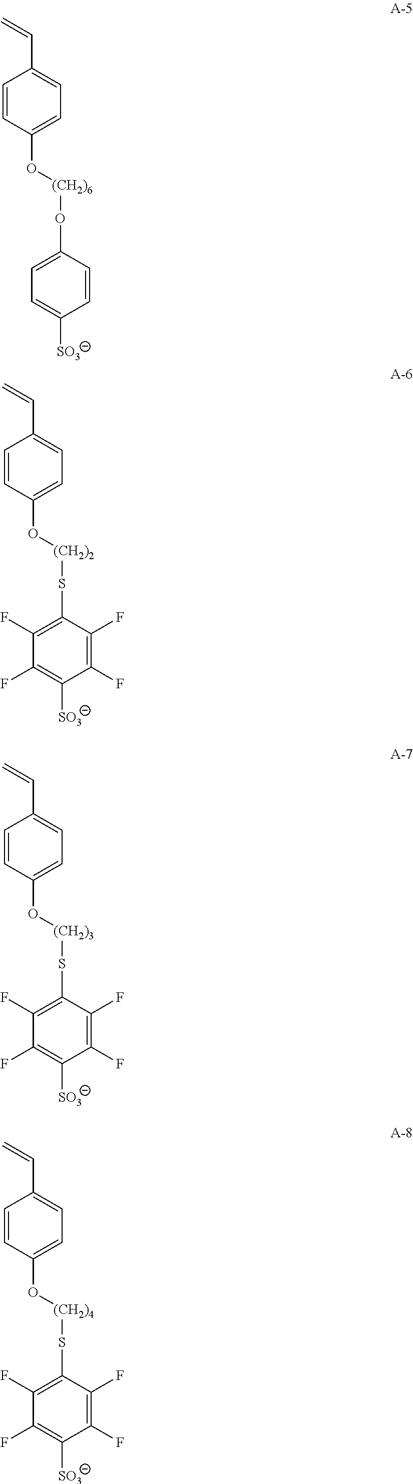

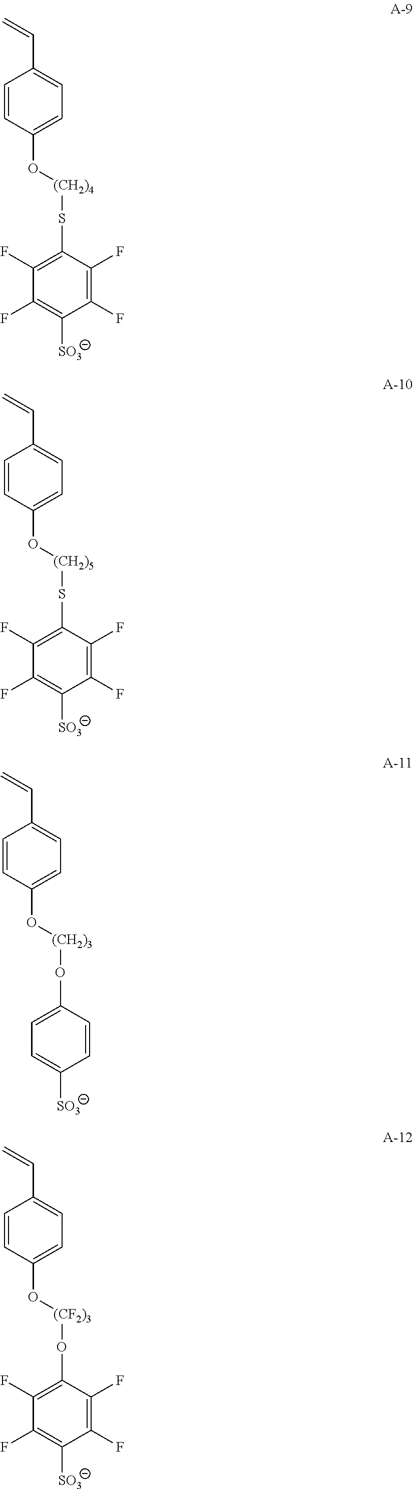

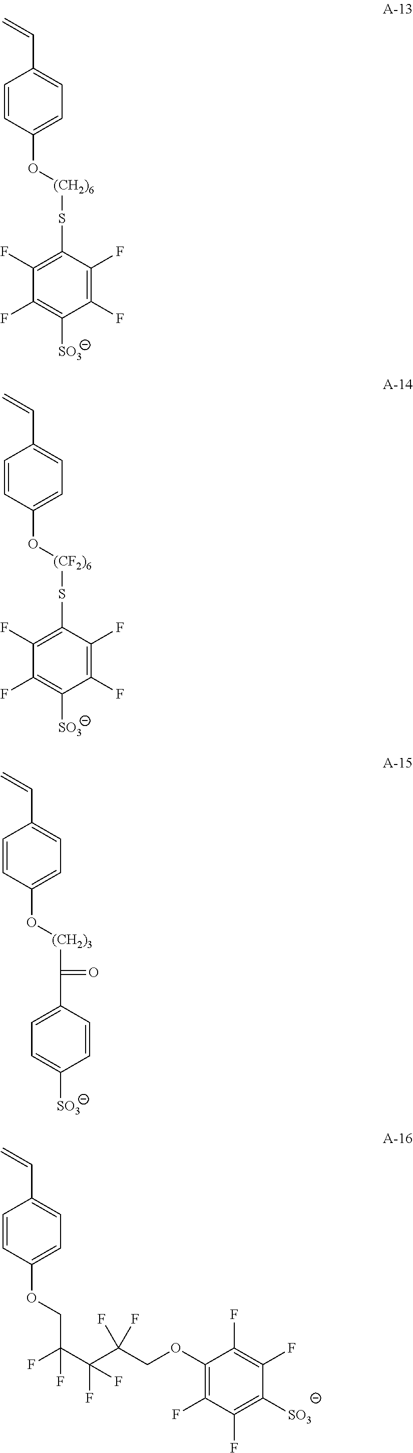

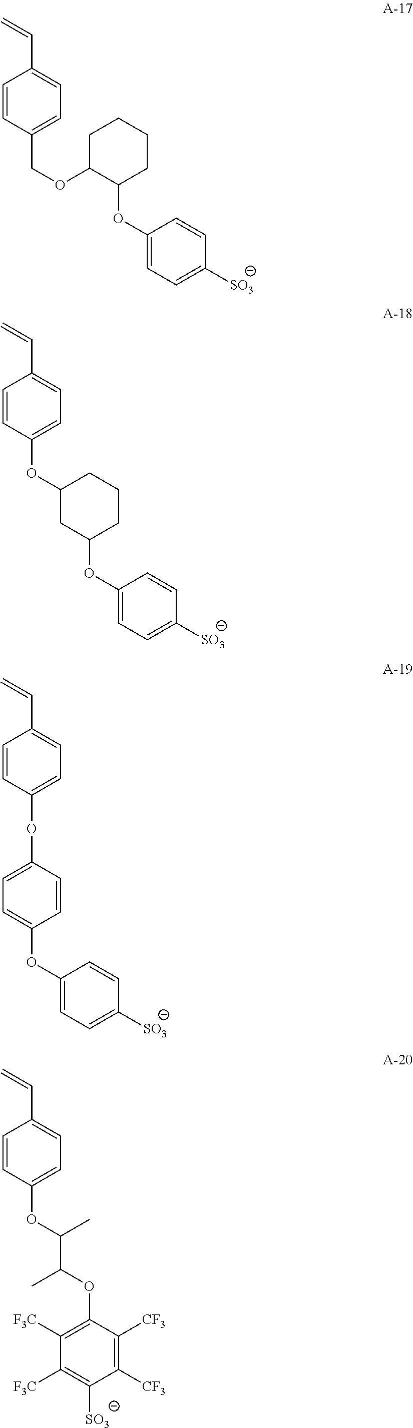

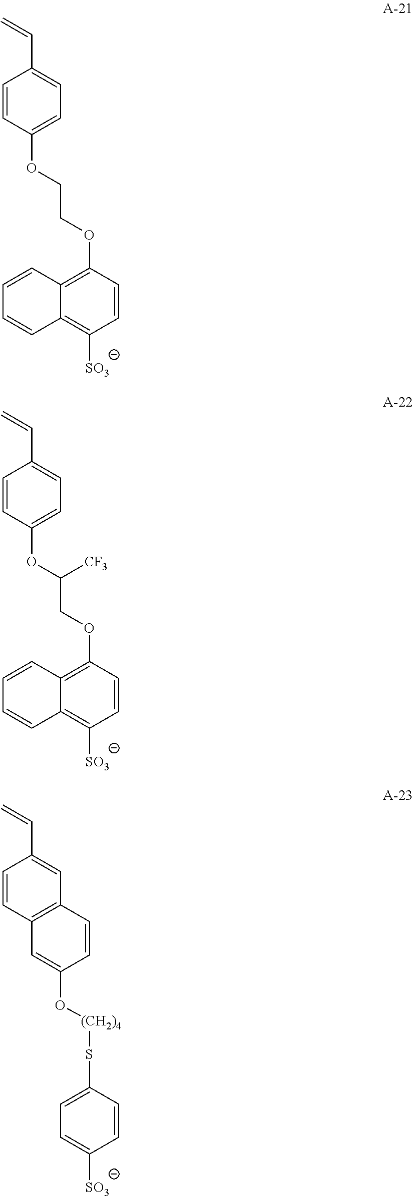

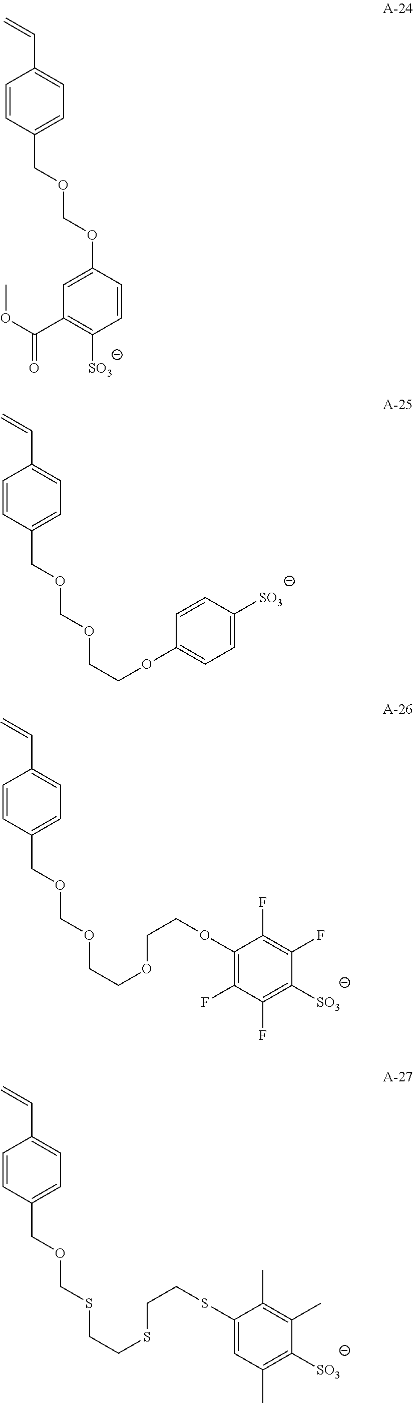

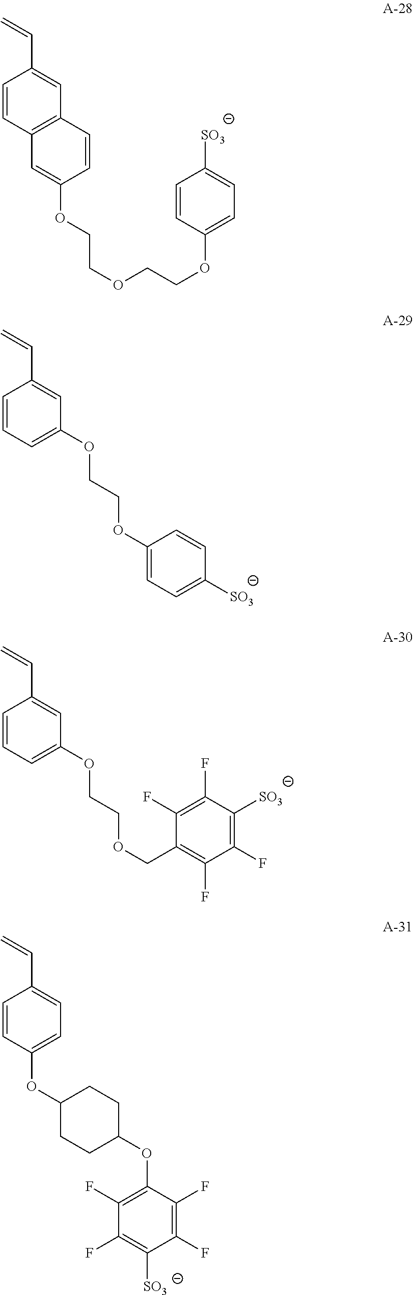

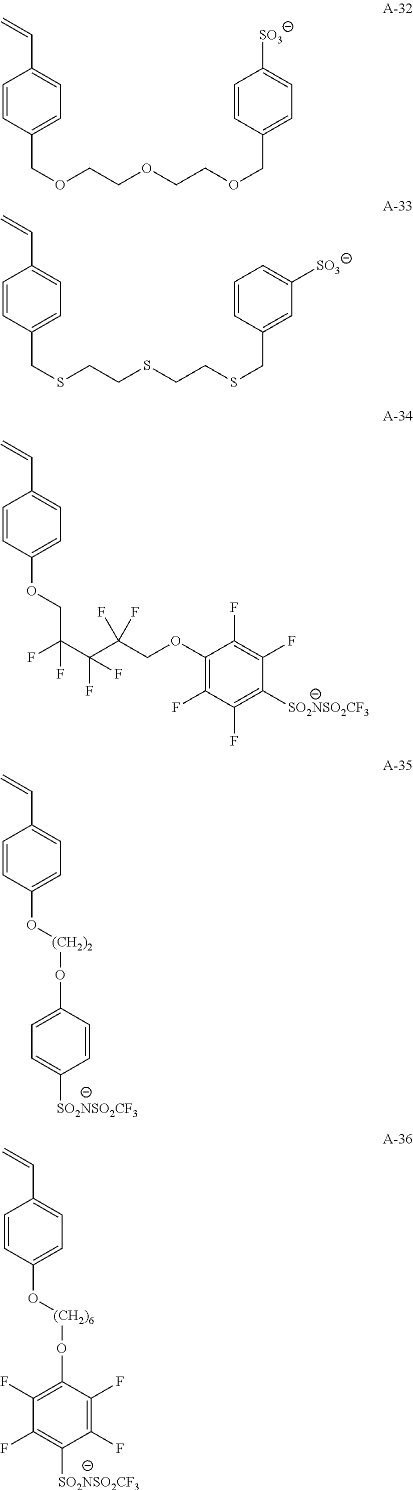

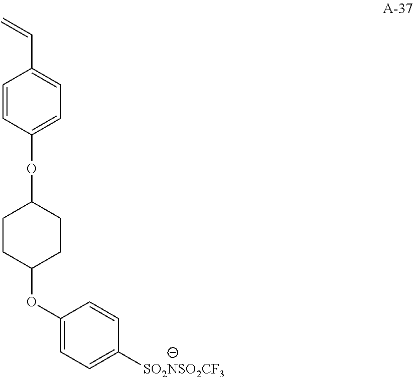

In the following Table 1, the specific examples of the monomers corresponding to repeating unit (A) are shown below as the combination of the cationic structure (above-shown (Z-1) to (Z-62)) and the anionic structure (above shown (A-1) to (A-37)).

TABLE 1

| Repeating | Cationic | Anionic | Repeating | Cationic | Anionic | Repeating | Cationic | Anionic |
|---|---|---|---|---|---|---|---|---|
| Unit (A) | Structure | Structure | Unit (A) | Structure | Structure | Unit (A) | Structure | Structure |
| M-001 | Z-1 | A-1 | M-051 | Z-18 | A-6 | M-101 | Z-43 | A-22 |
| M-002 | Z-8 | A-1 | M-052 | Z-31 | A-6 | M-102 | Z-59 | A-22 |
| M-003 | Z-11 | A-1 | M-053 | Z-47 | A-6 | M-103 | Z-1 | A-23 |
| M-004 | Z-26 | A-1 | M-054 | Z-1 | A-7 | M-104 | Z-11 | A-23 |
| M-005 | Z-27 | A-1 | M-055 | Z-8 | A-7 | M-105 | Z-2 | A-24 |
| M-006 | Z-33 | A-1 | M-056 | Z-23 | A-7 | M-106 | Z-24 | A-24 |
| M-007 | Z-38 | A-1 | M-057 | Z-38 | A-7 | M-107 | Z-1 | A-25 |
| M-008 | Z-52 | A-1 | M-058 | Z-55 | A-7 | M-108 | Z-2 | A-26 |
| M-009 | Z-55 | A-1 | M-059 | Z-1 | A-8 | M-109 | Z-47 | A-26 |
| M-010 | Z-56 | A-1 | M-060 | Z-3 | A-8 | M-110 | Z-7 | A-27 |
| M-011 | Z-59 | A-1 | M-061 | Z-16 | A-8 | M-111 | Z-33 | A-27 |
| M-012 | Z-60 | A-1 | M-062 | Z-28 | A-8 | M-112 | Z-1 | A-28 |
| M-013 | Z-1 | A-2 | M-063 | Z-1 | A-9 | M-113 | Z-2 | A-28 |
| M-014 | Z-2 | A-2 | M-064 | Z-6 | A-9 | M-114 | Z-4 | A-28 |
| M-015 | Z-4 | A-2 | M-065 | Z-32 | A-9 | M-115 | Z-27 | A-28 |
| M-016 | Z-6 | A-2 | M-066 | Z-46 | A-9 | M-116 | Z-38 | A-28 |
| M-017 | Z-15 | A-2 | M-067 | Z-1 | A-10 | M-117 | Z-39 | A-28 |
| M-018 | Z-29 | A-2 | M-068 | Z-2 | A-10 | M-118 | Z-52 | A-28 |
| M-019 | Z-37 | A-2 | M-069 | Z-12 | A-10 | M-119 | Z-60 | A-28 |
| M-020 | Z-45 | A-2 | M-070 | Z-27 | A-10 | M-120 | Z-7 | A-29 |
| M-021 | Z-60 | A-2 | M-071 | Z-38 | A-10 | M-121 | Z-23 | A-29 |
| M-022 | Z-1 | A-3 | M-072 | Z-39 | A-10 | M-122 | Z-55 | A-29 |
| M-023 | Z-2 | A-3 | M-073 | Z-59 | A-10 | M-123 | Z-1 | A-30 |
| M-024 | Z-16 | A-3 | M-074 | Z-60 | A-10 | M-124 | Z-13 | A-30 |
| M-025 | Z-22 | A-3 | M-075 | Z-1 | A-11 | M-125 | Z-28 | A-30 |
| M-026 | Z-33 | A-3 | M-076 | Z-19 | A-11 | M-126 | Z-4 | A-31 |
| M-027 | Z-37 | A-3 | M-077 | Z-4 | A-12 | M-127 | Z-26 | A-31 |
| M-028 | Z-38 | A-3 | M-078 | Z-49 | A-12 | M-128 | Z-37 | A-31 |
| M-029 | Z-40 | A-3 | M-079 | Z-7 | A-13 | M-129 | Z-1 | A-32 |
| M-030 | Z-44 | A-3 | M-080 | Z-33 | A-13 | M-130 | Z-23 | A-32 |
| M-031 | Z-53 | A-3 | M-081 | Z-41 | A-13 | M-131 | Z-38 | A-32 |
| M-032 | Z-57 | A-3 | M-082 | Z-9 | A-14 | M-132 | Z-46 | A-32 |
| M-033 | Z-59 | A-3 | M-083 | Z-48 | A-14 | M-133 | Z-1 | A-33 |
| M-034 | Z-60 | A-3 | M-084 | Z-13 | A-15 | M-134 | Z-22 | A-33 |
| M-035 | Z-1 | A-4 | M-085 | Z-29 | A-15 | M-135 | Z-30 | A-33 |
| M-036 | Z-4 | A-4 | M-086 | Z-23 | A-16 | M-136 | Z-52 | A-33 |
| M-037 | Z-11 | A-4 | M-087 | Z-36 | A-16 | M-137 | Z-2 | A-34 |
| M-038 | Z-27 | A-4 | M-088 | Z-1 | A-17 | M-138 | Z-12 | A-34 |
| M-039 | Z-33 | A-4 | M-089 | Z-26 | A-17 | M-139 | Z-5 | A-35 |
| M-040 | Z-38 | A-4 | M-090 | Z-2 | A-18 | M-140 | Z-34 | A-35 |
| M-041 | Z-40 | A-4 | M-091 | Z-43 | A-18 | M-141 | Z-1 | A-36 |
| M-042 | Z-52 | A-4 | M-092 | Z-4 | A-19 | M-142 | Z-11 | A-36 |
| M-043 | Z-60 | A-4 | M-093 | Z-32 | A-19 | M-143 | Z-45 | A-36 |
| M-044 | Z-1 | A-5 | M-094 | Z-57 | A-19 | M-144 | Z-53 | A-36 |
| M-045 | Z-12 | A-5 | M-095 | Z-1 | A-20 | M-145 | Z-60 | A-36 |
| M-046 | Z-24 | A-5 | M-096 | Z-25 | A-20 | M-146 | Z-1 | A-37 |
| M-047 | Z-33 | A-5 | M-097 | Z-5 | A-21 | M-147 | Z-20 | A-37 |
| M-048 | Z-38 | A-5 | M-098 | Z-49 | A-21 | M-148 | Z-38 | A-37 |
| M-049 | Z-52 | A-5 | M-099 | Z-8 | A-22 | M-149 | Z-59 | A-37 |
| M-050 | Z-60 | A-5 | M-100 | Z-29 | A-22 | M-150 | Z-60 | A-37 |

The content of the repeating unit (A) in the resin (P) is preferably in the range of 0.5 mol % to 80 mol % to all the repeating units in the resin (P), more preferably in the range of 1 mol % to 60 mol %, and still more preferably in the range of 3 mol % to 40 mol %.

### [Repeating Unit (B)]

It is preferred that the resin (P) further contains a repeating unit (B) having a group capable of decomposing by an action of an acid to generate a polar group.

The group capable of decomposing by the action of an acid to generate a polar group (hereinafter also referred to as “acid-decomposable group”) preferably has such a structure that a polar group is protected with a group capable of decomposing and leaving by the action of an acid.

The resin (P) is a resin whose polarity changes by the action of an acid, specifically a resin capable of increasing the solubility in an alkali developer or decreasing the solubility in a developer containing an organic solvent by the action of an acid.

The examples of the polar groups include a phenolic hydroxyl group, a carboxyl group, a fluorinated alcohol group, a sulfonic acid group, a sulfonamide group, a sulfonylimide group, a (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

As preferred polar groups, a carboxyl group, a fluorinated alcohol group (preferably a hexafluoroisopropanol group), and a sulfonic acid group are exemplified.

The repeating unit (B) is preferably a repeating unit represented by the following formula (a).

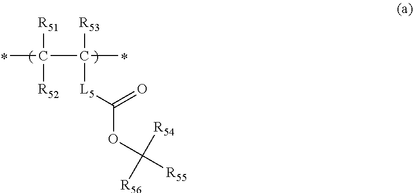

In formula (a), each of R₅₁, R₅₂ and R₅₃ independently represents a hydrogen atom, an alkyl group, a monovalent aliphatic hydrocarbon cyclic group, a halogen atom, a cyano group, or an alkoxycarbonyl group. R₅₂ and L₅ may be bonded to each other to form a ring (preferably a 5- or 6-membered ring), and R₅₂ represents an alkylene group in that case.

L₅ represents a single bond or a divalent linking group, and represents a trivalent linking group in the case of forming a ring with R₅₂.

R₅₄ represents an alkyl group. R₅₅ and R₅₆ independently represents a hydrogen atom, an alkyl group, a monovalent aliphatic hydrocarbon cyclic group or an aromatic cyclic group. R₅₅ and R₅₆ may be bonded to each other to form a ring, provided that R₅₅ and R₅₆ do not represent a hydrogen atom at the same time.

Formula (a) is described in further detail.

The alkyl group of R₅₁ to R₅₃ in formula (a) is preferably an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, or a dodecyl group, all of which groups may have a substituent, more preferably an alkyl group having 8 or less carbon atoms, and especially preferably an alkyl group having 3 or less carbon atoms.

The alkyl group contained in the alkoxycarbonyl group is preferably the same alkyl group as in R₅₁ to R₅₃.

The monovalent aliphatic hydrocarbon cyclic group is a monocyclic or polycyclic monovalent aliphatic hydrocarbon cyclic group. Preferably, a monocyclic monovalent aliphatic hydrocarbon cyclic group having 3 to 8 carbon atoms, such as a cyclopropyl group, a cyclopentyl group, and a cyclohexyl group, which groups may have a substituent, can be exemplified.

The halogen atom is a fluorine atom, a chlorine atom, a bromine atom or an iodine atom, and a fluorine atom is especially preferred.

The examples of substituents for the above each group include, e.g., an alkyl group, a monovalent aliphatic hydrocarbon cyclic group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the carbon atom number of these substituents is preferably 8 or less.

When R₅₂ represents an alkylene group, the alkylene group is preferably an alkylene group having 1 to 8 carbon atoms, such as a methylene group, an ethylene group, a propylene group, a butylene group, a hexylene group, or an octylene group, more preferably an alkylene group having 1 to 4 carbon atoms, and especially preferably an alkylene group having 1 or 2 carbon atoms.

Each of R₅₁ and R₅₃ in formula (a) more preferably represents a hydrogen atom, an alkyl group or a halogen atom, and especially preferably a hydrogen atom, a methyl group, an ethyl group, a trifluoromethyl group (—CF₃), a hydroxymethyl group (—CH₂—OH), a chloromethyl group (—CH₂—Cl), or a fluorine atom (—F). R₅₂ more preferably represents a hydrogen atom, an alkyl group, a halogen atom, or an alkylene group (forming a ring together with L₅), and especially preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring together with L₅), or an ethylene group (forming a ring together with L₅).

As the divalent linking group represented by L₅, an alkylene group, a divalent aromatic cyclic group, —COO-L₁-, —O-L₁-, -L₁-O—, and a group formed by combining two or more of these groups are exemplified, wherein L₁ represents an alkylene group, a divalent aliphatic hydrocarbon cyclic group, a divalent aromatic cyclic group, or a group obtained by combining an alkylene group and a divalent aromatic cyclic group, which may further be substituted with a fluorine atom or the like.

L₅ preferably represents a single bond, —COO-L₁- (L₁ is preferably an alkylene group having 1 to 5 carbon atoms, and more preferably a methylene group or a propylene group), or a group represented by a divalent aromatic cyclic group.

The alkyl group of R₅₄ to R₅₆ is preferably an alkyl group having 1 to 20 carbon atoms, more preferably an alkyl group having 1 to 10 carbon atoms, and especially preferably an alkyl group having 1 to 4 carbon atoms, such as a methyl group, an ethyl group, an n-propyl group, an isopropyl group, an n-butyl group, an isobutyl group, or a t-butyl group.

The monovalent aliphatic hydrocarbon cyclic group represented by R₅₅ and R₅₆ is preferably a monovalent aliphatic hydrocarbon cyclic group having 3 to 20 carbon atoms, which group may be monocyclic such as a cyclopentyl group or a cyclohexyl group, or may be polycyclic such as a norbonyl group, an adamantyl group, a tetracyclodecanyl group, or a tetracyclododecanyl group.

The ring formed by bonding R₅₅ to R₅₆ to each other is preferably a ring having 3 to 20 carbon atoms, which may be monocyclic such as a cyclopentyl group or a cyclohexyl group, or may be polycyclic such as a norbonyl group, an adamantyl group, a tetracyclodecanyl group, or a tetracyclododecanyl group. When R₅₅ and R₅₆ form a ring by bonding to each other, R₅₄ preferably represents an alkyl group having 1 to 3 carbon atoms, and more preferably a methyl group or an ethyl group.

The monovalent aromatic cyclic group represented by R₅₅ and R₅₆ is preferably an aromatic cyclic group having 6 to 20 carbon atoms, e.g., a phenyl group and a naphtyl group are exemplified. When either one of R₅₅ and R₅₆ is a hydrogen atom, the other is preferably a monovalent aromatic cyclic group.

A monomer corresponding to the repeating unit represented by formula (a) can be synthesized according to an ordinary synthesizing method of a polymerizable group-containing ester without any restriction.

The specific examples of the repeating units represented by formula (a) are shown below, but the invention is not restricted thereto.

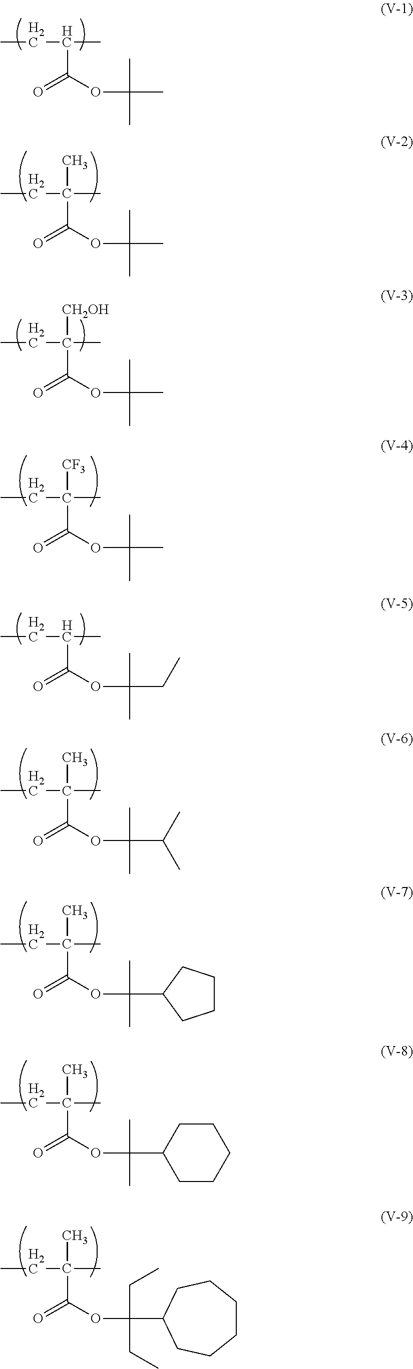

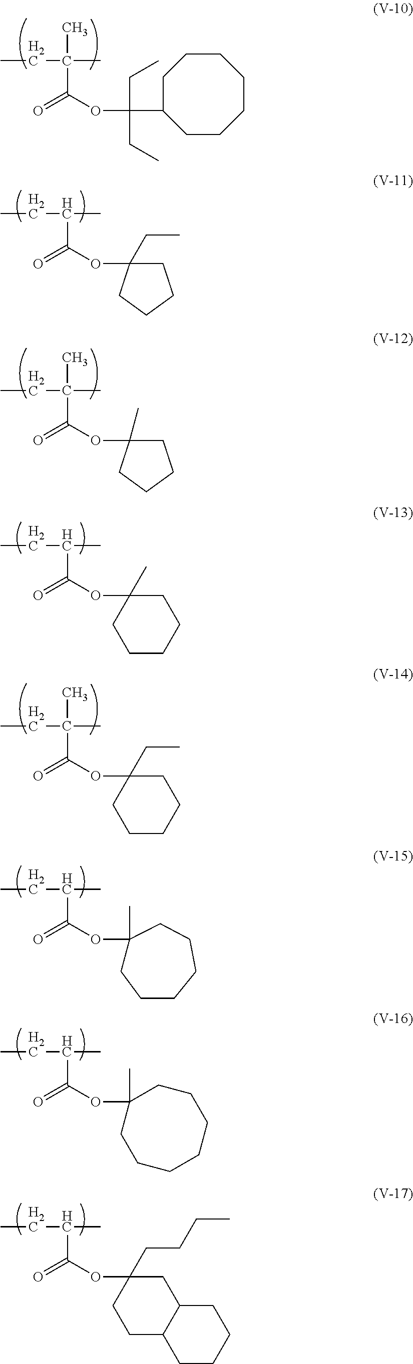

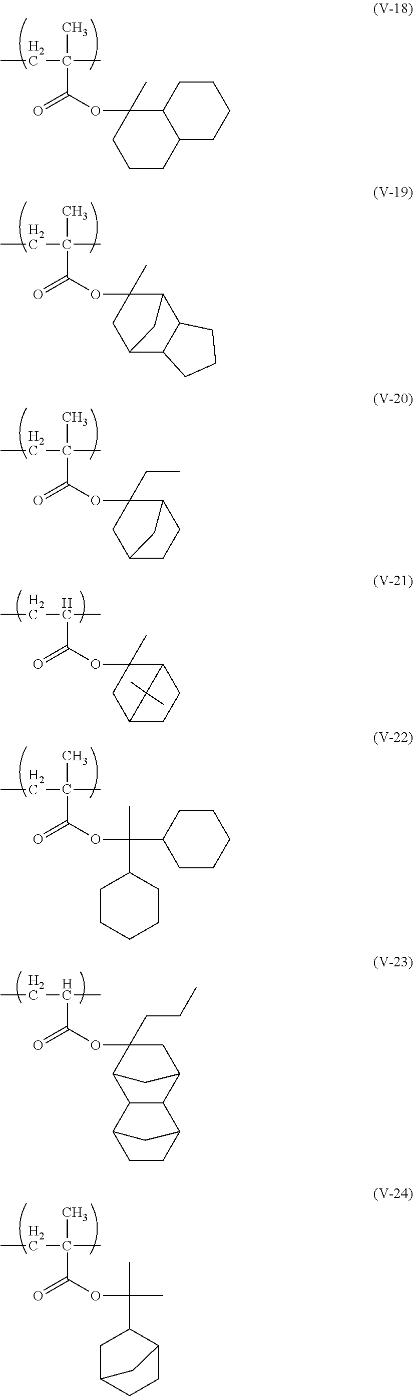

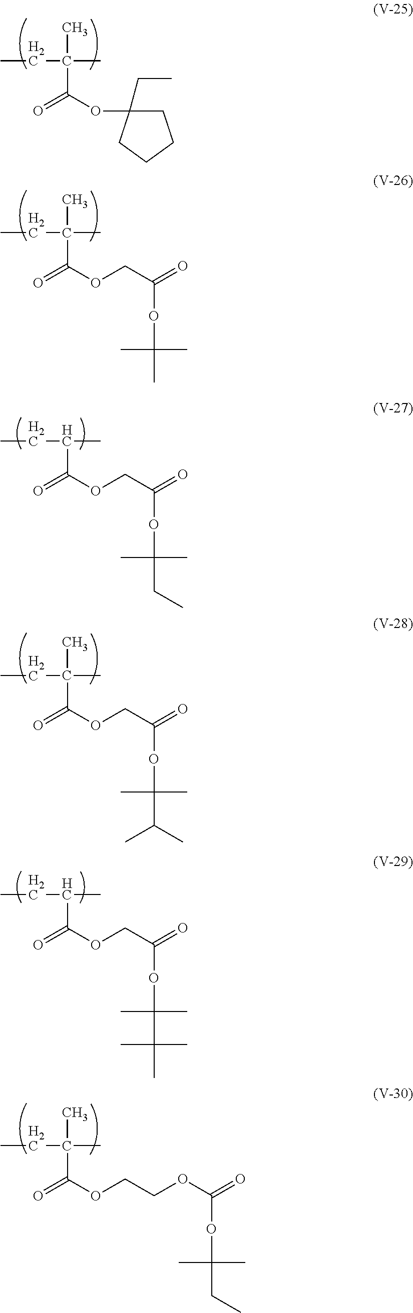

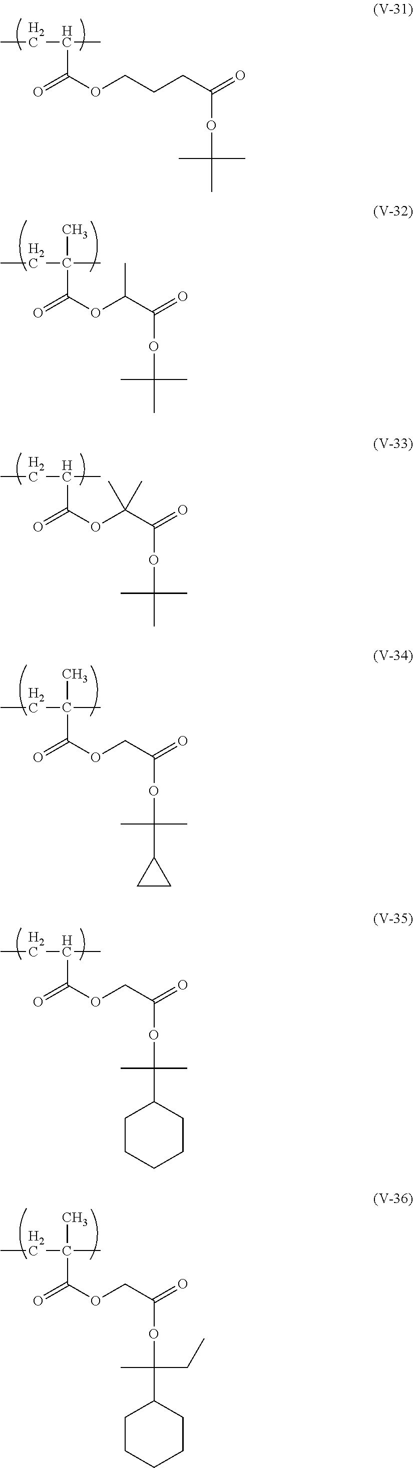

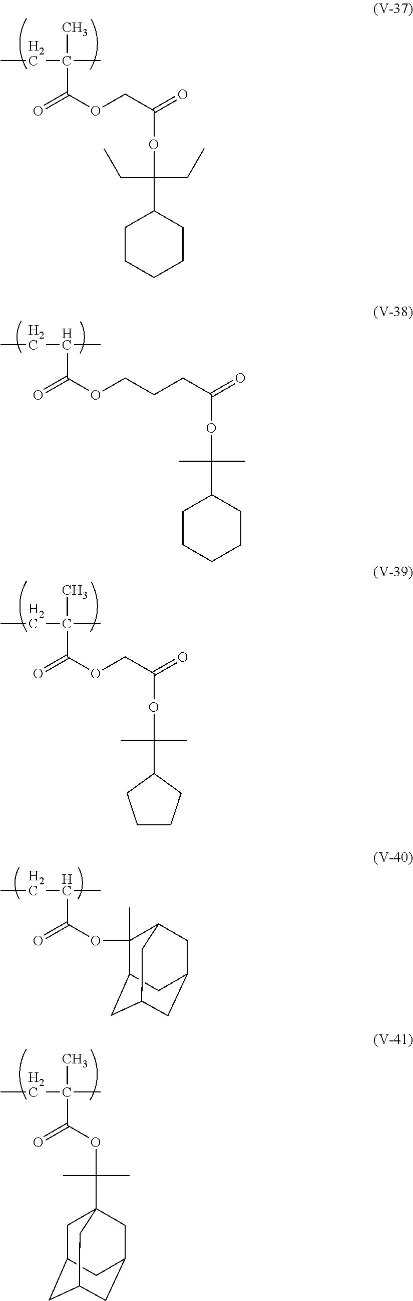

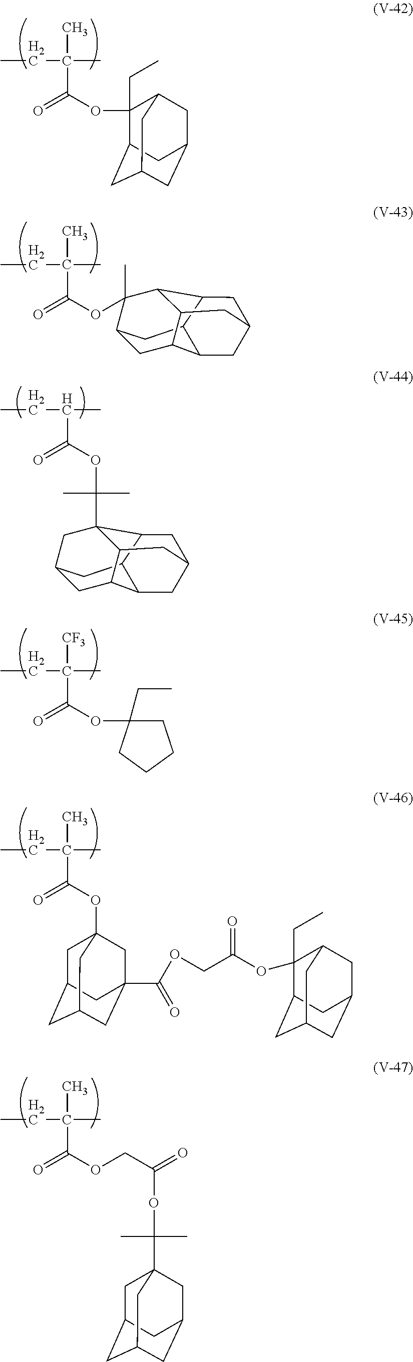

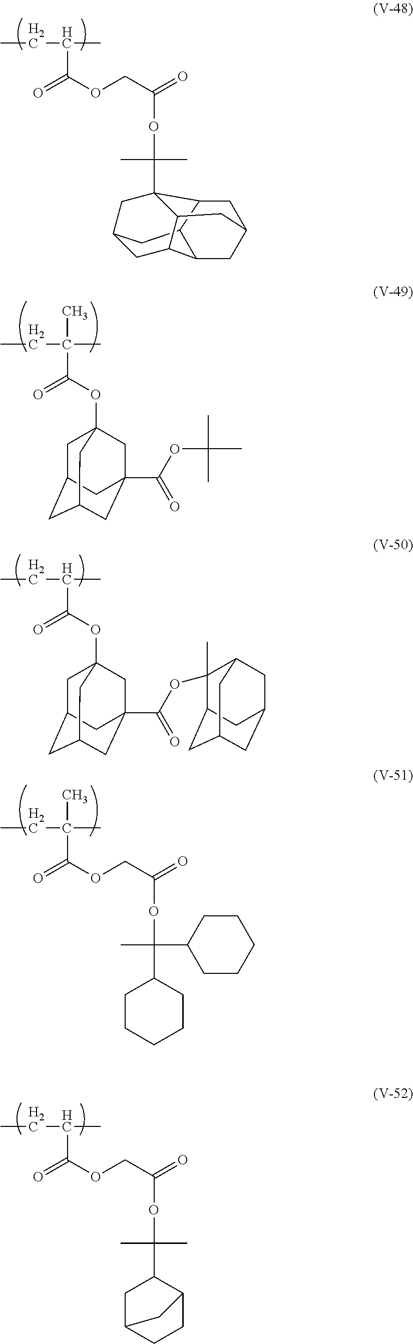

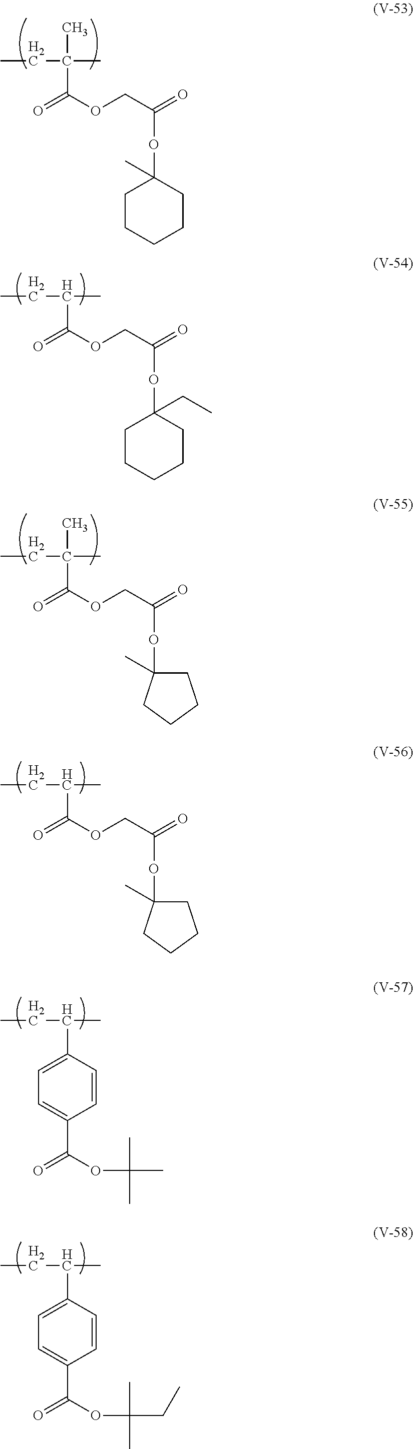

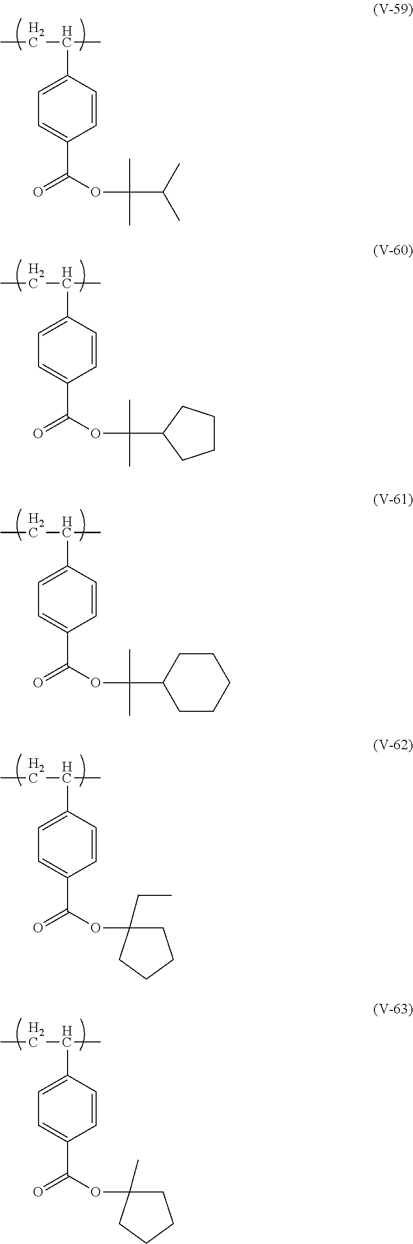

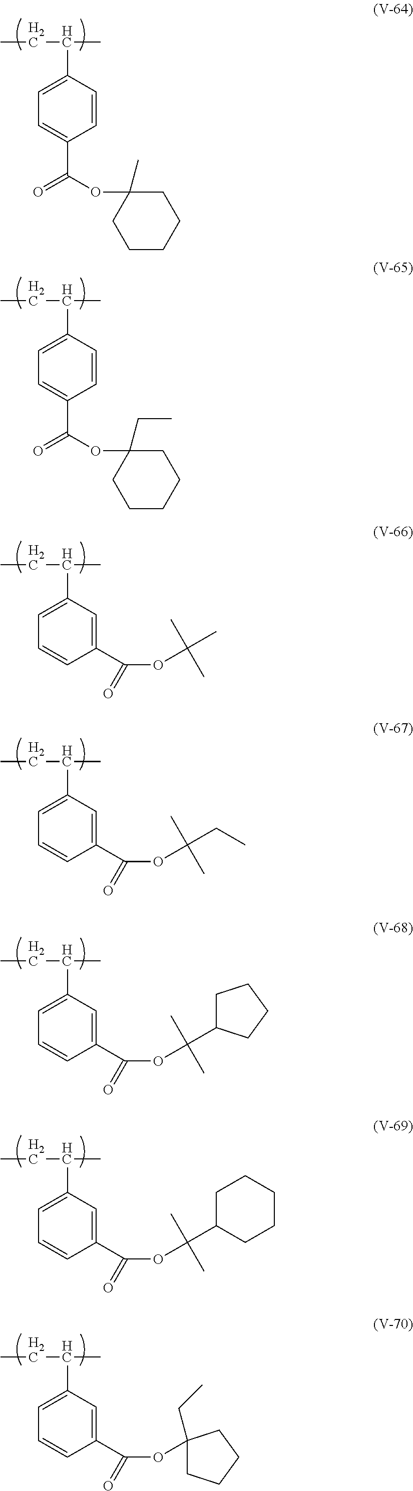

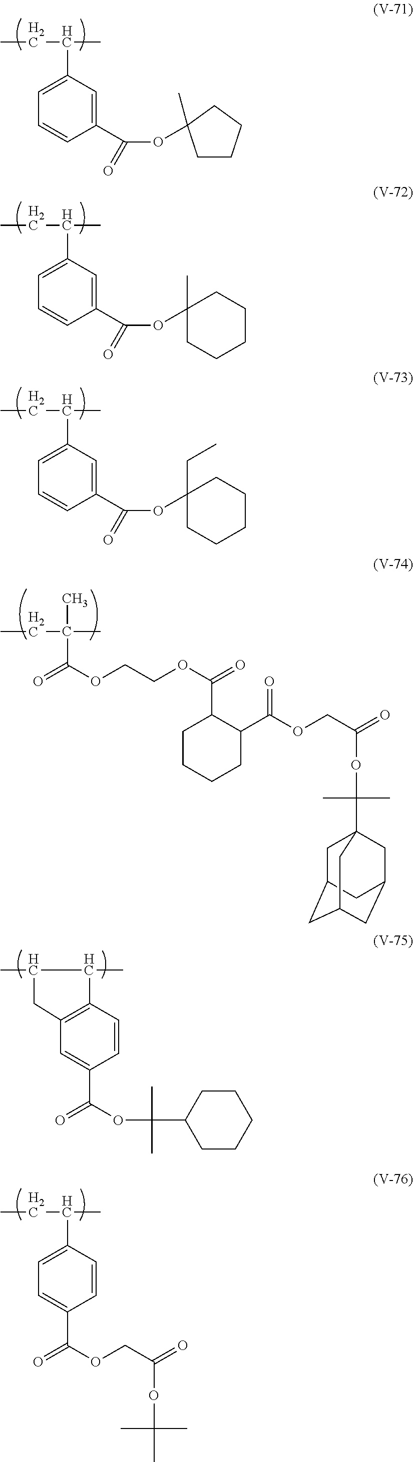

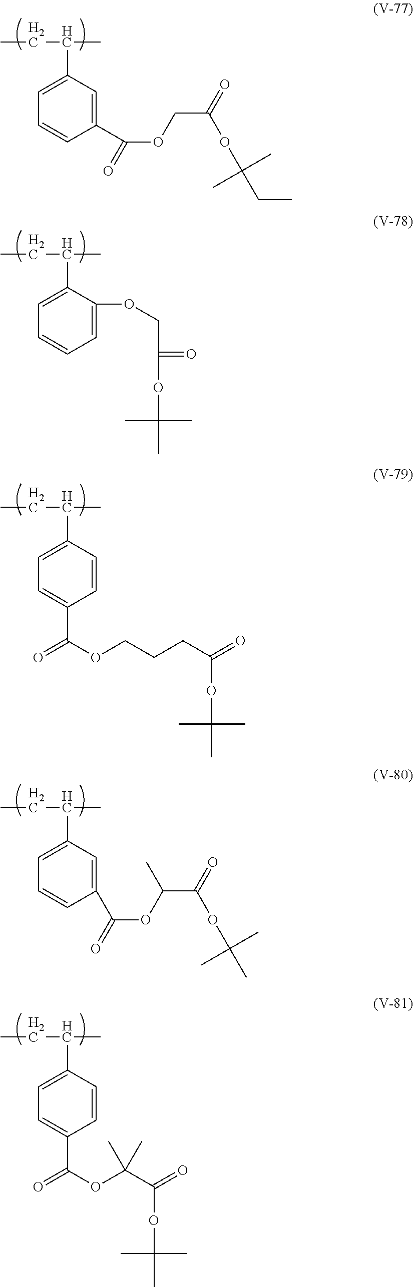

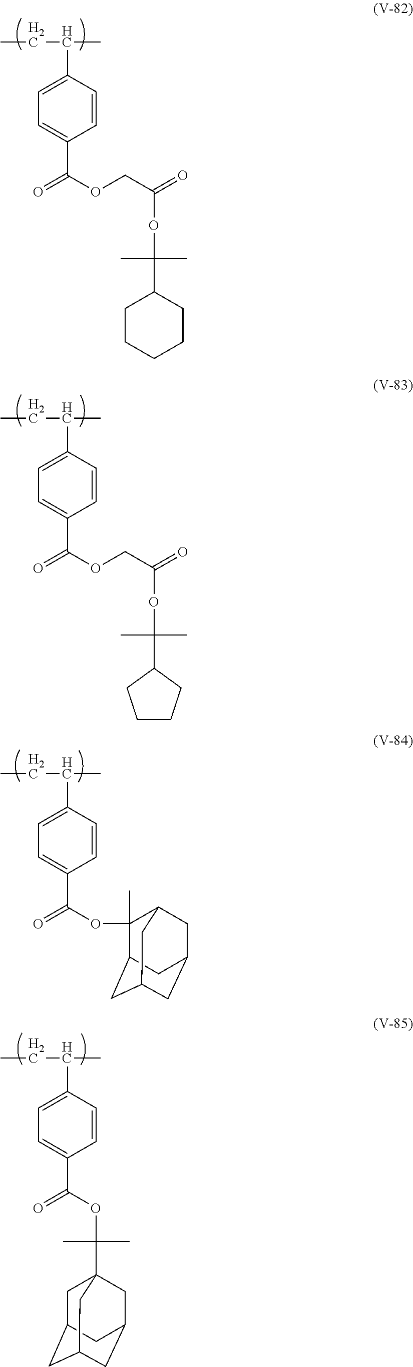

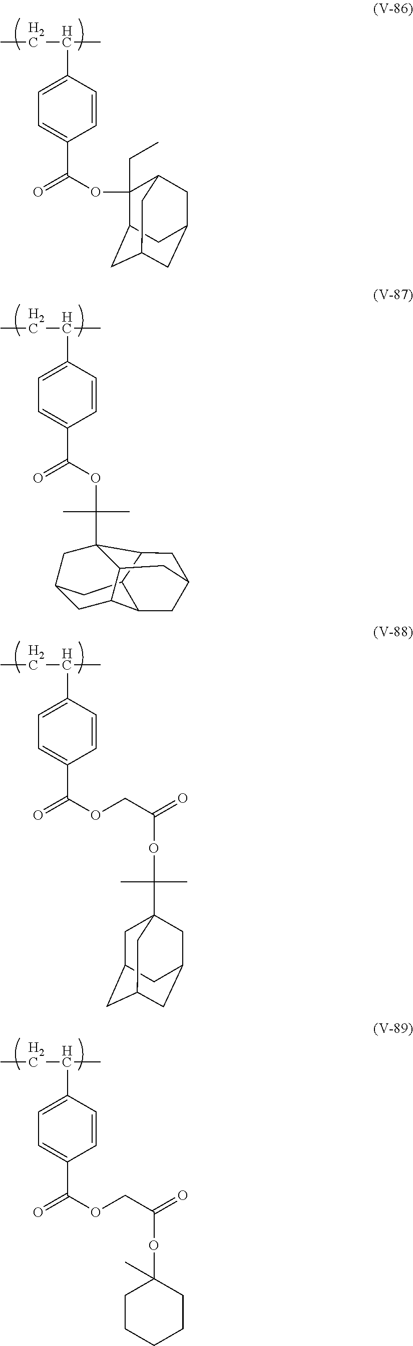

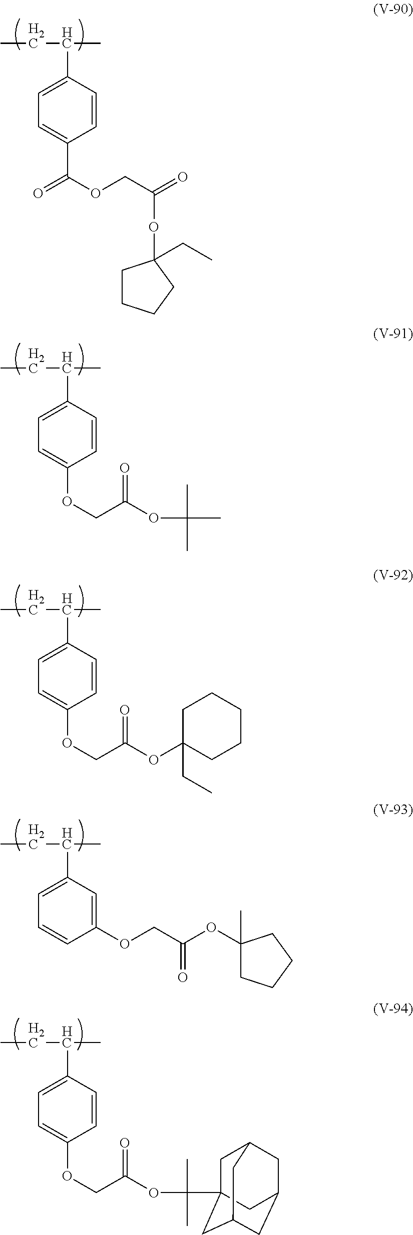

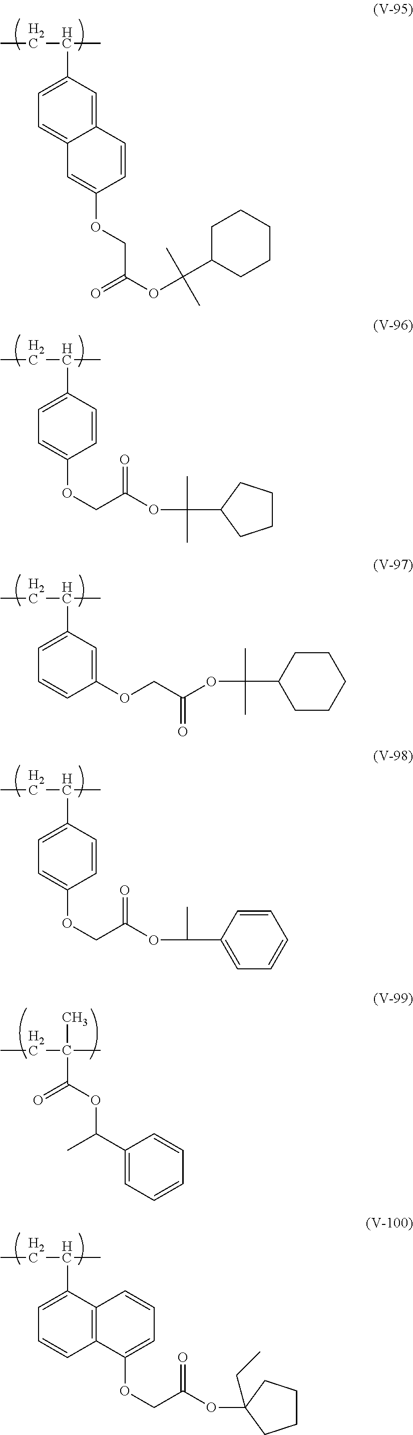

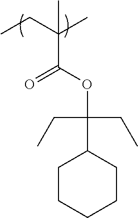

Specifically, the repeating unit (B) is more preferably a repeating unit represented by the following formula (b).

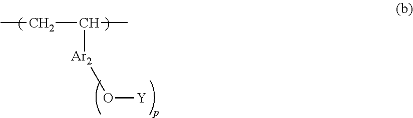

In formula (b), Ar₂ represents a (p+1)-valent aromatic cyclic group.

Y represents a hydrogen atom or a group capable of leaving by the action of an acid, and when two or more Y are present, these plurality of Y may be the same with or different from every other Y, provided that at least one of Y represents a group capable of leaving by the action of an acid.

p represents an integer of 1 or more.

Ar₂ represents a (p+1)-valent aromatic cyclic group.

The (p+1)-valent aromatic cyclic group represented by Ar₂ in formula (b) may have a substituent. As the (p+1)-valent aromatic cyclic group represented by Ar₂, when p is 1, for example, an arylene group having 6 to 18 carbon atoms, such as a phenylene group, a tolylene group and a naphthylene group, and a divalent aromatic cyclic group containing a heterocyclic ring, such as thiophene, furan, pyrrole, benzothiophene, benzofuran, benzopyrrole, triazine, imidazole, benzimidazole, triazole, thiadiazole, or thiazole, are exemplified as preferred examples.

The examples of preferred substituents in the (p+1)-valent aromatic cyclic group represented by Ar₂ include a hydroxyl group, a halogen atom (e.g., a fluorine atom, a chlorine atom, a bromine atom, an iodine atom), a nitro group, a cyano group, an amido group, and a sulfonamide group, an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, a cycloalkyl group having 3 to 17 carbon atoms, such as a cyclopentyl group, a cyclohexyl group, a norbonyl group, and an adamantyl group, an alkoxy group, such as a methoxy group, an ethoxy group, a hydroxyethoxy group, a propoxy group, a hydroxypropoxy group, and a butoxy group, an alkoxycarbonyl group, such as a methoxycarbonyl group and an ethoxycarbonyl group, an acyl group, such as a formyl group, an acetyl group, and a benzoyl group, an acyloxy group such as an acetoxy group and a butyryloxy group, and a carboxyl group.

When p is 1, Ar₂ more preferably represents an arylene group having 6 to 18 carbon atoms which may have a substituent, especially preferably a phenylene group, a naphthylene group, a biphenylene group, or a phenylene group substituted with a phenyl group, and still more preferably a phenylene group.

As the specific examples of the (p+1)-valent aromatic cyclic group represented by Ar₂ in the case where p is an integer of 2 or more, a group obtained by subtracting arbitrary (p−1) hydrogen atom(s) from the above divalent aromatic cyclic group is exemplified.

p represents an integer of 1 or more, preferably an integer of 1 to 5, more preferably 1 or 2, and most preferably 1.

In the repeating unit represented by formula (b), when Ar₂ is a phenylene group, the bonding position of the group represented by —O—Y to the benzene ring of Ar₂ may be the para-position, meta-position, or ortho-position to the bonding position with the polymer main chain of the benzene ring, but the para-position or meta-position is preferred, and the para-position is most preferred.

The examples of group Y capable of leaving by the action of an acid include the groups represented by —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—C—(R₃₆)(R₃₇)(R₃₈), and —CH(R₃₆)(Ar).

In the above formulae, each of R₃₆ to R₃₉ independently represents an alkyl group, a cycloalkyl group, an aryl group, an aralkyl group, or an alkenyl group. R₃₆ and R₃₇ may be bonded to each other to form a ring structure.

Each of R₀₁ and R₀₂ independently represents a hydrogen atom, an alkyl group, a cycloalkyl group, an aryl group, an aralkyl group, or an alkenyl group.

Ar represents an aryl group.

The alkyl group represented by R₃₆ to R₃₉, R₀₁ or R₀₂ is preferably an alkyl group having 1 to 8 carbon atoms, for example, a methyl group, an ethyl group, a propyl group, an n-butyl group, a sec-butyl group, a hexyl group, and an octyl group, are exemplified.

The cycloalkyl group represented by R₃₆ to R₃₉, R₀₁ or R₀₂ may be a monocyclic cycloalkyl group or may be a polycyclic cycloalkyl group. The monocyclic cycloalkyl group is preferably a cycloalkyl group having 3 to 8 carbon atoms and, for example, a cyclopropyl group, a cyclobutyl group, a cyclopentyl group, a cyclohexyl group and a cyclooctyl group are exemplified. The polycyclic cycloalkyl group is preferably a cycloalkyl group having 6 to 20 carbon atoms and, for example, an adamantyl group, a norbornyl group, an isoboronyl group, a camphanyl group, a dicyclopentyl group, an α-pinel group, a tricyclodecanyl group, a tetracyclododecyl group, and an androstanyl group are exemplified. Incidentally, a part of the carbon atoms in the cycloalkyl group may be substituted with a heteroatom such as an oxygen atom and the like.

The aryl group represented by R₃₆ to R₃₉, R₀₁, R₀₂ or Ar is preferably an aryl group having 6 to 10 carbon atoms and, for example, a phenyl group, a naphthyl group, and an anthryl group are exemplified.

The aralkyl group represented by R₃₆ to R₃₉, R₀₁ or R₀₂ is preferably an aralkyl group having 7 to 12 carbon atoms and, for example, a benzyl group, a phenethyl group, and a naphthylmethyl group are preferably exemplified.

The alkenyl group represented by R₃₆ to R₃₉, R₀₁ or R₀₂ is preferably an alkenyl group having 2 to 8 carbon atoms and, for example, a vinyl group, an allyl group, a butenyl group, and a cyclohexenyl group are exemplified.

The ring which can be formed by bonding R₃₆ to R₃₇ to each other may be monocyclic or polycyclic. As the monocyclic ring, a cycloalkane structure having 3 to 8 carbon atoms is preferred and, for example, a cyclopropane structure, a cyclobutane structure, a cyclopentane structure, a cyclohexane structure, a cycloheptane structure, and a cyclooctane structure are exemplified. As the polycyclic ring, a cycloalkane structure having 6 to 20 carbon atoms is preferred and, for example, an adamantane structure, a norbornane structure, a dicyclopentane structure, a tricyclodecane structure, and a tetracyclododecane structure are exemplified. Incidentally, a part of the carbon atoms in the structure may be substituted with a heteroatom such as an oxygen atom and the like.

The above each group may have a substituent. The examples of the substituents include, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. These substituents preferably have 8 or less carbon atoms.

As group Y capable of leaving by the action of an acid, the structure represented by the following formula (c) is more preferred.

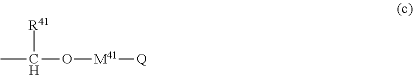

In formula (c), R⁴¹ represents a hydrogen atom, an alkyl group, a cycloalkyl group, an aryl group, or an aralkyl group.

M⁴¹ represents a single bond or a divalent linking group.

Q represents an alkyl group, an alicyclic group which may contain a heteroatom, or an aromatic cyclic group which may contain a heteroatom.

Incidentally, at least two of R⁴¹, M⁴¹ and Q may be bonded to each other to form a ring, and the ring is preferably a 5- or 6-membered ring.

The alkyl group as R⁴¹ is, for example, an alkyl group having 1 to 8 carbon atoms, and preferably a methyl group, an ethyl group, a propyl group, an isopropyl group, an n-butyl group, a sec-butyl group, a tert-butyl group, a hexyl group, and an octyl group are exemplified as the examples thereof.

The alkyl group as R⁴¹ may have a substituent and, for example, a cyano group, a halogen atom, a hydroxyl group, an alkoxy group, a carboxyl group, an alkoxycarbonyl group, and a cycloalkyl group are exemplified as the examples thereof

The cycloalkyl group as R⁴¹ is, for example, a cycloalkyl group having 3 to 15 carbon atoms, and preferably a cyclohexyl group, a norbornyl group, and an adamantyl group are exemplified as the examples thereof.

The aryl group as R⁴¹ is, for example, an aryl group having 6 to 15 carbon atoms, and preferably a phenyl group, a tolyl group, a naphthyl group, and an anthryl group are exemplified as the examples thereof.

The aralkyl group as R⁴¹ is, for example, an aralkyl group having 6 to 20 carbon atoms, and preferably a benzyl group and a phenethyl group are exemplified as the examples thereof.

R⁴¹ is preferably a hydrogen atom, a methyl group, an isopropyl group, a tert-butyl group, a cyclohexyl group, an adamantyl group, a phenyl group, or a benzyl group, and more preferably a methyl group or an adamantyl group.

The divalent linking group as M⁴¹ is, for example, an alkylene group (preferably an alkylene group having 1 to 8 carbon atoms, e.g., a methylene group, an ethylene group, a propylene group, a butylene group, a hexylene group, or an octylene group), a cycloalkylene group (preferably a cycloalkylene group having 3 to 15 carbon atoms, e.g., a cyclopentylene group or a cyclohexylene group), —S—, —O—, —CO—, —CS—, —SO₂—, —N(Ro)-, or a group formed by combining two or more of these groups, and the total carbon atom number is preferably 20 or less. Here, Ro is a hydrogen atom, or an alkyl group (for example, an alkyl group having 1 to 8 carbon atoms, specifically a methyl group, an ethyl group, a propyl group, an n-butyl group, a sec-butyl group, a hexyl group, or an octyl group).

M⁴¹ is preferably a single bond, an alkylene group, or a divalent linking group comprising a combination of an alkylene group and at least one of —O—, —CO—, —CS—, and —N(Ro)-, and more preferably a single bond, an alkylene group, or a divalent linking group comprising a combination of an alkylene group and —O—. Ro has the same meaning with the above Ro.

The alkyl group as Q is the same with the alkyl group as R⁴¹ described above.

As the alicyclic group and aromatic cyclic group as Q, the cycloalkyl group and aryl group as R⁴¹ described above are exemplified. The carbon atom number is preferably 3 to 18. Incidentally, in the invention, a group obtained by linking a plurality of aromatic rings via a single bond (e.g., a biphenyl group and a terphenyl group) is also included in the aromatic group as Q.

As the alicyclic group containing a hetero atom and the aromatic cyclic group containing a heteroatom, for example, thiirane, cyclothiolane, thiophene, furan, pyrrole, benzothiophene, benzofuran, benzopyrrole, triazine, imidazole, benzimidazole, triazole thiadiazole, thiazole, and pyrrolidone are exemplified. Incidentally, in the invention, a group obtained by linking “a plurality of aromatic rings containing hetero-atoms” via a single bond (e.g., a viologen group) is also included in the aromatic group as Q.

The alicyclic group and aromatic cyclic group as Q may have a substituent, for example, an alkyl group, a cycloalkyl group, a cyano group, a halogen atom, a hydroxyl group, an alkoxy group, a carboxyl group, and an alkoxycarbonyl group are exemplified.

(-M⁴¹-Q) is especially preferably a methyl group, an ethyl group, a cyclohexyl group, a norbornyl group, an aryloxyethyl group, a cyclohexylethyl group, or an arylethyl group.

As the case of forming a ring by bonding at least two of R⁴¹, M⁴¹ and Q to each other, for example, a case of bonding either M⁴¹ or Q to R⁴¹ to form a propylene group or a butylene group and to form a 5- or 6-membered ring containing an oxygen atom is exemplified.

Taking the sum total of the carbon atom number of R⁴¹, M⁴¹ and Q as Nc, in the case where Nc is large, the change of the solubility of the resin (P) in an alkali becomes large before and after leaving of the group represented by formula (c), and so the dissolution contrast is preferably improved. The range of Nc is preferably 4 to 30, more preferably 7 to 25, and especially preferably 7 to 20. When Nc is 30 or less, the reduction of the glass transition temperature of the resin (P) is suppressed, the exposure latitude (EL) of the resist is prevented from lowering, and the residue after leaving of the group represented by formula (c) is inhibited from remaining on the resist pattern as a defect, and so preferred.

It is preferred from the viewpoint of dry etching resistance that at least one of R⁴¹, M⁴¹ and Q has an alicyclic ring or an aromatic ring. The alicyclic group and the aromatic cyclic group here are the same with the alicyclic group and the aromatic cyclic group as Q described above.

The specific examples of the repeating unit (B) are shown below, but the invention is not restricted thereto.

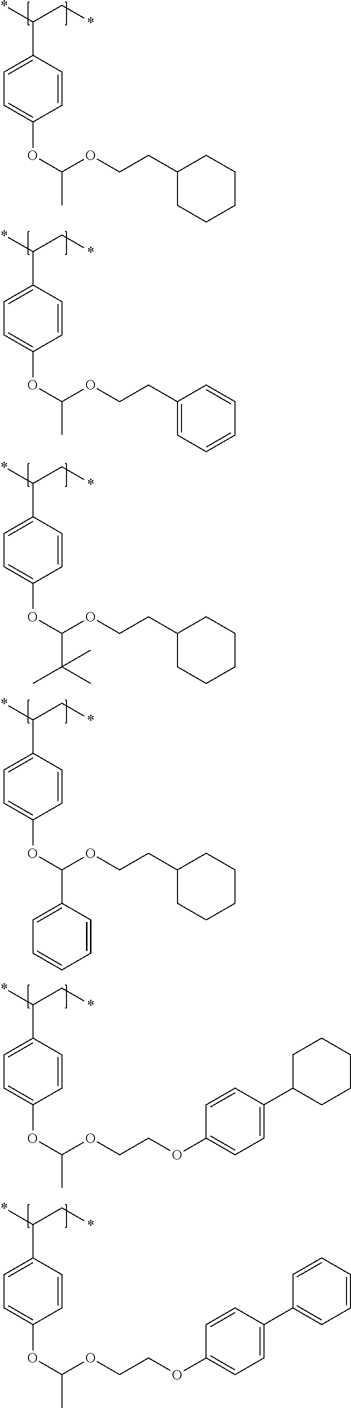

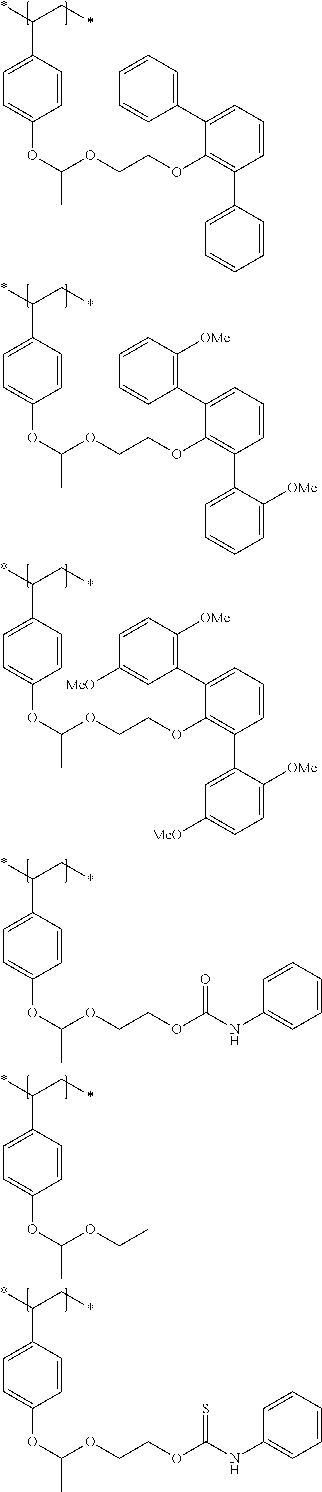

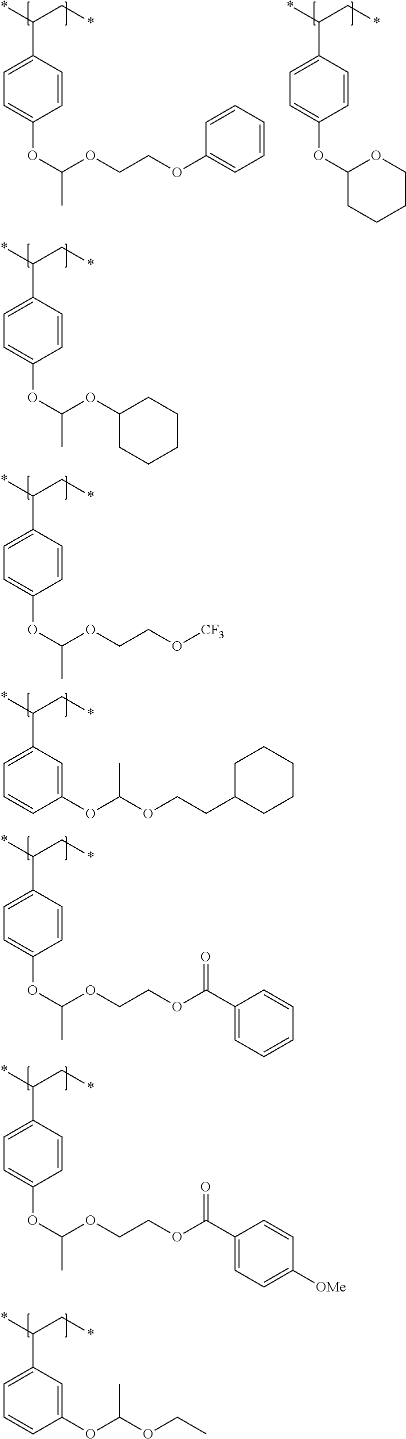

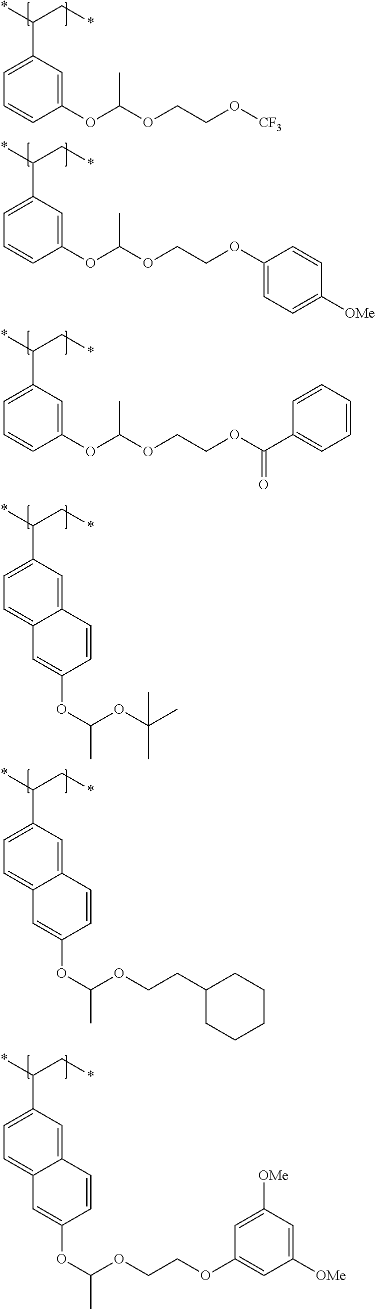

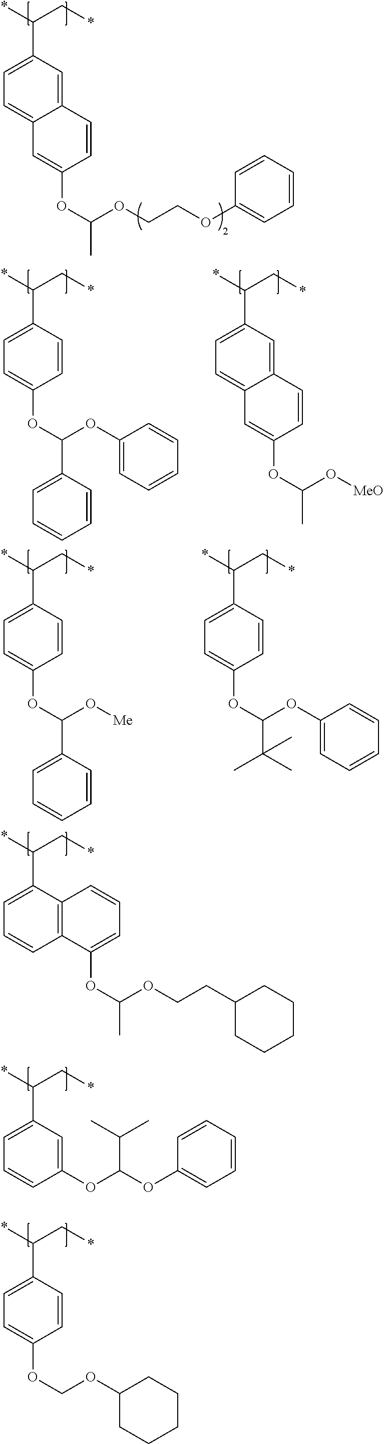

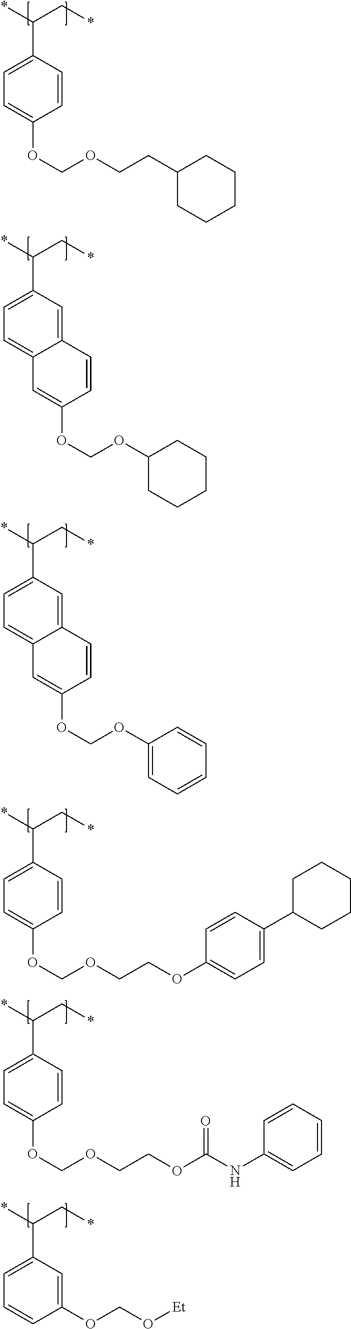

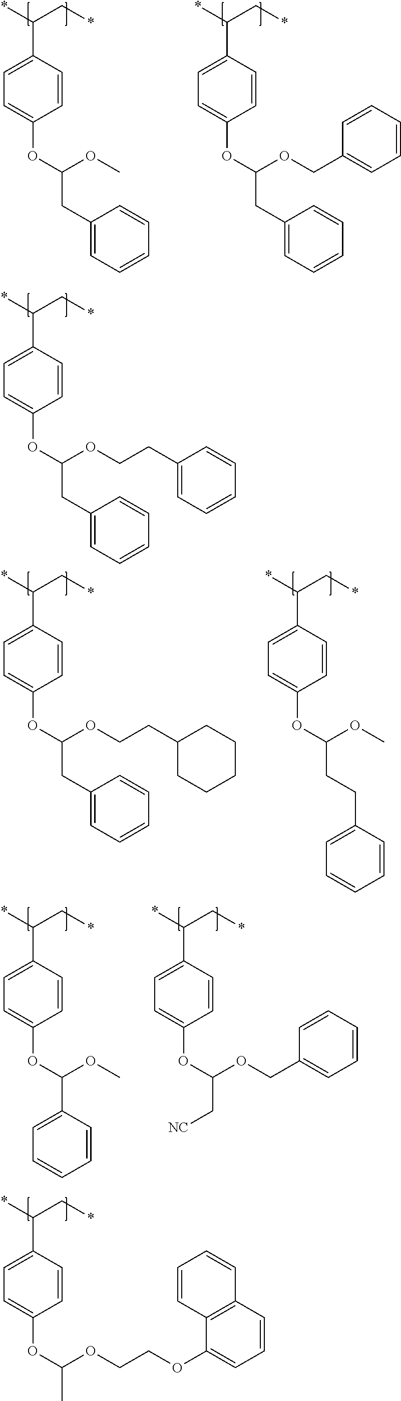

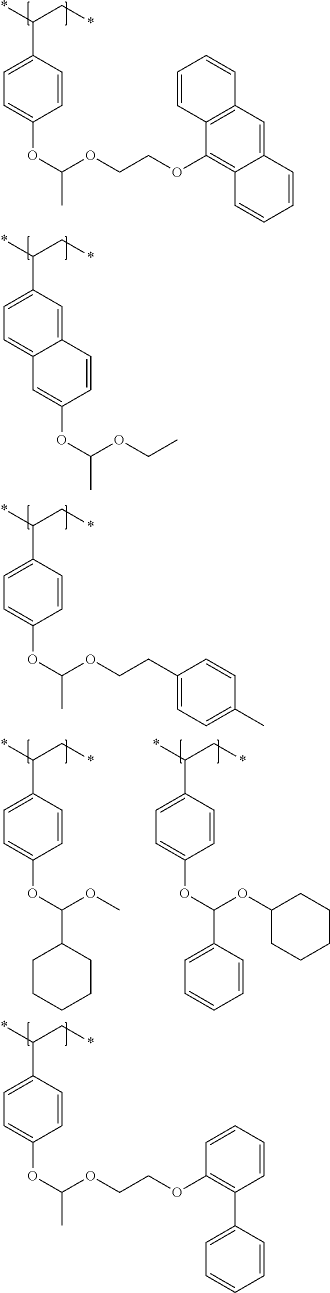

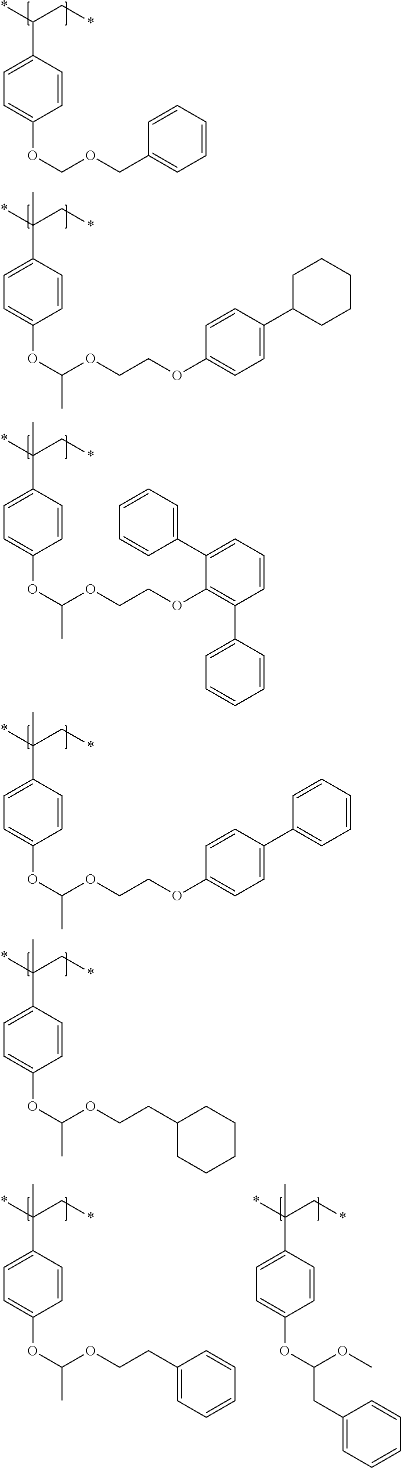

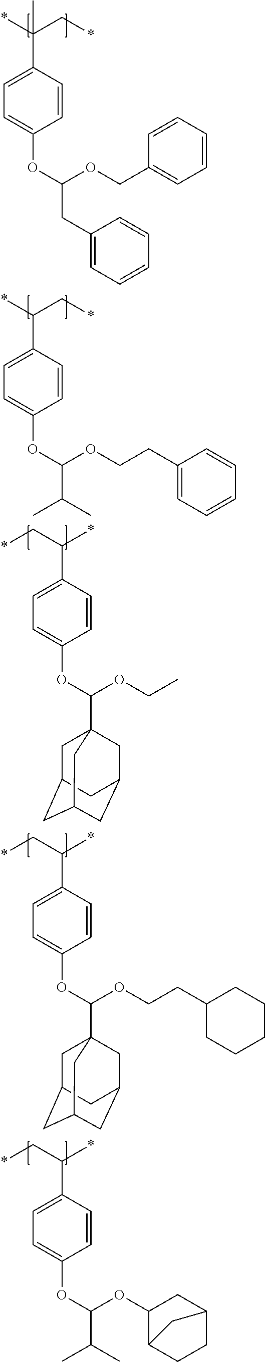

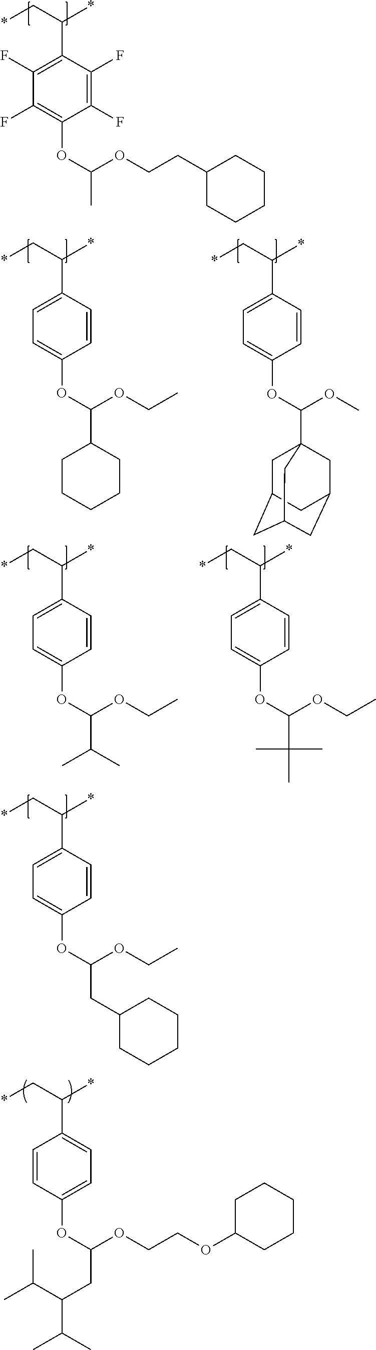

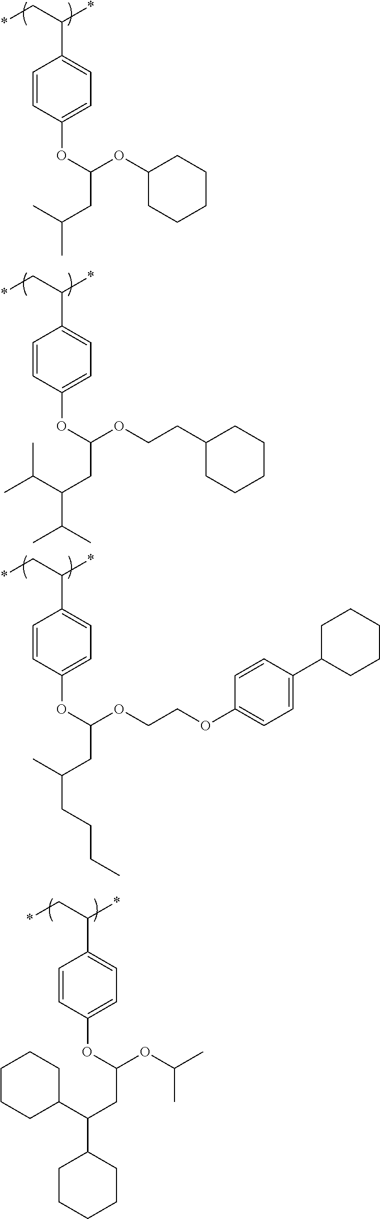

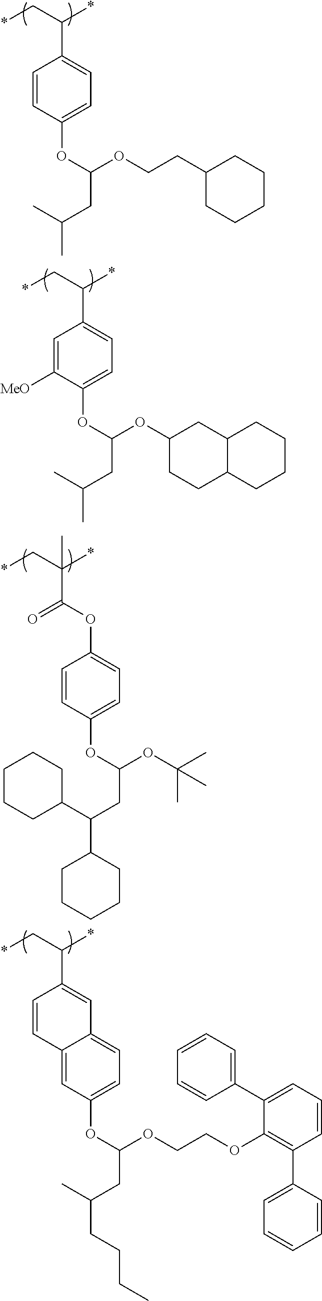

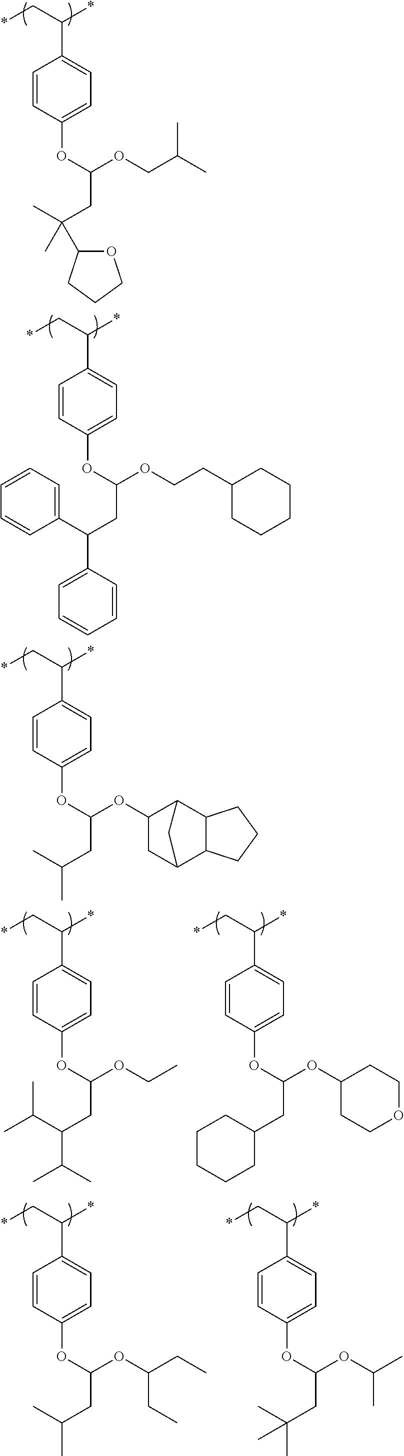

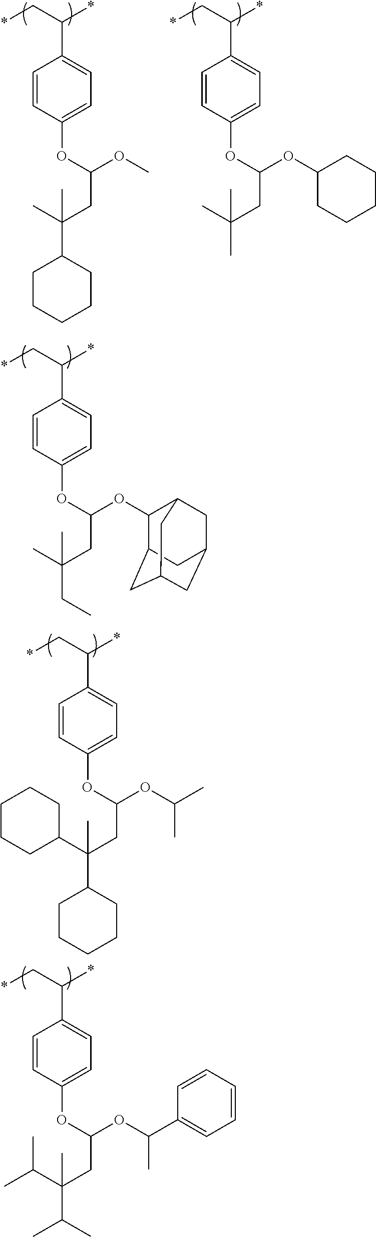

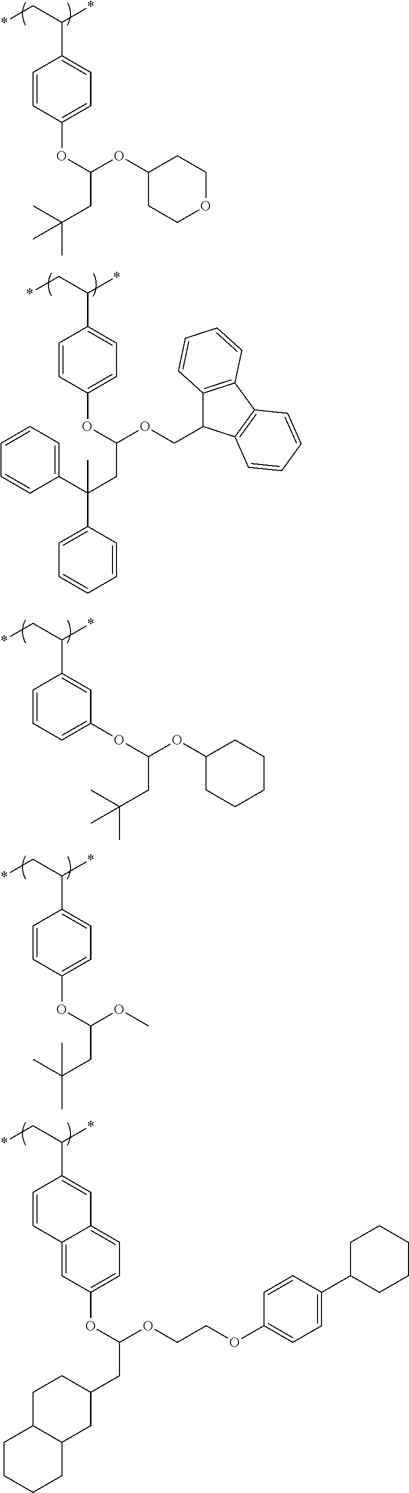

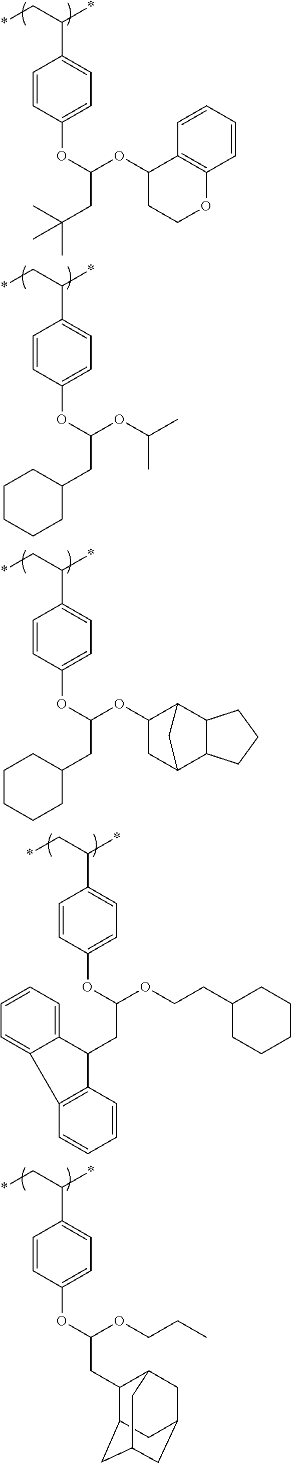

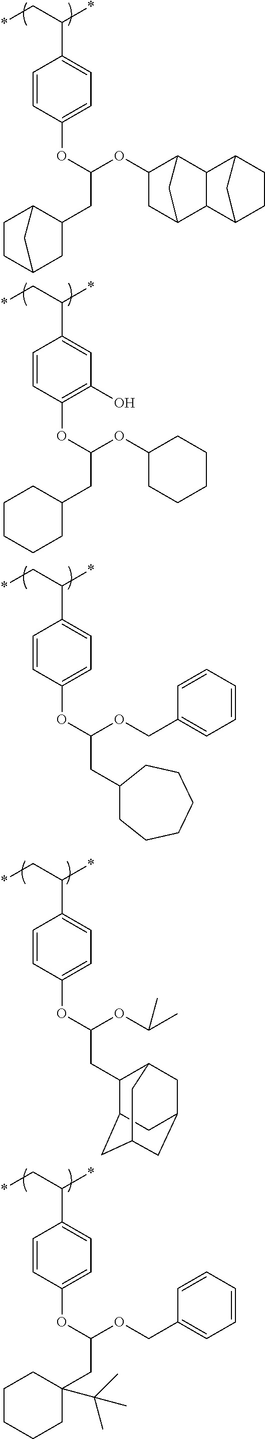

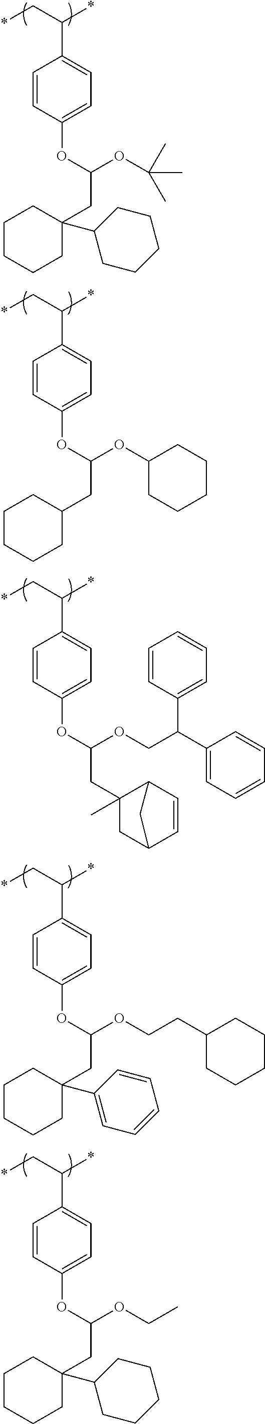

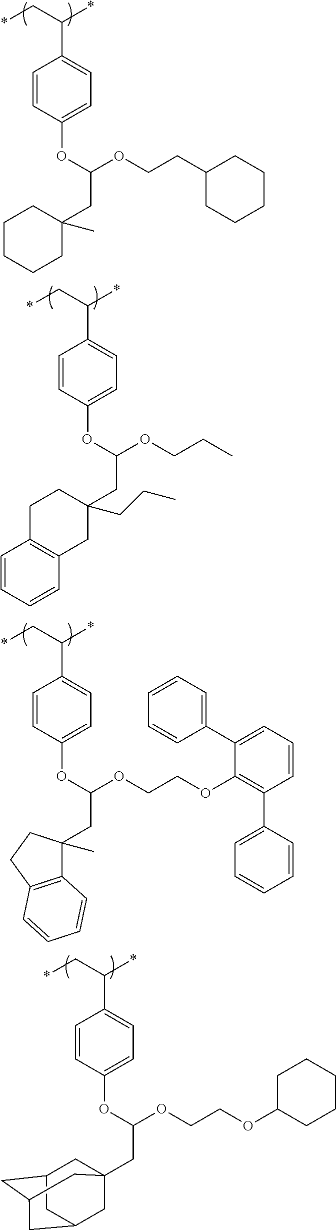

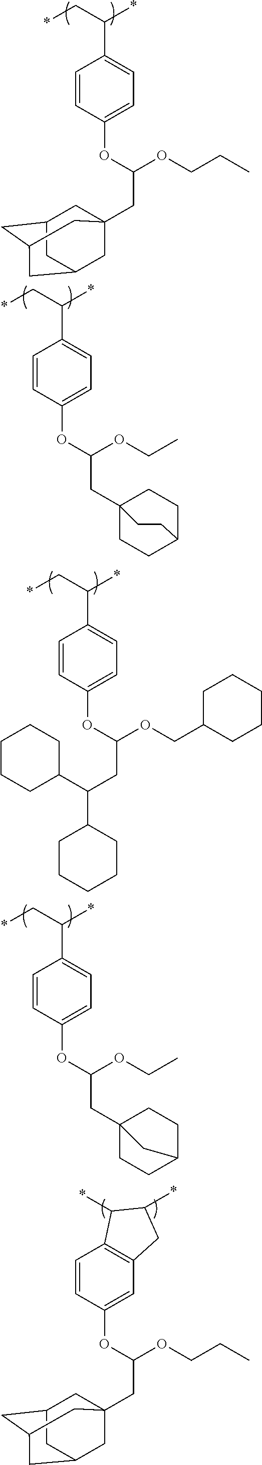

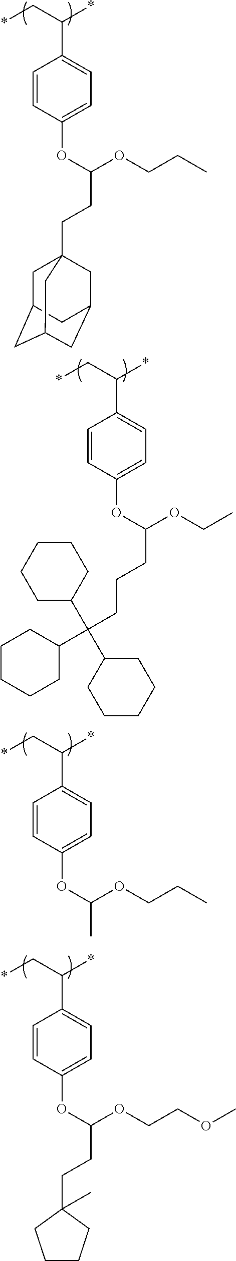

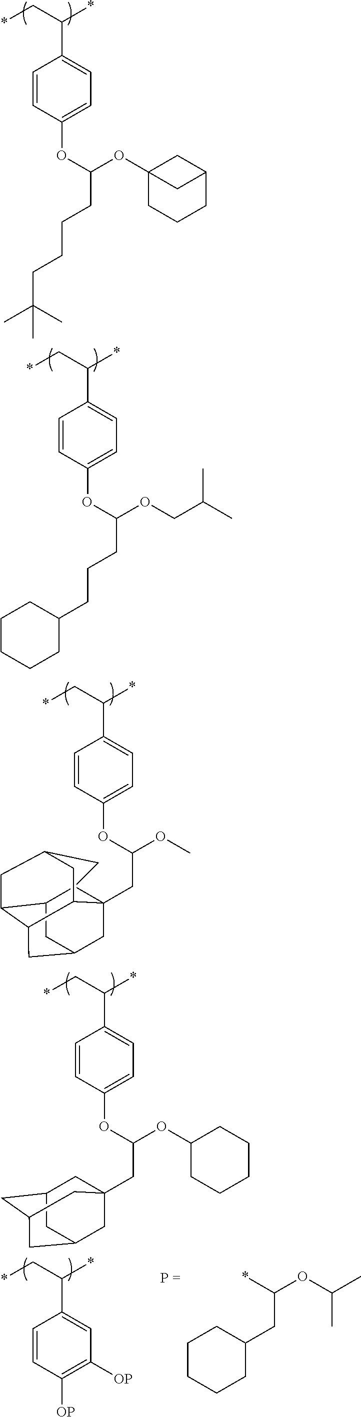

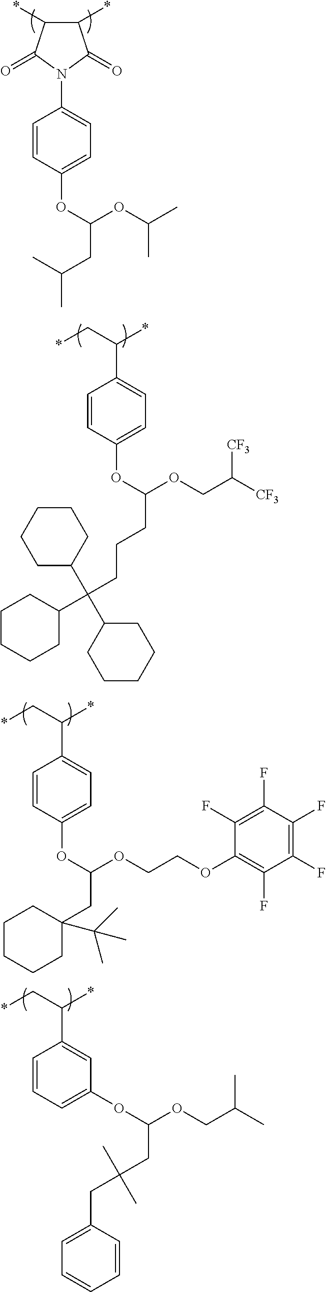

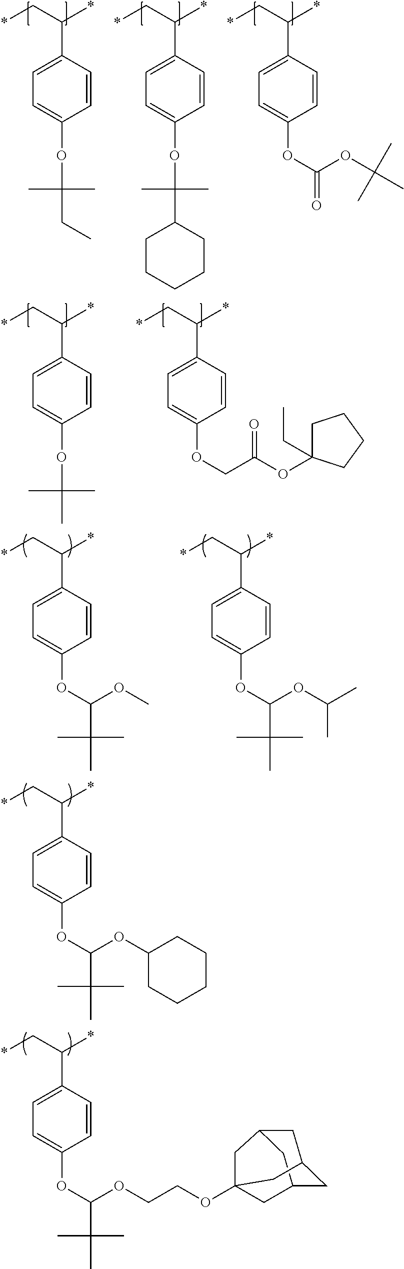

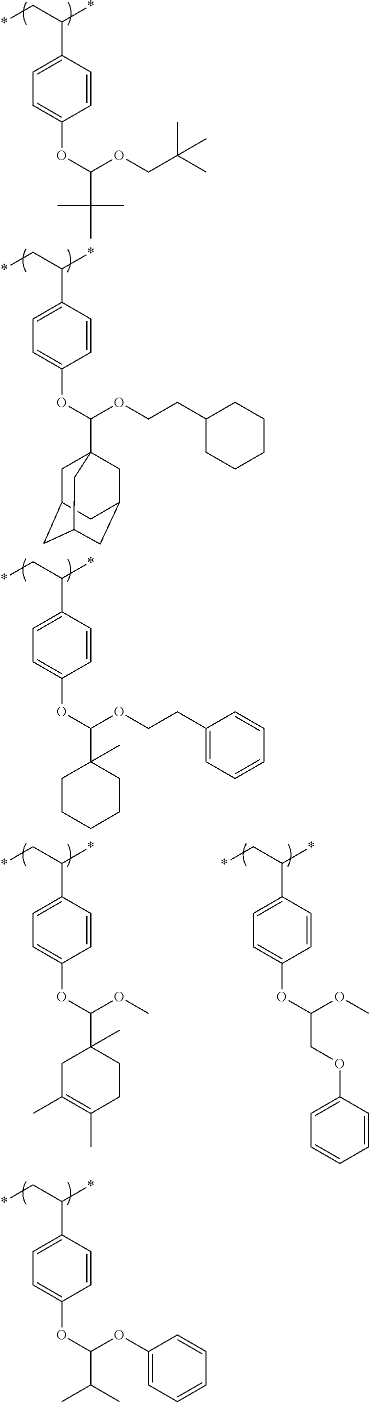

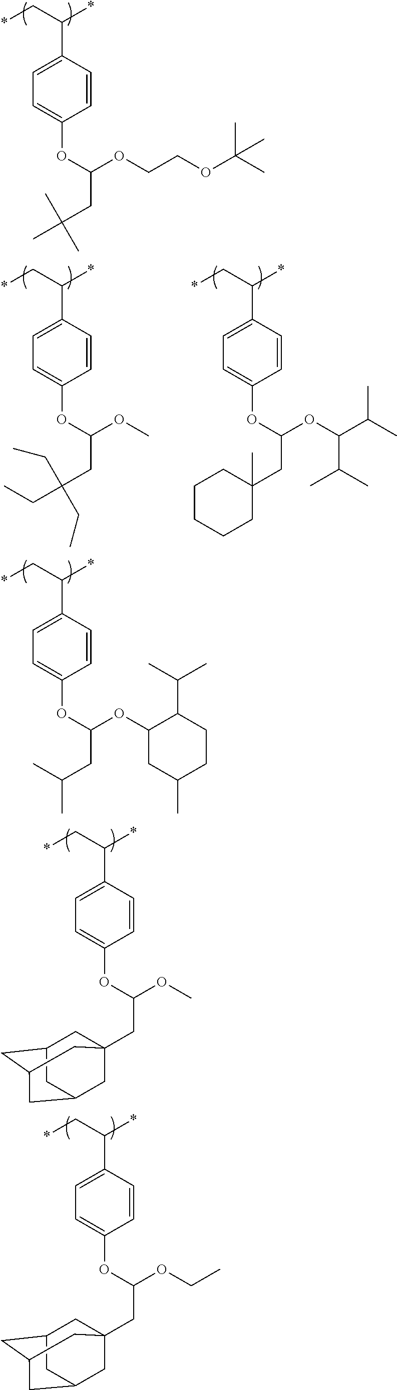

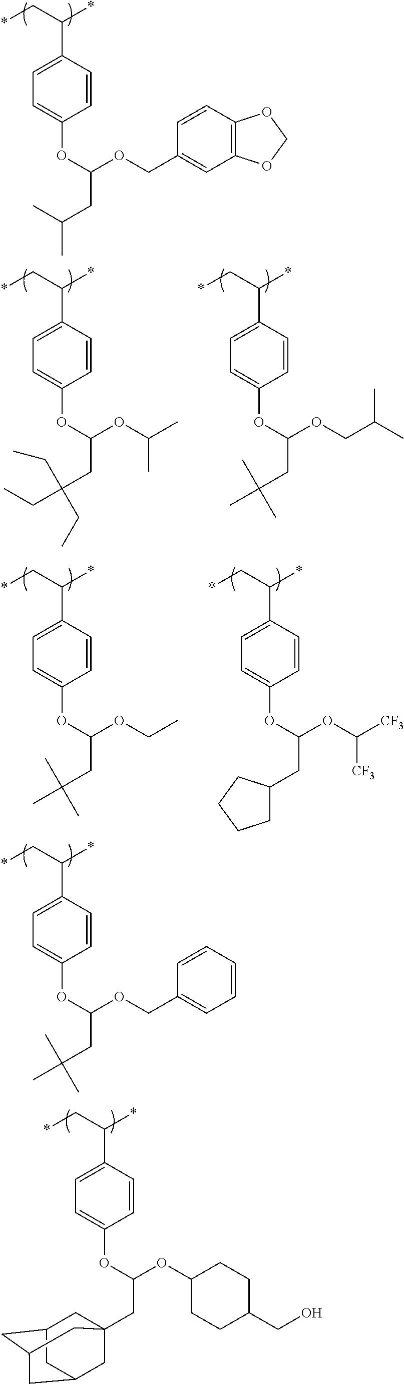

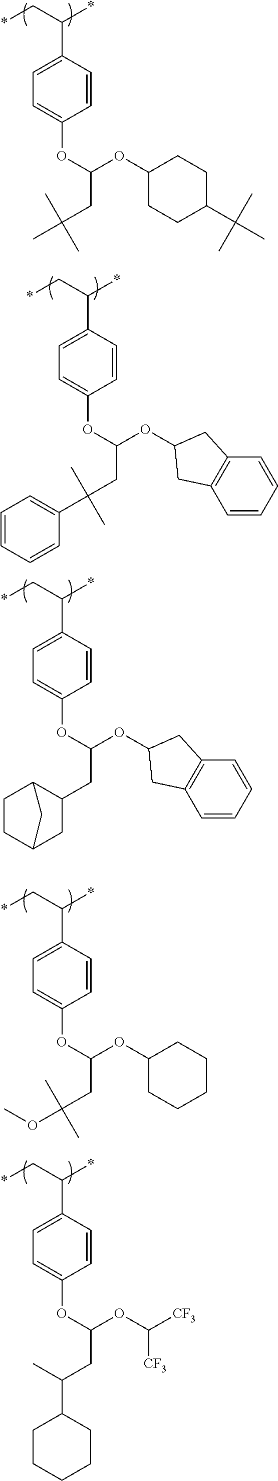

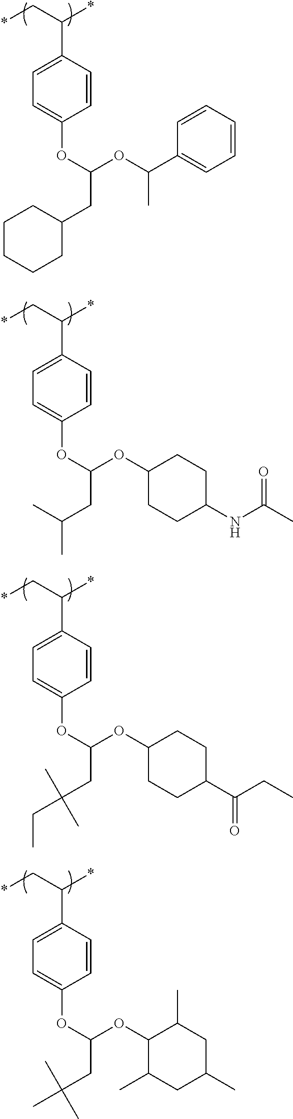

It is also preferred that the repeating unit (B) is a repeating unit represented by the following formula (II).

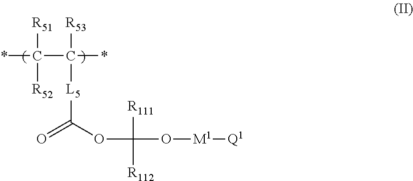

In formula (II), each of R₅₁, R₅₂ and R₅₃ independently represents a hydrogen atom, an alkyl group, a cycloalkyl group, a halogen atom, a cyano group, or an alkoxycarbonyl group. R₅₂ may be bonded to L₅ to form a ring and R₅₂ in such a case represents an alkylene group.

L₅ represents a single bond or a divalent linking group, and in the case of forming a ring together with R₅₂, L₅ represents a trivalent linking group.

R₁₁₁ represents a hydrogen atom or an alkyl group.

R₁₁₂ represents a hydrogen atom, an alkyl group, a cycloalkyl group, an aryl group, an aralkyl group, an alkoxy group, an acyl group, or a heterocyclic group.

M¹ represents a single bond or a divalent linking group.

Q¹ represents an alkyl group, a cycloalkyl group, an aryl group, or a heterocyclic group. Q¹ and R₁₁₂ may be bonded to each other to form a ring.

When M¹ is a divalent linking group, Q¹ may be bonded to M¹ via a single bond or a different linking group to form a ring.

The alkyl group of R₅₁ to R₅₃ in formula (II) is preferably an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, or a dodecyl group, each of which groups may have a substituent, more preferably an alkyl group having 8 or less carbon atoms, and especially preferably an alkyl group having 3 or less carbon atoms.

The alkyl group contained in the alkoxycarbonyl group is the same with the alkoxy group in R₅₁ to R₅₃ above.

The cycloalkyl group may be monocyclic or polycyclic. A monocyclic alkyl group having 3 to 8 carbon atoms, such as a cyclopropyl group, a cyclopentyl group, or a cyclohexyl group, which group may have a substituent, is preferably exemplified.

As the halogen atom, a fluorine atom, a chlorine atom, a bromine atom, and an iodine atom are exemplified, and a fluorine atom is especially preferred.

The preferred examples of the substituents in each group above include, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the number of the substituents is preferably 8 or less.

In the case where R₅₂ is an alkylene group and forms a ring together with L₅, the alkylene group is preferably an alkylene group having 1 to 8 carbon atoms, such as a methylene group, an ethylene group, a propylene group, a butylene group, a hexylene group, or an octylene group, more preferably an alkylene group having 1 to 4 carbon atoms, and especially preferably an alkylene group having 1 or 2 carbon atoms. The ring formed by bonding R₅₂ and L₅ is especially preferably 5- or 6-membered ring.

Each of R₅₁ and R₅₃ in formula (II) is more preferably a hydrogen atom, an alkyl group, or a halogen atom, and especially preferably a hydrogen atom, a methyl group, an ethyl group, a trifluoromethyl group (—CF₃), a hydroxymethyl group (—CH₂—OH), a chloromethyl group (—CH₂—Cl), or a fluorine atom (—F). R₅₂ is more preferably a hydrogen atom, an alkyl group, a halogen atom, or an alkylene group (forming a ring with L₅), and especially preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring with L₅), or an ethylene group (forming a ring with L₅).

In formula (II), the alkyl group of R₁₁₁ is preferably an alkyl group having 1 to 10 carbon atoms, more preferably an alkyl group having 1 to 5 carbon atoms, still more preferably an alkyl group having 1 to 3 carbon atoms, and still yet preferably an alkyl group having 1 or 2 carbon atoms (i.e., a methyl group or an ethyl group). As the specific examples of the alkyl group of R₁₁₁, for example, a methyl group, an ethyl group, an n-propyl group, an isopropyl group, an n-butyl group, an isobutyl group, a sec-butyl group, and a t-butyl group can be exemplified.

R₁₁₁ is preferably a hydrogen atom or an alkyl group having 1 to 5 carbon atoms, more preferably a hydrogen atom or an alkyl group having 1 to 3 carbon atoms, still more preferably a hydrogen atom, a methyl group, or an ethyl group, and especially preferably a hydrogen atom.

As the divalent linking group represented by L₅, an alkylene group, a divalent aromatic cyclic group, —COO-L₁-, —O-L₁-, and a group formed by combining two or more thereof are exemplified. Here, L₁ represents an alkylene group, a cycloalkylene group, a divalent aromatic cyclic group, or a group formed by combining an alkylene group and a divalent aromatic cyclic group.

As the divalent aromatic cyclic group, a 1,4-phenylene group, a 1,3-phenylene group, a 1,2-phenylene group, and a 1,4-naphthylene group are preferred, and a 1,4-phenylene group is more preferred.

L₅ is preferably a single bond, a group represented by —COO-L₁-, or a group represented by -L₂-O—CH₂—, and especially preferably a single bond. Here, L₂ represents a divalent aromatic cyclic group.

The cycloalkylene group of L₁ may contain an ester bond and form a lactone ring.

L₁ preferably represents an alkylene group having 1 to 15 carbon atoms which may contain a heteroatom or a carbonyl bond, more preferably an alkylene group which may contain a heteroatom, and still more preferably a methylene group, an ethylene group, or a propylene group.

L₂ preferably represents an arylene group (preferably having 1 to 10 carbon atoms), more preferably a 1,4-phenylene group, a 1,3-phenylene group, or a 1,2-phenylene group, and still more preferably a 1,4-phenylene group or a 1,3-phenylene group.

The specific examples of the partial structure (the partial structure of the main chain) represented by the following formula (1-1) in the repeating unit represented by formula (II) are described as follows, but the invention is not restricted thereto.

In the formulae, “.” indicates the bond connecting to the oxygen atom of the acetal structure in formula (II).

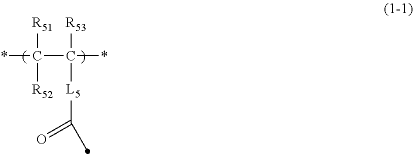

As the trivalent linking group represented by L₅ in the case where L₅ is bonded to R₅₂ to form a ring, a group obtained by subtracting arbitrary one hydrogen atom from the above-described specific examples of the divalent linking group represented by L₅ is preferably exemplified.

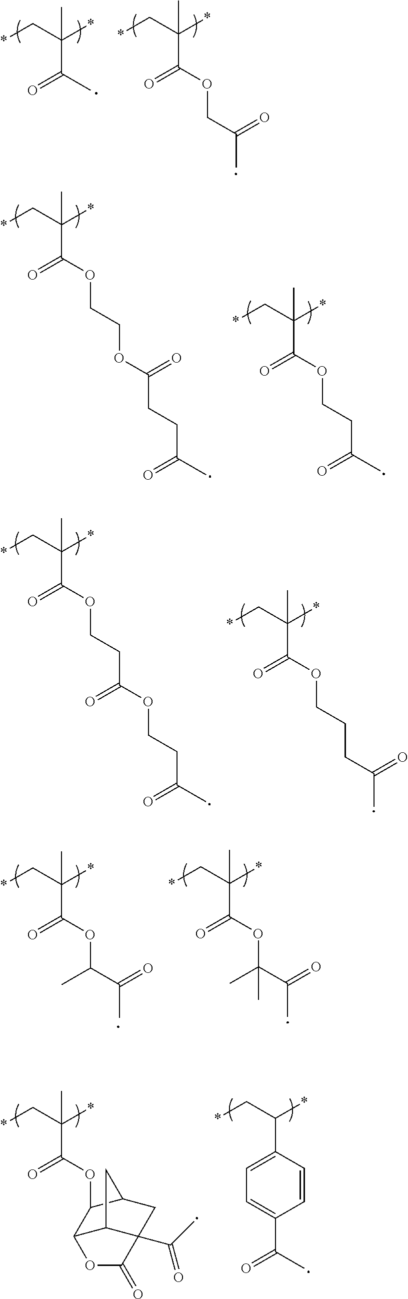

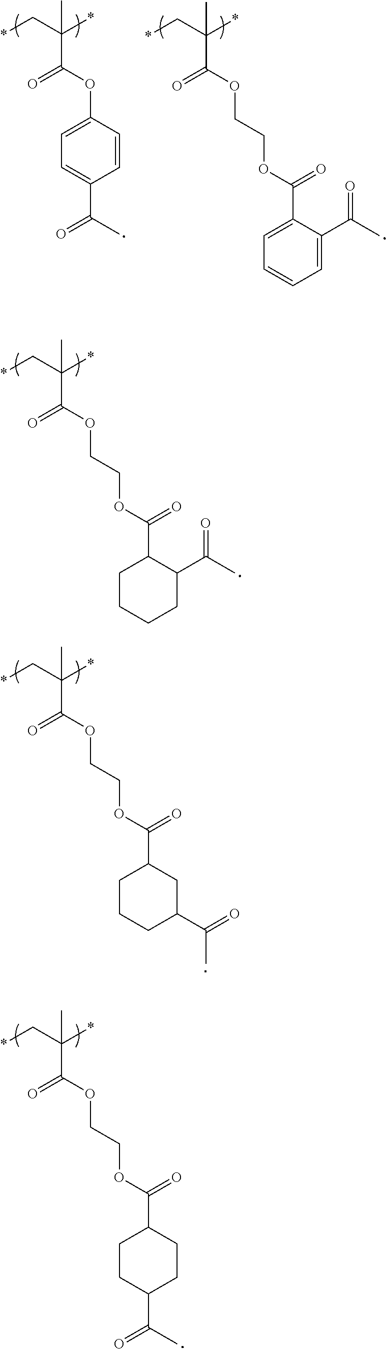

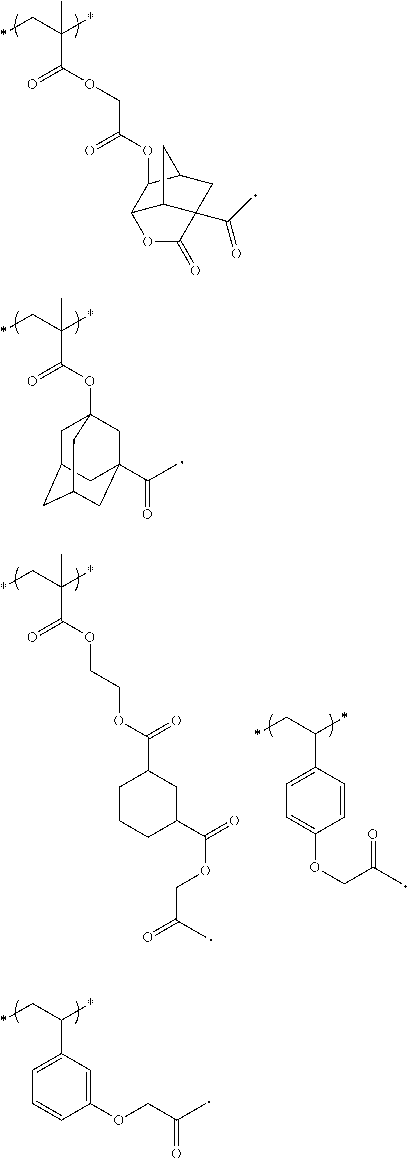

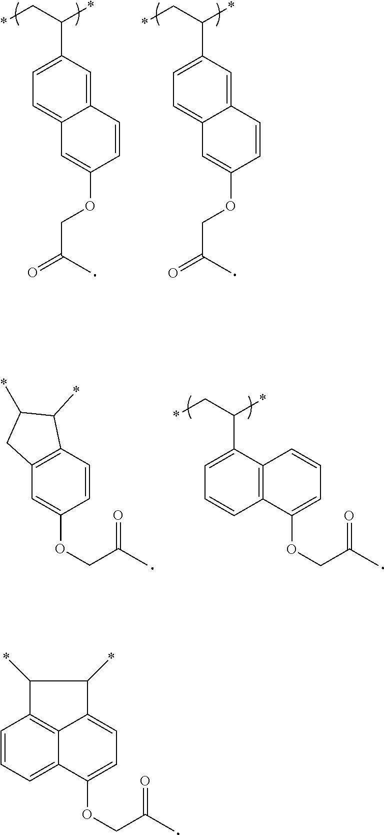

R₁₁₂ represents a hydrogen atom, an alkyl group, a cycloalkyl group, an aryl group, an aralkyl group, an alkoxy group, an acyl group, or a heterocyclic group. In view of lowering the rate of residual film thickness of the resin (P), the carbon atom number of R₁₁₂ is preferably 15 or less.

The alkyl group represented by R₁₁₂ is preferably an alkyl group having 1 to 15 carbon atoms, more preferably an alkyl group having 1 to 10 carbon atoms, and still more preferably an alkyl group having 1 to 6 carbon atoms. The specific examples of the alkyl groups of R₁₁₂ include, for example, a methyl group, an ethyl group, a propyl group, an isopropyl group, an n-butyl group, a sec-butyl group, a t-butyl group, a neopentyl group, a hexyl group, a 2-ethylhexyl group, an octyl group, and a dodecyl group. The alkyl group of R₁₁₂ is preferably a methyl group, an ethyl group, a propyl group, an isopropyl group, or a t-butyl group.

The cycloalkyl group represented by R₁₁₂ may be monocyclic or polycyclic, preferably a cycloalkyl group having 3 to 15 carbon atoms, more preferably a cycloalkyl group having 3 to 10 carbon atoms, and still more preferably a cycloalkyl group having 3 to 6 carbon atoms. The specific examples of the cycloalkyl groups of R₁₁₂ include, for example, a cyclopropyl group, a cyclobutyl group, a cyclopentyl group, a cyclohexyl group, a cycloheptyl group, a cyclooctyl group, a decahydronaphthyl group, a cyclodecyl group, a 1-adamantyl group, a 2-adamantyl group, a 1-norbornyl group, and a 2-norbornyl group. The cycloalkyl group of R₁₁₂ is preferably a cyclopropyl group, a cyclopentyl group, or a cyclohexyl group.

The aryl group of R₁₁₂ is preferably an aryl group having 6 to 15 carbon atoms, and more preferably an aryl group having 6 to 12 carbon atoms, which also includes the structure in which a plurality of aromatic rings are linked via a single bond (e.g., a biphenyl group and a terphenyl group). The specific examples of the aryl groups of R₁₁₂ include, for example, a phenyl group, a naphthyl group, an anthranyl group, a biphenyl group, and a terphenyl group. The aryl group of R₁₁₂ is preferably a phenyl group, a naphthyl group, or a biphenyl group.

The aralkyl group of R₁₁₂ is preferably an aralkyl group having 6 to 20 carbon atoms, and more preferably an aralkyl group having 7 to 12 carbon atoms. The specific examples of the aralkyl groups of R₁₁₂ include, for example, a benzyl group, a phenethyl group, a naphthylmethyl group, and a naphthylethyl group.

As the alkyl group moiety of the alkoxy group of R₁₁₂, the above-enumerated alkyl groups as alkyl groups as R₁₁₂ are exemplified. As this alkoxy group, a methoxy group, an ethoxy group, an n-propoxy group, and an n-butoxy group are especially preferred.

As the acyl group of R₁₁₂, a linear or branched acyl group having 7 to 12 carbon atoms, for example, an acetyl group, a propionyl group, an n-butanoyl group, an i-butanoyl group, an n-heptanoyl group, a 2-methylbutanoyl group, a 1-methylbutanoyl group, and a t-heptanoyl group can be exemplified.

The heterocyclic group of R₁₁₂ is preferably a heterocyclic group having 6 to 20 carbon atoms, and more preferably a heterocyclic group having 6 to 12 carbon atoms. The specific examples of the heterocyclic groups of R₁₁₂ include, for example, a pyridyl group, a pyrazyl group, a tetrahydrofuranyl group, a tetrahydropyranyl group, a tetrahydrothiophene group, a piperidyl group, a piperazyl group, a furanyl group, a pyranyl group, and a chromanyl group.

The alkyl group as R₁₁₁ and the alkyl group, cycloalkyl group, aryl group, aralkyl group, alkoxy group, acyl group and heterocyclic group as R₁₁₂ may further have a substituent.

As the examples of the substituents that the alkyl group as R₁₁₁ and R₁₁₂ may further have, for example, a cycloalkyl group, an aryl group, an amino group, an amido group, a ureido group, a urethane group, a hydroxyl group, a carboxyl group, a halogen atom, an alkoxy group, an aralkyloxy group, a thioether group, an acyl group, an acyloxy group, an alkoxycarbonyl group, a cyano group, and a nitro group are exemplified.

As the examples of the substituents that the cycloalkyl group as R₁₁₂ may further have, an alkyl group, and the groups described above as the specific examples of the substituents that the alkyl group may further have are exemplified.

The carbon atom number of the alkyl group and the carbon atom number of the substituents that the cycloalkyl group may further have is preferably 1 to 8.

As the examples of the substituents that the aryl group, aralkyl group and heterocyclic group as R₁₁₂ may further have, for example, a nitro group, a halogen atom, e.g., a fluorine atom, a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms) are exemplified.

R₁₁₂ is described in further detail.

R₁₁₂ in formula (II) is more preferably a hydrogen atom or a group represented by formula —(CH₂)ₙ₁—C(R²¹)(R²²)(R²³).

In the above formula, each of R²¹ to R²³ independently represents a hydrogen atom, an alkyl group, a cycloalkyl group, an aryl group, an aralkyl group, or a heterocyclic group, and at least two of R²¹ to R²³ independently represent an alkyl group, a cycloalkyl group, an aryl group, an aralkyl group, or a heterocyclic group.

At least two of R²¹ to R²³ may be bonded to each other to form a ring.

n represents an integer of 0 to 6.

Due to R₁₁₂ in formula (II) being the group represented by —(CH₂)ₙ₁—C(R²¹)(R²²)(R²³), bulkiness is improved and the glass transition temperature (Tg) of the resin (P) is further heightened. As a result, the dissolution contrast of the resin (P) and the resolution are improved the more.

As the specific examples and preferred examples of the alkyl group of R²¹ to R²³, the same specific examples and preferred examples of the alkyl group of R₁₁₂ as described above are exemplified.

As described above, it is preferred that at least two of R²¹ to R²³ independently represent an alkyl group, a cycloalkyl group, an aryl group, an aralkyl group, or a heterocyclic group, and all of R²¹ to R²³ represent an alkyl group, a cycloalkyl group, an aryl group, an aralkyl group, or a heterocyclic group.

As the specific examples and preferred examples of the cycloalkyl group of R²¹ to R²³, the same specific examples and preferred examples of the cycloalkyl group of R₁₁₂ as described above are exemplified.

As the specific examples and preferred examples of the aryl group of R²¹ to R²³, the same specific examples and preferred examples of the aryl group of R₁₁₂ as described above are exemplified.

As the specific examples and preferred examples of the aralkyl group of R²¹ to R²³, the same specific examples and preferred examples of the aralkyl group of R₁₁₂ as described above are exemplified.

As the specific examples and preferred examples of the heterocyclic group of R²¹ to R²³, the same specific examples and preferred examples of the heterocyclic group of R₁₁₂ as described above are exemplified.

The alkyl group, cycloalkyl group, aryl group, aralkyl group and heterocyclic group of R²¹ to R²³ may further have a substituent.

As the specific examples of the substituents that the alkyl group of R²¹ to R²³ may further have, the same specific examples of the substituents that the alkyl group of R₁₁₂ may further have as described above are exemplified.

As the specific examples of the substituents that the cycloalkyl group of R²¹ to R²³ may further have, an alkyl group and the same specific examples of the substituents that the alkyl group may further have as described above are exemplified.

The number of carbon atoms of the alkyl group and the number of carbon atoms of the substituents that the cycloalkyl group may further have are preferably 1 to 8, respectively.

When R²¹ to R²³ represent an alkyl group or a cycloalkyl group, it is more preferred that all of R²¹ to R²³ represent an alkyl group or all of R²¹ to R²³ represent a cycloalkyl group, it is still more preferred that all of R²¹ to R²³ represent an alkyl group, and it is most preferred that all of R²¹ to R²³ represent a methyl group.

As the specific examples and preferred examples of the substituents that the aryl group, aralkyl group and heterocyclic group of R²¹ to R²³ may further have, the same specific examples and preferred examples of the substituents that the aryl group, the aralkyl group and the heterocyclic group of R₁₁₂ may further have as described above are exemplified.

At least two of R²¹ to R²³ may be bonded to each other to form a ring.

When at least two of R²¹ to R²³ are bonded to each other to form a ring, the examples of the rings to be formed include a cyclopentane ring, a cyclohexane ring, an adamantane ring, a norbornene ring, and a norbornane ring. These rings may have a substituent, and as the substituents that these rings may have, an alkyl group, and the specific examples of the substituents that the alkyl group may further have as described above are exemplified.

When all of R²¹ to R²³ are bonded to each other to form a ring, the examples of the rings to be formed include, for example, an adamantane ring, a norbornane ring, a norbornene ring, a bicycle[2,2,2]octane ring, and a bicycle[3,1,1]heptane ring. Above all, an adamantane ring is especially preferred. These rings may have a substituent, and as the substituents that these rings may have, an alkyl group, and the specific examples of the substituents that the alkyl group may further have as described above are exemplified.

In view of capable of heightening the glass transition temperature of the resin (P) and capable of improving resolution, each of R²¹ to R²³ preferably independently represents an alkyl group.

The number of carbon atoms of the group represented by —(CH₂)ₙ₁—C(R²¹)(R²²)(R²³) in formula (II) is preferably 15 or less, by bringing the carbon atom number into the above range, the affinity of the resist film to be obtained and a developer becomes sufficient, and an exposed area can be more certainly removed by a developer (that is, sufficient developing property can be obtained).

In view of increasing the glass transition temperature of the resin, n1 is preferably an integer of 0 to 6, and more preferably 0 or 1. In the point of sensitivity increase, n1 is still more preferably 1, and in the point of the enhancement of resolution/resolution of isolated space, n1 is still yet preferably 0.

The specific examples of the groups represented by —C(R²¹)(R²²)(R²³) in R₁₁₂ (preferably the group represented by —(CH₂)ₙ₁—C(R²¹)(R²²)(R²³)) are shown below, but the invention is not restricted thereto. In the following specific examples, * indicates the carbon atom to which R₁₁₁ in formula (II) is connected, or a bond to be connected to the linking group represented by —(CH₂)ₙ₁— in R₁₁₂.

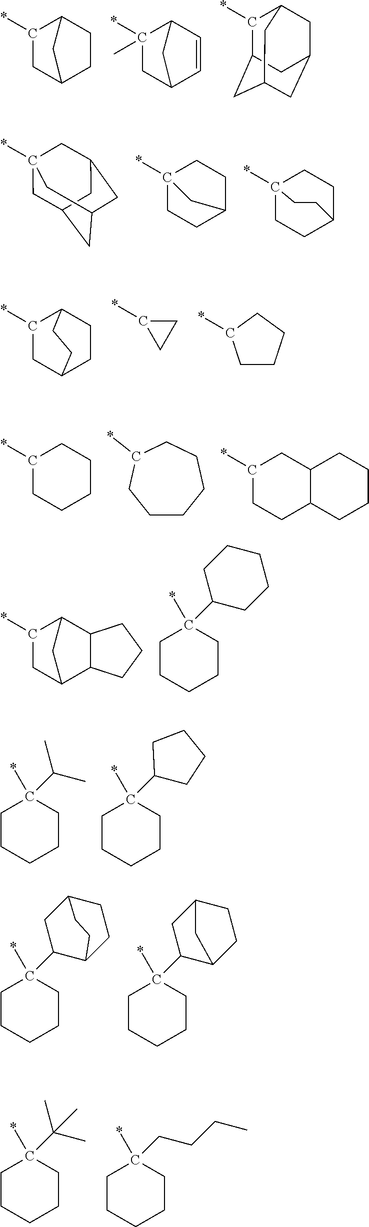

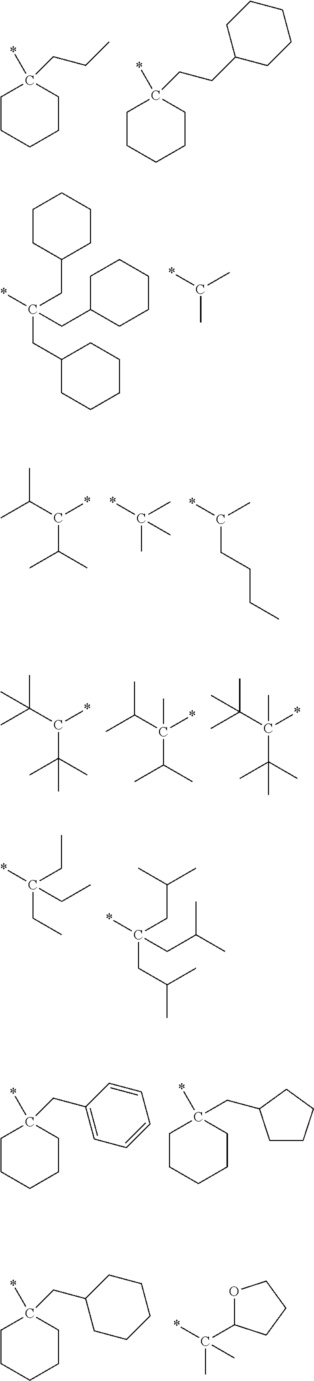

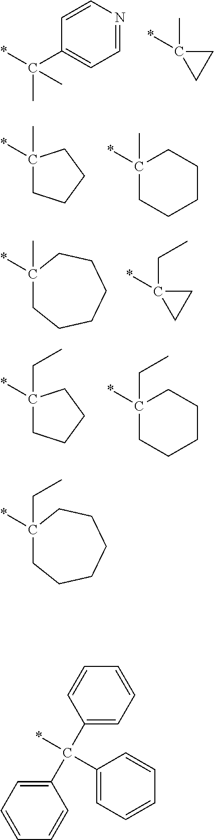

The divalent linking group represented by M¹ is, for example, an alkylene group (preferably an alkylene group having 1 to 8 carbon atoms, e.g., a methylene group, an ethylene group, a propylene group, a butylene group, a hexylene group, or an octylene group), a cycloalkylene group (preferably a cycloalkylene group having 3 to 15 carbon atoms, e.g., a cyclopentylene group or a cyclohexylene group), —S—, —O—, —CO—, —CS—, —SO₂—, —N(Ro)-, or a group formed by combining two or more of these groups, and the total carbon atom number is preferably 20 or less. Here, Ro is a hydrogen atom, or an alkyl group (for example, an alkyl group having 1 to 8 carbon atoms, specifically a methyl group, an ethyl group, a propyl group, an n-butyl group, a sec-butyl group, a hexyl group, or an octyl group).

M¹ is preferably a single bond, an alkylene group, or a divalent linking group comprising a combination of an alkylene group and at least one of —O—, —CO—, —CS—, and —N(Ro)-, and more preferably a single bond, an alkylene group, or a divalent linking group comprising a combination of an alkylene group and —O—. Ro has the same meaning with the above Ro.

M¹ may further have a substituent, and the substituents that M¹ may further have are the same with the substituents that the alkyl group of R²¹ may have.

The specific examples and preferred examples of the alkyl groups as Q¹ are the same with those described above as to the alkyl groups of R²¹.

The cycloalkyl group as Q¹ may be monocyclic or polycyclic. The carbon atom number of the cycloalkyl group is preferably 3 to 10. The examples of the cycloalkyl groups include, for example, a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}.0^{2,7}]dodecyl group, an 8-tricyclo[5.2.1.0^{2,6}]decyl group, and a 2-bicyclo[2.2.1]heptyl group. Of these groups, a cyclopentyl group, a cyclohexyl group, a 2-adamantyl group, an 8-tricyclo[5.2.1.0^{2,6}]decyl group, and a 2-bicyclo[2.2.1]heptyl group are preferred.

The specific examples and preferred examples of the aryl groups as Q¹ are, for example, the same with those as described above in the aryl groups as R²¹.

The specific examples and preferred examples of the heterocyclic groups as Q¹ are, for example, the same with those as described above in the heterocyclic groups as R²¹.

The alkyl group, cycloalkyl group, aryl group, and heterocyclic group as Q¹ may have a substituent and, for example, an alkyl group, a cycloalkyl group, a cyano group, a halogen atom, a hydroxyl group, an alkoxy group, a carboxyl group, and an alkoxycarbonyl group are exemplified as the examples of the substituents.

The group represented by -M¹-Q¹ is preferably an unsubstituted alkyl group, an alkyl group substituted with a cycloalkyl group, a cycloalkyl group, an aralkyl group, an aryloxyalkyl group, or a heterocyclic group. The specific examples and preferred examples of the unsubstituted alkyl group as the group represented by -M¹-Q¹, the “cycloalkyl group” as the group represented by -M¹-Q¹ and the cycloalkyl group in the “alkyl group substituted with a cycloalkyl group”, and the “aralkyl group (arylalkyl group)” as the group represented by -M¹-Q¹ and the aryl group in the “aryloxyalkyl group” are the same with those as described in the alkyl group, cycloalkyl group and aryl group as Q¹, respectively.

The specific examples and preferred examples of the alkyl moieties in the “alkyl group substituted with a cycloalkyl group”, the “aralkyl group (arylalkyl group)” and the “aryloxyalkyl group” as the group represented by -M¹-Q¹ are the same with those as described in the alkylene group as M¹.

The specific examples and preferred examples of the heterocyclic group as the group represented by -M¹-Q¹ are the same with those as described in the heterocyclic group as Q¹.

As the group represented by -M¹-Q¹, specifically for example, a methyl group, an ethyl group, an isopropyl group, a cyclopentyl group, a cyclohexyl group, a cyclohexylethyl group, a 2-adamantyl group, an 8-tricyclo[5.2.1.0.0^{2,6}]decyl group, a 2-bicyclo[2.2.1]heptyl group, a benzyl group, a 2-phenethyl group, and a 2-phenoxyethylene group are exemplified.

Also, as described above, when M¹ is a divalent linking group, Q¹ may be bonded to M¹ via a single bond or a different linking group to form a ring. As the above different linking group, an alkylene group (preferably an alkylene group having 1 to 3 carbon atoms) is exemplified, and the ring to be formed is preferably a 5- or 6-membered.

Q¹, M¹ and R₁₁₂ (in particular, Q¹ and R₁₁₂) may be bonded to each other to form a ring. The ring to be formed is preferably an oxygen-containing heterocyclic ring. The oxygen-containing heterocyclic ring structure may be monocyclic, polycyclic or spirocyclic, preferably a monocyclic oxygen-containing heterocyclic ring structure, and the carbon atom number is preferably 3 to 10, and more preferably 4 or 5.

The specific examples of the groups represented by -M¹-Q¹ are shown below, but the invention is not restricted thereto. In the following specific examples, * represents a bond to be bonded to the oxygen atom in formula (II). Also, Me represents a methyl group, Et represents an ethyl group, and Pr represents an n-propyl group.

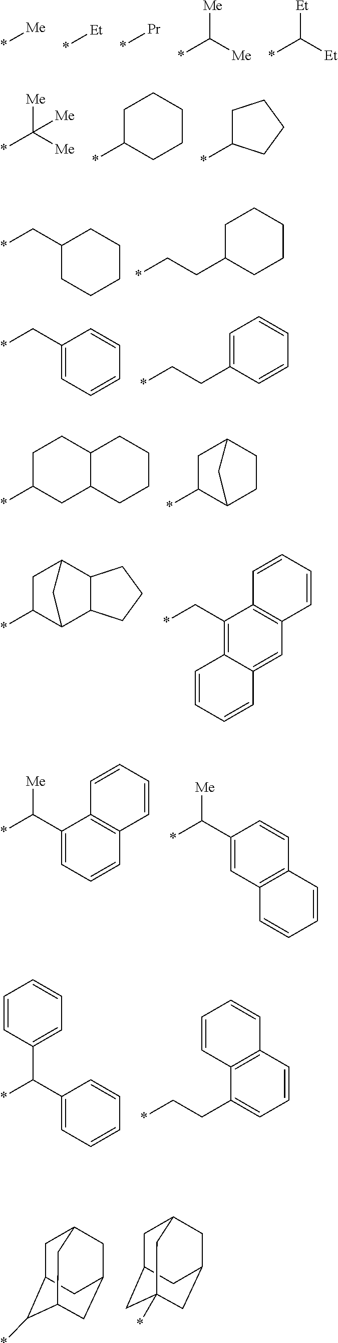

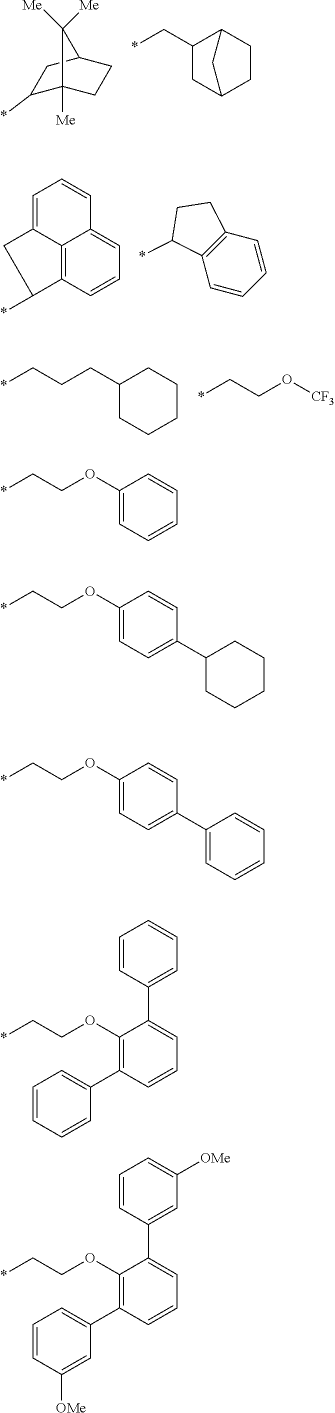

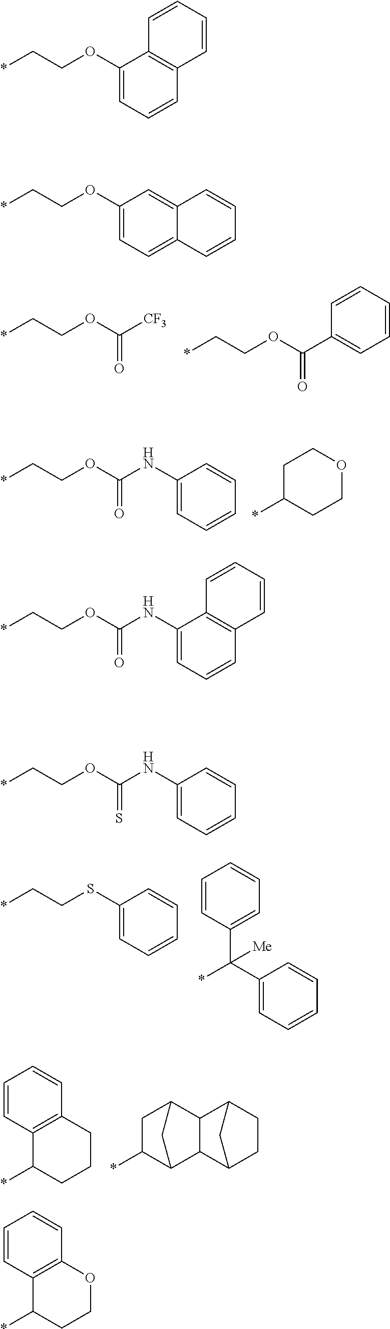

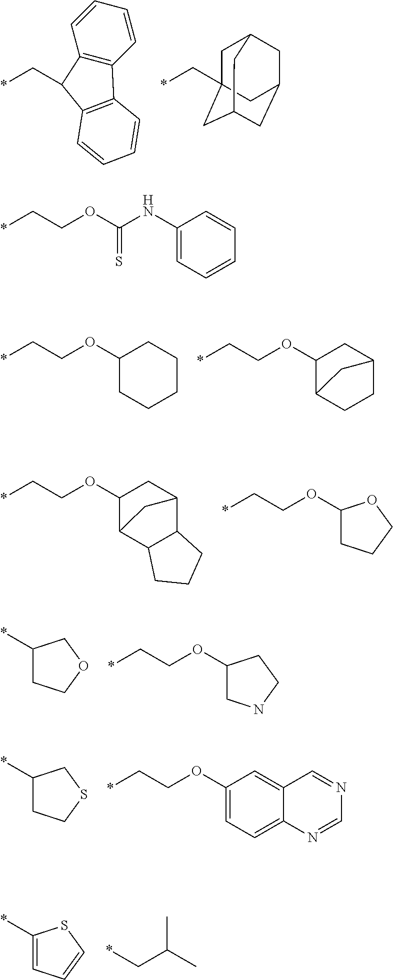

In the repeating unit represented by formula (II), the specific examples of the rings to be formed in the case where Q¹, M¹ and R₁₁₂ are bonded to each other to form a ring are shown below. * Represents a bond to be bonded to the oxygen atom in formula (II). R₄ has the same meaning as R₁₁₁ in formula (II).

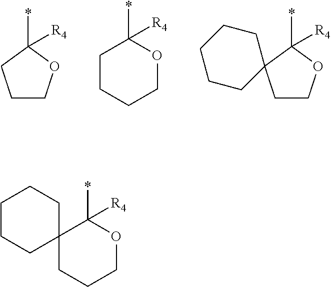

The specific examples of the parts of leaving group containing an acetal structure in the repeating unit represented by formula (II) are shown below, but the invention is not restricted thereto. In the following specific examples, * represents a bond to be bonded to the oxygen atom of the ester bond linked to L₅ in formula (II).

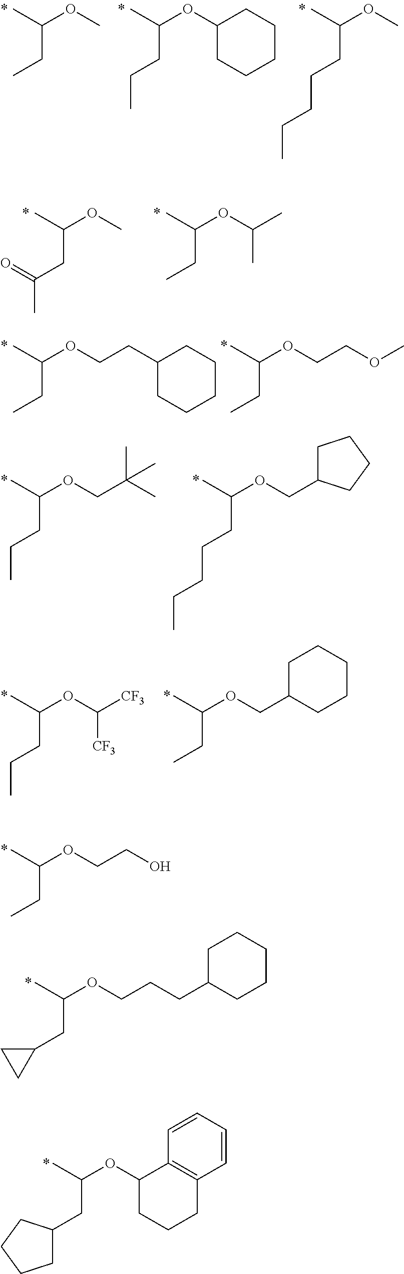

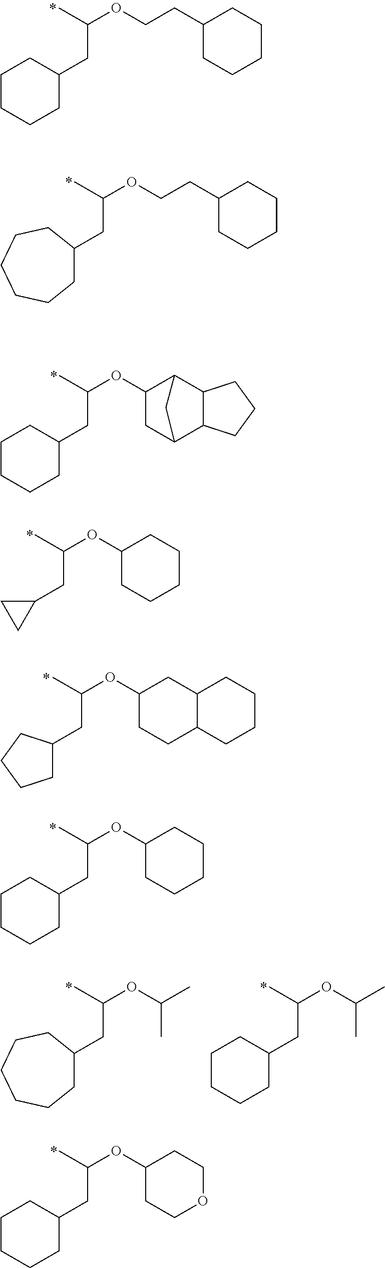

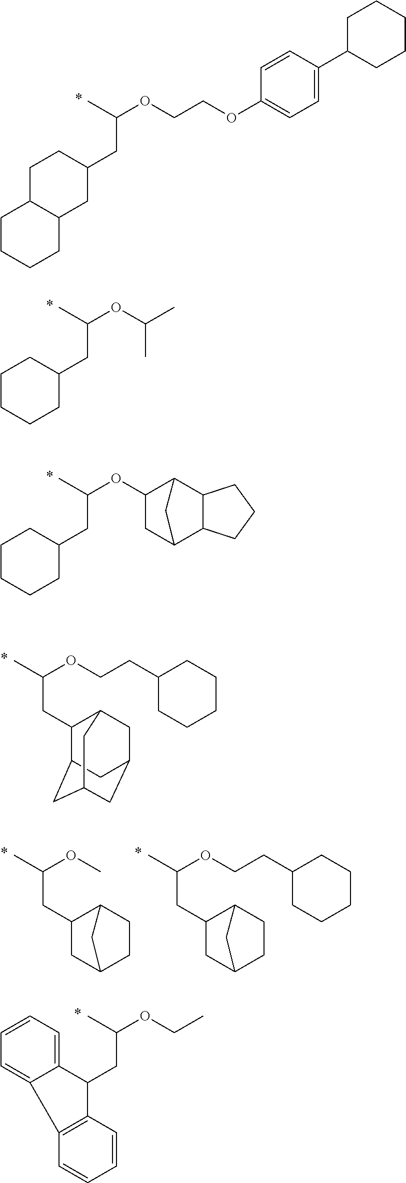

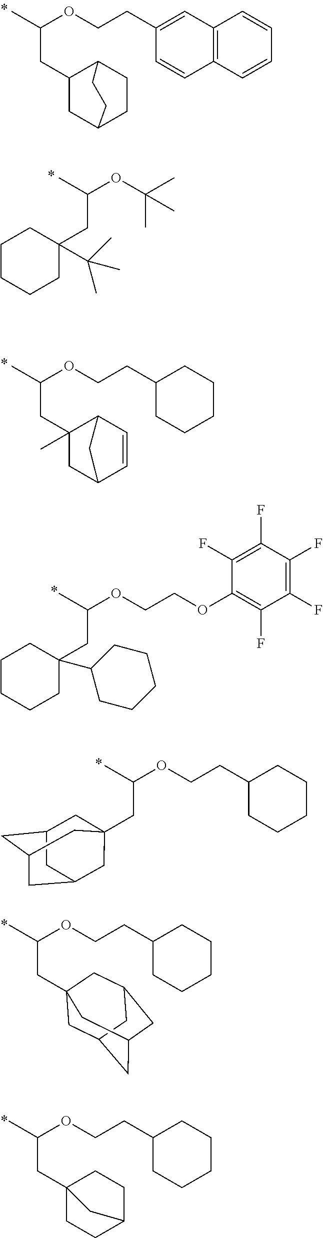

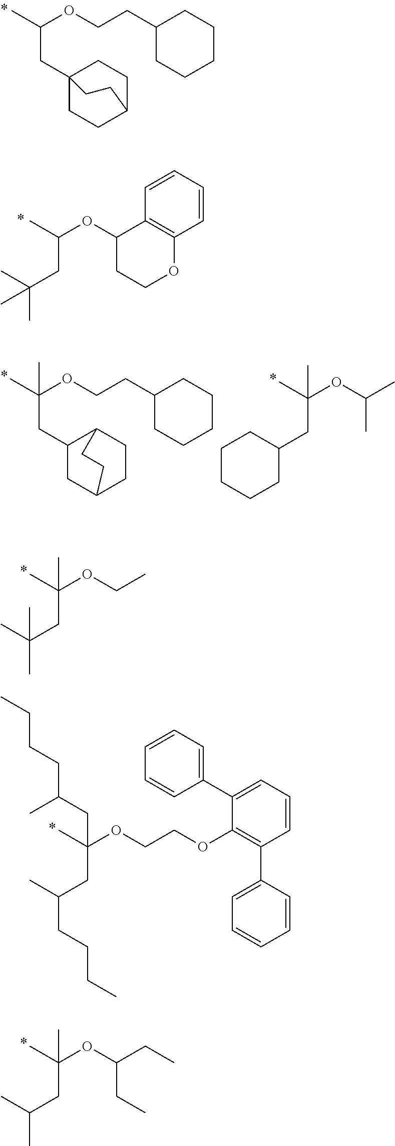

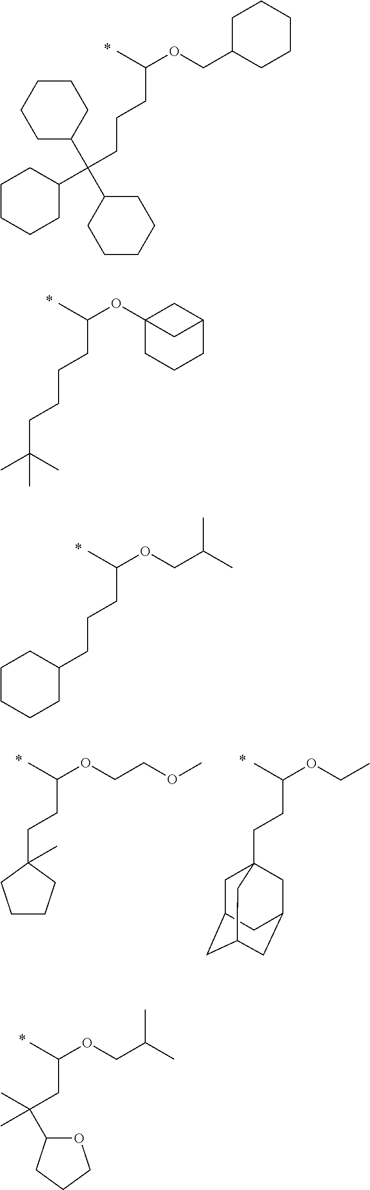

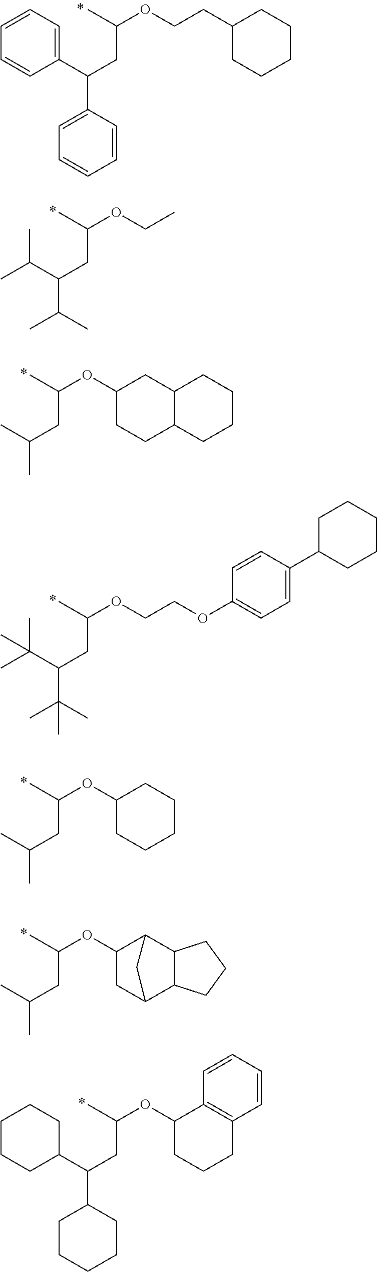

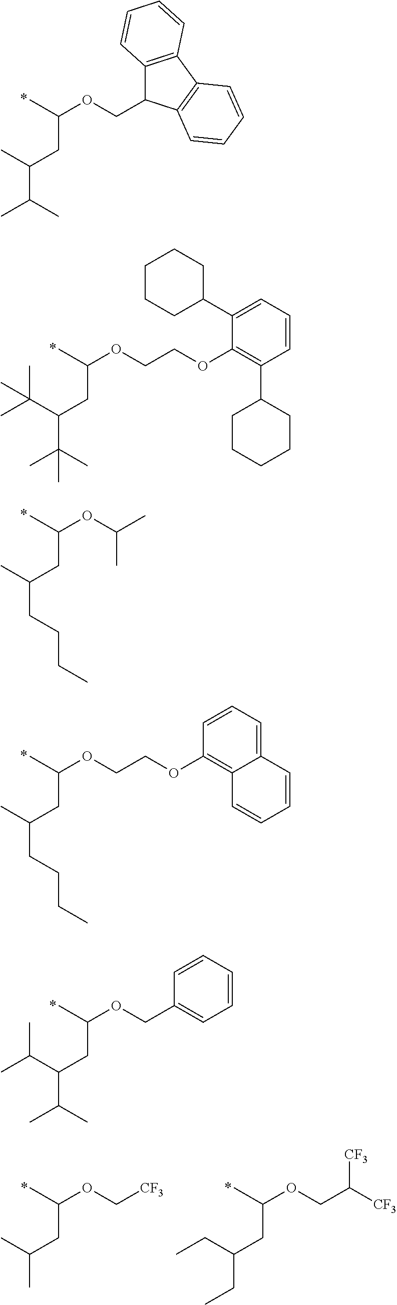

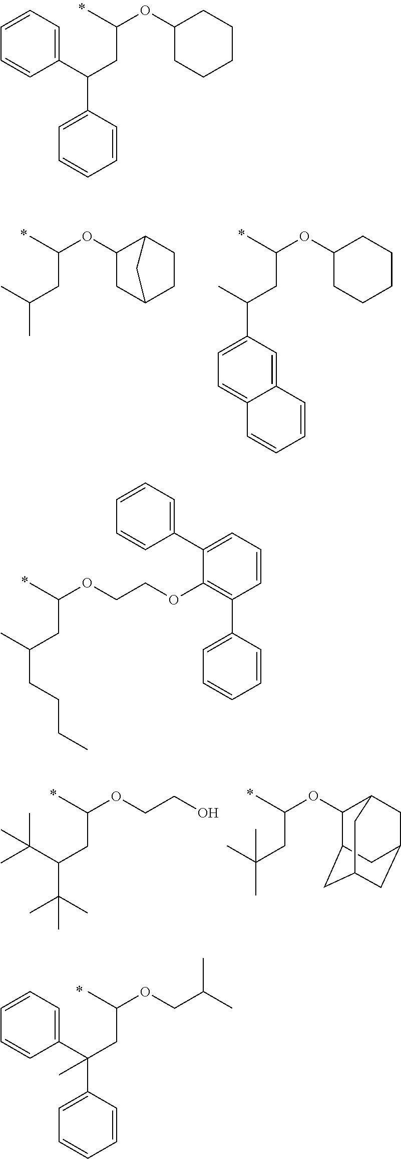

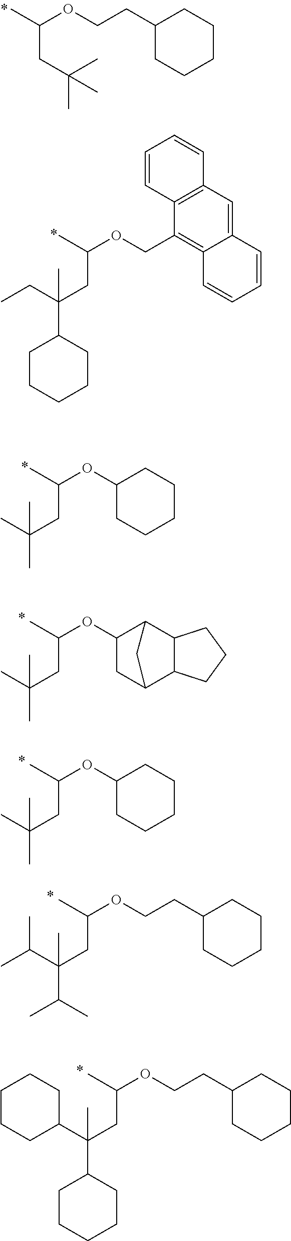

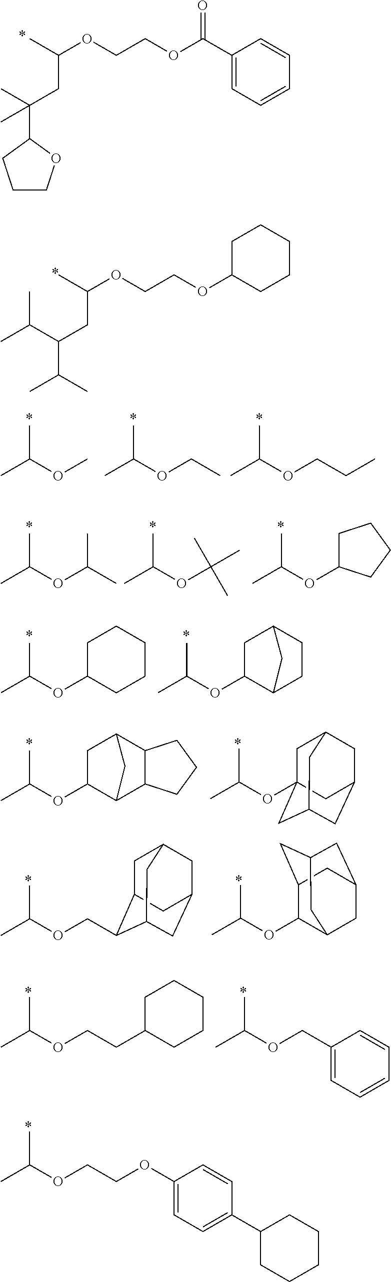

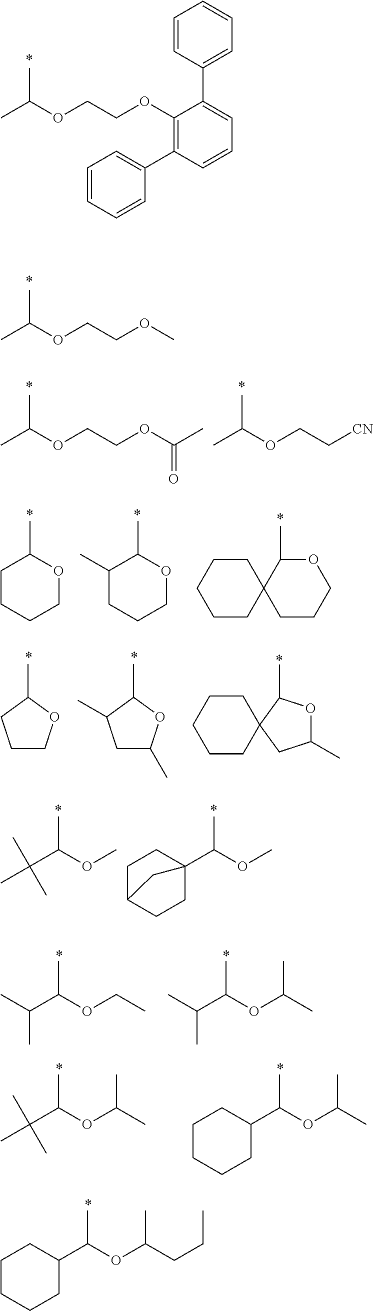

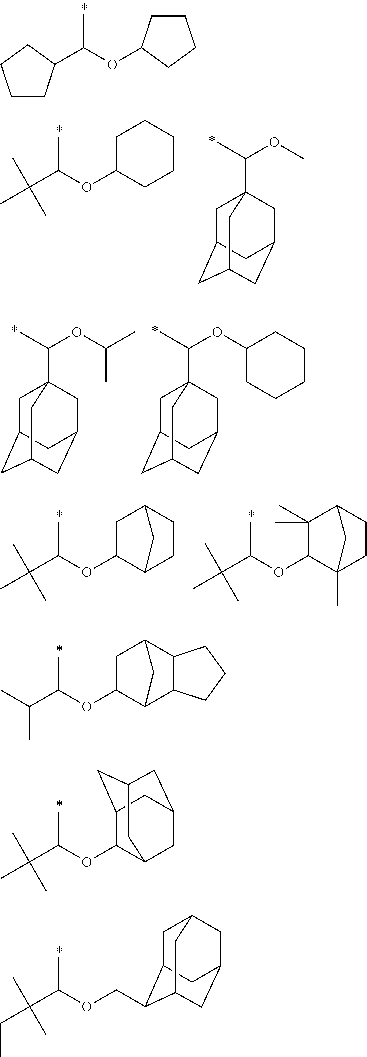

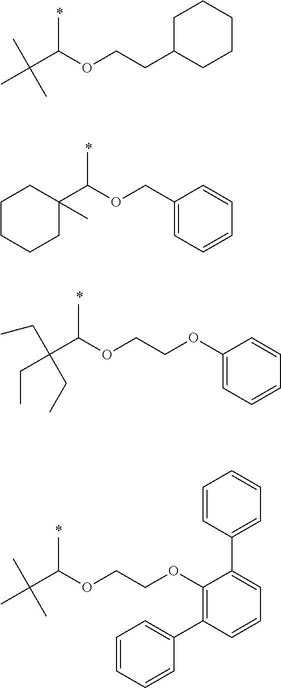

The specific examples of the repeating units represented by formula (II) are shown below, but the invention is not restricted thereto.

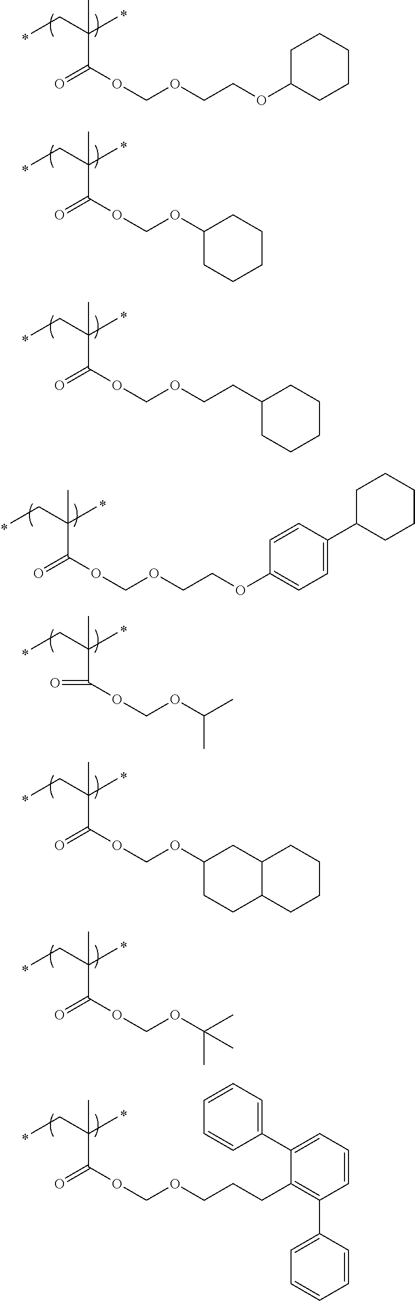

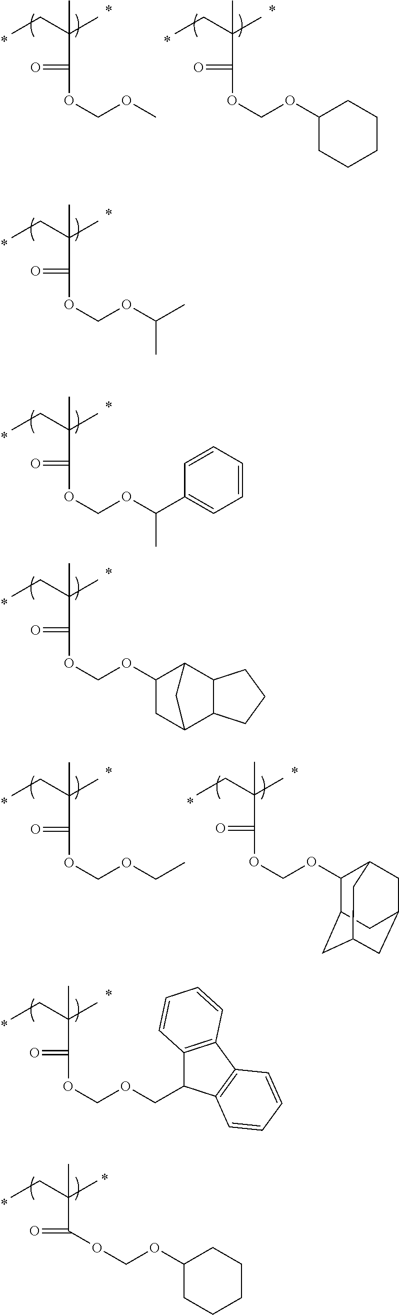

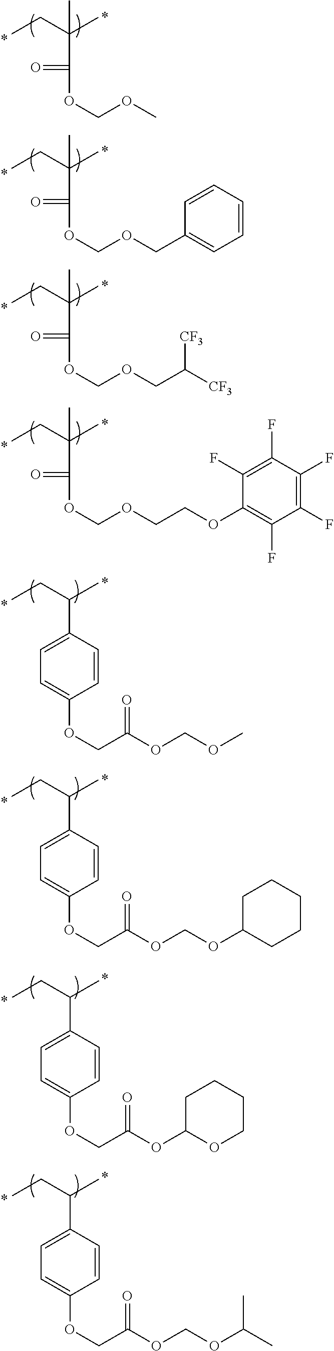

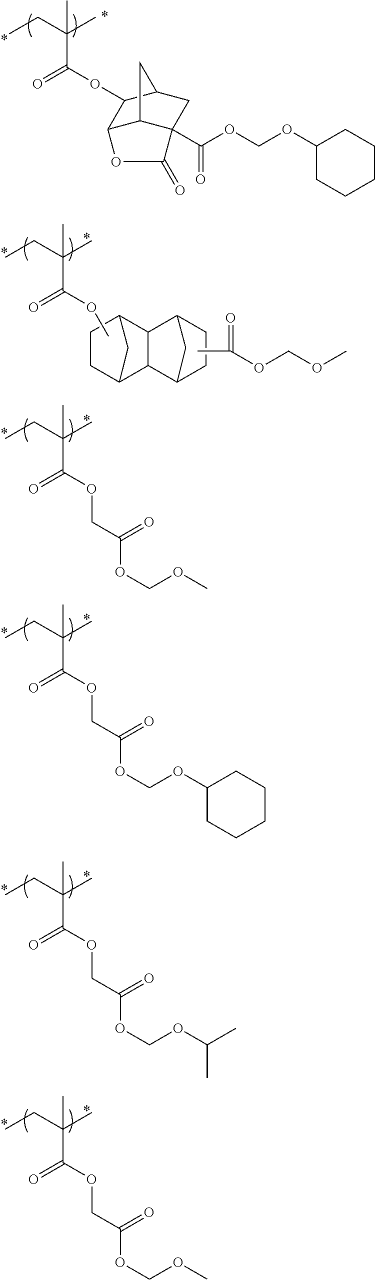

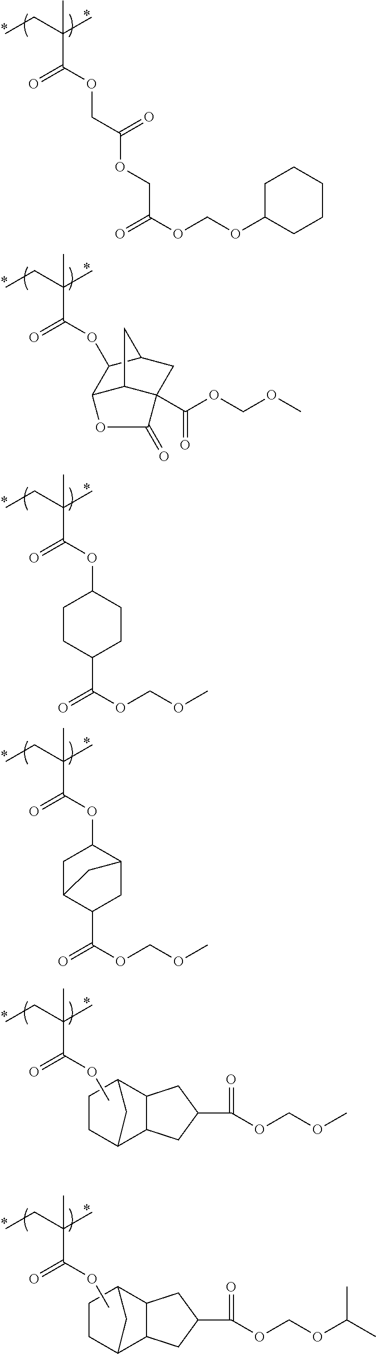

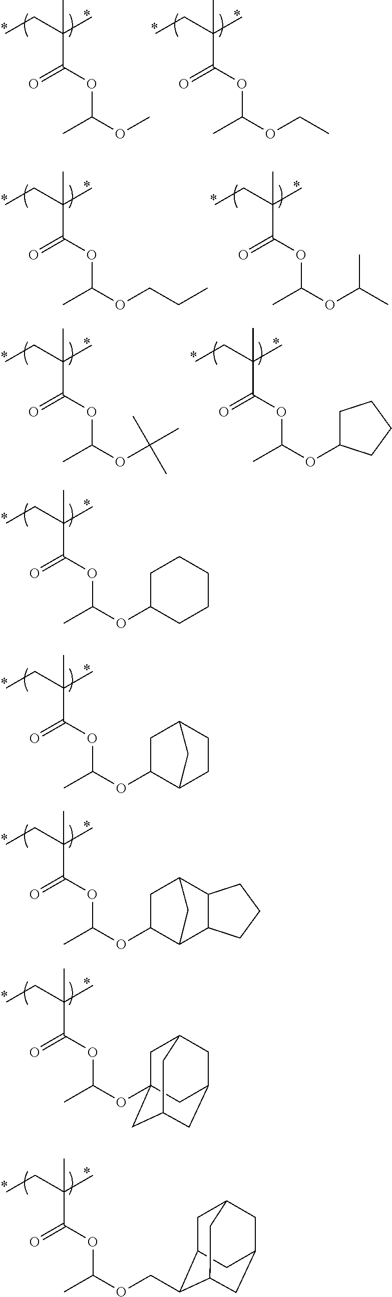

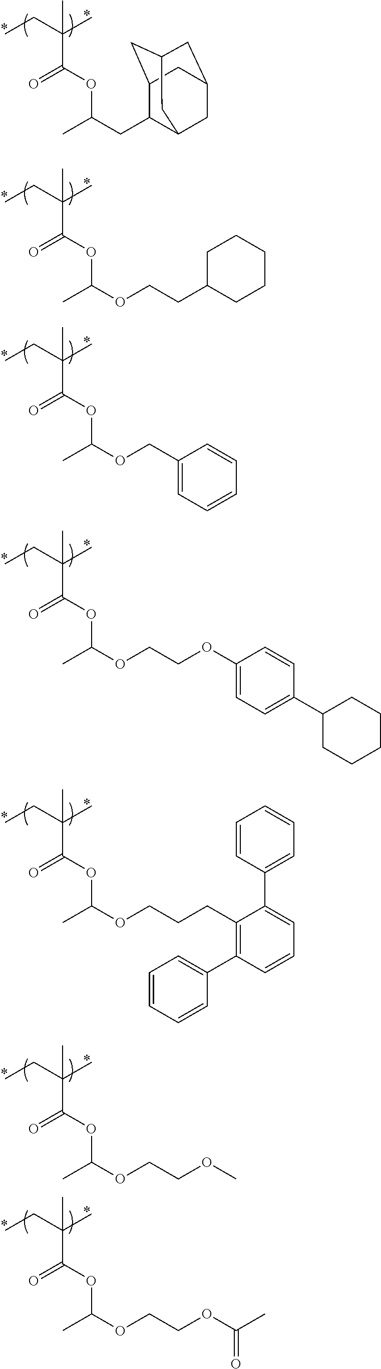

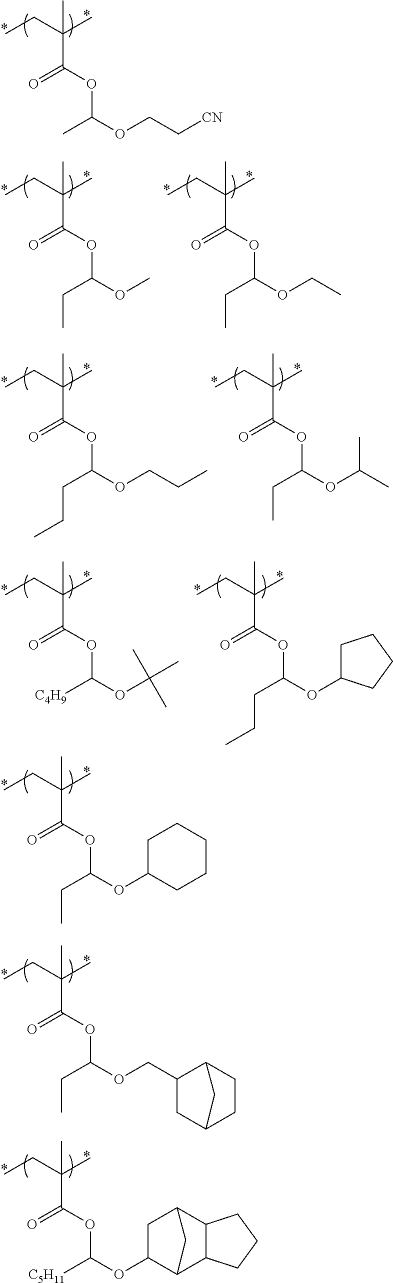

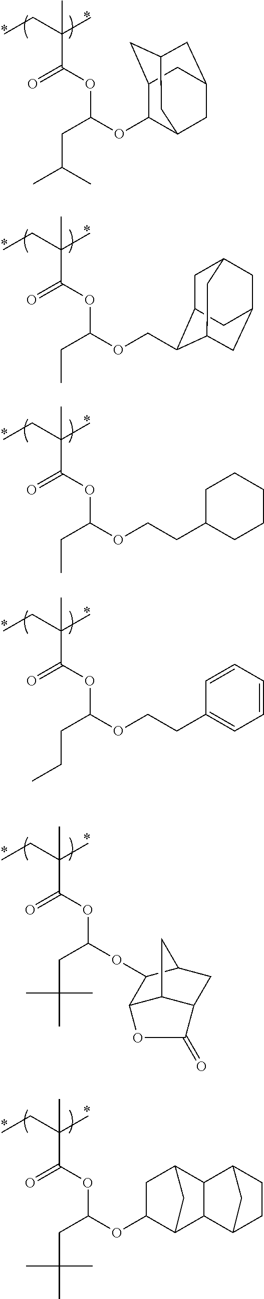

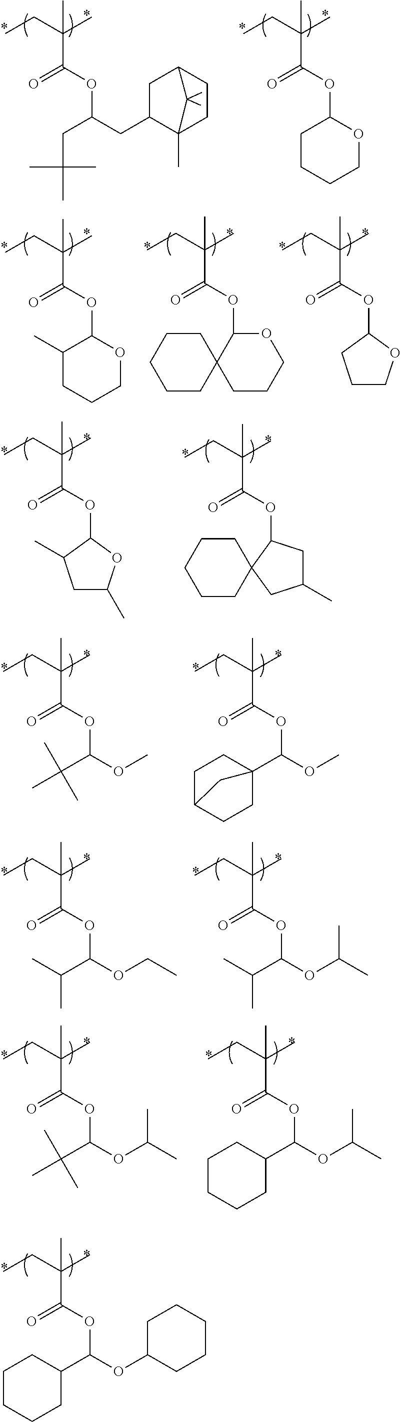

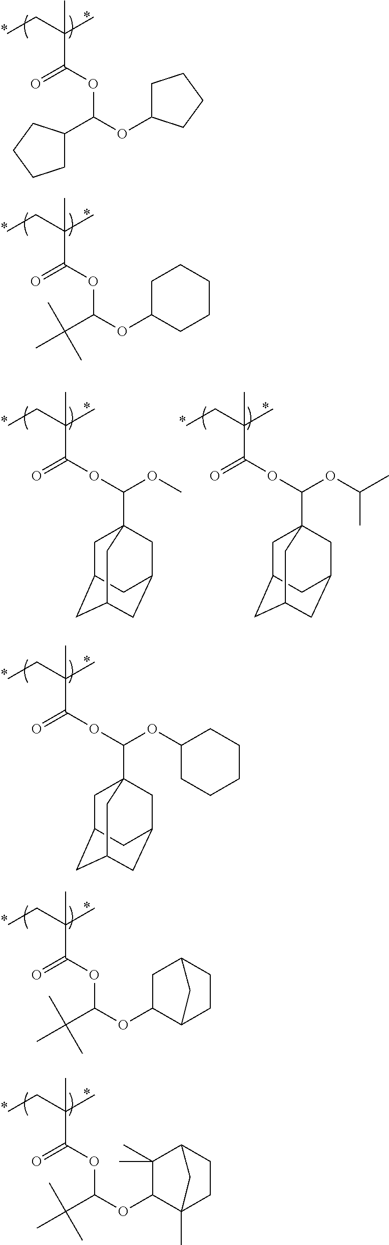

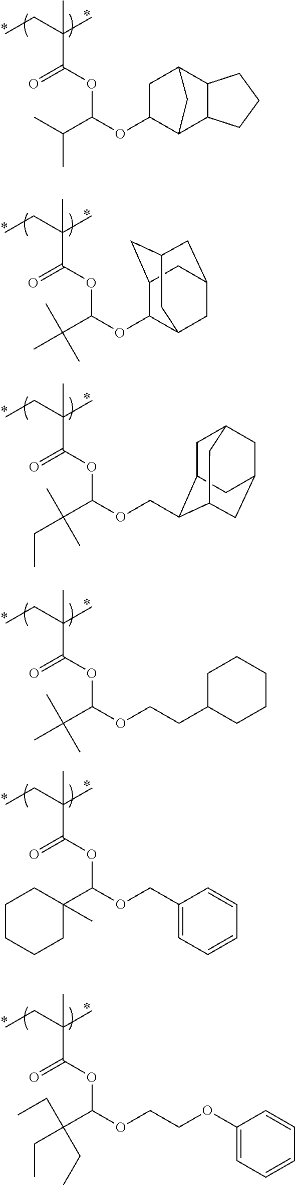

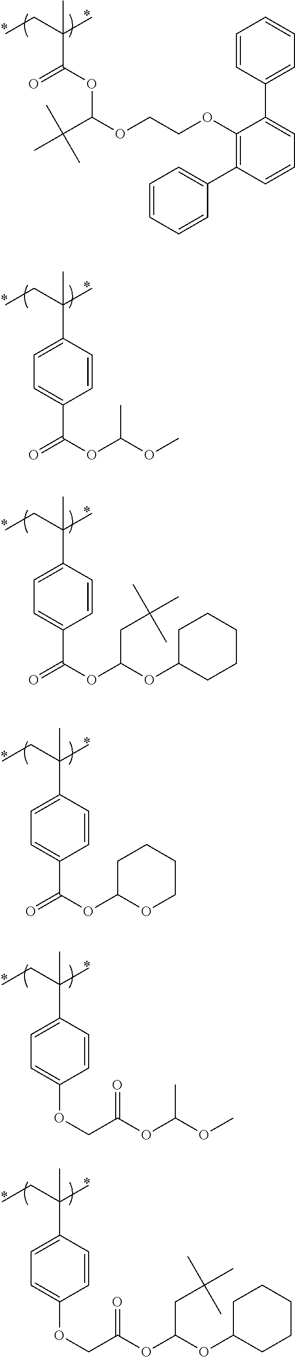

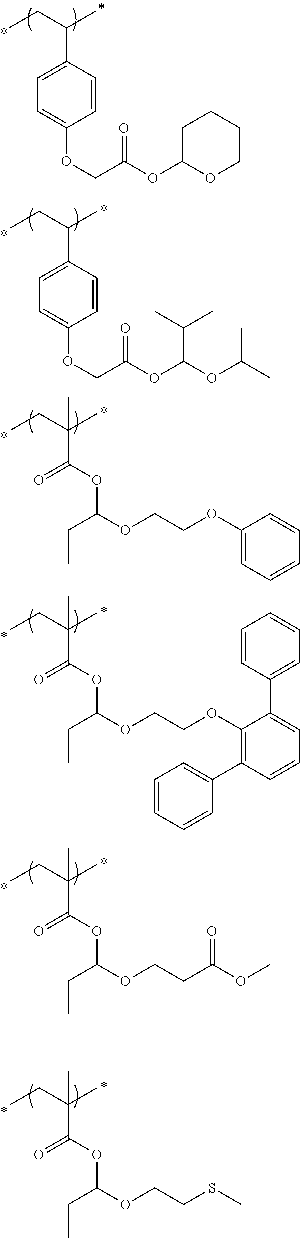

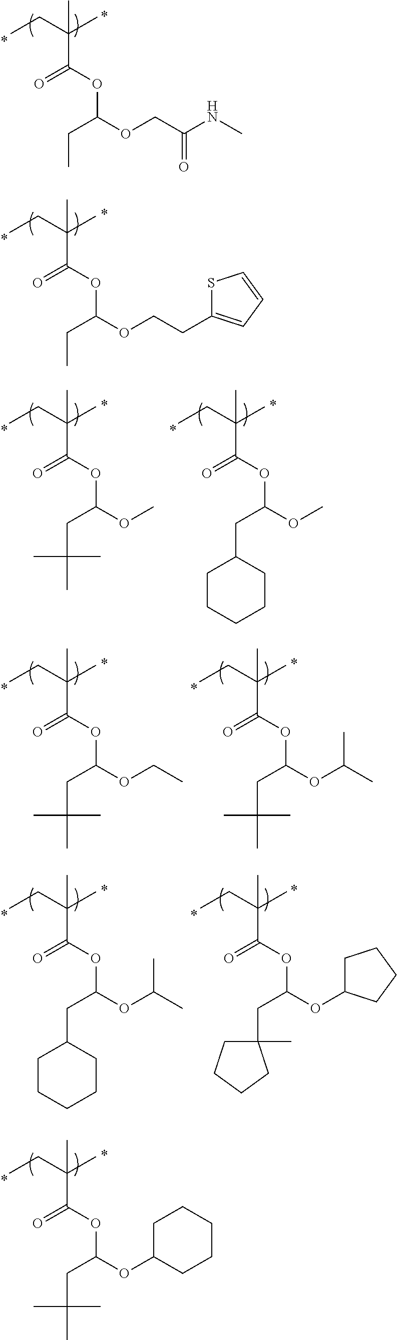

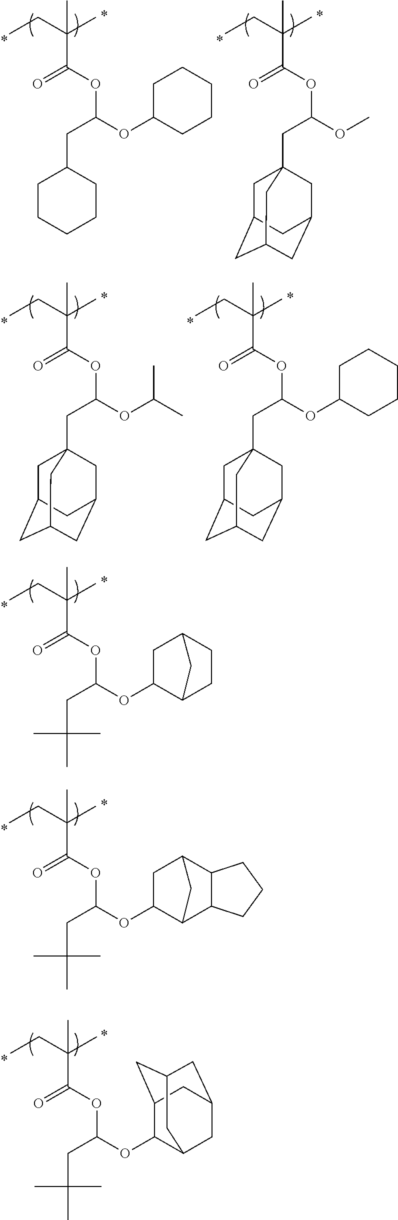

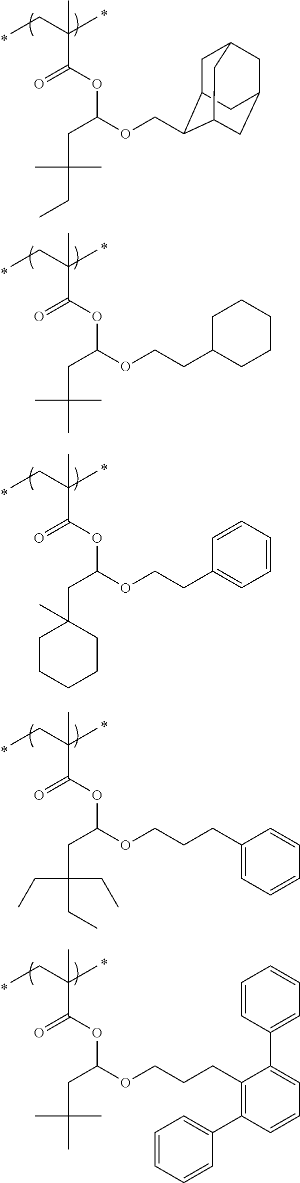

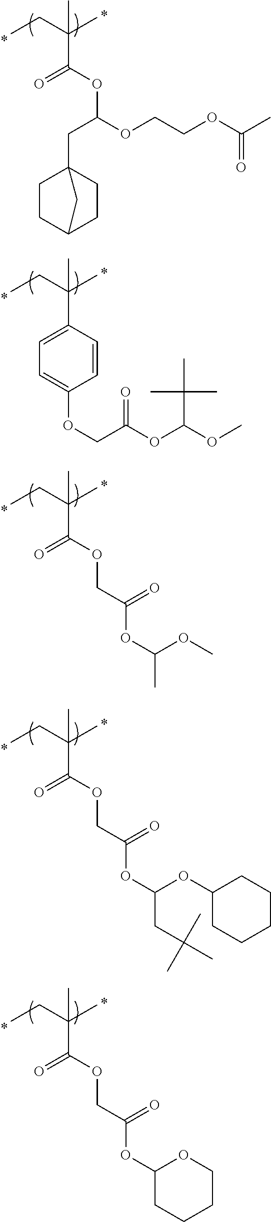

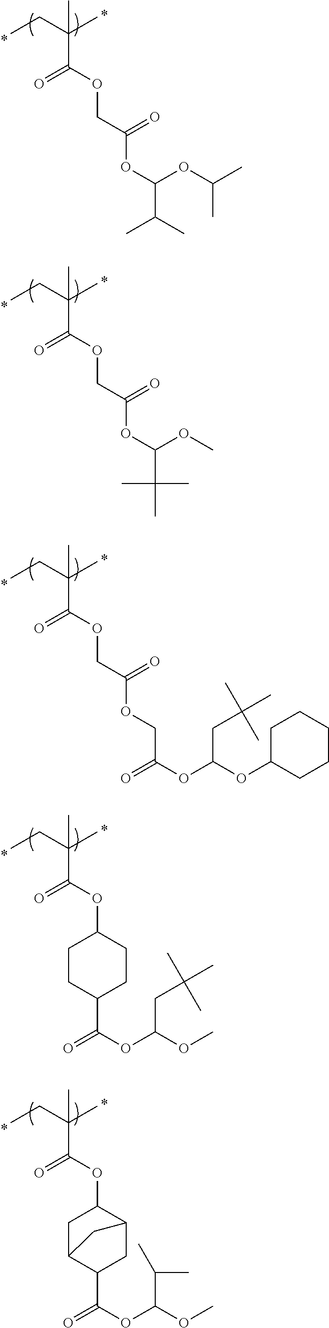

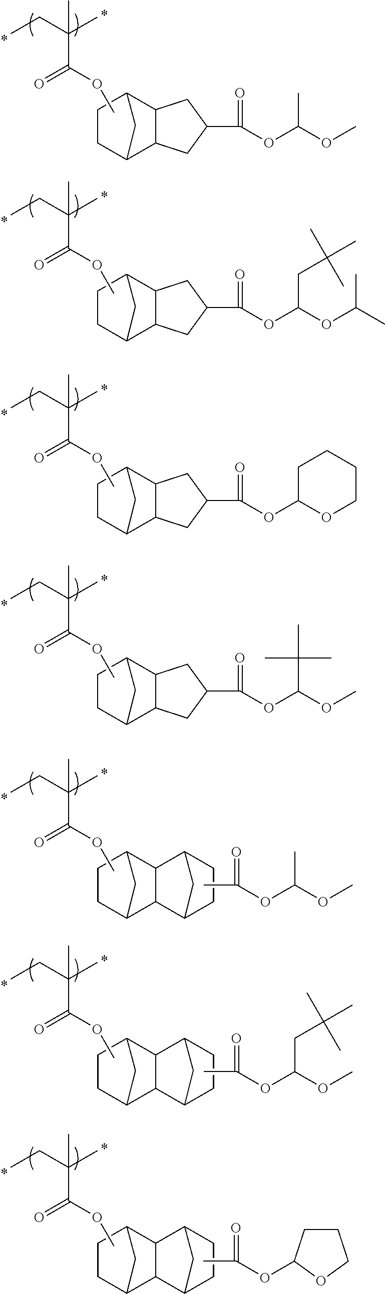

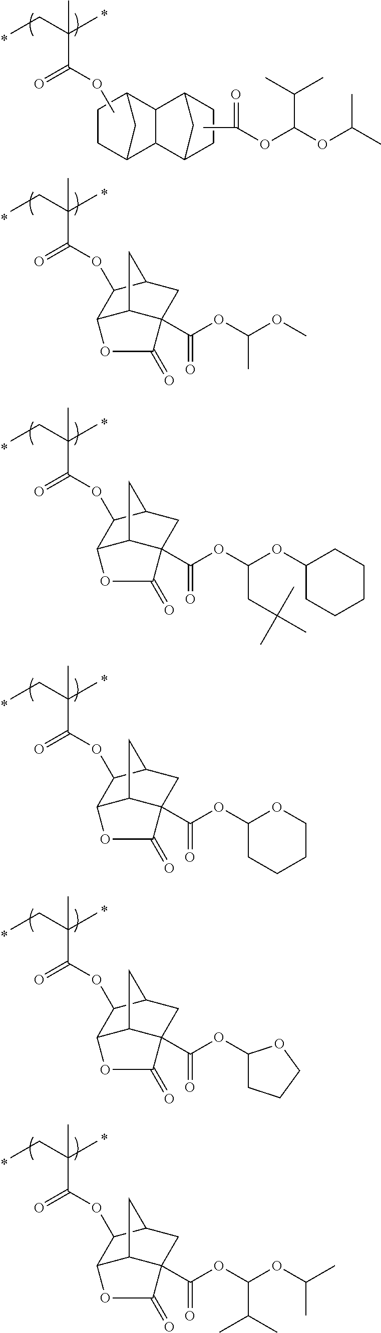

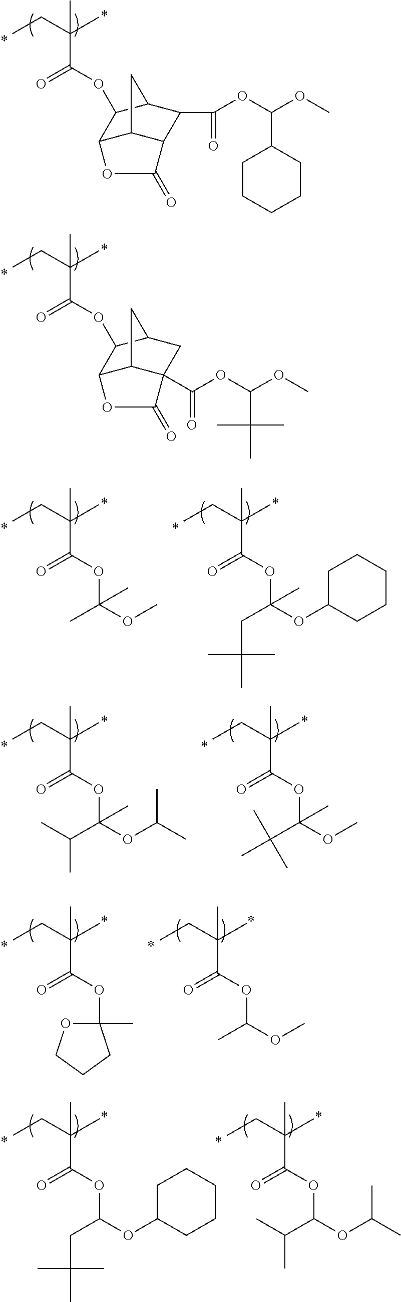

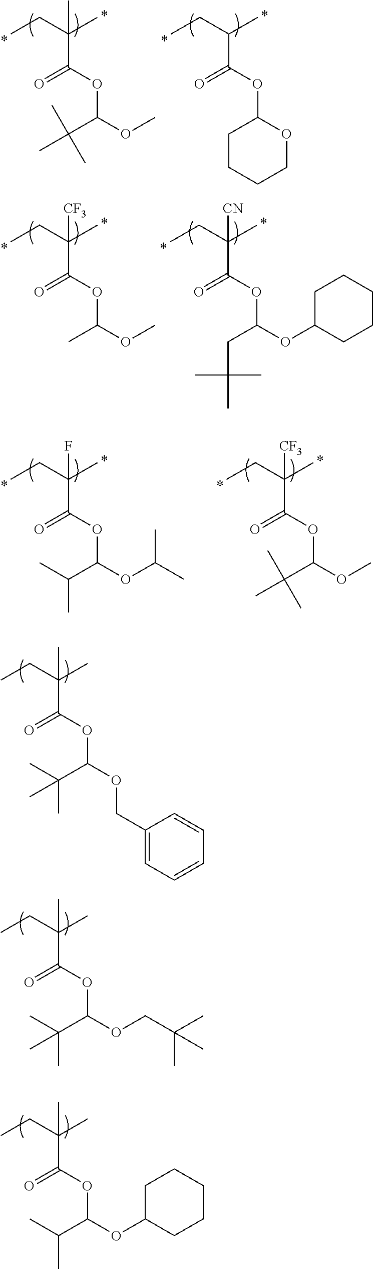

The content of the repeating unit (B) in the resin (P) is preferably in the range of 1 mol % to 80 mol %, more preferably in the range of 10 mol % to 70 mol %, and still more preferably in the range of 20 mol % to 60 mol %, based on all the repeating units in the resin (P).

It is preferred that the resin (P) further contains a repeating unit (C) having an aromatic hydroxyl group.

The repeating unit (C) is preferably represented by the following formula (d).

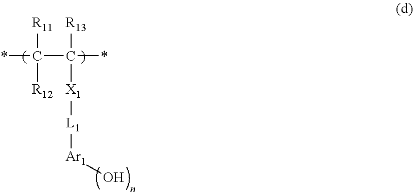

In formula (d), each of R₁₁, R₁₂ and R₁₃ independently represents a hydrogen atom, an alkyl group, a cycloalkyl group, a halogen atom, a cyano group, or an alkoxycarbonyl group. R₁₂ may be bonded to Ar₁ to form a ring, and R₁₂ in such a case represents an alkylene group.

X₁ represents a single bond, —COO—, or —CONR₁₄, and R₁₄ represents a hydrogen atom or an alkyl group.

L₁ represents a single bond or an alkylene group.

Ar₁ represents an (n+1)-valent aromatic cyclic group, provided that when Ar₁ is bonded to R₁₂, Ar₁ represents an (n+2)-valent aromatic cyclic group.

n represents an integer of 1 or more.

The alkyl group as R₁₁ to R₁₃ is, for example, an alkyl group having 20 or less carbon atoms, and preferably a methyl group, an ethyl group, a propyl group, an isopropyl group, an n-butyl group, a sec-butyl group, a hexyl group, a 2-ethylhexyl group, an octyl group, or a dodecyl group. The alkyl group is more preferably an alkyl group having 8 or less carbon atoms, which alkyl group may have a substituent.

The alkyl group contained in the alkoxycarbonyl group is preferably the same alkyl group as in R₁₁ to R₁₃ above.

The cycloalkyl group may be a monocyclic cycloalkyl group or a polycyclic cycloalkyl group, and preferably a monocyclic cycloalkyl group having 3 to 8 carbon atoms such as a cyclopropyl group, a cyclopentyl group, and a cyclohexyl group are exemplified as the examples thereof. Incidentally, these cycloalkyl groups may have a substituent.

As the halogen atom, a fluorine atom, a chlorine atom, a bromine atom, and an iodine atom are exemplified, and a fluorine atom is more preferred.

When R₁₂ represents an alkylene group, the alkylene group is preferably an alkylene group having 1 to 8 carbon atoms, and a methylene group, an ethylene group, a propylene group, a butylene group, a hexylene group and an octylene group are exemplified as the examples thereof.

Each of R₁₁, R₁₂ and R₁₃ independently preferably represents a hydrogen atom or an alkyl group, and more preferably a hydrogen atom.

X₁ represents a single bond, —COO— or —CONR₁₄—, and R₁₄ represents a hydrogen atom or an alkyl group.

The alkyl group of R₁₄ is the same with the alkyl group of R₁₁ to R₁₃, and the preferred range is also the same.

X₁ most preferably represents a single bond.

L₁ represents a single bond or an alkylene group.

The alkylene group as L₁ is a linear or branched chain alkylene group having preferably 1 to 20 carbon atoms, more preferably 1 to 10 carbon atoms and, for example, a methylene group, an ethylene group and a propylene group are exemplified.

L₁ most preferably represents a single bond.

Ar₁ represents an (n+1)-valent aromatic cyclic group, provided that when Ar₁ is bonded to R₁₂, Ar₁ represents an (n+2)-valent aromatic cyclic group.

The divalent aromatic cyclic group represented by Ar₁ when n is 1 is the same with the divalent aromatic cyclic group represented by Ar₂ when p is 1 in formula (b), and the preferred range is also the same.

The (n+1)-valent aromatic cyclic group represented by Ar₁ in formula (d) may have a substituent. As such substituents, the same substituents with the substituents that the (p+1)-valent aromatic cyclic group represented by Ar₂ in formula (b) may have are exemplified, and the preferred range is also the same.

As the specific example of the (n+1)-valent aromatic cyclic group represented by Ar₁ in the case where n is an integer of 2 or more, a group obtained by subtracting arbitrary (n−1) hydrogen atom(s) from the above divalent aromatic cyclic group is exemplified.

n represents an integer of 1 or more, preferably an integer of 1 to 5, more preferably represents 1 or 2, and most preferably 1.

In the repeating unit represented by formula (d), when Ar₁ represents a phenylene group, the bonding position of —OH to the benzene ring of Ar₁ may be the para-position, meta-position, or ortho-position to the bonding position with L₁ or X₁ (which is the polymer main chain when both L₁ and X₁ are single bonds) of the benzene ring, but the para-position or meta-position is preferred, and the para-position is most preferred.

The repeating unit (C) is more preferably a repeating unit represented by the following formula (e) from the point of compatibility of sensitivity and resolution.

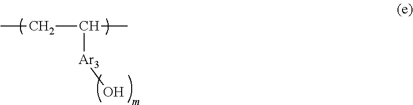

In formula (e), Ar₃ represents an (m+1)-valent aromatic cyclic group.

m represents an integer of 1 or more.

Ar₃ represents an (m+1)-valent aromatic cyclic group.

When m is 1, the divalent aromatic cyclic group represented by Ar₃ is the same with the divalent aromatic cyclic group represented by Ar₂ when p in the above formula (b) is 1, and the preferred range is also the same.

The (m+1)-valent aromatic cyclic group represented by Ar₃ in formula (e) may have a substituent. As such substituents, the same substituents with the substituents that the (p+1)-valent aromatic cyclic group represented by Ar₂ in the above formula (b) may have are exemplified, and the preferred range is also the same.

As the specific example of the (m+1)-valent aromatic cyclic group represented by Ar₃ in the case where m is an integer of 2 or more, a group obtained by subtracting arbitrary (m−1) hydrogen atom(s) from the above divalent aromatic cyclic group is exemplified.

m represents an integer of 1 or more, preferably an integer of 1 to 5, more preferably represents 1 or 2, and most preferably 1.

In the repeating unit represented by formula (e), when Ar₃ represents a phenylene group, the bonding position of —OH to the benzene ring of Ar₃ may be the para-position, meta-position, or ortho-position to the bonding position with the polymer main chain of the benzene ring, but the para-position or meta-position is preferred, and the para-position is most preferred.

The repeating unit (C) is a repeating unit having an alkali-soluble group, which has a function to control alkali developability of the resist.

The specific examples of the repeating unit (C) are shown below, but the invention is not restricted thereto.

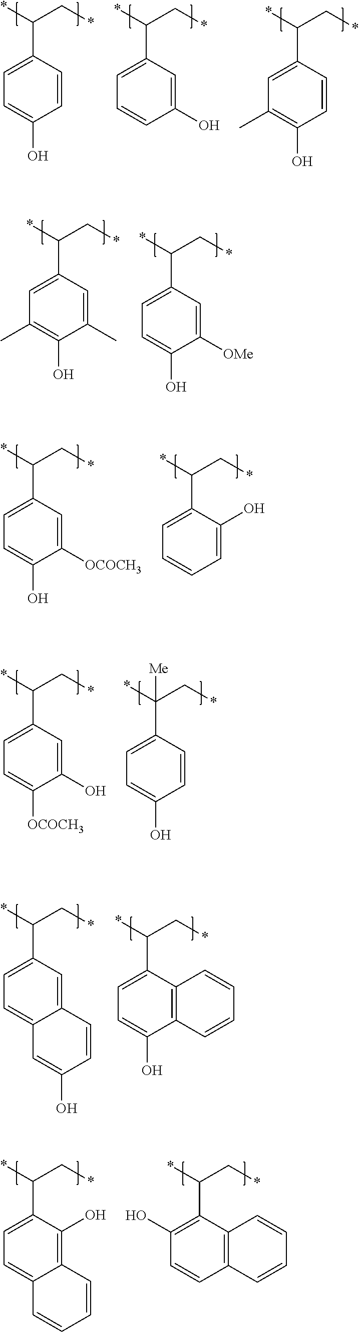

Of the above specific examples, preferred examples of the repeating unit (C) are the repeating units in which the aromatic cyclic group represented by Ar₁ or Ar₃ is an unsubstituted phenylene group, which are shown below.

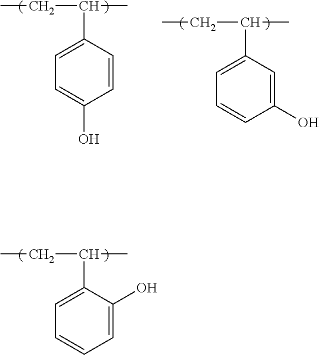

The content of the repeating unit (C) in the resin (P) is preferably in the range of 3 mol % to 98 mol %, more preferably in the range of 10 mol % to 80 mol %, and still more preferably in the range of 25 mol % to 70 mol %, based on all the repeating units in the resin (P).

It is also preferred for the resin (P) for use in the invention to contain the following repeating unit as the repeating unit other than the repeating units (A) to (C).

For example, a repeating unit having a group capable of decomposing by the action of an alkali developer to increase solubility in an alkali developer is exemplified. As such a group, a group having a lactone structure and a group having a phenyl ester structure are exemplified. As the repeating unit having a group capable of decomposing by the action of an alkali developer to increase solubility in an alkali developer, a repeating unit represented by the following formula (AII) is more preferred.

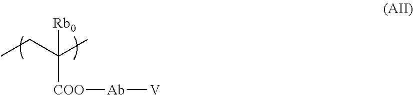

In formula (AII), V represents a group capable of decomposing by the action of an alkali developer to increase solubility in an alkali developer, Rbo represents a hydrogen atom or a methyl group, and Ab represents a single bond or a divalent organic group.

V which is a group capable of decomposing by the action of an alkali developer is a group having an ester bond, and a group having a lactone structure is more preferred. The group having a lactone structure is not restricted and any group can be used so long as it has a lactone structure, but preferably 5- to 7-membered ring lactone structures, and 5- to 7-membered ring lactone structures condensed with other ring structures to form a bicyclo structure or a spiro structure are preferred.

Ab is preferably a single bond, or a divalent linking group represented by -AZ—CO₂— (Az is an alkylene group or an aliphatic cyclic group (preferably a cycloalkylene group)). AZ is preferably a methylene group, an ethylene group, a cyclohexylene group, an adamantylene group, or a norbornylene group.

The specific examples thereof are shown below. In the formulae, Rx represents H or CH₃.

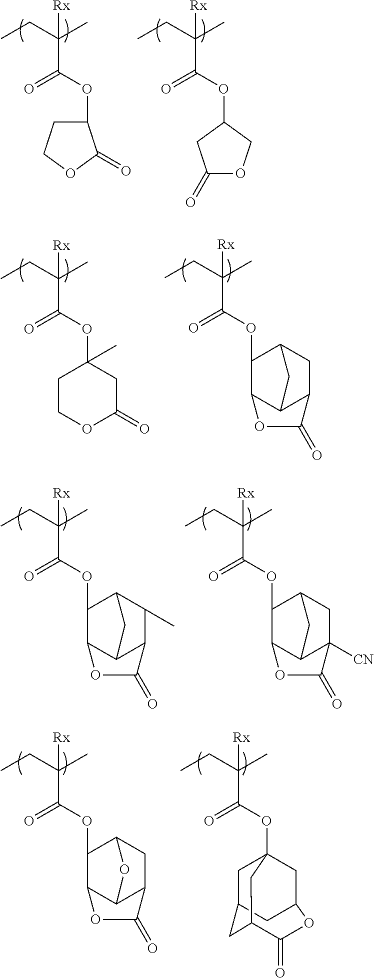

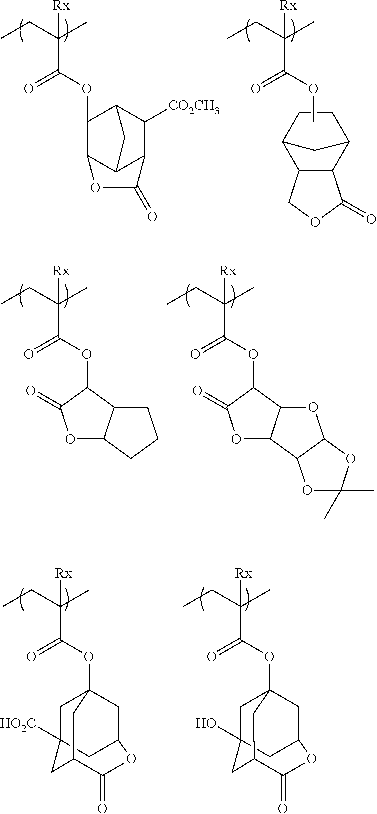

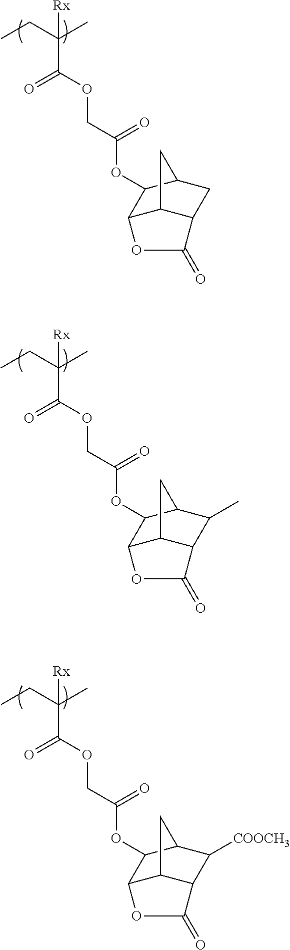

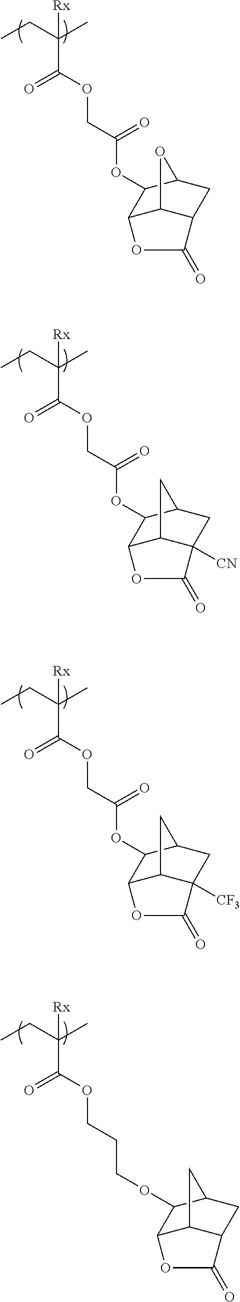

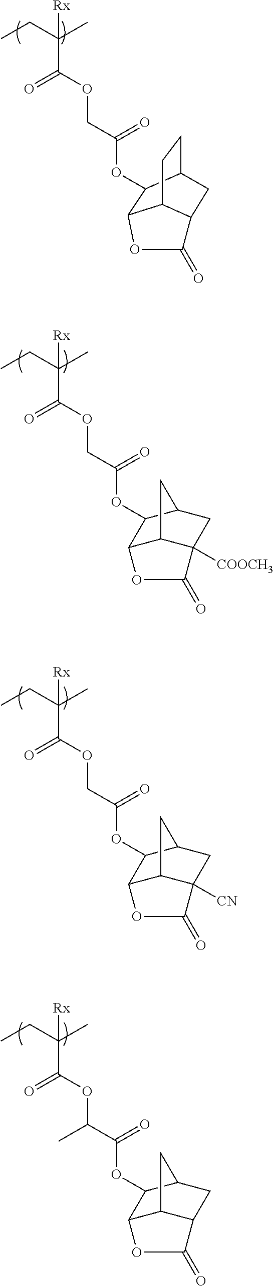

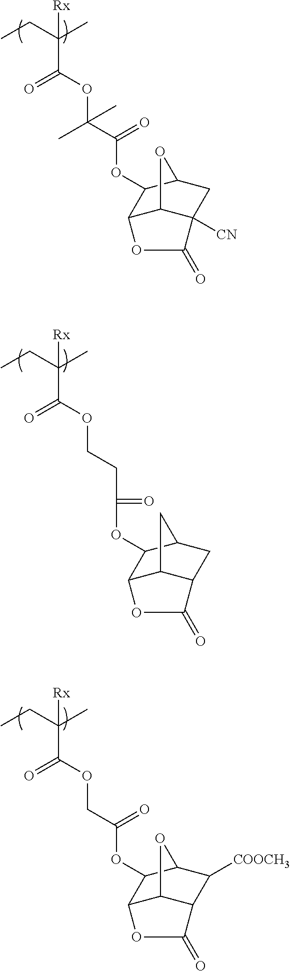

The resin (P) may contain or may not contain a repeating unit having a group capable of decomposing by the action of an alkali developer to increase solubility in an alkali developer, but when contains the repeating unit, the content of the repeating unit having such a group is preferably 5 mol % to 60 mol % based on all the repeating units in the resin (P), more preferably 5 mol % to 50 mol %, and still more preferably 10 mol % to 50 mol %.

The preferred examples of polymerizable monomers for forming repeating units other than the above repeating units in the resin (P) of the invention include styrene, alkyl-substituted styrene, alkoxy-substituted styrene, O-alkylated styrene, O-acylated styrene, hydrogenated hydroxystyrene, maleic anhydride, acrylic acid derivatives (e.g., acrylic acid, acrylic ester, and the like), methacrylic acid derivatives (e.g., methacrylic acid, methacrylic ester, and the like), N-substituted maleimide, acrylonitrile, methacrylonitrile, vinyl naphthalene, vinyl anthracene, and indenes which may have a substituent. Substituted styrenes are preferably 4-(1-naphthylmethoxy)styrene, 4-benzyloxystyrene, 4-(4-chlorobenzyloxyl)styrene, 3-(1-naphthylmethoxyl)styrene, 3-benzyloxystyrene, and 3-(4-chlorobenzyloxy)styrene.

The resin (P) may contain or may not contain these repeating units, but when contains, the content of these repeating units in the resin (P) is preferably 1 mol % to 80 mol % based on all the repeating units for constituting the resin (P), and more preferably 5 mol % to 50 mol %.

The specific examples of the resin (P) for use in the invention are shown below, but the invention is not restricted thereto.

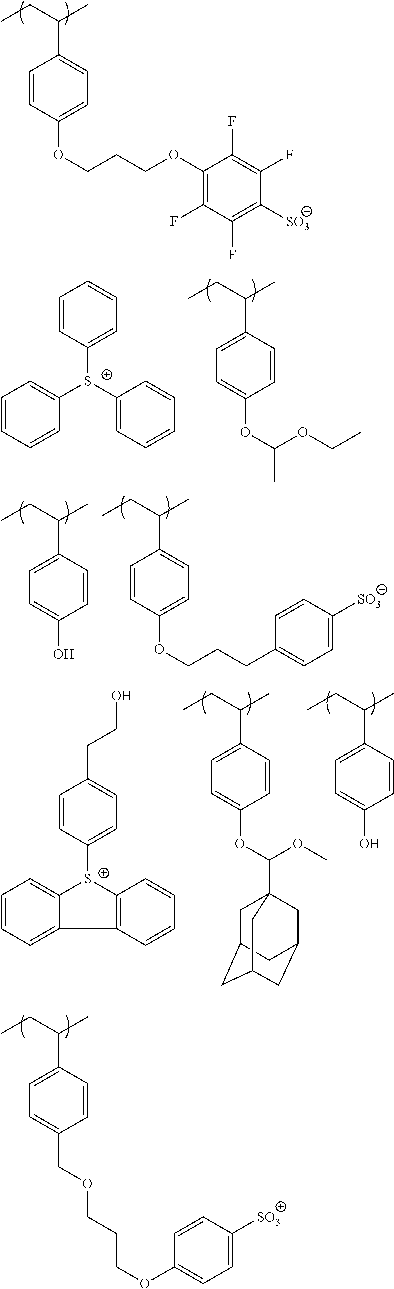

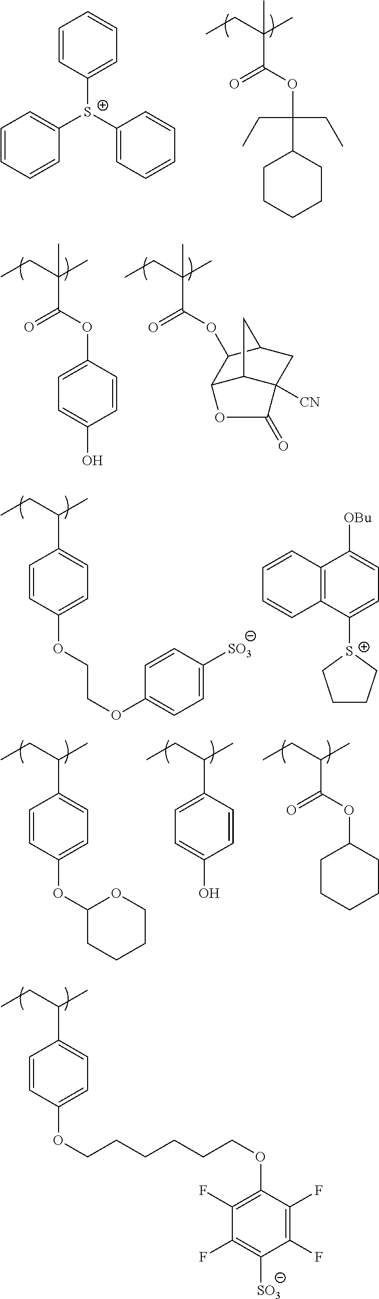

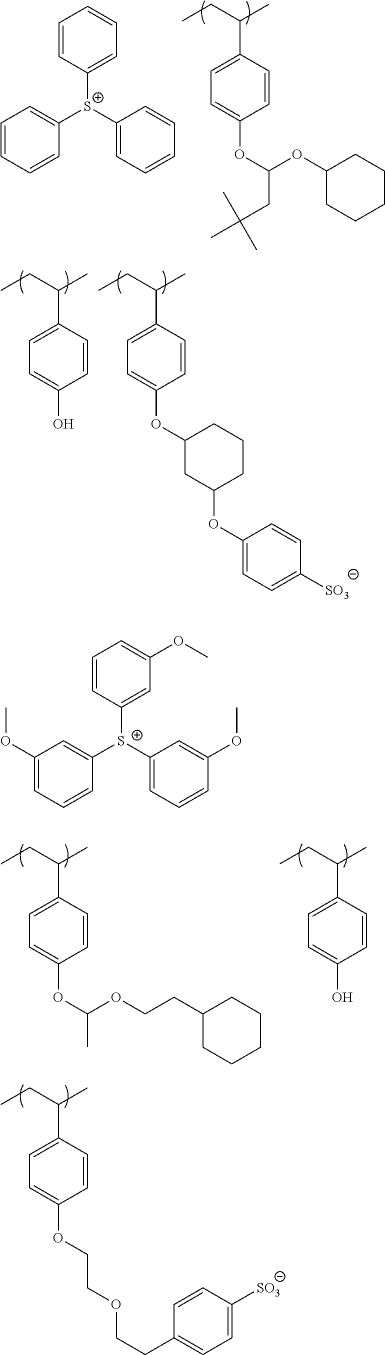

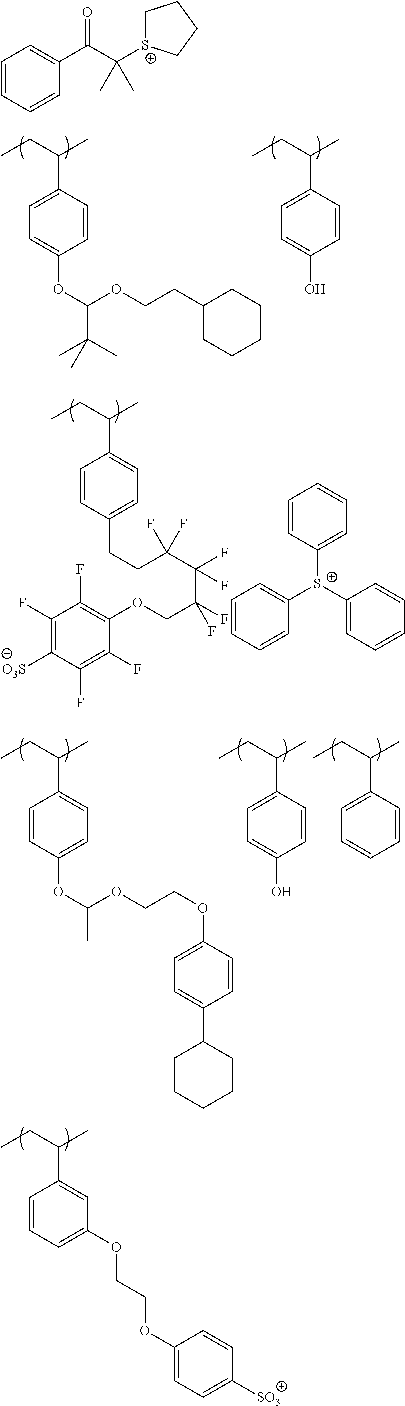

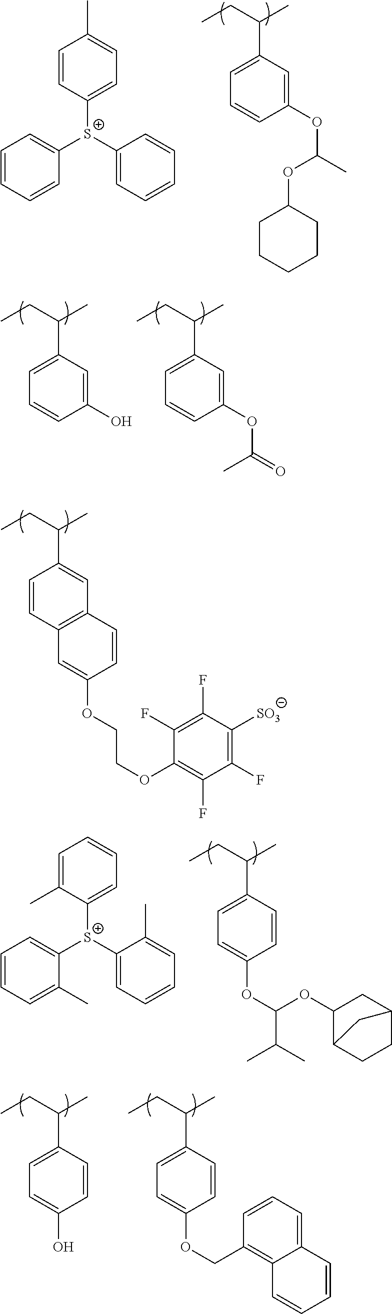

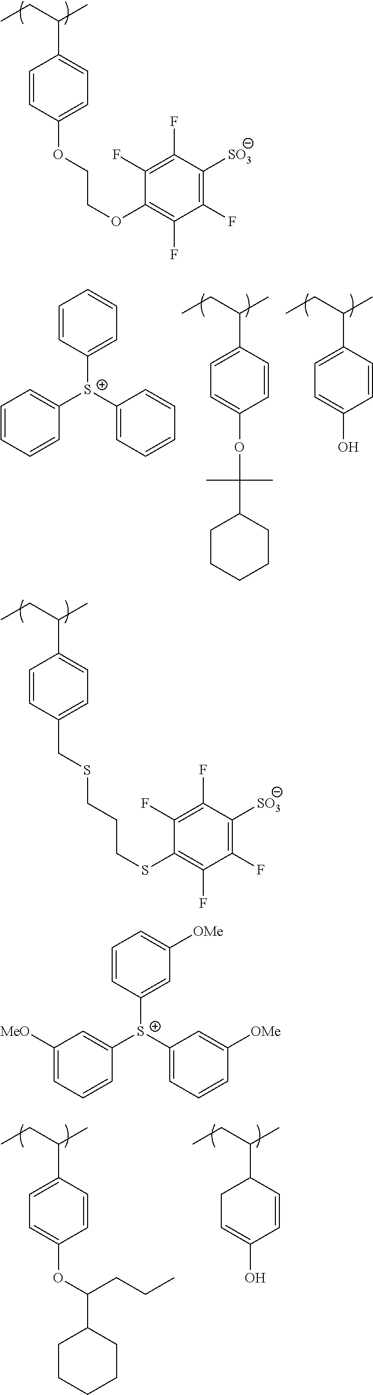

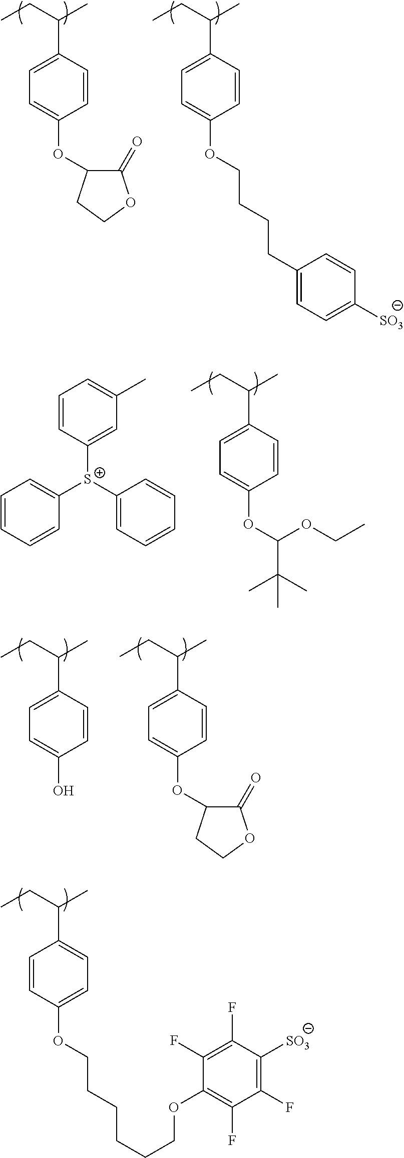

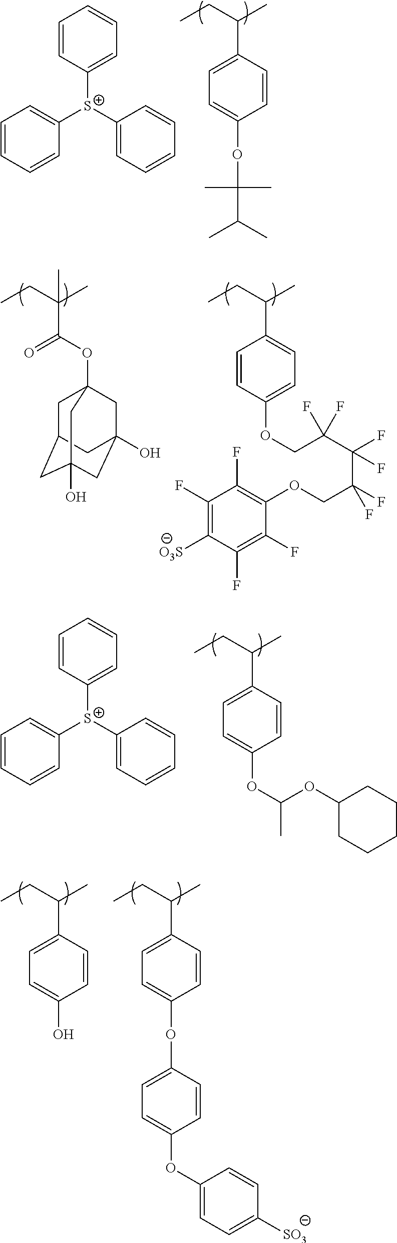

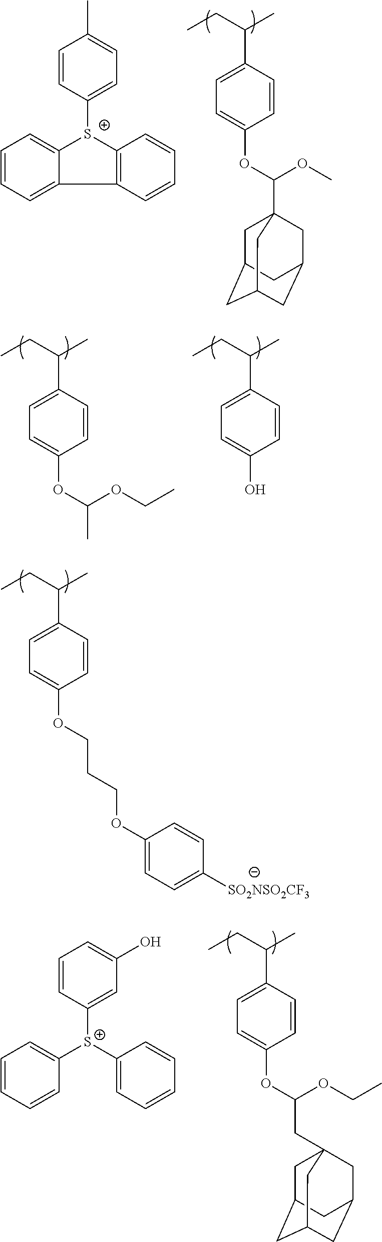

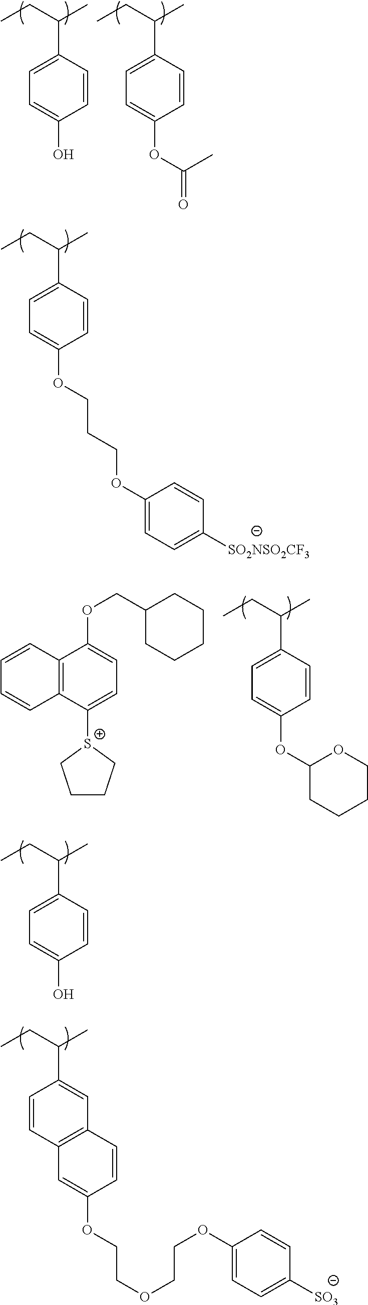

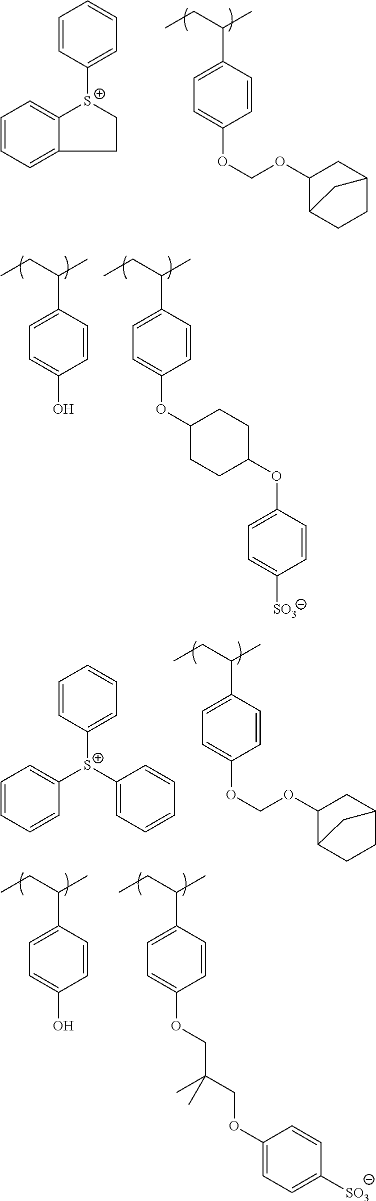

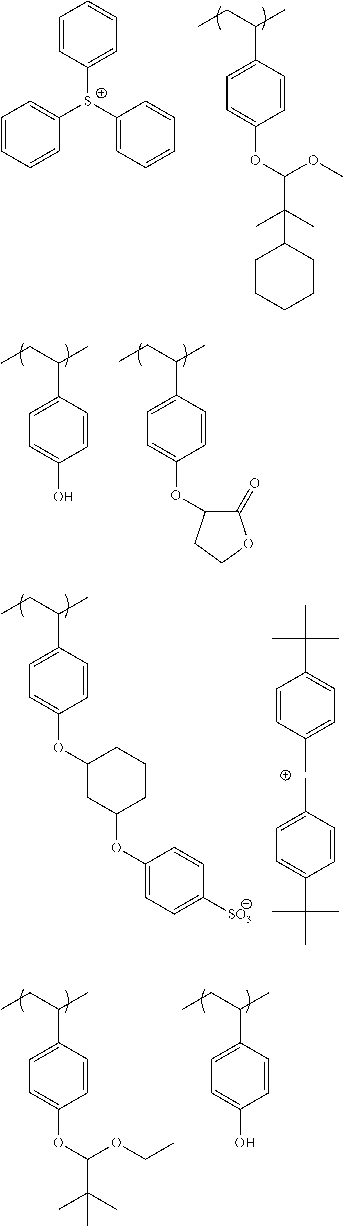

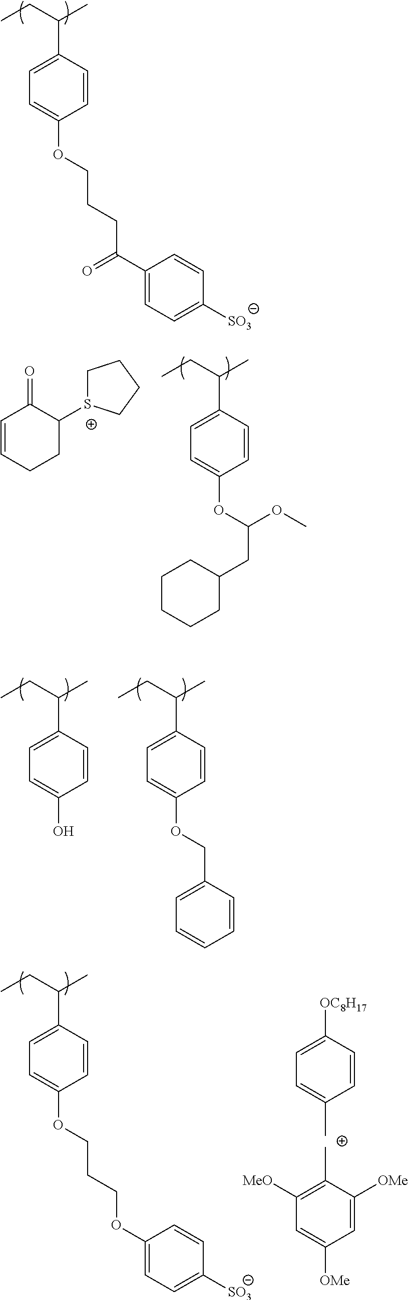

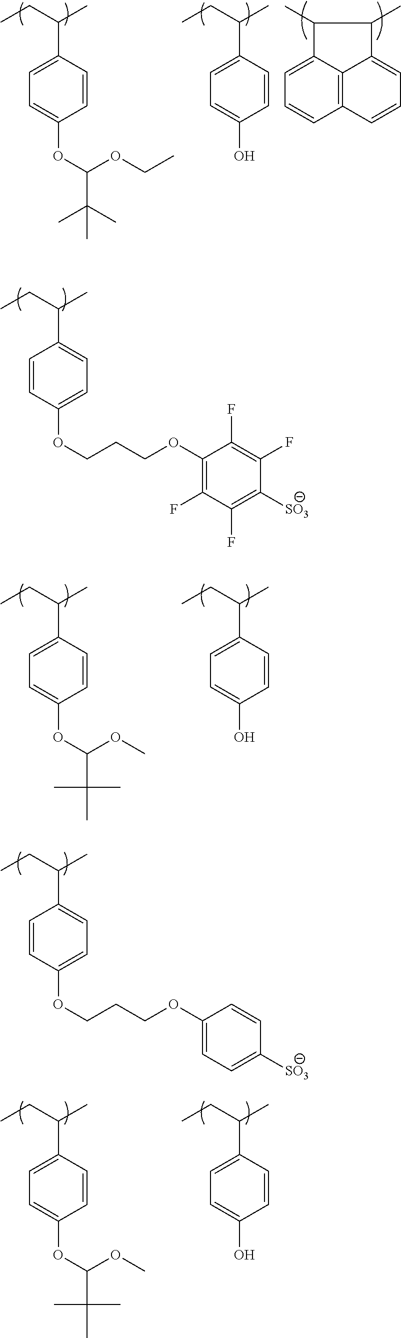

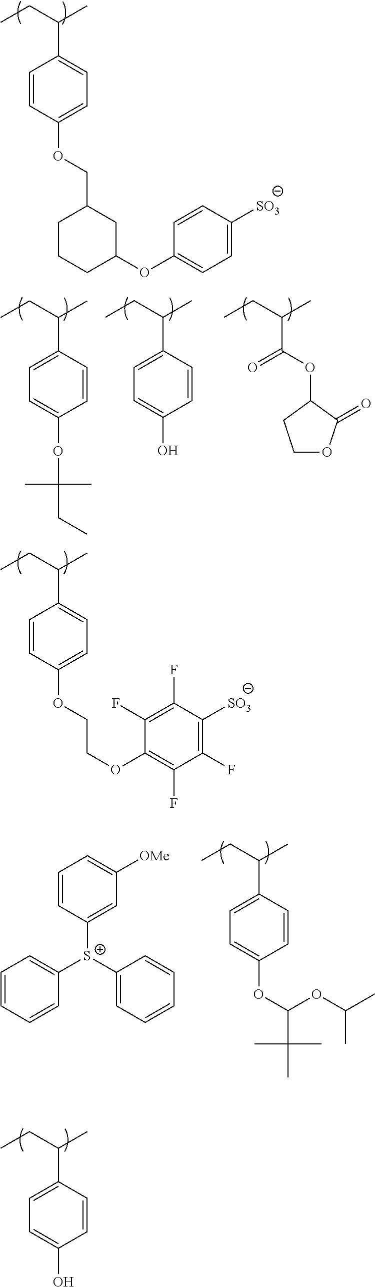

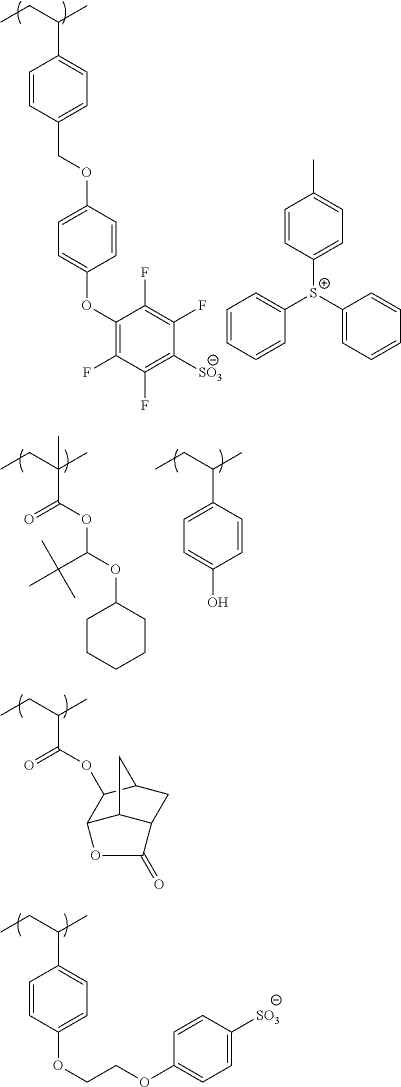

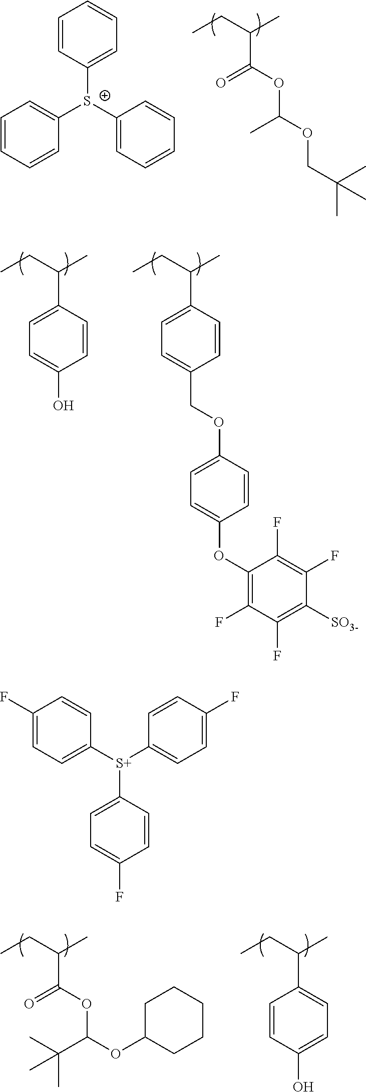

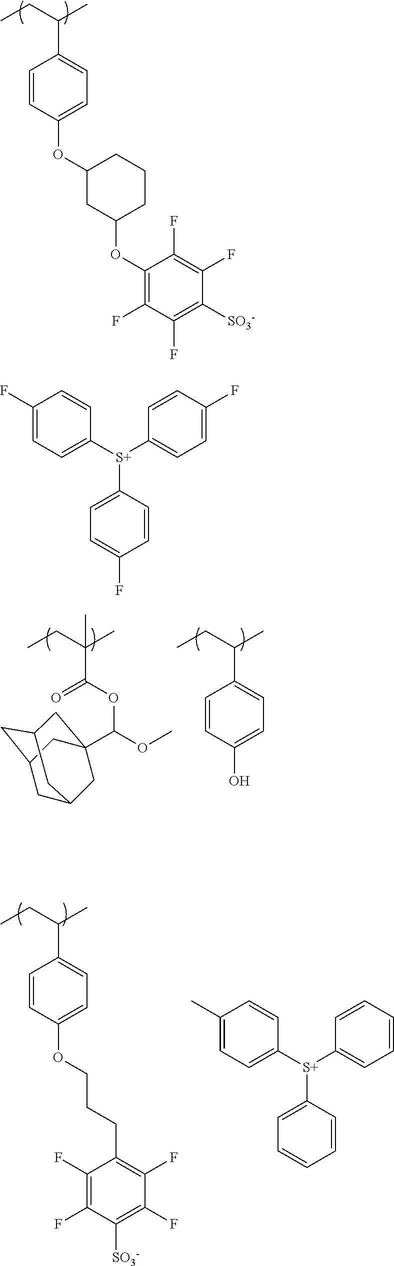

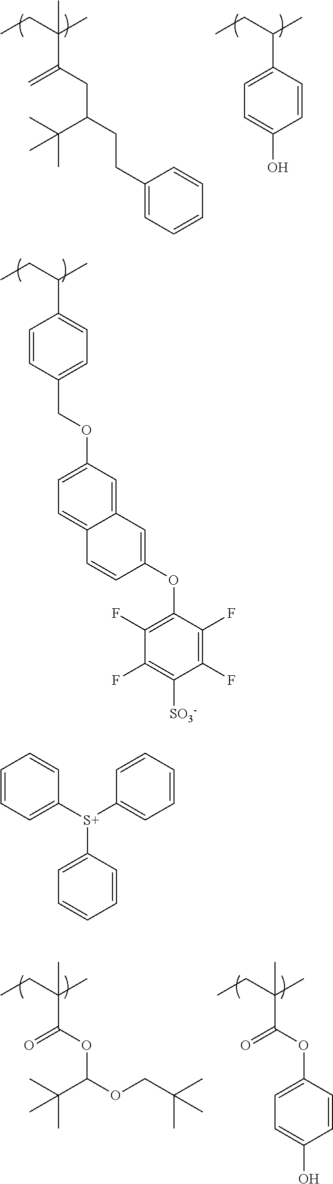

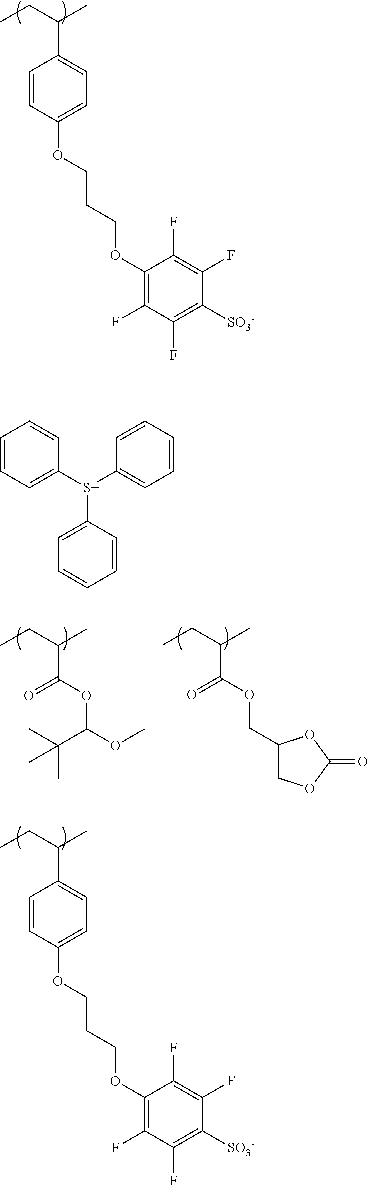

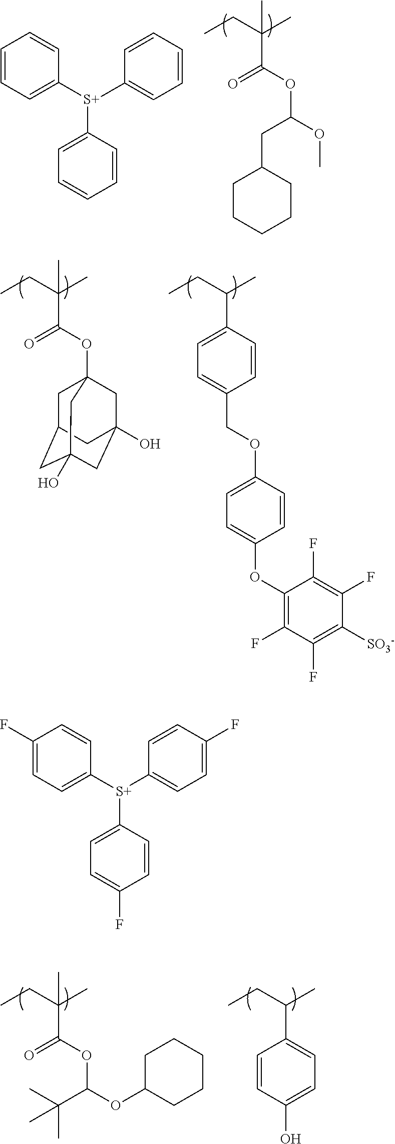

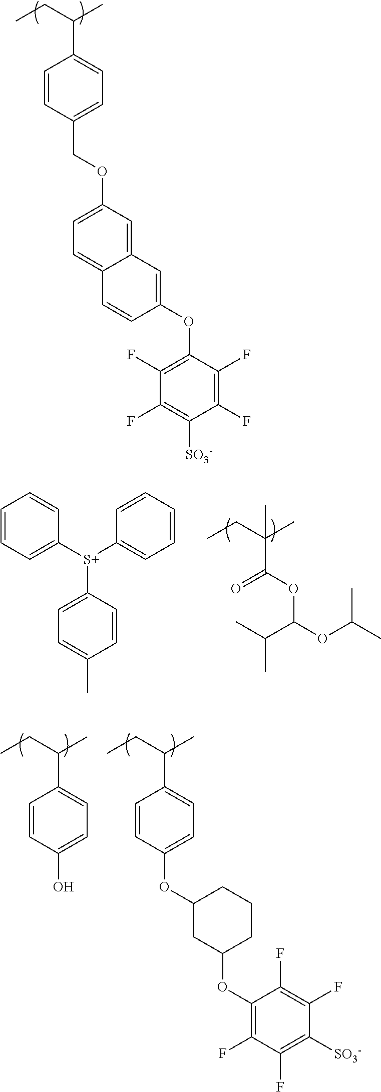

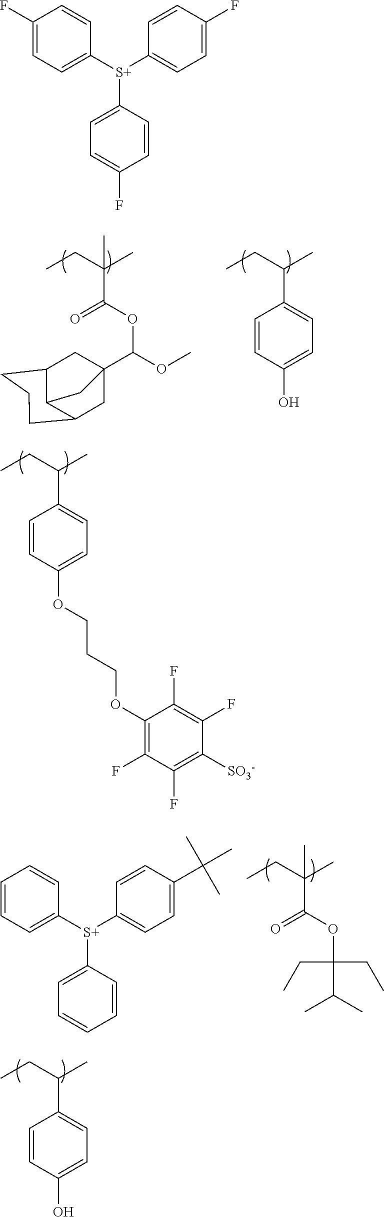

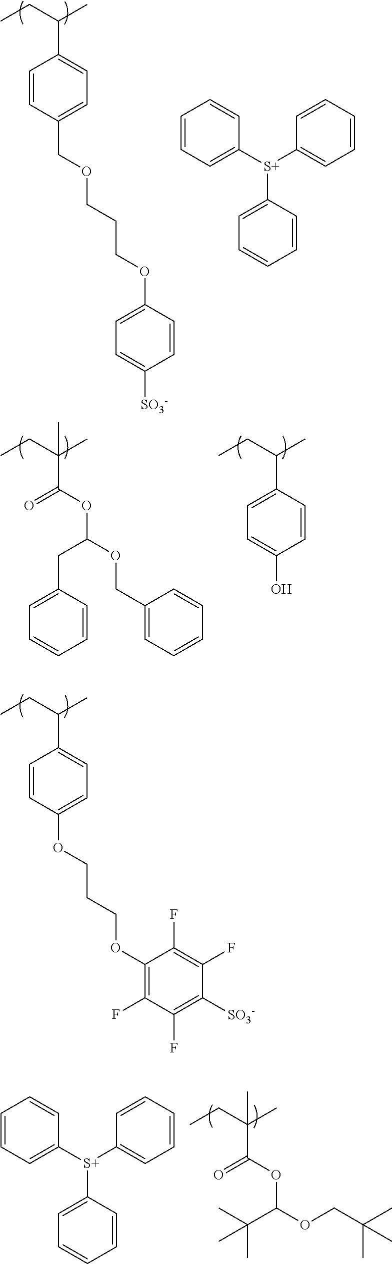

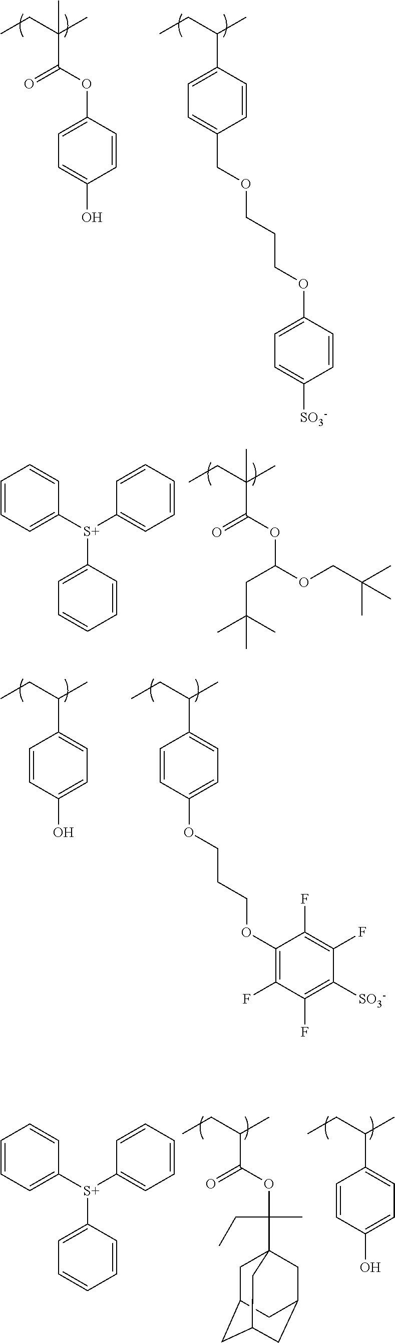

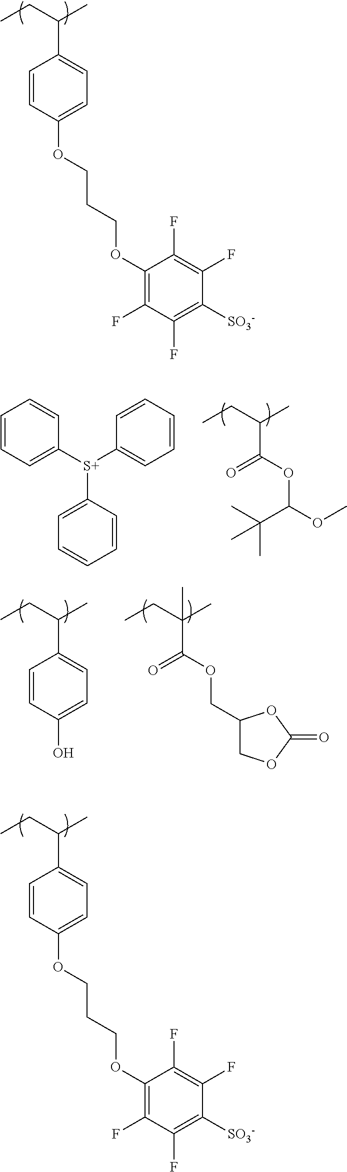

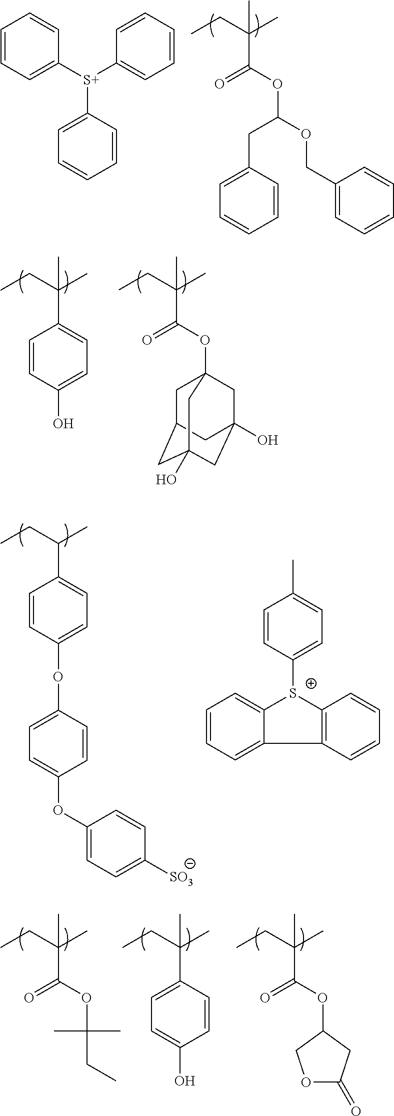

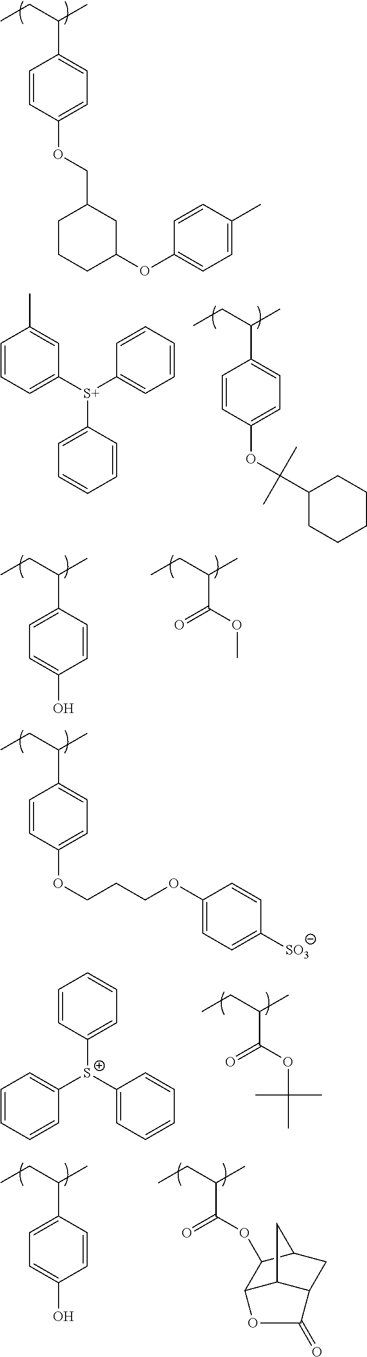

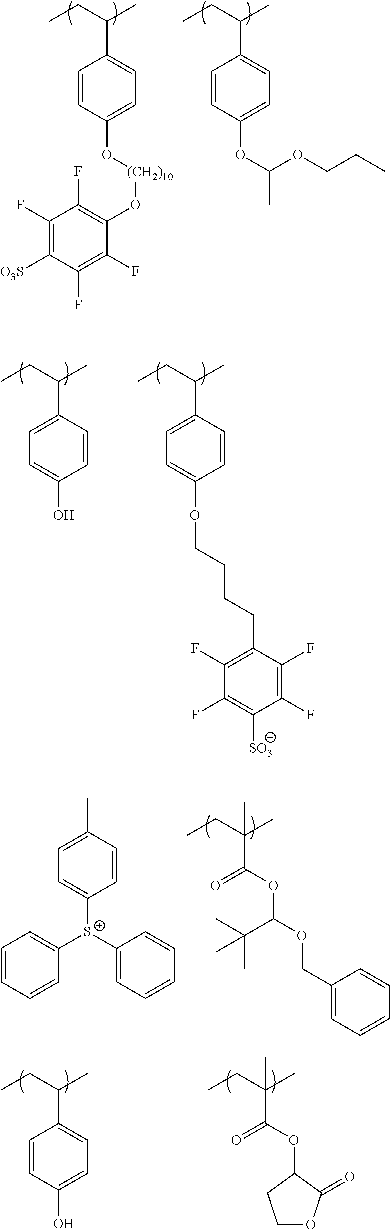

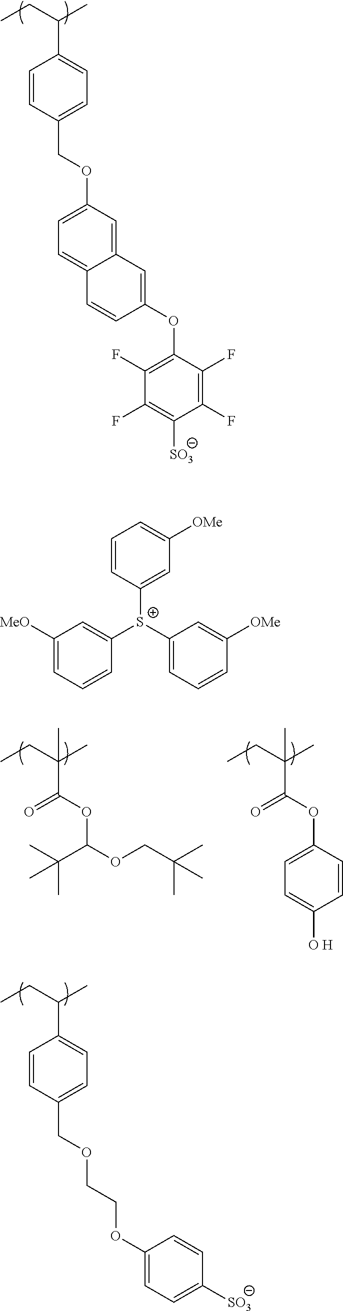

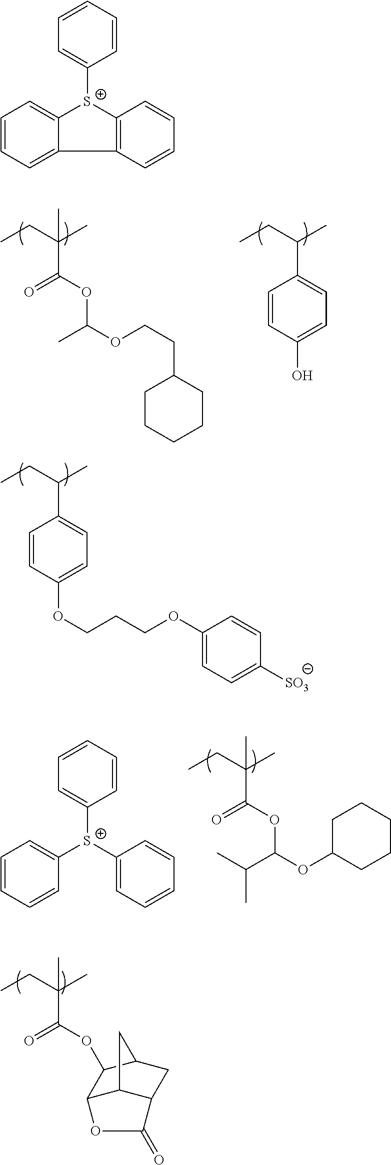

The resin (P) in the invention may contain, in addition to the above repeating structural units, various repeating structural units for the purpose of controlling dry etching resistance, suitability for standard developer, adhesion to substrate, resist profile, and characteristics generally required of the resist, such as resolution, heat resistance and sensitivity.

As such repeating structural units, the repeating structural units corresponding to the monomers shown below can be exemplified, but the invention is not restricted thereto.

Due to such repeating structural units, fine control of the performances required of the resin for use in the composition of the invention, in particular the following performances, becomes possible, that is,

(1) Solubility in a coating solvent,
(2) A film-forming property (a glass transition temperature),
(3) Alkali developability,
(4) Film reduction (selection of hydrophilic, hydrophobic, alkali-soluble group),
(5) Adhesion of an unexposed area to a substrate, and
(6) Dry etching resistance.

The examples of such monomers include compounds having one addition polymerizable unsaturated bond selected from acrylic esters, methacrylic esters, acrylamides, methacrylamides, allyl compounds, vinyl ethers, vinyl esters, styrenes, and crotonic esters. In addition to the above, maleic anhydride, maleimide, acrylonitrile, methacrylonitrile, and maleylonitrile can also be exemplified.

Other than the above, an addition polymerizable unsaturated compound copolymerizable with the monomers corresponding to the above various repeating structural units may be copolymerized.

The preferred specific examples of repeating units deriving from such other polymerizable monomers are shown below, but the invention is not restricted thereto.

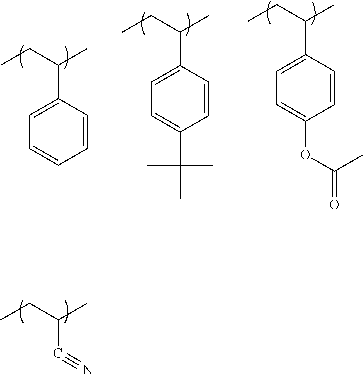

In the resin (P) for use in the composition of the invention, the molar ratio of the contents of respective repeating structural units is appropriately set to control dry etching resistance of the resist, suitability for standard developer, adhesion to substrate, resist profile, and performances generally required of the resist, such as resolution, heat resistance and sensitivity.

The form of the resin (P) in the invention may be any of a random type, a block type, a comb type and a star type.

The resin (P) can be synthesized, for example, by radical, cationic or anionic polymerization of unsaturated monomers corresponding to respective structures. The objective resin can also be obtained by polymerizing unsaturated monomers corresponding to the precursors of respective structures and then performing a polymer reaction.

The examples of ordinary synthesizing methods include a batch polymerization method of dissolving an unsaturated monomer and a polymerization initiator in a solvent and heating the solution, to thereby effect the polymerization, and a dropping polymerization method of dropwise adding a solution containing an unsaturated monomer and a polymerization initiator to a heated solvent over 1 to 10 hours. A dropping polymerization method is preferred.

As the solvents for use in polymerization, for example, the solvents which can be used in preparing the later-described actinic ray-sensitive or radiation-sensitive resin composition can be exemplified. It is more preferred to perform polymerization with the same solvents as used in the composition of the invention. By the use of the same solvent, generation of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). An azo-based initiator is preferred as the radical initiator, and an azo-based initiator having an ester bond, a cyano group, or a carboxyl group is preferred. The examples of the preferred initiators include azobisisobutyronitrile, azobisdimethylvaleronitrile and dimethyl 2,2′-azobis(2-methylpropionate). Polymerization may be performed in the presence of a chain transfer agent (e.g., alkylmercaptan), if necessary.

The concentration of the solute in a reaction solution is 5% by mass to 70% by mass, and preferably 10% by mass to 50% by mass. The reaction temperature is usually 10° C. to 150° C., preferably 30° C. to 120° C., and more preferably 40° C. to 100° C.

The reaction time is usually 1 hour to 48 hours, preferably 1 hour to 24 hours, and more preferably 1 hour to 12 hours.

After completion of the reaction, the reaction solution is allowed to be cooled to room temperature and purified. The purification may be performed by normal methods, and these methods can be applied to the invention. For example, a liquid-liquid extraction method of applying water washing or combining it with an appropriate solvent to remove the residual monomers or oligomer components; a purification method in a solution state, such as ultrafiltration of extracting and removing only the polymers having a molecular weight not more than a specific value; a reprecipitation method of dropwise adding the reaction solution into a poor solvent to solidify the resin in the poor solvent, to thereby remove the residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent for the polymer, and the solvent which can be used may be appropriately selected from a hydrocarbon, a halogenated hydrocarbon, a nitro compound, an ether, a ketone, an ester, a carbonate, an alcohol, a carboxylic acid, water, and a mixed solvent containing these solvents, according to the kind of the polymer. Of these solvents, a solvent containing at least an alcohol (especially, methanol or the like) or water is preferred as the precipitation or reprecipitation solvent.

The amount of the precipitation or reprecipitation solvent used may be properly selected considering the efficiency, yield and the like, but the amount used is generally 100 to 10,000 parts by mass per 100 parts by mass of the polymer solution, preferably 200 to 2,000 parts by mass, and more preferably from 300 to 1,000 parts by mass.

The temperature in precipitation or reprecipitation may be arbitrarily selected considering the efficiency or operability, but is generally on the order of 0° C. to 50° C., preferably in the vicinity of room temperature (for example, approximately 20° C. to 35° C.). The precipitation or reprecipitation operation may be performed using commonly employed mixing vessel such as stirring tank by a known method such as a batch system and a continuous system.

The precipitated or reprecipitated polymer is usually subjected to commonly employed solid-liquid separation such as filtration and centrifugation, then dried and used. The filtration is performed using a solvent resisting filter element preferably under pressure. The drying is performed under atmospheric pressure or reduced pressure (preferably under reduced pressure) at a temperature of approximately 30° C. to 100° C., and preferably on the order of 30° C. to 50° C.

Incidentally, after the resin is once precipitated and separated, the resin may be again dissolved in a solvent and then brought into contact with a solvent in which the resin is sparingly soluble or insoluble. That is, there may be used a method comprising, after the completion of radical polymerization reaction, bringing the polymer into contact with a solvent in which the resin is sparingly soluble or insoluble, to precipitate a resin (step a), separating the resin from the solution (step b), anew dissolving the resin in a solvent to prepare resin solution A (step c), bringing the resin solution A into contact with a solvent in which the resin is sparingly soluble or insoluble in a volumetric amount of less than 10 times (preferably 5 times or less) the resin solution A, to precipitate a resin solid (step d), and separating the precipitated resin (step e).

The weight average molecular weight of the resin (P) for use in the invention is preferably 1,000 to 200,000, more preferably 2,000 to 50,000, and still more preferably 2,000 to 20,000.

The polydispersity (Mw/Mn) of the resin (P) is preferably 1.0 to 3.0, more preferably 1.0 to 2.5, and still more preferably 1.0 to 2.0. The weight average molecular weight and polydispersity of the resin (P) are defined in terms of polystyrene by the GPC method.

These resins (P) may be used as mixture of two or more kinds.

The addition amount of the resin (P) for use in the invention is preferably 30% by mass to 100% by mass, more preferably 50% by mass to 99.95% by mass, and especially preferably 70% by mass to 99.90% by mass, on the basis of all the solid contents of the composition. (In this specification, mass ratio is equal to weight ratio.)

### [2] Hydrophobic Resin (HR)

Differently from the resin (P) as above, the actinic ray-sensitive or radiation-sensitive resin composition of the invention may contain a hydrophobic resin (HR). When exposure is performed by filling a liquid having a refractive index higher than that of air (e.g., pure water or the like) between a photosensitive film and a lens, that is, in the case of performing immersion exposure, or in the case of obtaining a negative pattern by using an organic developer as the developer, the hydrophobic resin (HR) is preferably used.

Since the hydrophobic resin (HR) is localized on the film surface, it is preferred to contain a group having a fluorine atom, a group having a silicon atom, or a hydrocarbon group having 5 or more carbon atoms. These groups may be contained in the main chain of the resin or may be substituted on the side chain.

The standard polystyrene equivalent weight average molecular weight of the hydrophobic resin (HR) is preferably 1,000 to 100,000, more preferably 1,000 to 50,000, and still more preferably 2,000 to 15,000.

Also, the hydrophobic resin (HR) may be used alone, or two or more kinds may be used in combination.

The content of the hydrophobic resin (HR) in the composition is preferably 0.01% by mass to 15% by mass, more preferably 0.05% by mass to 8% by mass, and still more preferably 0.1% by mass to 7% by mass., based on all the solid content in the composition of the invention.

Specific examples of the hydrophobic resins (HR) are shown below.

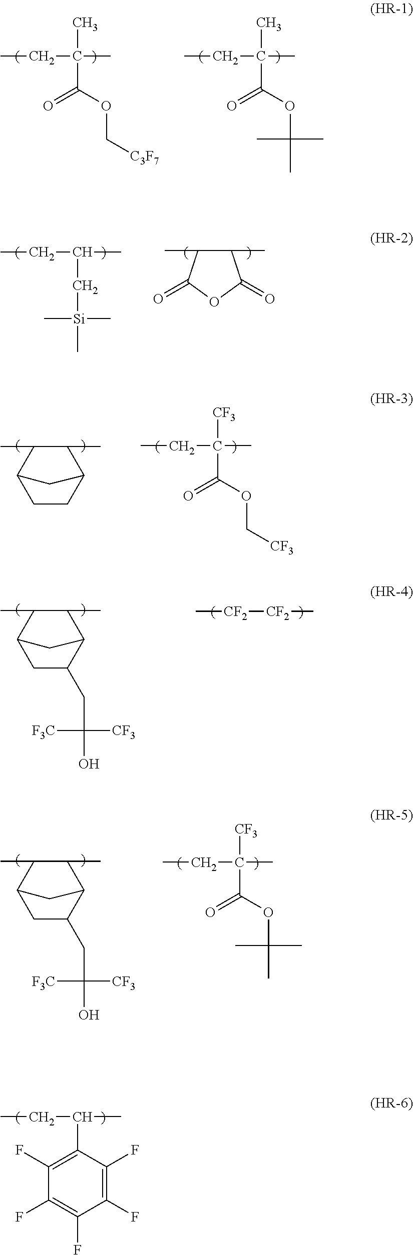

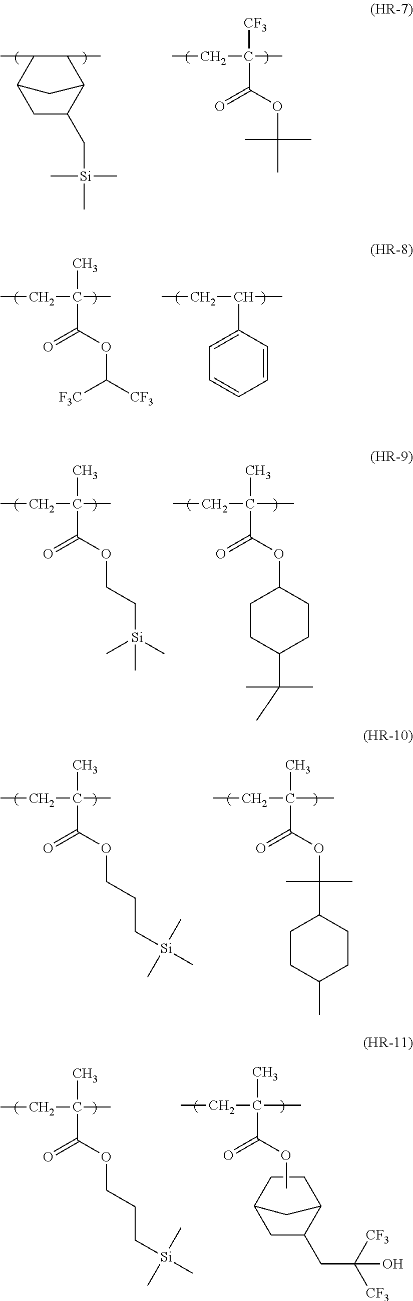

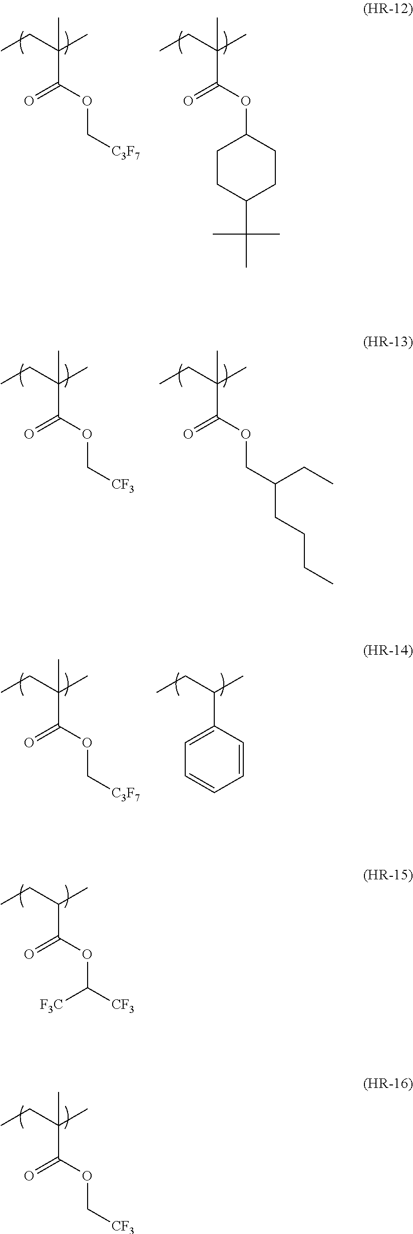

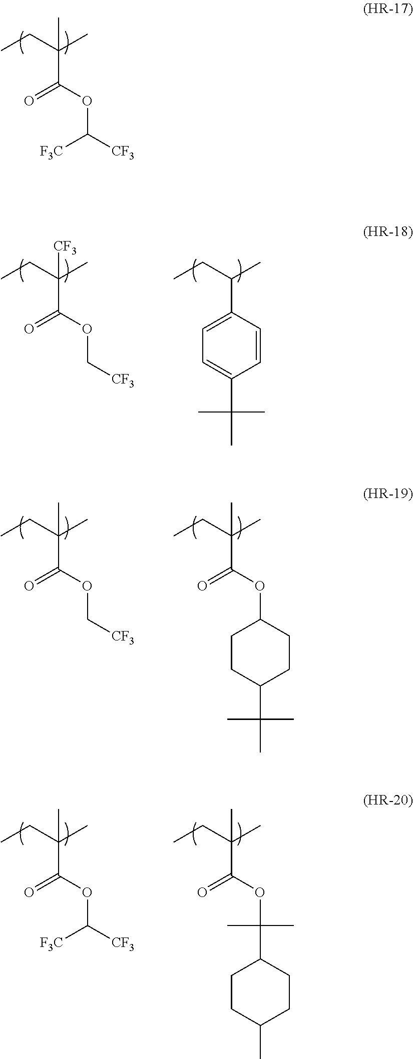

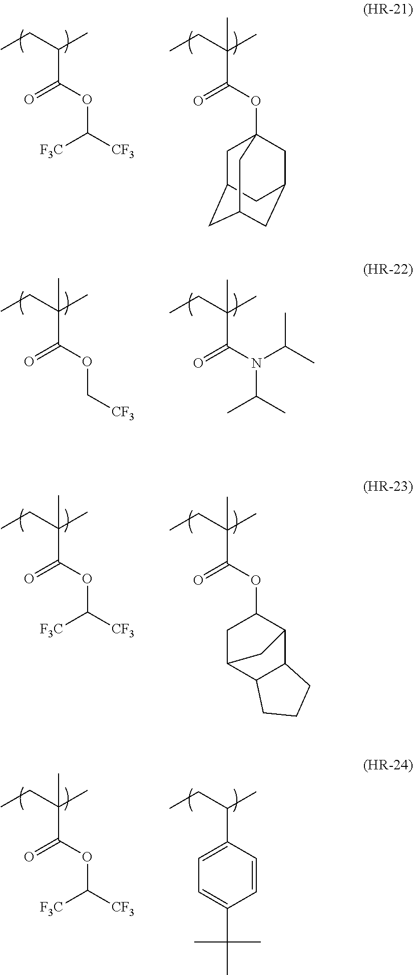

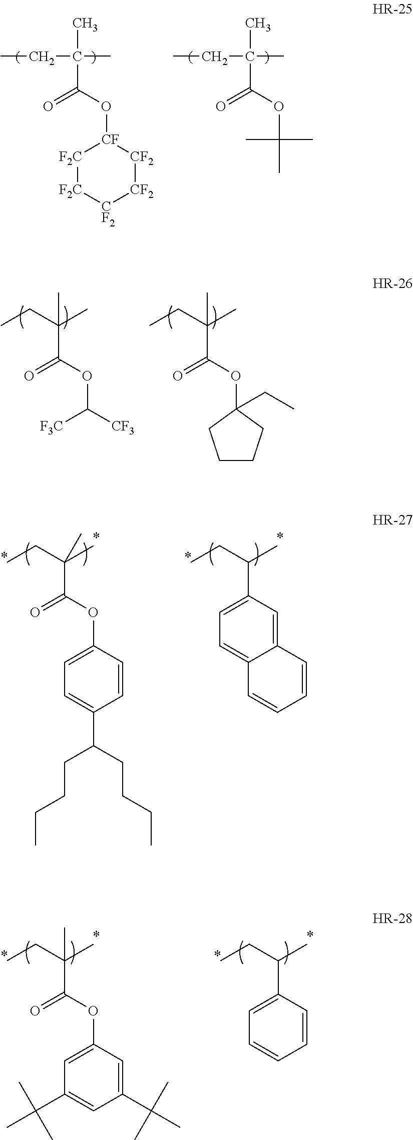

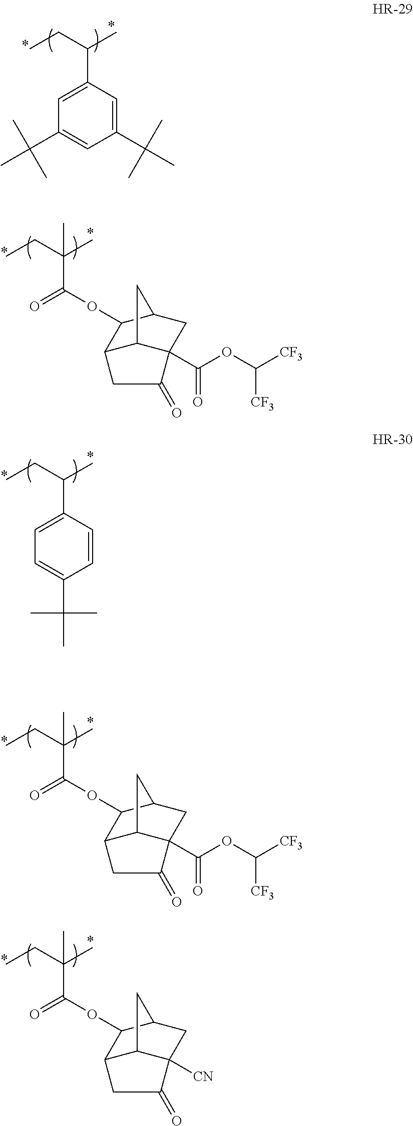

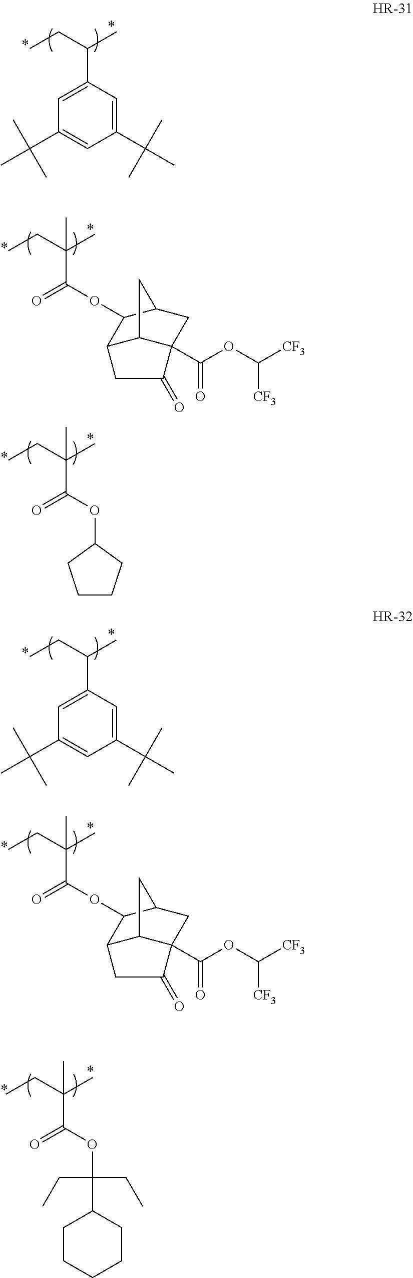

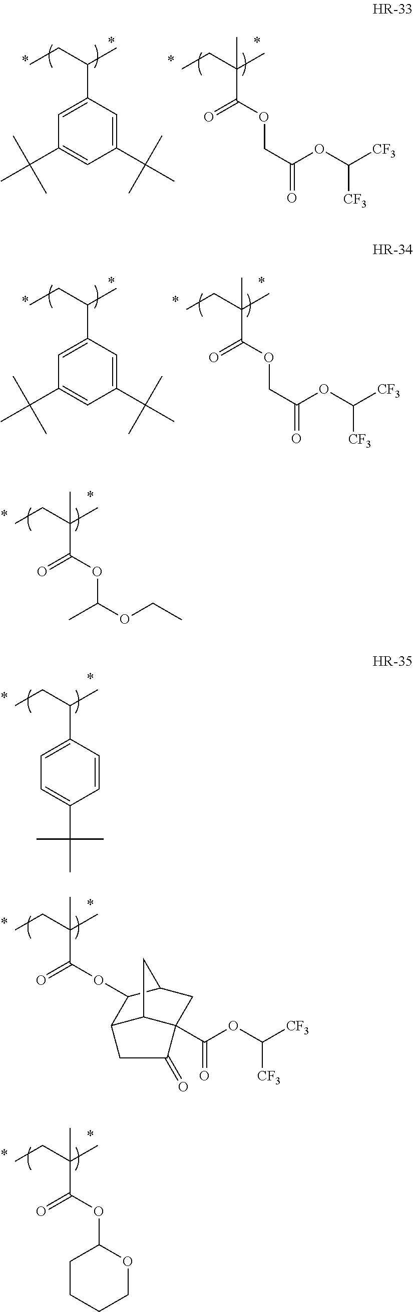

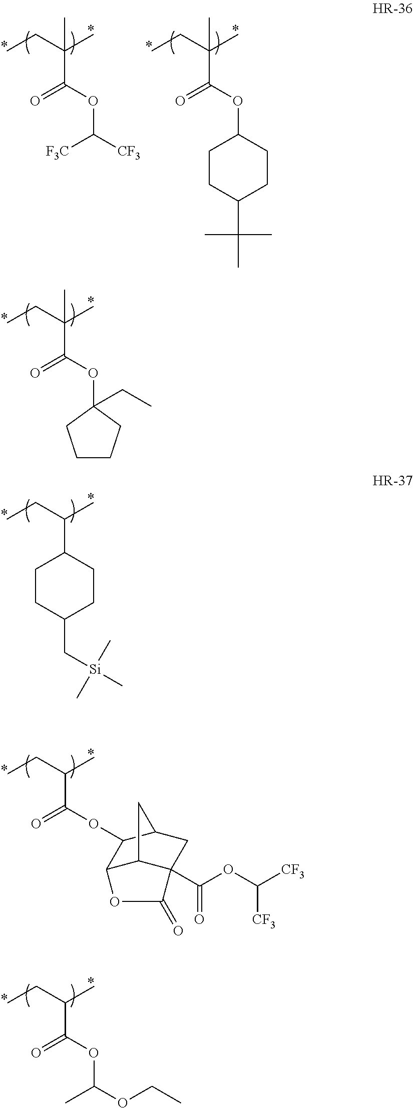

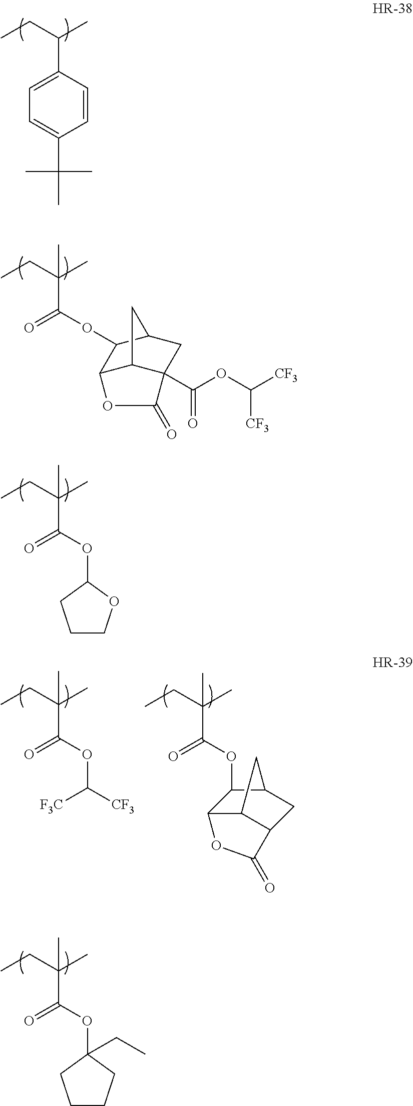

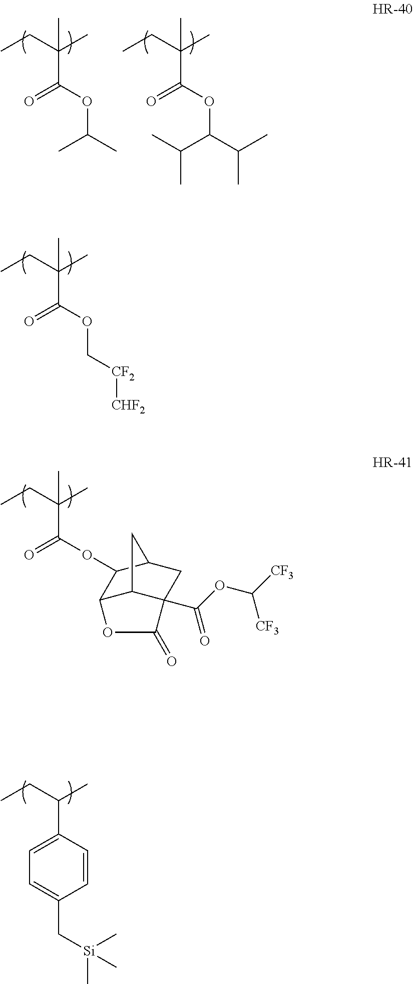

As the hydrophobic resins (HR), in addition to the above, those described in JP-A-2011-248019, JP-A-2010-175859 and JP-A-2012-032544 can also be preferably used.

It is especially preferred to use the hydrophobic resin (HR) having an acid-decomposable group.

[3] (B) Compound Capable of Generating an Acid Upon Irradiation with an Actinic Ray or Radiation

The actinic ray-sensitive or radiation-sensitive resin composition according to the invention may contain (B) a compound capable of generating an acid upon irradiation with an actinic ray or radiation (hereinafter abbreviated to “acid generator (B)”).

The acid generator (B) may take the form of a low molecular compound, or may take the form of being included in a part of a polymer. Also, the form as a low molecular compound and the form of being included in a part of a polymer may be used in combination.

When the acid generator (B) takes the form of a low molecular compound, the molecular weight is preferably 3,000 or less, more preferably 2,000 or less, and still more preferably 1,000 or less.

In the case where the acid generator (B) takes the form of being included in a part of a polymer, the acid generator (B) may be included in a part of the resin (P) and constitute the resin (P), or may be included in a resin different from the resin (P).

In the invention, the acid generator (B) preferably takes the form of a low molecular compound.

The preferred form of the acid generator (B) is an onium compound. As such a form of the acid generator (B), for example, a sulfonium salt, an iodonium salt, and a phosphonium salt are exemplified.

As preferred other form of the acid generator (B), a compound capable of generating a sulfonic acid, an imidic acid, or a methide acid upon irradiation with an actinic ray or radiation can be exemplified. As the acid generator (B) in that form, for example, a sulfonium salt, an iodonium salt, a phosphonium salt, an oxime sulfonate, an imidosulfonate and the like can be exemplified.

The acid generator (B) is preferably a compound capable of generating an acid upon irradiation with an electron beam or an extreme ultraviolet ray.

The actinic ray-sensitive or radiation-sensitive resin composition according to the invention may contain or may not contain the acid generator (B), but when contains the acid generator (B), the content is preferably 0.1% by mass to 30% by mass, more preferably 0.5% by mass to 20% by mass, and still more preferably 1.0% by mass to 10% by mass, based on all the solid content in the composition.

The acid generator (B) can be used by one kind alone, or two or more kinds may be used in combination.

The specific examples of the acid generators (B) are shown below.

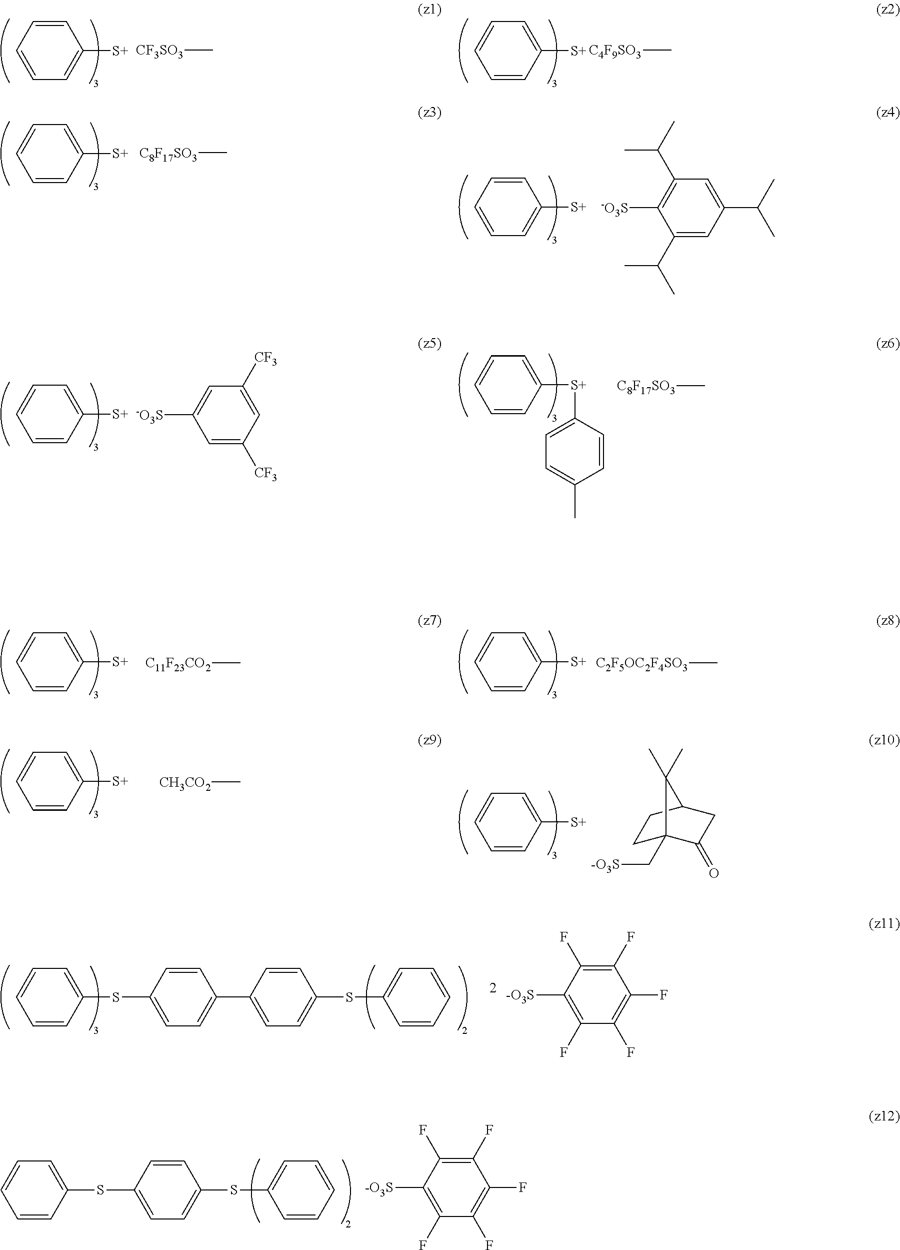

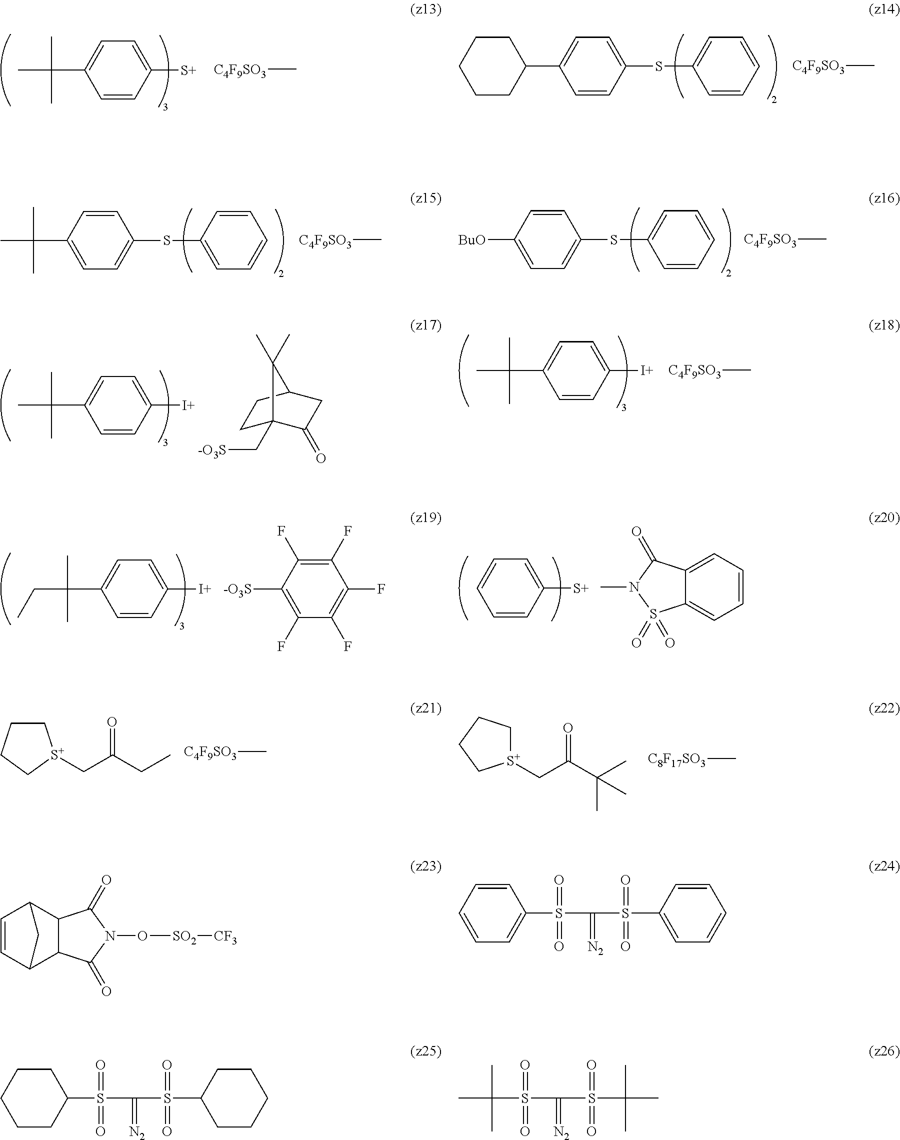

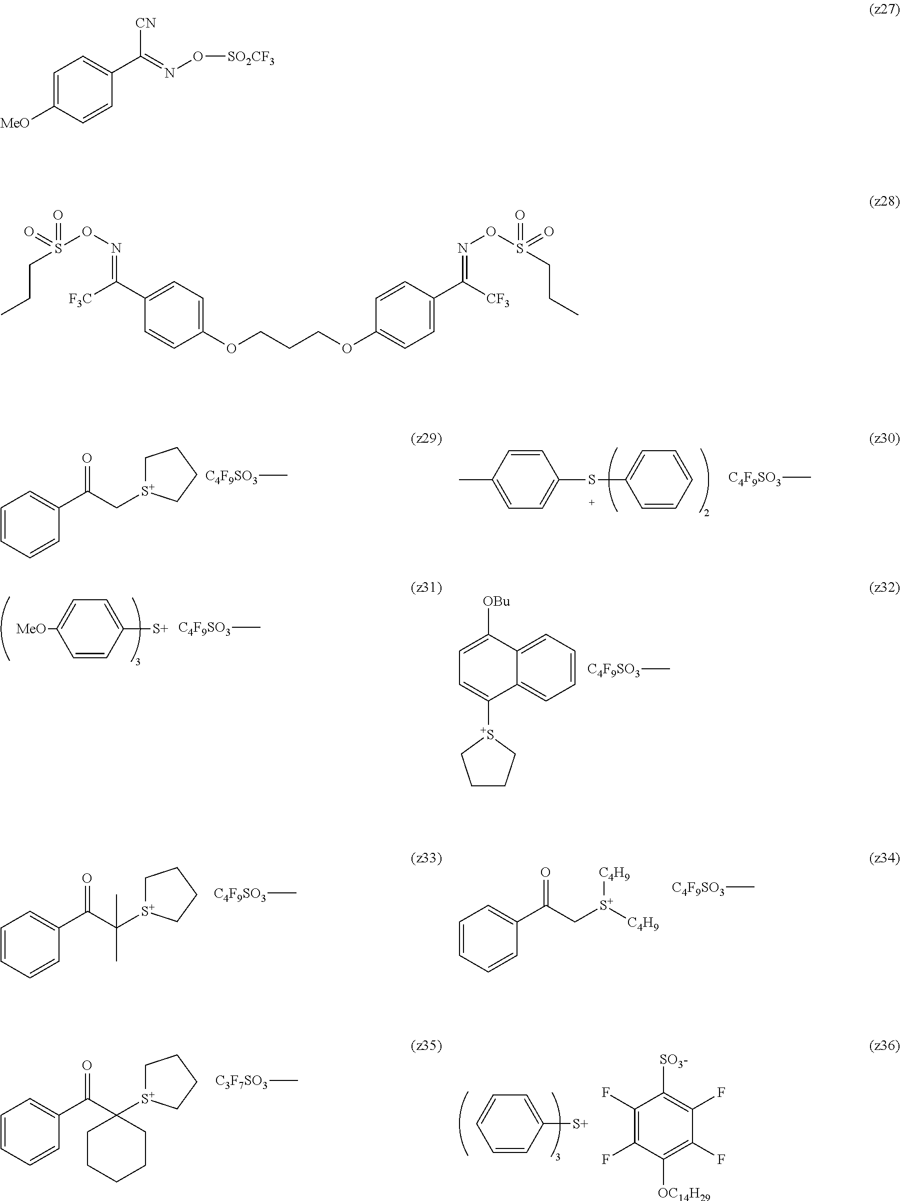

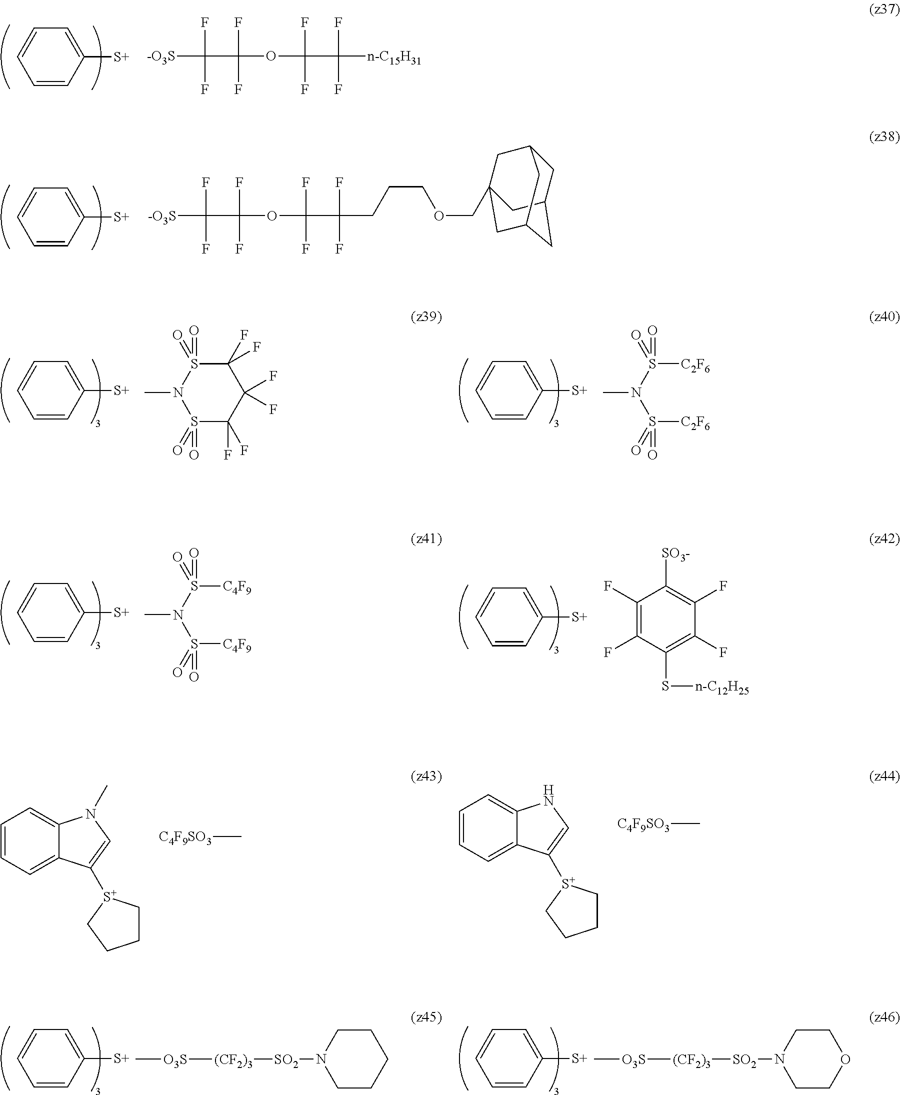

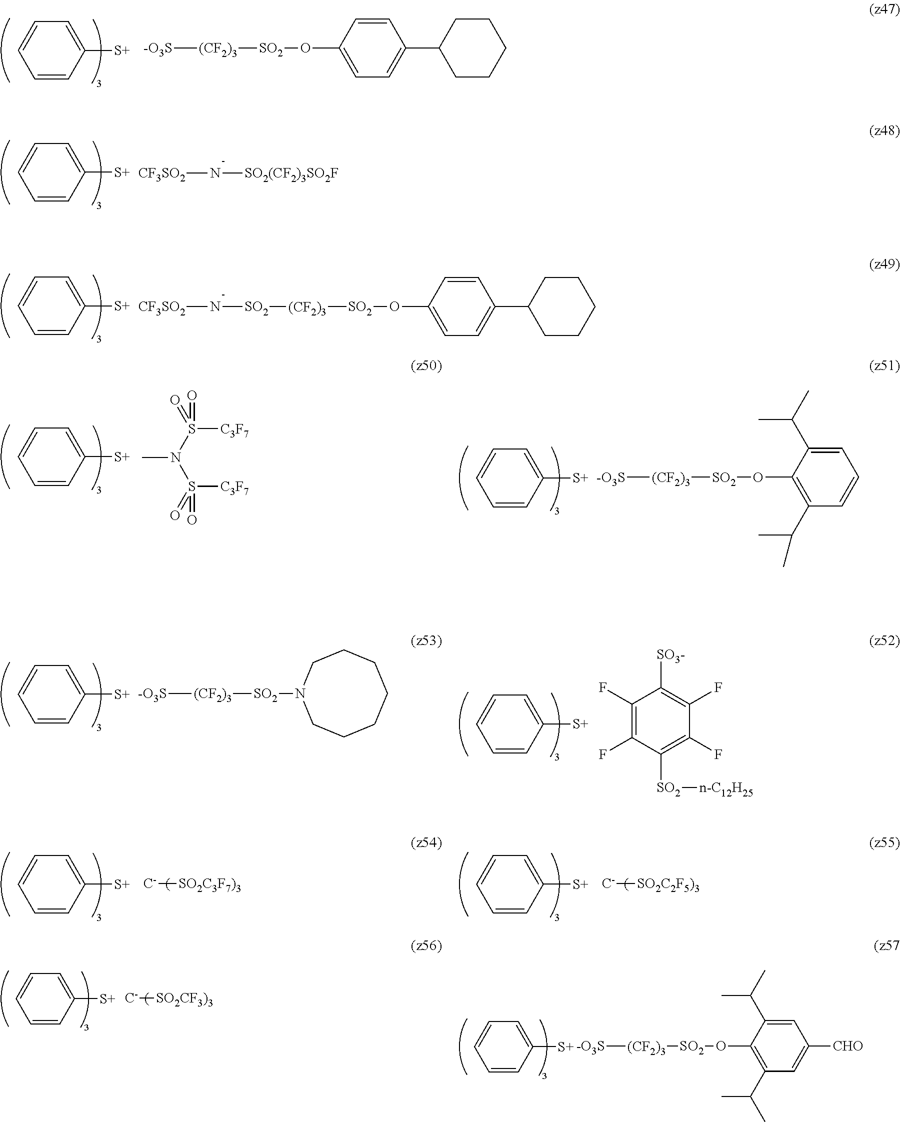

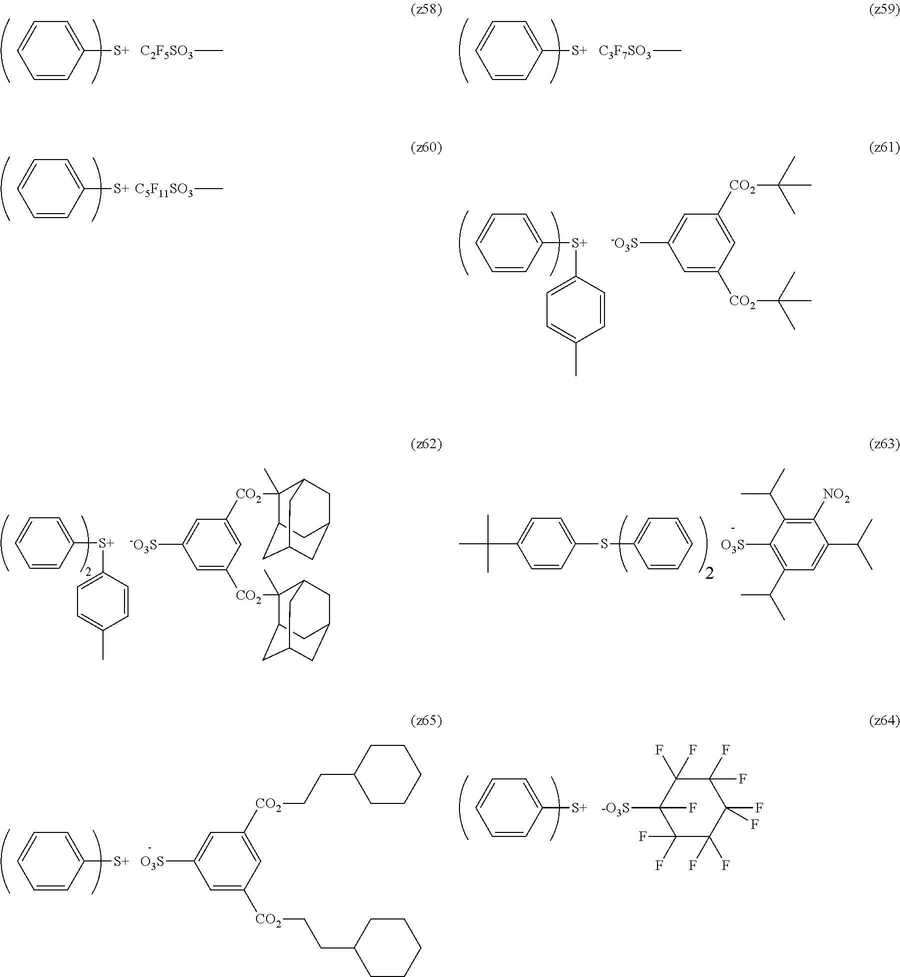

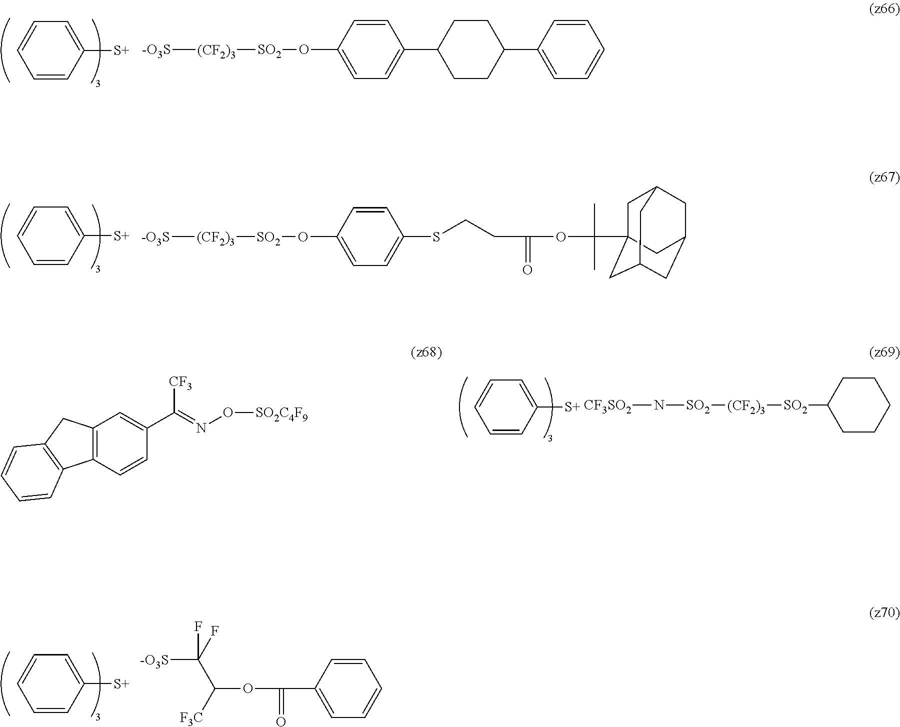

### [4] Basic Compound

The actinic ray-sensitive or radiation-sensitive resin composition in the invention preferably contains a basic compound as an acid capturer in addition to the above components. By using a basic compound, performance fluctuation by aging from exposure to heating can be lessened. Such a basic compound is preferably an organic basic compound, and more specifically aliphatic amines, aromatic amines, heterocyclic amines, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amide derivatives, and imide derivatives are exemplified. An amine oxide compound (refer to JP-A-2008-102383), and an ammonium salt (preferably a hydroxide or a carboxylate, more specifically tetraalkylammonium hydroxide typified by tetrabutylammonium hydroxide is preferred in view of LER) are also properly used.

A compound capable of increasing basicity by the action of an acid can also be used as a kind of the basic compound.

The specific examples of amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropyl-aniline, 2,4,6-tri(t-butyl)aniline, triethanolamine, N,N-dihydroxyethylaniline, tris(methoxyethoxyethyl)amine, tetrabutylammoniium benzoate, the compounds exemplified in U.S. Pat. No. 6,040,112, column 3, on and after line 60, 2-[2-{2-(2,2-dimethoxyphenoxyl)ethyl}bis(2-methoxyethyl)]amine, and compounds (C1-1) to (C3-3) exemplified in U.S. Patent Publication 2007/0224539A1, paragraph [0066]. The examples of compounds having a nitrogen-containing heterocyclic structure include 2-phenylbenzimidazole, 2,4,5-triphenylimidazole, N-hydroxyethyl-piperidine, bis(1,2,2,6,6-pentamethyl-4-piperidyl)sebacate, 4-dimethylaminopyridine, antipyrine, hydroxyantipyrine, 1,5-diazabicyclo[4.3 0.0]nona-5-ene, and 1,8-diazabicyclo[5.4.0]undeca-7-ene. Tetrabutylammonium hydroxide is preferred as ammonium salt.

Of these basic compounds, ammonium salts are preferred in view of the improvement of the resolution.

The actinic ray-sensitive or radiation-sensitive resin composition according to the invention may contain or may not contain a basic compound, but when contains, the content of the basic compound for use in the invention is preferably 0.01% by mass to 10% by mass, more preferably 0.03% by mass to 5% by mass, and especially preferably 0.05% by mass to 3% by mass, based on all the solid content of the composition.

### [5] Surfactant and Other Additives

The actinic ray-sensitive or radiation-sensitive resin composition according to the invention may further contain a surfactant for the purpose of the improvement of coating property. The examples of surfactants are not particularly limited. The examples include nonionic surfactants, e.g., polyoxyethylene alkyl ethers, polyoxyethylene alkylaryl ethers, polyoxyethylene polyoxypropylene block copolymers, sorbitan fatty acid esters, and polyoxyethylene sorbitan fatty acid ester, fluorine surfactants, e.g., Megaface F176 (manufactured by DIC Corporation), Fluorad FC 430 (manufactured by Sumitomo 3M Limited), Surfynol E 1004 (manufactured by ASAHI GLASS CO., LTD.), and PF656, PF6320 (manufactured by OMNOVA), fluorine and silicon surfactants, e.g., Megaface R08 (manufactured by DIC Corporation), and organosiloxane polymers, e.g., polysiloxane polymer KP-341 (manufactured by Shin-Etsu Chemical Co., Ltd.).

The actinic ray-sensitive or radiation-sensitive resin composition according to the invention may contain or may not contain a surfactant, but when the composition contains a surfactant, the amount of the surfactant used is preferably 0.0001% by mass to 2% by mass based on the gross amount of the composition (exclusive of solvents), and more preferably 0.0005% mass to 1% by mass.

The actinic ray-sensitive or radiation-sensitive resin composition according to the invention may further contain other additives, such as a dye, a plasticizer, a photo-decomposable basic compound, and a photo-base generator, if necessary. As for these compounds, respective compounds described in JP-A-2002-6500 can be exemplified.

### [6] Solvent

The examples of the solvents which are used in the actinic ray-sensitive or radiation-sensitive resin composition of the invention preferably include, for example, ethylene glycol monoethyl ether acetate, cyclohexanone, 2-heptanone, propylene glycol monomethyl ether (PGME, 1-methoxy-2-propanol by another name), propylene glycol monomethyl ether acetate (PGMEA, 1-methoxy-2-acetoxypropane by another name), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate, and ethylene carbonate. These solvents are used alone or in combination.

The solid content of the actinic ray-sensitive or radiation-sensitive resin composition according to the invention is preferably dissolved in the above solvents in the solid content concentration of 1% by mass to 40% by mass, more preferably 1% by mass to 30% by mass, and still more preferably 3% by mass to 20% by mass.

### [7] Compound Capable of Decomposing by the Action of an Acid to Generate an Acid

The actinic ray-sensitive or radiation-sensitive resin composition in the invention may contain one or two or more kinds of compounds capable of decomposing by the action of an acid to generate an acid. The acid generated by the compound capable of decomposing by the action of an acid to generate an acid is preferably a sulfonic acid, a methide acid, or an imidic acid.

The specific examples of the compounds capable of decomposing by the action of an acid to generate an acid are shown below, but the invention is not restricted thereto.

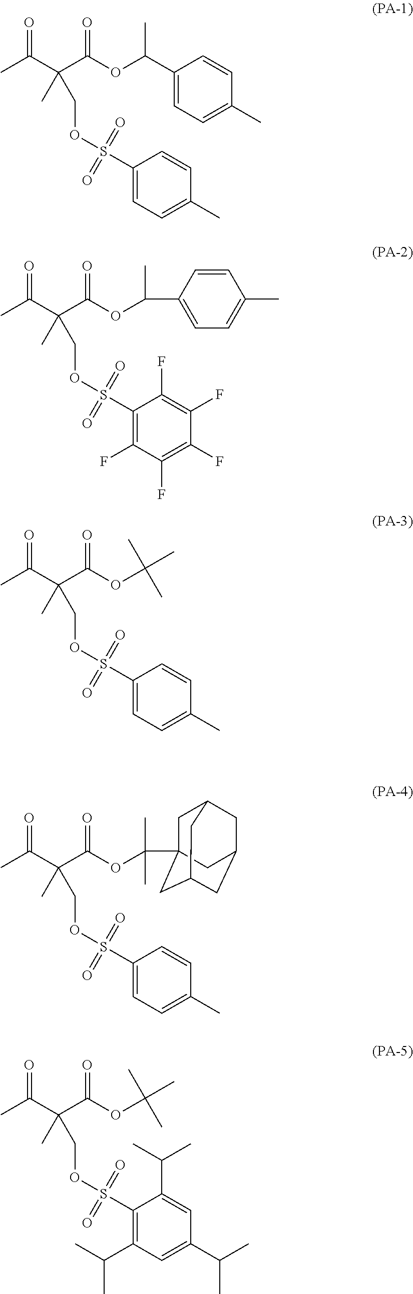

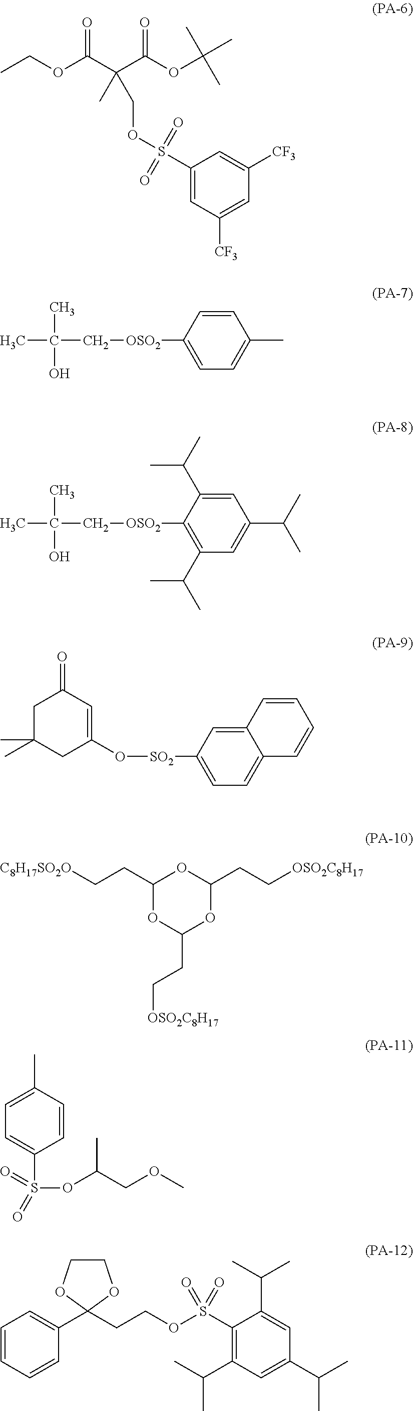

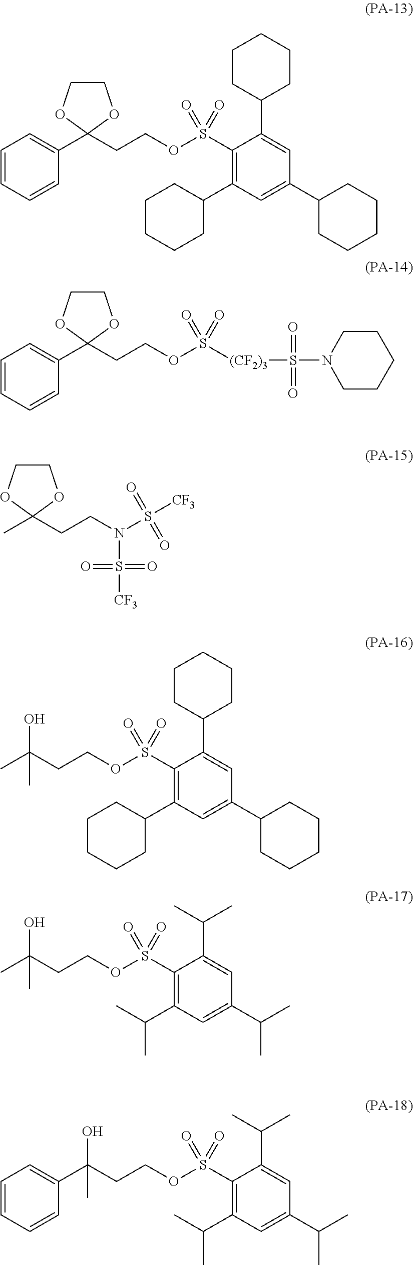

The compound capable of decomposing by the action of an acid to generate an acid can be used one kind alone or two or more kinds may be used in combination.

The content of the compound capable of decomposing by the action of an acid to generate an acid is preferably 0.1% by mass to 40% by mass based on all the solid content in the electron beam-sensitive or extreme ultraviolet ray-sensitive resin composition, more preferably 0.5% by mass to 30% by mass, and still more preferably 1.0% by mass to 20% by mass.

### [8] Pattern Forming Method

The invention also relates to a resist film formed with the actinic ray-sensitive or radiation-sensitive resin composition according to the invention. The resist film is, for example, formed by coating the composition on a support such as a substrate. The actinic ray-sensitive or radiation-sensitive resin composition of the invention is coated on a substrate by a proper coating method such as spin coating, roll coating, flow coating, dip coating, spray coating, or doctor coating, and then the composition is subjected to pre-baking at 60° C. to 150° C. for 1 min to 20 min, preferably at 80° C. to 130° C. for 1 min to 10 min to form a film. The thickness of the coated film is preferably 30 nm to 200 nm.

The substrates suitable for the invention are a silicon substrate and a substrate provided with a metal deposited film or a film containing a metal, and more suitable substrates are substrates provided with a deposited film of Cr, MoSi, TaSi, or oxides or nitrides thereof on the surface.

The invention also relates to a resist-coated mask blank obtained by coating the resist film formed as above. For obtaining such a resist-coated mask blank, in the case of forming a resist pattern on a photomask blank for the manufacture of a photomask, a transparent substrate of quartz or calcium fluoride is used. In general, necessary functional films such as a light-shielding film, an antireflection film, further, a phase shift film, additionally an etching stopper film, and an etching mask film are laminated on a substrate. Functional films containing such materials as silicon, or transition metals, e.g., chromium, molybdenum, zirconium, tantalum, tungsten, titanium and niobium are laminated. The materials which are used for the outermost surface layer include materials comprising silicon, or materials comprising silicon and oxygen and/or nitrogen as main components, silicon compound materials comprising the materials containing transition metals as the main components in addition to the above silicon components, and transition metal compound materials comprising materials containing transition metals, in particular, one or more kinds selected from chromium, molybdenum, zirconium, tantalum, tungsten, titanium and niobium, or further containing one or more elements selected from oxygen, nitrogen and carbon as the main components are exemplified.

The light-shielding film may be a single layer but is more preferably a multiple layered structure by recoating a plurality of materials, one on another. In the case of a multiple layered structure, the layer thickness per one layer is not especially restricted, but is preferably 5 nm to 100 nm, and more preferably 10 nm to 80 nm. The thickness of the light-shielding material at large is not especially restricted but is preferably 5 nm to 200 nm, and more preferably 10 nm to 150 nm.

When a pattern is formed by using the actinic ray-sensitive or radiation-sensitive resin composition on a photomask blank having the outermost surface layer of the material generally containing oxygen and nitrogen in chromium, of the above materials, trailing is formed in the vicinity of the substrate and liable to be a tapered form, but when the composition of the invention is used, a tapered form can be improved as compared with conventional materials.

In the next place, the resist film is subjected to irradiation with an actinic ray or radiation (electron beam and the like), and development, preferably after baking (usually 80° C. to 150° C., and preferably 90° C. to 130° C.), thereby a good pattern can be obtained. A semiconductor fine circuit, a mold structure for imprinting, a photomask and the like are manufactured by using the pattern as the mask and properly performing etching treatment, ion injection and the like.

Incidentally, the processes in the case of manufacturing a mold for imprinting with the composition of the invention are described, for example, in Japanese Patent 4109085, JP-A-2008-162101, and compiled by Yoshihiko Hirai, Fundamentals, Technical Development and Development of Applications of Nano-Imprinting—Techniques on The Substrates And The Latest Technical Development of Nano-Imprinting, published by Frontier Publishing Company.

### <Topcoat Composition>

In the pattern forming method of the invention, a topcoat layer may be formed on the above-described resist film. The topcoat composition used for forming the topcoat layer is described below.

The solvent for the topcoat composition in the invention is preferably water or an organic solvent, and more preferably water.

When the solvent for the topcoat composition is an organic solvent, the resist film is preferably insoluble in the solvent. The usable solvents are alcohol-based solvents, fluorine-based solvents and hydrocarbon-based solvents, and non-fluorine alcohol-based solvents are more preferably used. As the alcohol-based solvents, primary alcohols are preferably used from the point of coating property, and more preferably primary alcohols having 4 to 8 carbon atoms. The primary alcohols having 4 to 8 carbon atoms may be linear, branched or cyclic, but linear or branched alcohols are preferably used. The specific examples thereof include, for example, 1-butanol, 1-hexanol, 1-pentanol, and 3-methyl-1-butanol.

When the solvent for the topcoat composition of the invention is water, it is preferred for the composition to contain a water-soluble resin. By such selection, it is presumed that the uniformity of the wettability by the developer can be further enhanced. As preferred water-soluble resins, polyacrylic acid, polymethacrylic acid, polyhydroxystyrene, polyvinyl pyrrolidone, polyvinyl alcohol, polyvinyl ether, polyvinyl acetal, polyacrylimide, polyethylene glycol, polyethylene oxide, polyethyleneimine, polyester polyol, polyether polyol, and polysaccharide are exemplified. Especially preferred are polyacrylic acid, polymethacrylic acid, polyhydroxystyrene, polyvinyl pyrrolidone, and polyvinyl alcohol. Incidentally, water-soluble resins are not limited to homopolymers alone, and copolymers can also be used. For example, copolymers having monomers corresponding to the repeating unit of homopolymers described above and other monomer units may be used. Specifically, acrylic acid-methacrylic acid copolymers, and acrylic acid-hydroxystyrene copolymers can also used in the invention. Further, as the resins for the topcoat composition, resins having an acidic group as described in JP-A-2009-134177 and JP-A-2009-91798 can also be preferably used.

The weight average molecular weight of the water-soluble resin is not particularly limited, but is preferably 2,000 to 1,000,000, more preferably 5,000 to 500,000, and especially preferably 10,000 to 100,000. The weight average molecular weight of the resin is the molecular weight in terms of polystyrene measured by GPC (carrier: THF or N-methyl-2-pyrrolidone (NMP)).

The pH of the topcoat is not especially restricted, but is preferably 1 to 10, more preferably 2 to 8, and especially preferably 3 to 7.

When the solvent for the topcoat composition is an organic solvent, the topcoat composition preferably contains a hydrophobic resin. As the hydrophobic resin, the hydrophobic resins described in JP-A-2008-209889 are preferably used.

The concentration of the resin in the topcoat composition is preferably 0.1% by mass to 10% by mass, more preferably 0.2% by mass to 5% by mass, and especially preferably 0.3% by mass to 3% by mass,

The materials of the topcoat may contain components other than resin, but the rate of the resin accounting for in the solids content of the topcoat composition is preferably 80% by mass to 100% by mass, more preferably 90% by mass to 100% by mass, and especially preferably 95% by mass to 100% by mass. As the components other than the resin added to the topcoat composition, a photo-acid generator and a basic compound are exemplified as preferred components. The specific compounds thereof are the same with the compounds as exemplified in the resist composition.

As the components other than the resin which can be added to the topcoat material, a surfactant, a photo-acid generator, and a basic compound are exemplified. The specific examples of surfactants and basic compounds are the same compounds with the acid generators and basic compounds as described above.

When a surfactant is used, the addition amount of the surfactant is preferably 0.0001% by mass to 2% by mass based on the gross amount of the topcoat composition, and is more preferably 0.001% by mass to 1% by mass.

By the addition of a surfactant to the treating agent, the coating property at the time of coating the treating agent is improved. The examples of the surfactants are nonionic, anionic, cationic and amphoteric surfactants.

As nonionic surfactants, PLUFARAC series (manufactured by BASF Japan), ELEBASE series, FINESURF series, FLAUNON series (manufactured by Aoki Oil Industrial Co., Ltd.), ADEKA PLURONIC P-103 (manufactured by Adeka Corporation), EMULGEN series, AMEET series, AMINON PK-02S, EMANON CH-25, REODOR series (manufactured by Kao Chemicals), SURFLON S-141 (manufactured by AGC Seimi Chemical Co., Ltd.), NOIGEN series (manufactured by Daiichi Kogyo Seiyaku Co., Ltd.), NEW KALGEN series (manufactured by Takemoto Oil & Fat Co., Ltd.), DYNOL 604, ENVIROGEM AD01, OLFINE EXP series, SURFYNOL series (manufactured by Nisshin Chemical Industrial Co., Ltd.), and FTERGENT 300 (manufactured by Ryoko Chemical Co., Ltd.) can be used.

As nonionic surfactants, EMAL 20T, POIS 532A (manufactured by Kao Chemicals), PHOSPHANOL ML-200 (manufactured by TOHO Chemical Industry Co., Ltd.), EMULSOGEN series, (manufactured by Clariant Japan), SURFLON S-111N, SURFLON S-211 (manufactured by AGC Seimi Chemical Co., Ltd.), PLYSURF series (manufactured by Daiichi Kogyo Seiyaku Co., Ltd.), PIONIN series (manufactured by Takemoto Oil & Fat Co., Ltd.), OLFINE PD-201, OLFINE PD-202 (manufactured by Nisshin Chemical Industrial Co., Ltd.), AKYPO RLM45, ECT-3 (manufactured by Nippon Surfactant Co., Ltd.), and LIPON (manufactured by Lion Corporation) can be used.

As cationic surfactants, ACETAMINE 24, ACETAMINE 86 (manufactured by Kao Chemicals) can be used.

As amphoteric surfactants, SURFLON S-131 (manufactured by AGC Seimi Chemical Co., Ltd.), ENAGYCOL C-40H, LIPOMIN LA (manufactured by Kao Chemicals) can be used.

These surfactants may be used as mixtures.

### <Pattern Forming Method>

In the pattern forming method of the invention, for example, in the case where a negative pattern is formed with an organic developer as the developer, a photo-resist layer is formed on a substrate with the resist composition, and a topcoat layer may be formed on the photo-resist layer with the topcoat composition. The thickness of the topcoat layer is preferably 10 nm to 200 nm, more preferably 20 nm to 100 nm, and especially preferably 40 nm to 80 nm.

A spin coating method is preferably used for coating the resist composition on a substrate at a revolution speed of 1,000 rpm to 3,000 rpm.

For example, the resist composition is coated on such a substrate as used in the manufacture of a precision integrated circuit device (e.g., silicon/silicon dioxide coating) by a proper coating method such as with a spinner or a coater, and dried to form a resist film. Incidentally, a well-known antireflection film may be coated in advance. It is preferred to dry a resist film before forming a topcoat layer.

In the next place, the topcoat composition is coated on the obtained resist layer by the method similar to the method of the resist layer forming, and the topcoat composition is dried to form a topcoat layer.

A resist film having a topcoat layer as the upper layer is irradiated with an actinic ray or radiation usually through a mask, preferably baked (heated), and developed. A good pattern can be obtained by these operations.

Using methods of the actinic ray-sensitive or radiation-sensitive resin composition and the resist pattern forming methods of the invention are described below.

The invention also relates to a forming method of a resist pattern including exposing the above resist film or a resist-coated mask blank, and developing the exposed resist film or the resist-coated mask blank. In the invention, the exposure is preferably performed with an electron beam or an extreme ultraviolet ray.

In the manufacture of a precise integrated circuit device, exposure onto a resist film (a pattern forming process) is performed in the first place with an electron beam or an extreme ultraviolet ray pattern-wise on the resist film of the invention. Exposure is performed so that the dose (quantity of exposure) reaches 0.1 μC/cm² to 60 μC/cm² or so in the case of electron beam, preferably 3 μC/cm² to 50 μC/cm² or so, and 0.1 mJ/cm² to 40 mJ/cm² or so in the case of extreme ultraviolet ray, and preferably 3 mJ/cm² to 30 mJ/cm² or so. In the next place, post exposure baking is performed on a hot plate at 60° C. to 150° C. for 1 min to 20 min, and preferably at 80° C. to 120° C. for 1 min to 10 min, and then development, rising, and drying to form a resist pattern.

An alkali developer or a developer containing an organic solvent (hereinafter also referred to as an organic developer”) is used as the developer.

An alkali developer is an alkaline aqueous solution containing inorganic alkalis, e.g., sodium hydroxide, potassium hydroxide, sodium carbonate, sodium silicate, sodium metasilicate, or aqueous ammonia, primary amines, e.g., ethylamine, or n-propylamine, secondary amines, e.g., diethylamine or di-n-butylamine, tertiary amines, e.g., triethylamine or methyldiethylamine, alcohol amines, e.g., dimethylethanolamine or triethanolamine, quaternary ammonium salts, e.g., tetramethylammonium hydroxide or tetraethylammonium hydroxide, or cyclic amines, e.g., pyrrole or piperidine.

An alkali developer may contain a proper amount of alcohols and/or surfactants.

The concentration of an alkali developer is generally 0.1% by mass to 20% by mass. The pH of an alkali developer is generally 10.0 to 15.0.

When the developer is an alkali developer, pure water is used as the rinsing solution, and an appropriate amount of a surfactant may be added.

As the organic developer, a polar solvent such as a ketone-based solvent, an ester-based solvent, an alcohol-based solvent, an amide-based solvent, or an ether-based solvent, and a hydrocarbon-based solvent can be used. Butyl acetate, 2-heptanone, anisole, 4-methyl-2-pentanol, 1-hexanol, and decane and the like are preferably used.

The organic developer may contain a basic compound. The specific examples and preferred examples of the basic compounds which can be contained in the developer for use in the invention are the same with the basic compounds which can be contained in the actinic ray-sensitive or radiation-sensitive resin composition according to the invention.

In the pattern forming method of the invention, in addition to development using a developer containing an organic solvent (the organic solvent development process), a process of development using an alkali aqueous solution (the alkali development process) may be sued in combination, by way of performing such processes in combination, a further precise pattern can be formed.

In the invention, the area of weak exposure intensity is removed by the organic solvent development process, but by further performing the alkali development process, the area of strong exposure intensity is also removed. By the multiple development process of performing a plurality of times of developments as above, pattern formation can be effected without dissolving only the area of intermediate exposure intensity, therefore, a pattern finer than ordinary patterns can be formed (the similar mechanism to that described in JP-A-2008-292975, paragraph [0077]).

In the pattern forming method of the invention, the order of the alkali development process and the organic solvent development process is not particularly restricted, but it is more preferred to perform the alkali development process prior to the organic solvent development process.

The water content as the organic developer at large is preferably less than 10% by mass, and it is more preferred not to substantially contain moisture.

That is, the use amount of an organic solvent in an organic developer is preferably 90% by mass or more and 100% by mass or less to the total amount of the developer, and more preferably 95% by mass or more and 100% by mass or less.

When the developer is an organic developer, it is preferred to use a rinsing solution containing at least one organic solvent selected from the group consisting of a ketone-based solvent, an ester-based solvent, an alcohol-based solvent, and an amide-based solvent.

Development is performed with an alkali aqueous solution of 0.1% by mass to 5% by mass, preferably 2% by mass to 3% by mass of tetramethylammonium hydroxide (TMAH) for 0.1 min to 3 min, preferably 0.5 min to 2 min, by an ordinary method, such as a dipping method, a puddling method, or a spraying method. Thus, the exposed area is dissolved in the developer, and the unexposed area is sparingly dissolved in the developer, thereby the aiming pattern is formed on a substrate.

The invention also relates to a photomask obtained by exposing and developing a resist-coated mask blank. As the exposure and development, the above-described processes are applicable. The photomask is preferably used for the manufacture of a semiconductor.

The photomask in the invention may be a light transmitting type mask for use in ArF excimer laser and the like or may be a light reflecting type mask for use in reflecting lithography with an EUV ray as the light source.

The invention also relates to a manufacturing method of a semiconductor device including the above-described pattern forming method of the invention, and also relates to a semiconductor device manufactured by the same method.

The semiconductor device according to the invention is preferably mounted on electric and electronic equipments (such as home electric and electronic devices, OA/media-related devices, optical devices and communication devices).

### EXAMPLES

### Synthesis Example 1

### Synthesis of Monomer (M-054)

A compound represented by the following formula (AA-1) (100 g), a compound represented by the following formula (AA-2) (170.7 g) were dissolved in 1,000 g of methylene chloride, and 500 g of a 1N—NaOH aqueous solution and 9.6 g of tetramethylammonium hydrogensulfate were added thereto, followed by stirring at room temperature for 2 hours. The reaction solution was poured into a separating funnel, the organic layer was washed with 100 g of a 1N—NaOH aqueous solution two times, and the organic layer was concentrated with an evaporator. The obtained transparent oil was dissolved in 500 g of acetonitrile, 84.1 g of sodium iodide was added thereto, and the solution was stirred at room temperature for 4 hours. Further, 192.6 g of triphenylsulfonium bromide was added to the reaction solution, and the solution was stirred at room temperature for 1 hour. After the obtained reaction solution was concentrated in an evaporator, the concentrated solution was poured into a separating funnel containing 300 mL of ethyl acetate, the organic layer was washed with 50 mL of distilled water five times, and the organic layer was concentrated in the evaporator to thereby obtain 352.3 g of monomer (M-054).

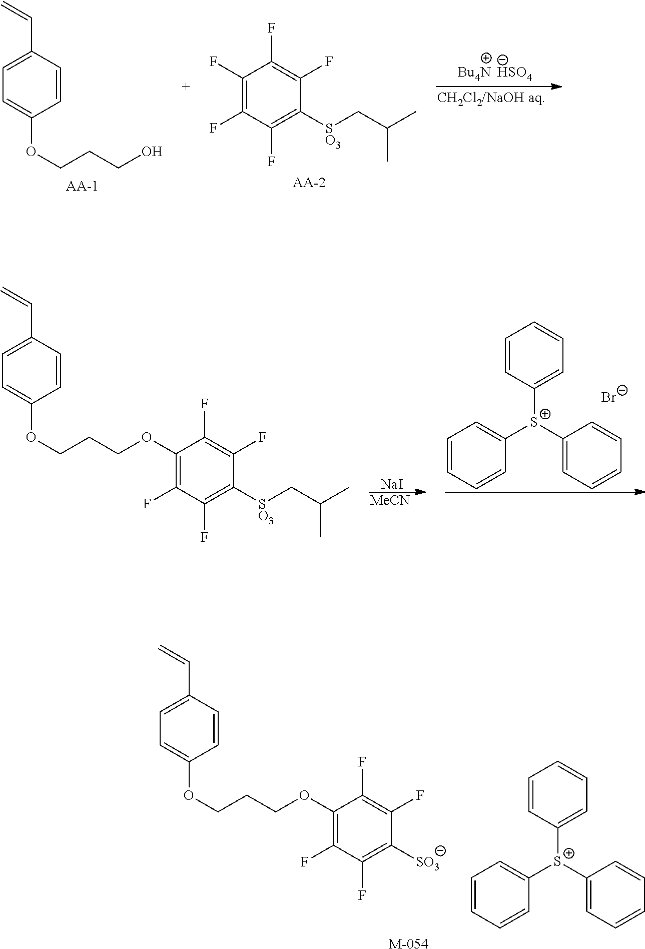

### Synthesis Example 2

### Synthesis of Resin (P-1)

1-Methoxy-2-propanol (8.10 g) was heated to 80° C. under nitrogen flow. While stirring the solution, a mixed solution containing 6.69 g of monomer (M-054), 9.60 g of the monomer represented the following structural formula A, 4.80 g of the monomer represented by the following structural formula B, 32.5 g of 1-methoxy-2-propanol, and 1.61 g of dimethyl 2,2′-azobisisobutyrate (V-601, manufactured by Wako Pure Chemical Industries) was dropwise added thereto over 2 hours. After completion of dropping, the solution was further stirred for 4 hours at 80° C. After being allowed to be cooled, the reaction solution was reprecipitated by a large amount of hexane, and vacuum dried to thereby obtain 19.5 g of resin (P-1) of the invention.

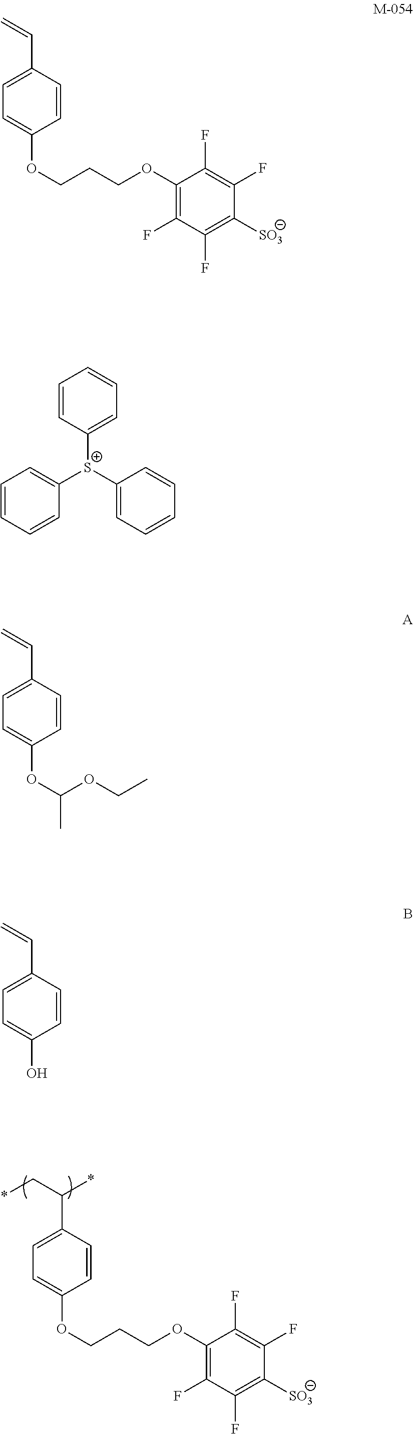

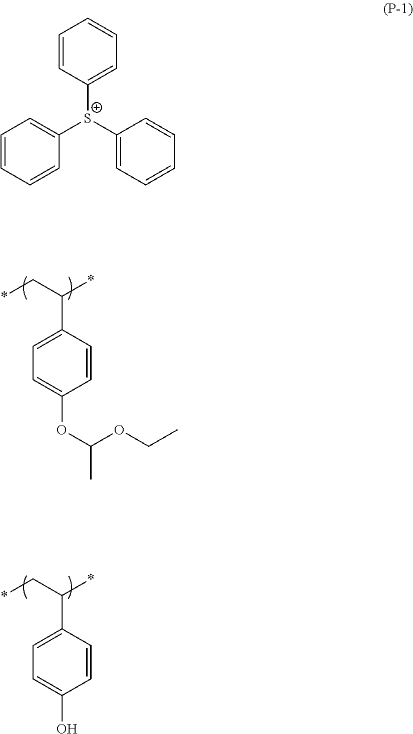

Resins (P-2) to (P-14) were synthesized in the same manner. The structure, composition ratio (molar ratio), weight average molecular weight and polydispersity of each of the synthesized resins were shown below.

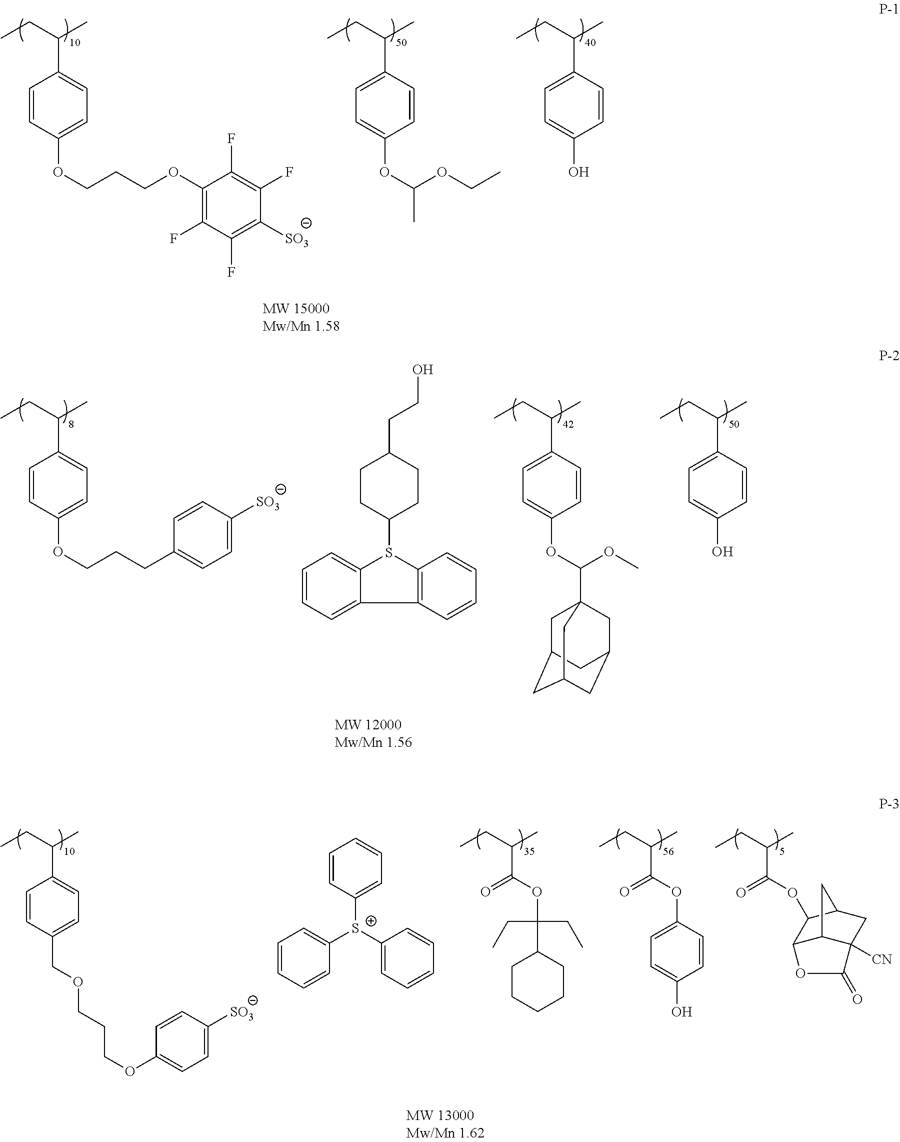

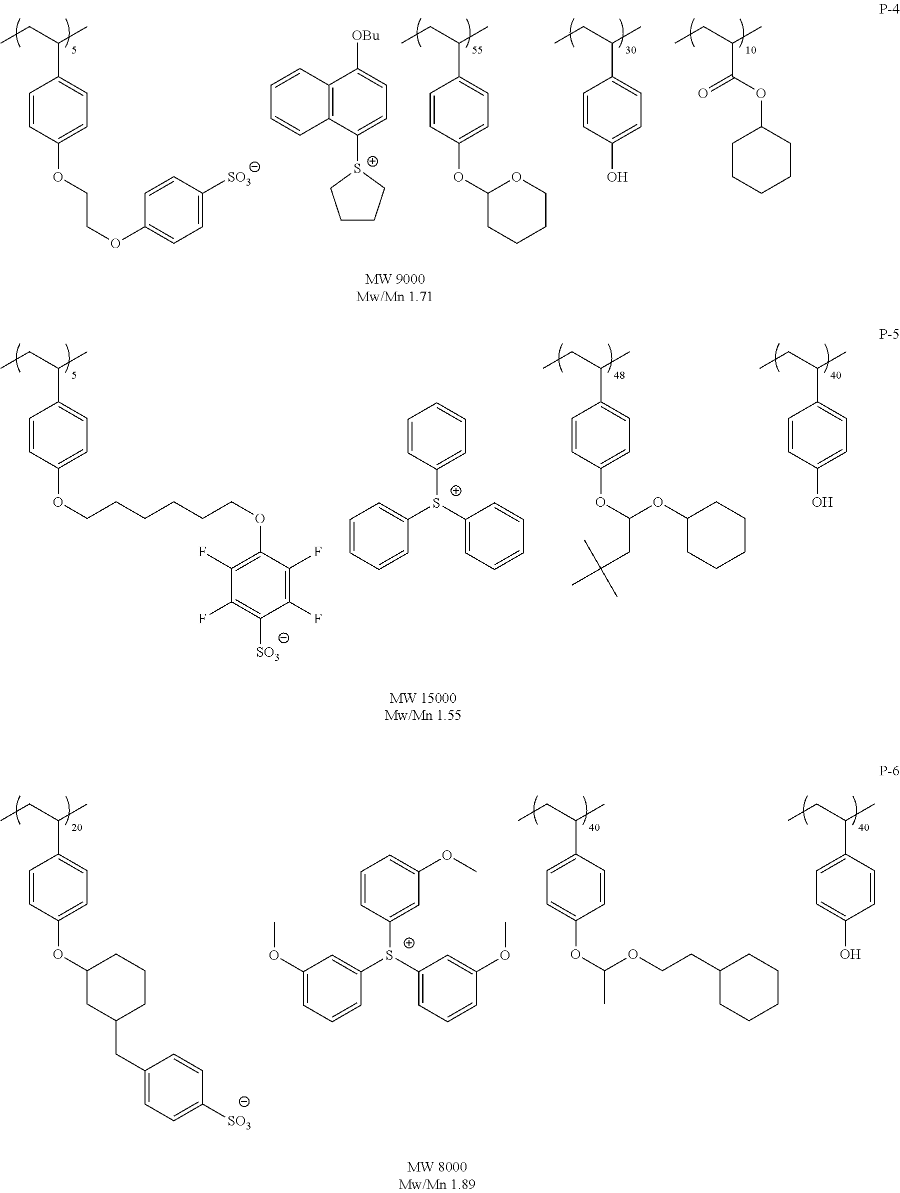

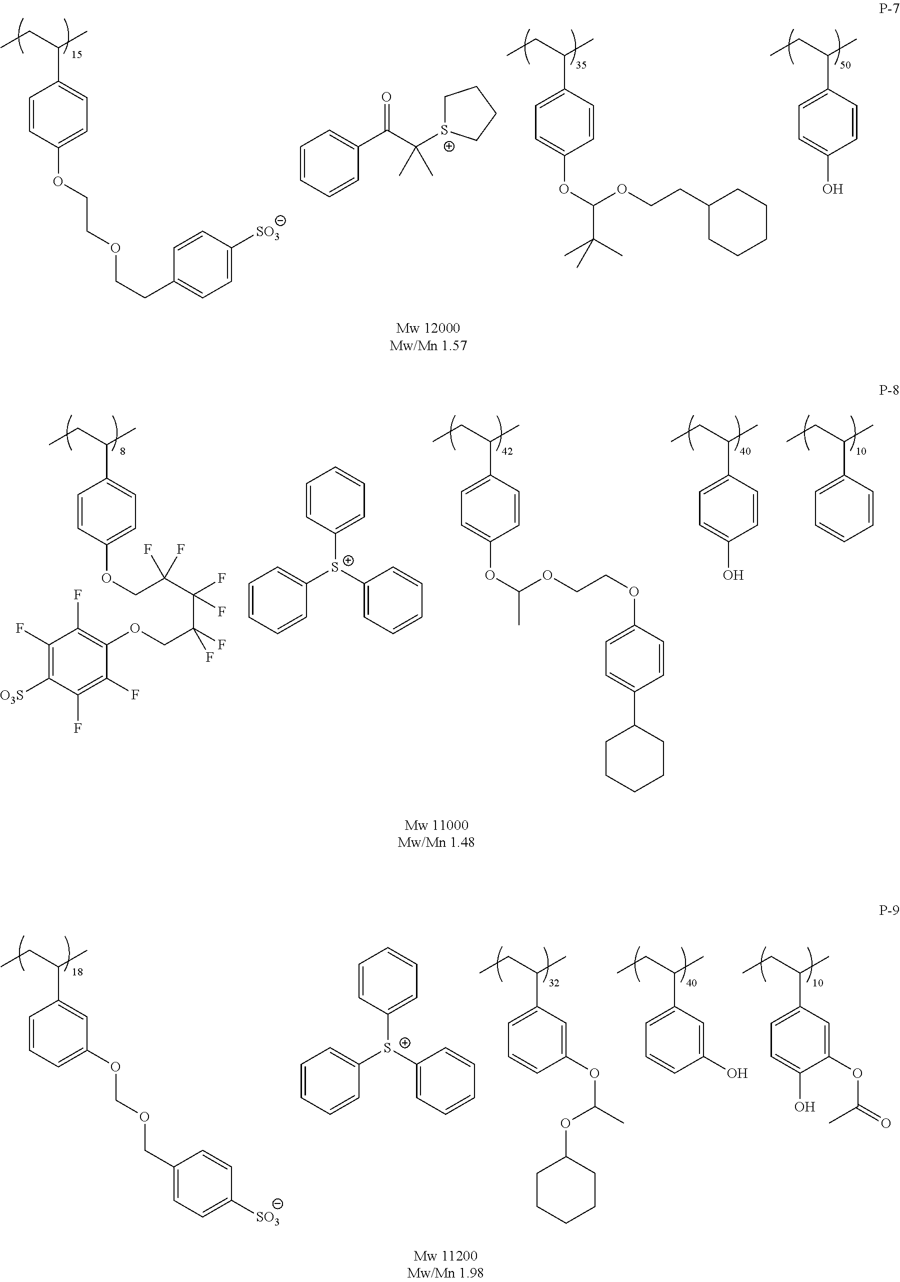

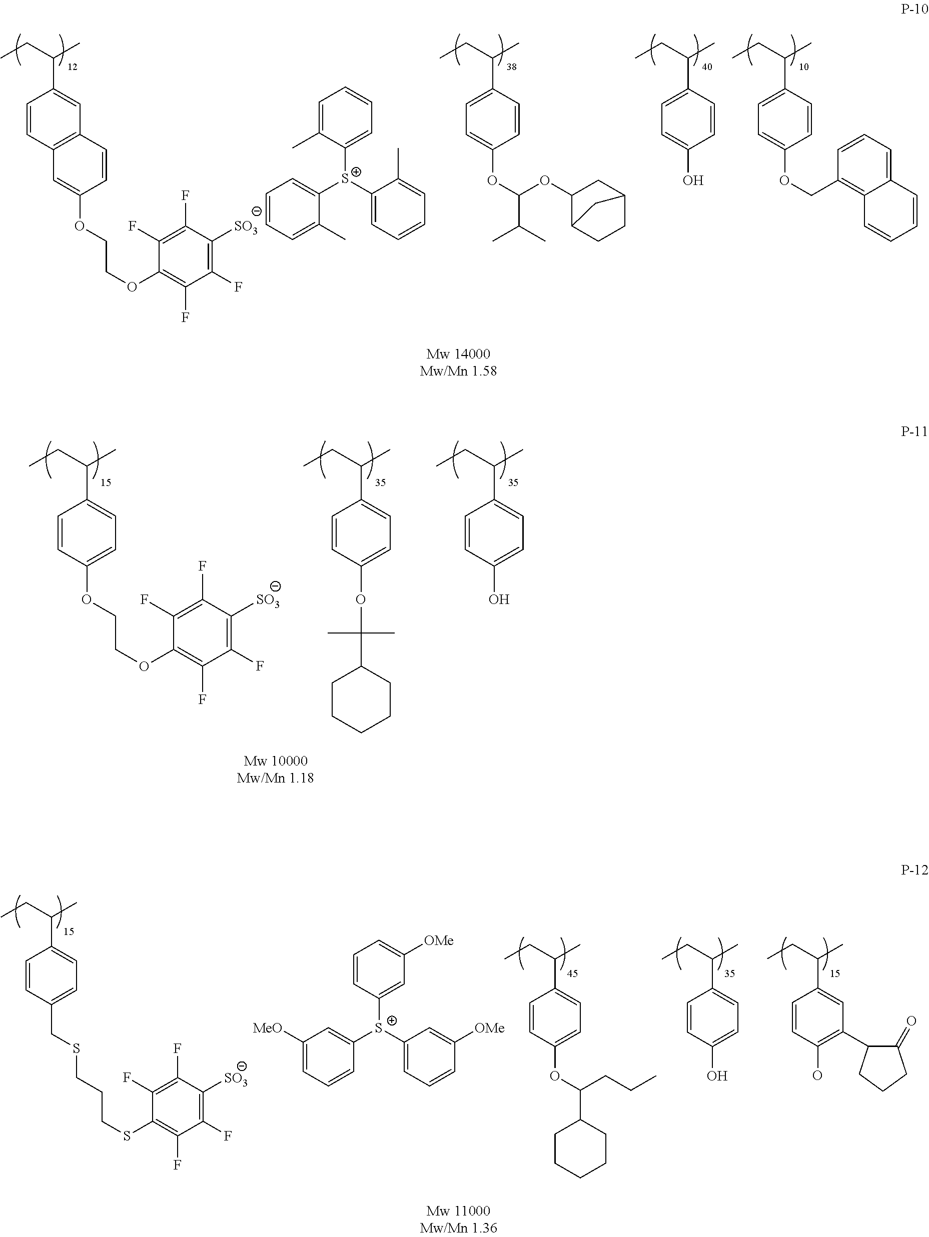

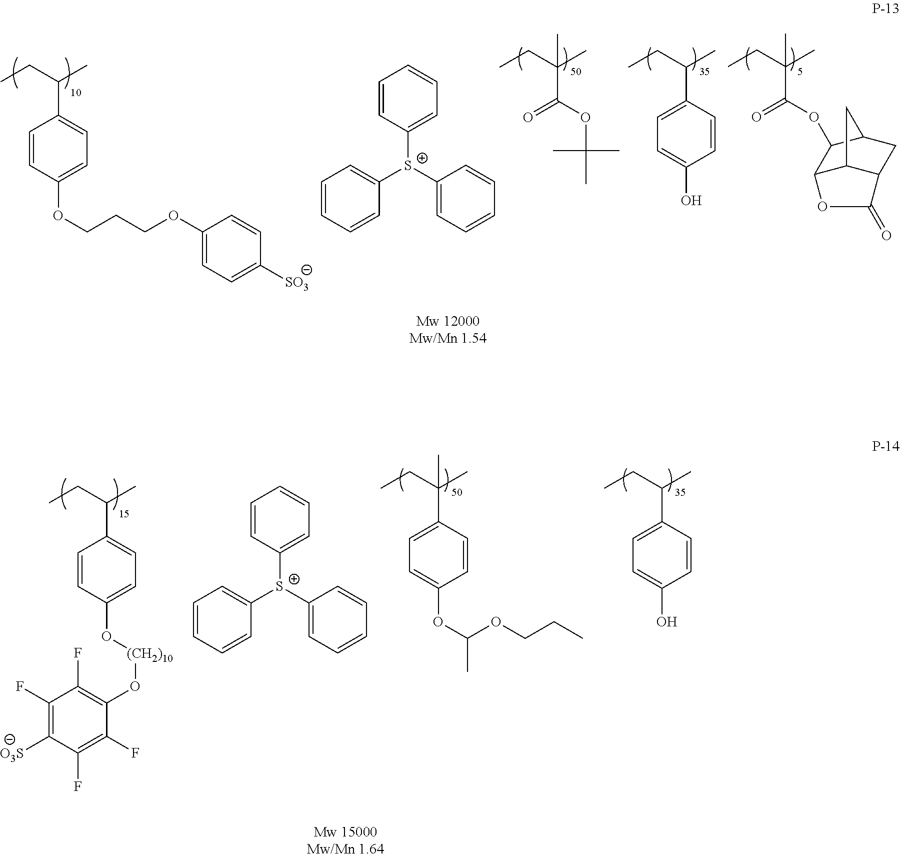

Other resins, photo-acid generators, basic compounds, surfactants, solvents and hydrophobic resins (HR) used in the Examples and Comparative Examples were shown below.

### [Resin]

The structure, composition ratio (molar ratio), weight average molecular weight and polydispersity of each resin were shown below.

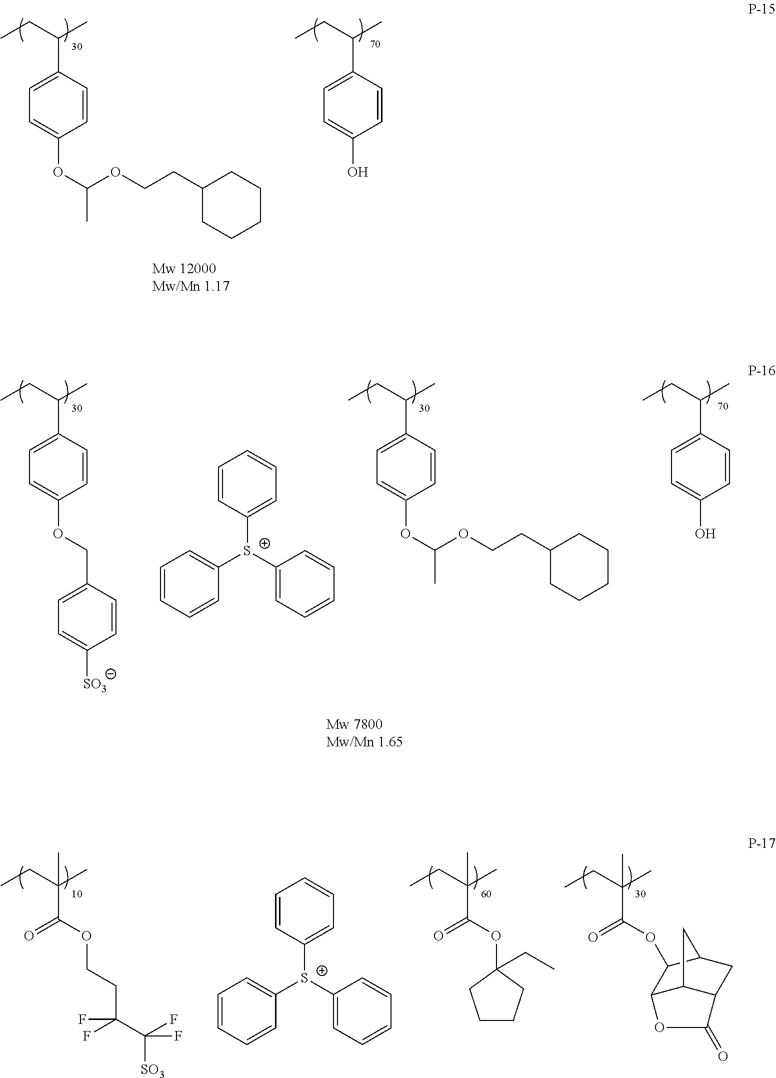

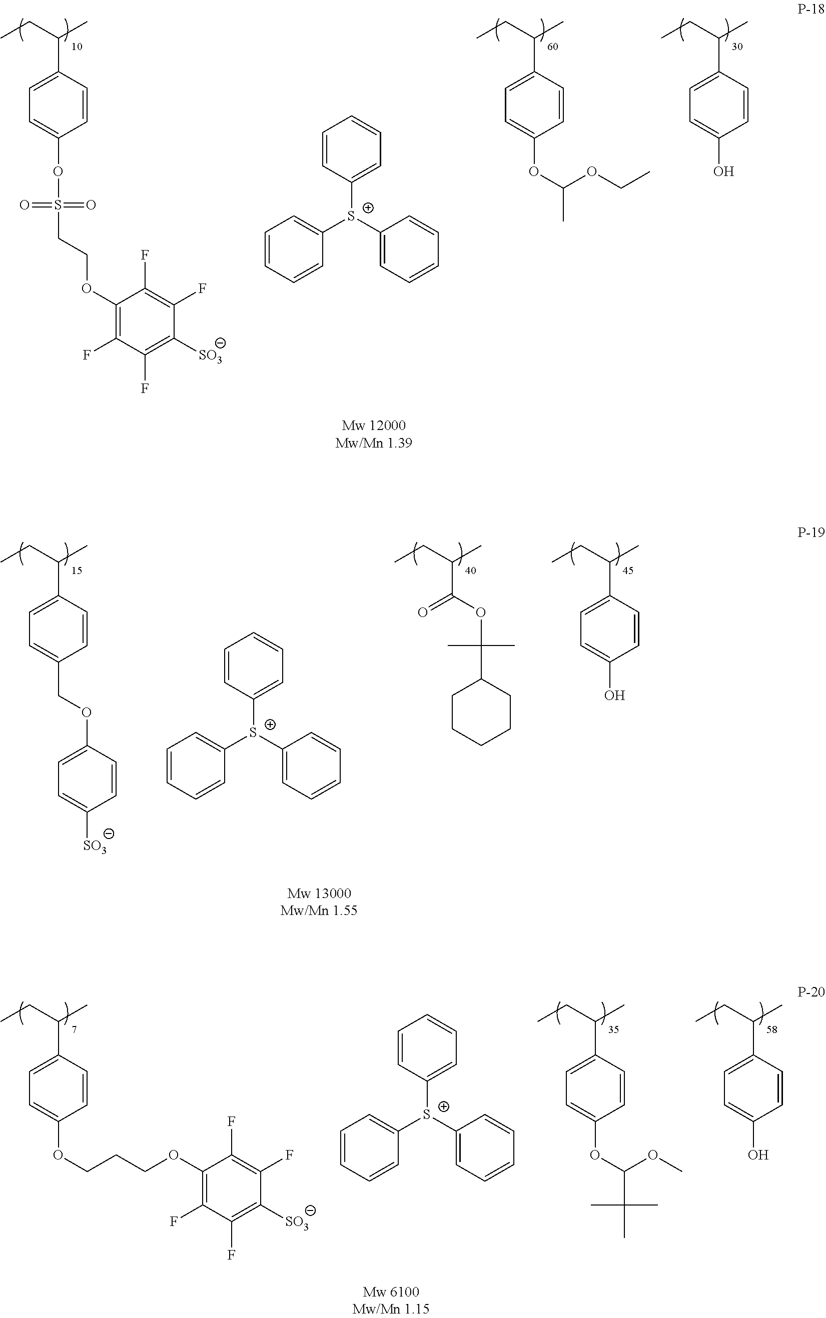

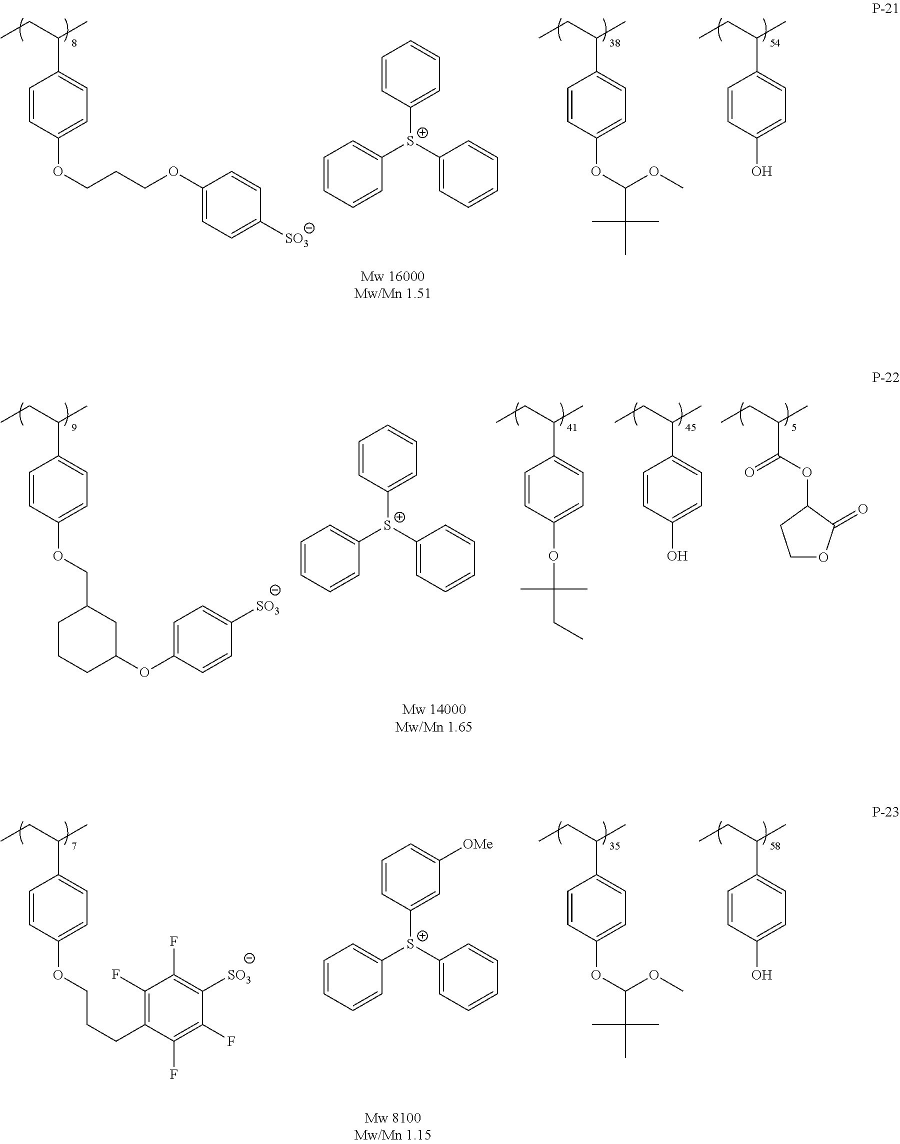

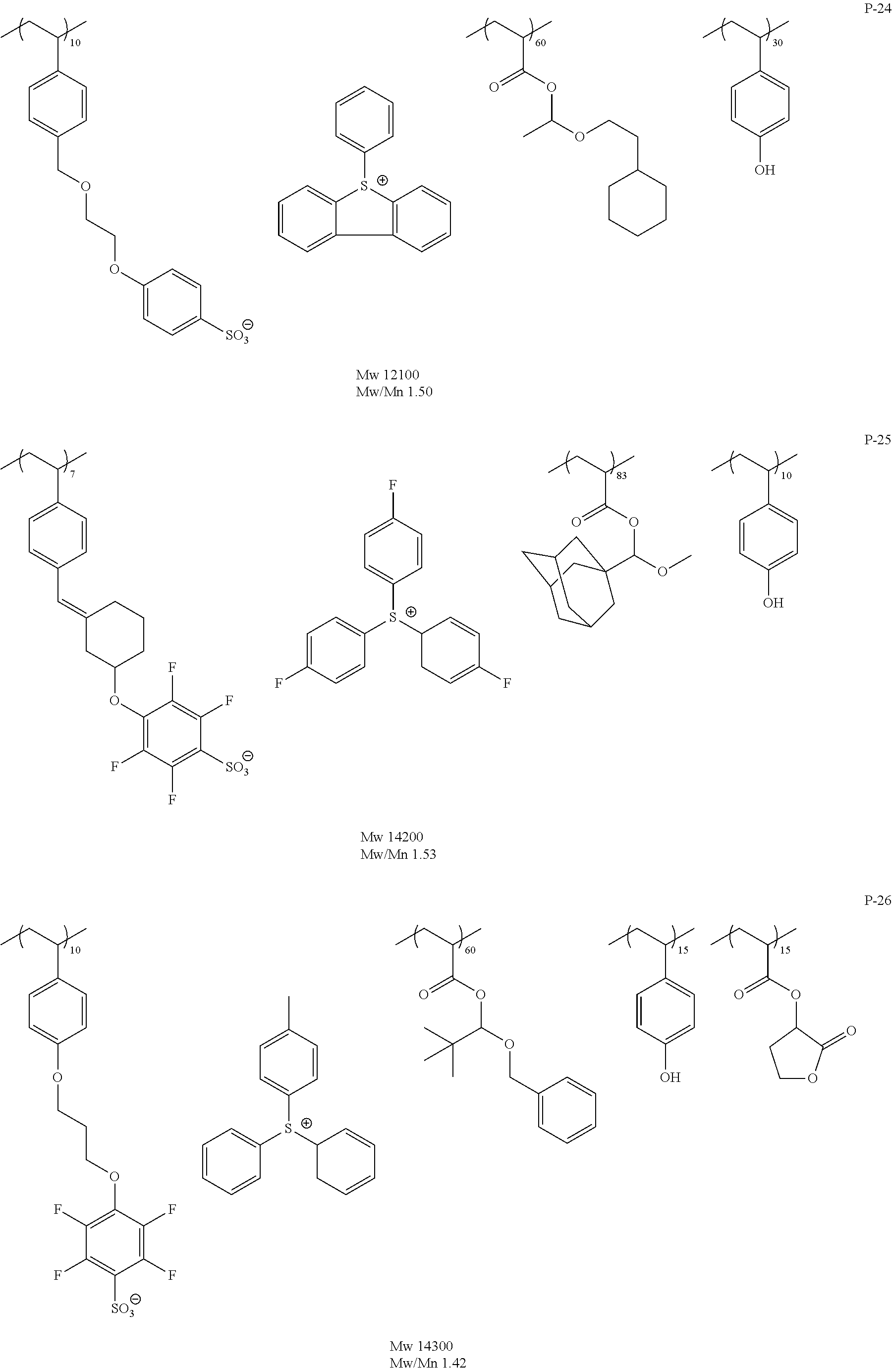

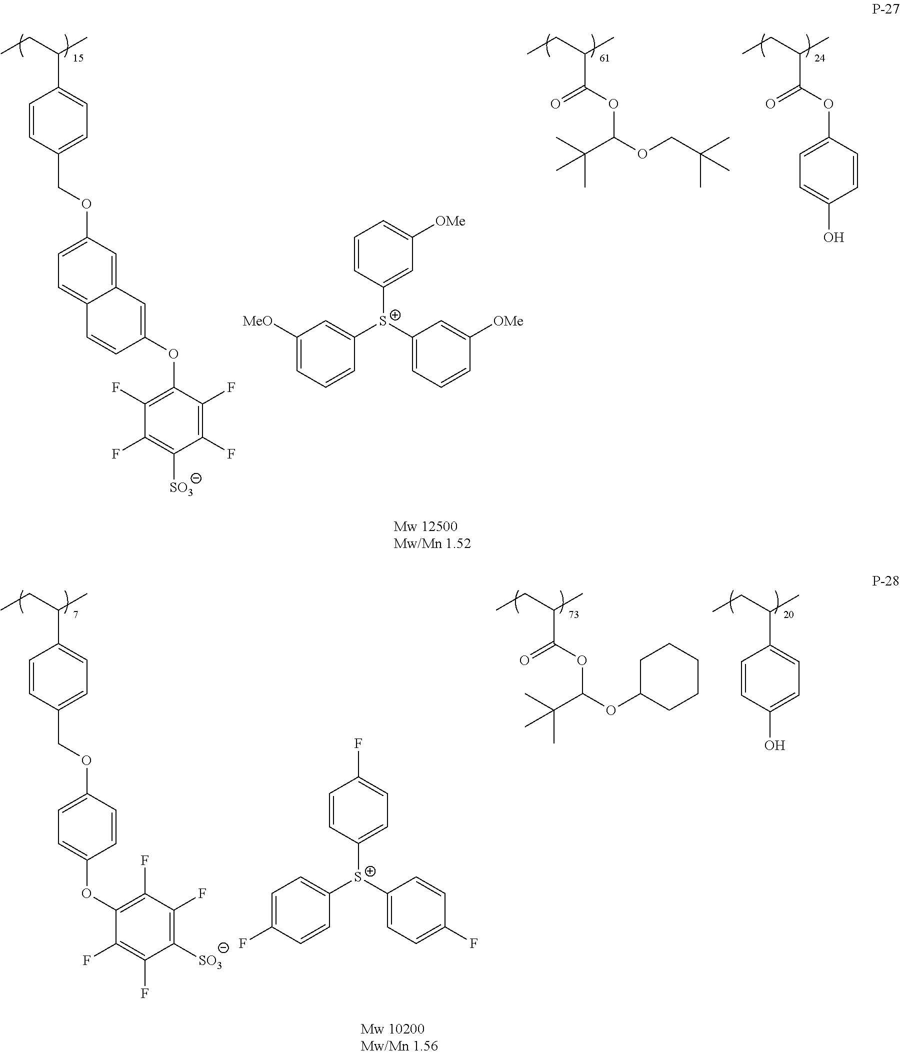

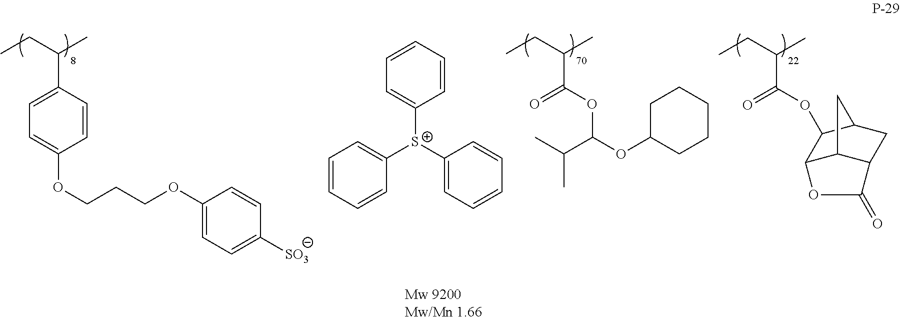

### [Photo Acid Generator]

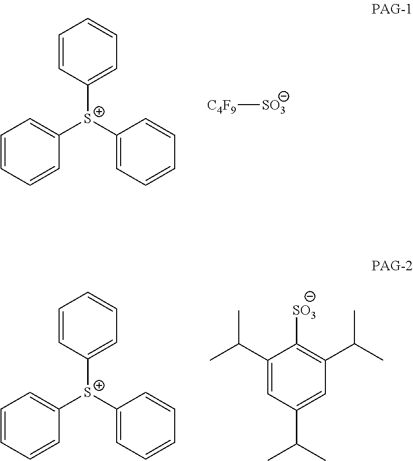

### [Basic Compound]

TBAH: Tetrabutylammonium hydroxide

### TOA: Tri(n-octyl)amine

### TPI: 2,4,5-Triphenylimidazole

TBAB: Tetrabutylammonium benzoate

### [Surfactant]

W-1: Megaface F176 (fluorine surfactant, manufactured by DIC Corporation)
W-2: Megaface R08 (fluorine/silicon surfactant, manufactured by DIC Corporation)
W-3: Polysiloxane polymer KP-341 (silicon surfactant, manufactured by Shin-Etsu Chemical Co., Ltd.)
W-4: PF6320 (fluorine surfactant, manufactured by OMNOVA Solutions Inc.)

### [Solvent]

S1: Polypropylene glycol monomethyl ether acetate (PGMEA, 1-methoxy-2-acetoxypropane)
S2: Polypropylene glycol monomethyl ether (PGME, 1-methoxy-2-propanol)

### S3: Cyclohexanone

### S4: γ-Butyrolactone

### [Hydrophobic Resin (HR)]

The structure, composition ratio (molar ratio), weight average molecular weight and polydispersity of the hydrophobic resins (HR) were shown below.

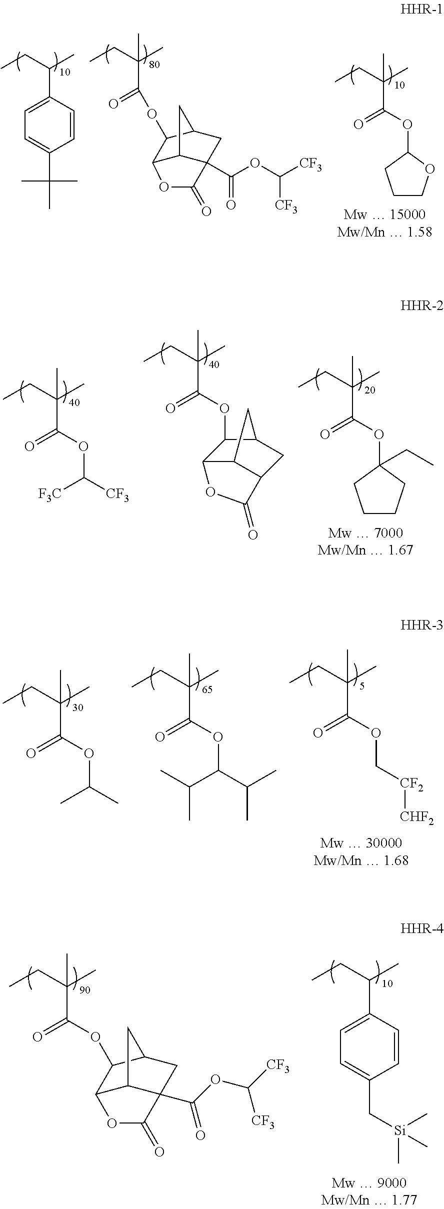

### [Developer, Rinsing Solution]

G-1: Butyl acetate

### G-2: 2-Heptanone

### G-3: Anisole

G-4: 4-Methyl-2-pentanol

### G-5: 1-Hexanol

### G-6: Decane

### <Evaluation of Resist>

An actinic ray-sensitive or radiation-sensitive resin composition (a resist composition) was prepared by dissolving each component shown in the following Tables 2 to 5 in a solvent to prepare each solution having solid content concentration of 4.0% by mass, and the prepared solution was filtered through a polytetrafluoroethylene filter having a pore size of 0.10 μm. The actinic ray-sensitive or radiation-sensitive resin composition was evaluated by the following method, and the results obtained were shown in Tables 2 to 5.

As for each component, the ratio in the case of using a plurality of components was shown in a mass ratio.

### Exposure Condition 1: EB (Electron Beam) Exposure/Alkali Development

### Examples 1 to 17 and 29 to 47, and Comparative Examples 1 to 5

The prepared actinic ray-sensitive or radiation-sensitive resin composition was uniformly coated by a spin coater on a silicon substrate having been subjected to hexamethyldisilazane treatment, and then subjected to heat-drying on a hot plate at 120° C. for 90 sec to thereby obtain an actinic ray-sensitive or radiation-sensitive film (a resist film) having a thickness of 50 nm. The actinic ray-sensitive or radiation-sensitive film was irradiated with an electron beam by using an electron beam irradiating apparatus (HL750, manufactured by Hitachi, Ltd., accelerating voltage: 50 keV). Immediately after irradiation, the film was heated at 110° C. for 90 sec on a hot plate. Further, the film was developed with a tetramethylammonium hydroxide aqueous solution having concentration of 2.38% by mass at 23° C. for 60 sec, rinsed with pure water for 30 sec, and spin dried to obtain a resist pattern.

### Exposure Condition 2: EUV (Extreme Ultraviolet Ray) Exposure/Alkali Development

### Examples 18 to 28 and 48 to 60, and Comparative Examples 6 to 8

The prepared actinic ray-sensitive or radiation-sensitive resin composition was uniformly coated by a spin coater on a silicon substrate having been subjected to hexamethyldisilazane treatment, and then subjected to heat-drying on a hot plate at 120° C. for 90 sec to form an actinic ray-sensitive or radiation-sensitive film (a resist film) having a thickness of 50 nm. The actinic ray-sensitive or radiation-sensitive film was subjected to exposure by an EUV exposure apparatus (Micro Exposure Tool, NA 0.3, Quadrupole, outer sigma 0.68, inner sigma 0.36, manufactured by Exitech) through a reflection type mask of a 1/1 line and space pattern of a line width of 50 nm. Immediately after exposure, the film was heated at 110° C. for 90 sec on a hot plate. Further, the film was developed with a tetramethylammonium hydroxide aqueous solution having concentration of 2.38% by mass at 23° C. for 60 sec, rinsed with pure water for 30 sec, and spin dried to obtain a resist pattern.

### Exposure Condition 3: EB (Electron Beam) Exposure/Organic Solvent Development

### Examples 61 to 76, and Comparative Examples 9 to 13

The prepared actinic ray-sensitive or radiation-sensitive resin composition was uniformly coated by a spin coater on a silicon substrate having been subjected to hexamethyldisilazane treatment, and then subjected to heat-drying on a hot plate at 120° C. for 90 sec to form an actinic ray-sensitive or radiation-sensitive film (a resist film) having a thickness of 50 nm. The actinic ray-sensitive or radiation-sensitive film was irradiated with an electron beam by using an electron beam irradiating apparatus (HL750, manufactured by Hitachi, Ltd., accelerating voltage: 50 keV). Immediately after irradiation, the film was heated at 110° C. for 90 sec on a hot plate. Further, the film was developed with the developer shown in Table 4 at 23° C. for 60 sec, rinsed with the rising solution shown in Table 4 (rinsing is not performed in the case of description of “None”) for 30 sec, and spin dried to obtain a resist pattern.

### Exposure Condition 4: EUV (Extreme Ultraviolet Ray) Exposure/Organic Solvent Development

### Examples 77 to 90, and Comparative Examples 14 to 18

The prepared actinic ray-sensitive or radiation-sensitive resin composition was uniformly coated by a spin coater on a silicon substrate having been subjected to hexamethyldisilazane treatment, and then subjected to heat-drying on a hot plate at 120° C. for 90 sec to form an actinic ray-sensitive or radiation-sensitive film (a resist film) having a thickness of 50 nm. The actinic ray-sensitive or radiation-sensitive film was subjected to exposure by an EUV exposure apparatus (Micro Exposure Tool, NA 0.3, Quadrupole, outer sigma 0.68, inner sigma 0.36, manufactured by Exitech) through a reflection type mask of a 1/1 line and space pattern of a line width of 50 nm. Immediately after exposure, the film was heated at 110° C. for 90 sec on a hot plate. Further, the film was developed with the developer shown in Table 5 at 23° C. for 60 sec, rinsed with the rising solution shown in Table 5 (rinsing is not performed in the case of description of “None”) for 30 sec, and spin dried to obtain a resist pattern.

### (Evaluation of Sensitivity)

The sectional form of the obtained pattern was observed with a scanning electron microscope (S-9220, manufactured by Hitachi, Ltd.). The minimum quantity of exposure of EB or EUV ray at the time of resolving the 1/1 line and space pattern of a line width of 50 nm was taken as sensitivity.

### (Evaluation of Resolution)

The critical resolution at the quantity of exposure showing the above sensitivity (the minimum line width capable of decomposing and resolving the line and space) was taken as resolution.

### (Evaluation of Pattern Profile)

The sectional form of the 1/1 line and space pattern of a line width of 50 nm at the quantity of exposure showing the above sensitivity was observed with a scanning electron microscope (S-4300, manufactured by Hitachi, Ltd.). Evaluation is performed by four grades of rectangle, a little taper, taper, and reverse taper.

### (Evaluation of Line Edge Roughness (LER))

As for optional 30 points at 50 μm in the longitudinal direction of the 1/1 line and space pattern of a line width of 50 nm at the quantity of exposure showing the above sensitivity, the distance from the baseline where the edge has to be located was measured with a scanning electron microscope (S-9220, manufactured by Hitachi, Ltd.). The standard deviations of the distances were found and 3σ was computed. The smaller the value, the better is the performance.

### (Evaluation of Pattern Collapse)

The sectional form of the 1/1 line and space pattern of a line width of 50 nm at the quantity of exposure showing the above sensitivity was observed with a scanning electron microscope (S-4300, manufactured by Hitachi, Ltd.), and evaluation was performed by two grades of whether the pattern collapses or not. Grade A: not collapses, and grade B: collapses.

### (Outgas Performance: Coefficient of Variation of Film Thickness by Exposure)

Each resist film was exposed overall with electron beam or extreme ultraviolet ray by the quantity of exposure of 2.0 times the quantity of exposure giving the above sensitivity, and the film thickness after exposure and before heating was measured. The coefficient of variation from the film thickness at unexposed time was found by the following equation.

Coefficient of variation of film thickness (%)=[(film thickness at unexposed time−film thickness after exposure)/film thickness at unexposed time]×100

The smaller the value of the coefficient of variation of film thickness, the better is the performance.

The results of measurements are shown in the following Tables 2 to 5. In Tables 2 to 5, the concentration of each component means “% by mass” based on all the solid content.

TABLE 2
Results of evaluations of EB exposure/alkali development

| | | | | | Acid | | | | | |
|---|---|---|---|---|---|---|---|---|---|---|
| | | Concen- | | Concen- | Generator | Concen- | | Concen- | | |
| Example | | tration | Other | tration | for Use in | tration | Basic | tration | Organic | Mass |
| No. | Resin | (wt %) | Resin | (wt %) | Combination | (wt %) | Compound. | (wt %) | Solvent | Ratio |
| Example 1 | P-1 | 97.95 | None | | None | | TPI | 2 | S1/S2 | 40/60 |
| Example 2 | P-1 | 97.95 | None | | None | | TBAH | 2 | S1/S2 | 40/60 |
| Example 3 | P-2 | 97.95 | None | | None | | TPI | 2 | S1/S2 | 40/60 |
| Example 4 | P-2 | 95.95 | None | | PAG-1 | 1 | TPI | 3 | S1/S2 | 40/60 |
| Example 5 | P-3 | 97.95 | None | | None | | TBAH | 2 | S1/S2 | 40/60 |
| Example 6 | P-4 | 98.5 | None | | None | | TPI | 1.5 | S1/S2/S3 | 30/60/10 |
| Example 7 | P-5 | 97.95 | None | | None | | TPI | 2 | S1/S2 | 40/60 |
| Example 8 | P-5 | 97.95 | None | | None | | TBAH | 2 | S1/S2 | 40/60 |
| Example 9 | P-6 | 87.95 | P-15 | 10 | None | | TBAH | 2 | S1/S2 | 40/60 |
| Example 10 | P-7 | 96.95 | None | | None | | TOA | 3 | S2/S4 | 40/60 |
| Example 11 | P-8 | 97.95 | None | | None | | TBAH | 2 | S1/S2 | 40/60 |
| Example 12 | P-9 | 97.95 | None | | None | | TBAH | 2 | S1/S2 | 40/60 |
| Example 13 | P-10 | 95.95 | None | | None | | TBAH | 4 | S1/S2 | 40/60 |
| Example 14 | P-11 | 95.95 | None | | None | | TPI | 4 | S1/S2 | 40/60 |
| Example 15 | P-12 | 97.95 | None | | None | | TOA | 2 | S1/S2 | 40/60 |
| Example 16 | P-13 | 97.95 | None | | None | | TBAH | 2 | S1/S2 | 40/60 |
| Example 17 | P-14 | 97.95 | None | | None | | TPI | 2 | S1/S2 | 40/60 |
| Comparative | P-15 | 77.95 | None | | PAG-2 | 20 | TBAH | 2 | S1/S2 | 40/60 |
| Example 1 | | | | | | | | | | |
| Comparative | P-16 | 97.95 | None | | None | | TBAH | 2 | S1/S2 | 40/60 |
| Example 2 | | | | | | | | | | |
| Comparative | P-17 | 97.95 | None | | None | | TBAH | 2 | S1/S2 | 40/60 |
| Example 3 | | | | | | | | | | |
| Comparative | P-18 | 97.95 | None | | None | | TBAH | 2 | S1/S2 | 40/60 |
| Example 4 | | | | | | | | | | |
| Comparative | P-19 | 97.95 | None | | None | | TPI | 2 | S1/S2 | 40/60 |
| Example 5 | | | | | | | | | | |
| | | | | Concentration | | | | | | |
| | | | Concen- | of All the | | | | | | |
| | Example | | tration | Solid Content | Sensitivity | Resolution | Pattern | LER | | Outgas |
| | No. | Surfactant | (wt %) | (wt %) | (μC/cm²) | (nm) | Profile | (nm) | Collapse | Performance |
| | Example 1 | W-1 | 0.05 | 4.0 | 28.5 | 35 | Rectangle | 5.5 | A | 1.5 |
| | Example 2 | W-2 | 0.05 | 4.0 | 28.3 | 40 | Rectangle | 5.6 | A | 1.5 |
| | Example 3 | W-1 | 0.05 | 4.0 | 28.6 | 40 | Rectangle | 5.1 | A | 3.8 |
| | Example 4 | W-1 | 0.05 | 4.0 | 29.5 | 42 | Rectangle | 5.3 | A | 3.2 |
| | Example 5 | W-2 | 0.05 | 4.0 | 31.2 | 41 | Rectangle | 6.0 | A | 4.3 |
| | Example 6 | None | | 4.0 | 32.5 | 40 | Rectangle | 5.9 | A | 4.0 |
| | Example 7 | W-1 | 0.05 | 4.0 | 28.1 | 38 | Rectangle | 5.5 | A | 1.6 |
| | Example 8 | W-1 | 0.05 | 4.0 | 27.6 | 32 | Rectangle | 5.3 | A | 1.2 |
| | Example 9 | W-2 | 0.05 | 4.0 | 27.4 | 34 | Rectangle | 5.2 | A | 1.9 |
| | Example 10 | W-4 | 0.05 | 4.0 | 28.3 | 38 | Rectangle | 5.1 | A | 3.4 |
| | Example 11 | W-2 | 0.05 | 4.0 | 27.0 | 34 | Rectangle | 5.9 | A | 2.8 |
| | Example 12 | W-1/W-2 | 0.05 | 4.0 | 33.3 | 41 | Rectangle | 6.0 | A | 1.8 |
| | | (mass ratio | | | | | | | | |
| | | 1/1) | | | | | | | | |
| | Example 13 | W-3 | 0.05 | 4.0 | 28.9 | 39 | Rectangle | 5.3 | A | 1.4 |
| | Example 14 | W-1 | 0.05 | 4.0 | 33.0 | 41 | Rectangle | 5.2 | A | 1.6 |
| | Example 15 | W-1 | 0.05 | 4.0 | 31.2 | 42 | Rectangle | 5.4 | A | 1.7 |
| | Example 16 | W-1 | 0.05 | 4.0 | 32.0 | 44 | Rectangle | 6.0 | A | 1.4 |
| | Example 17 | W-1 | 0.05 | 4.0 | 30.5 | 43 | Rectangle | 6.2 | A | 1.5 |
| | Comparative | W-1 | 0.05 | 4.0 | 35.8 | 50 | Taper | 8.0 | A | 8.5 |
| | Example 1 | | | | | | | | | |
| | Comparative | W-1 | 0.05 | 4.0 | 35.5 | 50 | Rectangle | 7.0 | B | 4.5 |
| | Example 2 | | | | | | | | | |
| | Comparative | W-1 | 0.05 | 4.0 | 45.8 | 48 | Rectangle | 7.1 | B | 4.5 |
| | Example 3 | | | | | | | | | |
| | Comparative | W-1 | 0.05 | 4.0 | 35.5 | 48 | A little | 7.0 | B | 5.5 |
| | Example 4 | | | | | | taper | | | |
| | Comparative | W-1 | 0.05 | 4.0 | 40.0 | 47 | Rectangle | 6.5 | B | 6.5 |
| | Example 5 | | | | | | | | | |
| | | | | | Acid | | | | | |
| | | Concen- | | Concen- | Generator | Concen- | | Concen- | | |
| Example | | tration | Hydrophobic | tration | for Use in | tration | Basic | tration | Organic | Mass |
| No. | Resin | (wt %) | Resin (HR) | (wt %) | Combination | (wt %) | Compound. | (wt %) | Solvent | Ratio |
| Example 29 | P-1 | 97.95 | None | | None | | TBAB | 2 | S1/S2 | 40/60 |
| Example 30 | P-1 | 92.95 | HHR-4 | 5 | None | | TBAH | 2 | S1/S2 | 40/60 |
| Example 31 | P-2 | 97.95 | None | | None | | TBAB | 2 | S1/S2 | 40/60 |
| Example 32 | P-2 | 93.95 | HHR-1 | 4 | None | | TBAH | 2 | S1/S2/S4 | 30/60/10 |
| Example 33 | P-6 | 95.95 | None | | None | | TBAB | 4 | S1/S2 | 40/60 |
| Example 34 | P-11 | 86.95 | HHR-3 | 10 | None | | TPI | 3 | S1/S2 | 40/60 |
| Example 35 | P-20 | 97.95 | None | | None | | TBAH | 2 | S1/S2 | 40/60 |
| Example 36 | P-20 | 93.5 | HHR-1 | 5 | None | | TPI | 1.5 | S1/S2 | 40/60 |
| Example 37 | P-20 | 97.95 | None | | None | | TBAB | 2 | S1/S2 | 40/60 |
| Example 38 | P-21 | 97.95 | None | | None | | TBAB | 2 | S1/S2 | 40/60 |
| Example 39 | P-21 | 97.95 | None | | None | | TBAH | 2 | S1/S2 | 40/60 |
| Example 40 | P-21 | 92.95 | HHR-4 | 5 | None | | TPI | 2 | S1/S2 | 40/60 |
| Example 41 | P-22 | 97.95 | None | | None | | TBAB | 2 | S1/S2 | 40/60 |
| Example 42 | P-22 | 96.95 | None | | None | | TOA | 3 | S2/S4 | 40/60 |
| Example 43 | P-22 | 94.95 | HHR-1 | 3 | None | | TPI | 2 | S1/S2 | 40/60 |
| Example 44 | P-23 | 97.95 | None | | None | | TBAH | 2 | S1/S2 | 40/60 |
| Example 45 | P-23 | 82.95 | HHR-2 | 10 | PAG-2 | 5 | TPI | 2 | S1/S2 | 40/60 |
| Example 46 | P-24 | 97.95 | None | | None | | TBAB | 2 | S1/S2 | 40/60 |
| Example 47 | P-26 | 89.95 | HHR-4 | 7 | None | | TBAH | 3 | S1/S2 | 40/60 |
| | | | | Concentration | | | | | | |
| | | | Concen- | of All the | | | | | | |
| | Example | | tration | Solid Content | Sensitivity | Resolution | Pattern | LER | | Outgas |
| | No. | Surfactant | (wt %) | (wt %) | (μC/cm²) | (nm) | Profile | (nm) | Collapse | Performance |
| | Example 29 | W-1 | 0.05 | 4.0 | 28.3 | 34 | Rectangle | 5.1 | A | 2.2 |
| | Example 30 | W-1 | 0.05 | 4.0 | 29.3 | 35 | Rectangle | 5.2 | A | 1.5 |
| | Example 31 | W-2 | 0.05 | 4.0 | 29.2 | 38 | Rectangle | 5.3 | A | 2.2 |
| | Example 32 | W-1 | 0.05 | 4.0 | 30.0 | 36 | Rectangle | 5.8 | A | 2.4 |
| | Example 33 | W-1 | 0.05 | 4.0 | 30.2 | 41 | Rectangle | 5.4 | A | 4.2 |
| | Example 34 | W-1 | 0.05 | 4.0 | 28.4 | 40 | Rectangle | 6.0 | A | 3.8 |
| | Example 35 | W-2 | 0.05 | 4.0 | 28.5 | 33 | Rectangle | 5.0 | A | 2.3 |
| | Example 36 | None | | 4.0 | 32.5 | 32 | Rectangle | 5.2 | A | 1.9 |
| | Example 37 | W-1 | 0.05 | 4.0 | 28.5 | 34 | Rectangle | 5.3 | A | 2.2 |
| | Example 38 | W-1 | 0.05 | 4.0 | 28.1 | 34 | Rectangle | 5.1 | A | 2.5 |
| | Example 39 | W-1 | 0.05 | 4.0 | 27.6 | 35 | Rectangle | 5.0 | A | 2.2 |
| | Example 40 | W-1 | 0.05 | 4.0 | 28.5 | 35 | Rectangle | 5.3 | A | 1.2 |
| | Example 41 | W-2 | 0.05 | 4.0 | 28.5 | 39 | Rectangle | 5.5 | A | 3.3 |
| | Example 42 | W-4 | 0.05 | 4.0 | 27.9 | 38 | Rectangle | 5.4 | A | 3.4 |
| | Example 43 | W-1 | 0.05 | 4.0 | 28.5 | 40 | Rectangle | 5.8 | A | 2.5 |
| | Example 44 | W-2 | 0.05 | 4.0 | 27.0 | 38 | Rectangle | 5.9 | A | 1.8 |
| | Example 45 | W-1 | 0.05 | 4.0 | 28.5 | 37 | Rectangle | 5.7 | A | 1.5 |
| | Example 46 | W-1 | 0.05 | 4.0 | 27.0 | 41 | Rectangle | 6.1 | A | 3.9 |
| | Example 47 | W-2 | 0.05 | 4.0 | 30.5 | 35 | Rectangle | 6.2 | A | 4.2 |

The concentration of each component shows the concentration (% by mass) in concentration of the entire solid content.

TABLE 3
Results of evaluations of EUV exposure/alkali development

| | | | | | Acid | | | | | |
|---|---|---|---|---|---|---|---|---|---|---|
| | Resin | Concen- | | Concen- | Generator | Concen- | | Concen- | | |
| Example | of the | tration | Other | tration | for Use in | tration | Basic | tration | Organic | Mass |
| No. | Invention | (wt %) | Resin | (wt %) | Combination | (wt %) | Compound | (wt %) | Solvent | Ratio |
| Example 18 | P-1 | 97.95 | None | | None | | TPI | 2 | S1/S2 | 40/60 |
| Example 19 | P-2 | 97.95 | None | | None | | TPI | 2 | S1/S2 | 40/60 |
| Example 20 | P-3 | 97.95 | None | | None | | TBAH | 2 | S1/S2 | 40/60 |
| Example 21 | P-5 | 97.95 | None | | None | | TPI | 2 | S1/S2 | 40/60 |
| Example 22 | P-6 | 87.95 | P-15 | 10 | None | | TBAH | 2 | S1/S2 | 40/60 |
| Example 23 | P-7 | 97.95 | None | | None | | TOA | 2 | S1/S2 | 40/60 |
| Example 24 | P-8 | 95.95 | None | | None | | TBAH | 4 | S1/S2 | 40/60 |
| Example 25 | P-9 | 97.95 | None | | None | | TBAH | 2 | S1/S2 | 40/60 |
| Example 26 | P-10 | 95.95 | None | | None | | TBAH | 4 | S1/S2 | 40/60 |
| Example 27 | P-11 | 95.95 | None | | None | | TPI | 4 | S1/S2 | 40/60 |
| Example 28 | P-12 | 95.95 | None | | None | | TBAH | 4 | S1/S2 | 40/60 |
| Comparative | P-15 | 77.95 | None | | PAG-2 | 20 | TBAH | 2 | S1/S2 | 40/60 |
| Example 6 | | | | | | | | | | |
| Comparative | P-16 | 97.95 | None | | None | | TBAH | 2 | S1/S2 | 40/60 |
| Example 7 | | | | | | | | | | |
| Comparative | P-17 | 97.95 | None | | None | | TBAH | 2 | S1/S2 | 40/60 |
| Example 8 | | | | | | | | | | |
| | | | | Concentration | | | | | | |
| | | | Concen- | of All the | | | | | | |
| | Example | | tration | Solid Content | Resolution | Sensitivity | LER | Pattern | | Outgas |
| | No. | Surfactant | (wt %) | (wt %) | (nm) | (mJ/cm²) | (nm) | Form | Collapse | Performance |
| | Example 18 | W-1 | 0.05 | 4.0 | 25 | 25.3 | 5.0 | Rectangle | A | 2.0 |
| | Example 19 | W-1 | 0.05 | 4.0 | 30 | 28.8 | 5.5 | Rectangle | A | 4.5 |
| | Example 20 | W-2 | 0.05 | 4.0 | 35 | 25.5 | 6.5 | Rectangle | A | 5.0 |
| | Example 21 | W-1 | 0.05 | 4.0 | 30 | 23.9 | 5.0 | Rectangle | A | 1.2 |
| | Example 22 | W-2 | 0.05 | 4.0 | 25 | 24.7 | 6.5 | Rectangle | A | 2.2 |
| | Example 23 | W-1 | 0.05 | 4.0 | 35 | 26.3 | 7.0 | Rectangle | A | 2.0 |
| | Example 24 | W-1 | 0.05 | 4.0 | 40 | 27.3 | 6.5 | Rectangle | A | 2.2 |
| | Example 25 | W-1 | 0.05 | 4.0 | 40 | 26.0 | 6.5 | Rectangle | A | 3.5 |
| | Example 26 | W-1 | 0.05 | 4.0 | 35 | 25.0 | 5.5 | Rectangle | A | 3.5 |
| | Example 27 | W-1 | 0.05 | 4.0 | 35 | 25.5 | 7.0 | Rectangle | A | 4.0 |
| | Example 28 | W-1 | 0.05 | 4.0 | 35 | 27.3 | 6.0 | Rectangle | A | 3.2 |
| | Comparative | W-1 | 0.05 | 4.0 | 50 | 30.0 | 8.0 | Taper | B | 9.0 |
| | Example 6 | | | | | | | | | |
| | Comparative | W-1 | 0.05 | 4.0 | 45 | 28.0 | 7.5 | Rectangle | A | 5.5 |
| | Example 7 | | | | | | | | | |
| | Comparative | W-1 | 0.05 | 4.0 | 45 | 40.0 | 7.5 | Rectangle | A | 6.6 |
| | Example 8 | | | | | | | | | |
| | | | | | Acid | | | | | |
| | Resin | Concen- | | Concen- | Generator | Concen- | | Concen- | | |
| Example | of the | tration | Hydrophobic | tration | for Use in | tration | Basic | tration | Organic | Mass |
| No. | Invention | (wt %) | Resin (HR) | (wt %) | Combination | (wt %) | Compound | (wt %) | Solvent | Ratio |
| Example 48 | P-1 | 97.95 | None | | None | | TBAB | 2 | S1/S2 | 40/60 |
| Example 49 | P-1 | 92.95 | HHR-4 | 5 | None | | TBAH | 2 | S1/S2 | 40/60 |
| Example 50 | P-2 | 97.95 | None | | None | | TBAH | 2 | S1/S2 | 40/60 |
| Example 51 | P-2 | 92.95 | HHR-1 | 5 | None | | TPI | 2 | S1/S2 | 40/60 |
| Example 52 | P-20 | 97.95 | None | | None | | TBAB | 2 | S1/S2 | 40/60 |
| Example 53 | P-20 | 94.95 | HHR-4 | 3 | None | | TBAB | 2 | S1/S2 | 40/60 |
| Example 54 | P-21 | 97.95 | None | | None | | TBAH | 2 | S1/S2 | 40/60 |
| Example 55 | P-21 | 92.95 | HHR-1 | 5 | None | | TBAH | 2 | S1/S2 | 40/60 |
| Example 56 | P-22 | 96.95 | None | | None | | TBAB | 3 | S1/S2 | 40/60 |
| Example 57 | P-22 | 93.95 | HHR-2 | 4 | None | | TBAH | 2 | S1/S2 | 40/60 |
| Example 58 | P-23 | 97.95 | None | | None | | TPI | 2 | S1/S2 | 40/60 |
| Example 59 | P-24 | 82.95 | HHR-3 | 3 | PAG-2 | 10 | TPI | 4 | S1/S2 | 40/60 |
| Example 60 | P-25 | 96.95 | None | | None | | TBAB | 3 | S1/S2 | 40/60 |
| | | | | Concentration | | | | | | |
| | | | Concen- | of All the | | | | | | |
| | Example | | tration | Solid Content | Resolution | Senstivity | LER | Pattern | | Outgas |
| | No. | Surfactant | (wt %) | (wt %) | (nm) | (mJ/cm²) | (nm) | Form | Collapse | Performance |
| | Example 48 | W-1 | 0.05 | 4.0 | 25 | 25.5 | 5.0 | Rectangle | A | 3.5 |
| | Example 49 | W-1 | 0.05 | 4.0 | 30 | 26.0 | 5.5 | Rectangle | A | 2.5 |
| | Example 50 | W-2 | 0.05 | 4.0 | 30 | 28.5 | 6.5 | Rectangle | A | 4.0 |
| | Example 51 | W-1 | 0.05 | 4.0 | 35 | 28.3 | 5.0 | Rectangle | A | 3.5 |
| | Example 52 | W-2 | 0.05 | 4.0 | 25 | 24.5 | 6.5 | Rectangle | A | 3.0 |
| | Example 53 | W-1 | 0.05 | 4.0 | 30 | 25.5 | 7.0 | Rectangle | A | 2.2 |
| | Example 54 | W-1 | 0.05 | 4.0 | 25 | 25.0 | 6.5 | Rectangle | A | 2.1 |
| | Example 55 | W-1 | 0.05 | 4.0 | 30 | 25.0 | 5.5 | Rectangle | A | 2.0 |
| | Example 56 | None | 0.05 | 4.0 | 35 | 24.5 | 6.0 | Rectangle | A | 3.5 |
| | Example 57 | W-1 | 0.05 | 4.0 | 35 | 25.5 | 8.0 | Rectangle | A | 3.3 |
| | Example 58 | W-1 | 0.05 | 4.0 | 35 | 25.3 | 8.0 | Rectangle | A | 1.5 |
| | Example 59 | W-1 | 0.05 | 4.0 | 40 | 27.0 | 7.5 | Rectangle | A | 4.5 |
| | Example 60 | W-1 | 0.05 | 4.0 | 35 | 27.5 | 7.5 | Rectangle | A | 4.8 |

The concentration of each component shows the concentration (% by mass) in concentration of the entire solid content.

TABLE 4
Results of evaluations of EB exposure/organic solvent development

| | | | Hydro- | | Acid | | | | | | |
|---|---|---|---|---|---|---|---|---|---|---|---|
| | | Concen- | phobic | Concen- | Generator | Concen- | | Concen- | | | |
| Example | | tration | Resin | tration | for Use in | tration | Basic | tration | Organic | Mass | |
| No. | Resin | (wt %) | (HR) | (wt %) | Combination | (wt %) | Compound | (wt %) | Solvent | Ratio | |
| Example 61 | P-1 | 97.95 | None | | None | | TBAH | 2 | S1/S2 | 40/60 | |
| Example 62 | P-1 | 87.95 | HHR-4 | 3 | PAG-2 | 5 | TBAH | 4 | S1/S2 | 40/60 | |
| Example 63 | P-2 | 97.95 | None | | None | | TBAB | 2 | S1/S2 | 40/60 | |
| Example 64 | P-3 | 97.95 | None | | None | | TBAB | 2 | S1/S2 | 40/60 | |
| Example 65 | P-3 | 91.95 | HHR-1 | 5 | None | | TPI | 3 | S1/S2 | 40/60 | |
| Example 66 | P-11 | 95.95 | None | | None | | TBAH | 4 | S1/S2 | 40/60 | |
| Example 67 | P-13 | 97.95 | None | | None | | TBAB | 2 | S1/S3 | 40/60 | |
| Example 68 | P-20 | 97.95 | None | | None | | TBAH | 2 | S1/S2 | 40/60 | |
| Example 69 | P-21 | 97.95 | None | | None | | TPI | 2 | S1/S2 | 40/60 | |
| Example 70 | P-22 | 87.95 | HHR-2 | 10 | None | | TBAB | 2 | S1/S2/S4 | 30/60/10 | |
| Example 71 | P-24 | 97.95 | None | | None | | TPI | 2 | S1/S2 | 40/60 | |
| Example 72 | P-25 | 97.95 | None | | None | | TBAB | 2 | S1/S2 | 40/60 | |
| Example 73 | P-26 | 97.95 | None | | None | | TBAH | 2 | S1/S2 | 40/60 | |
| Example 74 | P-27 | 90.95 | HHR-4 | 5 | None | | TPI | 4 | S1/S2 | 40/60 | |
| Example 75 | P-28 | 97.95 | None | | None | | TBAH | 2 | S1/S2 | 40/60 | |
| Example 76 | P-29 | 87.95 | HHR-4 | 5 | PAG-1 | 5 | TBAB | 2 | S1/S2 | 40/60 | |
| Comparative | P-15 | 77.95 | None | | PAG-2 | 20 | TBAH | 2 | S1/S2 | 40/60 | |
| Example 9 | | | | | | | | | | | |
| Comparative | P-16 | 97.95 | None | | None | | TBAH | 2 | S1/S2 | 40/60 | |
| Example 10 | | | | | | | | | | | |
| Comparative | P-17 | 97.95 | None | | None | | TPI | 2 | S1/S2 | 40/60 | |
| Example 11 | | | | | | | | | | | |
| Comparative | P-18 | 97.95 | None | | None | | TBAB | 2 | S1/S2 | 40/60 | |
| Example 12 | | | | | | | | | | | |
| Comparative | P-19 | 97.95 | None | | None | | TPI | 2 | S1/S2 | 40/60 | |
| Example 13 | | | | | | | | | | | |
| | | | Concen- | | | | | | | | |
| | | | tration | | | | | | | | |
| | | | of All the | | | | | | | | |
| | | Concen- | Solid | | | | | | | | |
| Example | | tration | Content | | Rinsing | Sensitivity | Resolution | Pattern | LER | | Outgas |
| No. | Surfactant | (wt %) | (wt %) | Developer | Solution | (μC/cm²) | (nm) | Profile | (nm) | Collapse | Performance |
| Example 61 | W-1 | 0.05 | 4.0 | G-1 | None | 38.0 | 34 | Rectangle | 6.1 | A | 3.5 |
| Example 62 | W-1 | 0.05 | 4.0 | G-1 | G-5 | 40.0 | 35 | Rectangle | 6.3 | A | 3.4 |
| Example 63 | W-2 | 0.05 | 4.0 | G-1 | G-5 | 37.0 | 38 | Rectangle | 6.8 | A | 3.9 |
| Example 64 | W-1 | 0.05 | 4.0 | G-1 | None | 38.5 | 41 | Rectangle | 6.4 | A | 4.3 |
| Example 65 | W-1 | 0.05 | 4.0 | G-1 | G-6 | 39.0 | 40 | Rectangle | 6.8 | A | 4.5 |
| Example 66 | W-2 | 0.05 | 4.0 | G-3 | None | 40.0 | 33 | Rectangle | 7.0 | A | 3.8 |
| Example 67 | W-1 | 0.05 | 4.0 | G-1 | None | 41.0 | 34 | Rectangle | 6.3 | A | 3.5 |
| Example 68 | W-1 | 0.05 | 4.0 | G-1 | G-5 | 38.0 | 35 | Rectangle | 6.5 | A | 2.2 |
| Example 69 | W-4 | 0.05 | 4.0 | G-1 | None | 37.0 | 35 | Rectangle | 7.0 | A | 3.0 |
| Example 70 | W-2 | 0.05 | 4.0 | G-1 | None | 28.5 | 39 | Rectangle | 7.5 | A | 4.5 |
| Example 71 | W-1 | 0.05 | 4.0 | G-1 | None | 27.5 | 40 | Rectangle | 6.8 | A | 4.2 |
| Example 72 | W-1 | 0.05 | 4.0 | G-2 | G-5 | 33.0 | 33 | Rectangle | 6.8 | A | 4.2 |
| Example 73 | W-2 | 0.05 | 4.0 | G-1 | G-5 | 35.0 | 35 | Rectangle | 6.4 | A | 3.1 |
| Example 74 | W-3 | 0.05 | 4.0 | G-4 | G-5 | 36.5 | 37 | Rectangle | 6.9 | A | 2.5 |
| Example 75 | W-2 | 0.05 | 4.0 | G-1 | None | 35.0 | 38 | Rectangle | 6.4 | A | 3.1 |
| Example 76 | W-2 | 0.05 | 4.0 | G-1 | None | 33.5 | 40 | Rectangle | 6.4 | A | 3.1 |
| Comparative | W-1 | 0.05 | 4.0 | G-1 | G-6 | 51.0 | 50 | taper. | 8.0 | B | 8.5 |
| Example 9 | | | | | | | | | | | |
| Comparative | W-2 | 0.05 | 4.0 | G-1 | None | 45.0 | 45 | Rectangle | 8.5 | B | 5.5 |
| Example 10 | | | | | | | | | | | |
| Comparative | W-1 | 0.05 | 4.0 | G-1 | None | 46.5 | 50 | Rectangle | 8.3 | B | 4.8 |
| Example 11 | | | | | | | | | | | |
| Comparative | W-3 | 0.05 | 4.0 | G-1 | G-5 | 48.0 | 45 | Reverse | 8.2 | B | 3.8 |
| Example 12 | | | | | | | | taper. | | | |
| Comparative | W-1 | 0.05 | 4.0 | G-1 | None | 52.0 | 45 | Rectangle | 8.5 | B | 4.9 |
| Example 13 | | | | | | | | | | | |

The concentration of each component shows the concentration (% by mass) in concentration of the entire solid content.

TABLE 5
Results of evaluations of EUV exposure/organic solvent development

| | | | Hydro- | | Acid | | | | | | |
|---|---|---|---|---|---|---|---|---|---|---|---|
| | | Concen- | phobic | Concen- | Generator | Concen- | | Concen- | | | |
| Example | | tration | Resin | tration | for Use in | tration | Basic | tration | Organic | Mass | |
| No. | Resin | (wt %) | (HR) | (wt %) | Combination | (wt %) | Compound | (wt %) | Solvent | Ratio | |
| Example 77 | P-1 | 97.95 | None | | None | | TBAH | 2 | S1/S2 | 40/60 | |
| Example 78 | P-2 | 87.95 | HHR-4 | 3 | PAG-2 | 5 | TBAH | 4 | S1/S2 | 40/60 | |
| Example 79 | P-3 | 97.95 | None | | None | | TBAB | 2 | S1/S2 | 40/60 | |
| Example 80 | P-11 | 97.95 | None | | None | | TBAB | 2 | S1/S2 | 40/60 | |
| Example 81 | P-13 | 91.95 | HHR-1 | 5 | None | | TPI | 3 | S1/S2 | 40/60 | |
| Example 82 | P-20 | 95.95 | None | | None | | TBAH | 4 | S1/S2 | 40/60 | |
| Example 83 | P-21 | 97.95 | None | | None | | TBAB | 2 | S1/S3 | 40/60 | |
| Example 84 | P-22 | 97.95 | None | | None | | TBAH | 2 | S1/S2 | 40/60 | |
| Example 85 | P-24 | 97.95 | None | | None | | TBAH | 2 | S1/S2 | 40/60 | |
| Example 86 | P-25 | 87.95 | HHR-2 | 10 | None | | TBAB | 2 | S1/S2/S4 | 30/60/10 | |
| Example 87 | P-26 | 97.95 | None | | None | | TPI | 2 | S1/S2 | 40/60 | |
| Example 88 | P-27 | 97.95 | None | | None | | TBAH | 2 | S1/S2 | 40/60 | |
| Example 89 | P-28 | 92.95 | HHR-4 | 5 | None | | TPI | 2 | S1/S2 | 40/60 | |
| Example 90 | P-29 | 94.95 | HHR-3 | 3 | None | | TBAB | 2 | S1/S2 | 40/60 | |
| Comparative | P-15 | 77.95 | None | | PAG-2 | 20 | TBAH | 2 | S1/S2 | 40/60 | |
| Example 14 | | | | | | | | | | | |
| Comparative | P-16 | 97.95 | None | | None | | TBAH | 2 | S1/S2 | 40/60 | |
| Example 15 | | | | | | | | | | | |
| Comparative | P-17 | 97.95 | None | | None | | TPI | 2 | S1/S2 | 40/60 | |
| Example 16 | | | | | | | | | | | |
| Comparative. | P-18 | 97.95 | None | | None | | TBAB | 2 | S1/S2 | 40/60 | |
| Example 17 | | | | | | | | | | | |
| Comparative | P-19 | 97.95 | None | | None | | TPI | 2 | S1/S2 | 40/60 | |
| Example 18 | | | | | | | | | | | |
| | | | Concen- | | | | | | | | |
| | | | tration | | | | | | | | |
| | | | of All the | | | | | | | | |
| | | Concen- | Solid | | | | | | | | |
| Example | | tration | Content | | Rinsing | Sensitivity | Resolution | Pattern | LER | | Outgas |
| No. | Surfactant | (wt %) | (wt %) | Developer | Solution | (μC/cm²) | (nm) | Profile | (nm) | Collapse | Performance |
| Example 77 | W-1 | 0.05 | 4.0 | G-1 | None | 55.0 | 38 | Rectangle | 6.2 | A | 2.8 |
| Example 78 | W-1 | 0.05 | 4.0 | G-1 | None | 50.0 | 34 | Rectangle | 6.4 | A | 3.3 |
| Example 79 | W-2 | 0.05 | 4.0 | G-1 | G-6 | 48.0 | 35 | Rectangle | 6.9 | A | 2.8 |
| Example 80 | W-1 | 0.05 | 4.0 | G-1 | None | 52.0 | 40 | Rectangle | 6.0 | A | 2.7 |
| Example 81 | W-1 | 0.05 | 4.0 | G-4 | None | 55.0 | 38 | Rectangle | 6.8 | A | 4.5 |
| Example 82 | W-2 | 0.05 | 4.0 | G-1 | None | 58.0 | 34 | Rectangle | 5.9 | A | 4.4 |
| Example 83 | W-1 | 0.05 | 4.0 | G-1 | None | 57.0 | 35 | Rectangle | 6.2 | A | 3.3 |
| Example 84 | W-1 | 0.05 | 4.0 | G-1 | G-5 | 53.0 | 36 | Rectangle | 5.5 | A | 2.1 |
| Example 85 | W-4 | 0.05 | 4.0 | G-3 | None | 50.0 | 36 | Rectangle | 5.8 | A | 2.8 |
| Example 86 | W-2 | 0.05 | 4.0 | G-1 | None | 58.0 | 34 | Rectangle | 6.0 | A | 3.8 |
| Example 87 | W-1 | 0.05 | 4.0 | G-1 | None | 55.0 | 36 | Rectangle | 5.8 | A | 3.8 |
| Example 88 | W-2 | 0.05 | 4.0 | G-1 | G-5 | 52.0 | 35 | Rectangle | 5.9 | A | 3.5 |
| Example 89 | W-3 | 0.05 | 4.0 | G-2 | None | 54.0 | 33 | Rectangle | 6.5 | A | 3.9 |
| Example 90 | None | 0.05 | 4.0 | G-4 | G-5 | 55.0 | 39 | Rectangle | 7.0 | A | 4.0 |
| Comparative | W-1 | 0.05 | 4.0 | G-1 | None | 65.0 | 45 | Reverse | 8.2 | B | 7.8 |
| Example 14 | | | | | | | | taper | | | |
| Comparative | W-2 | 0.05 | 4.0 | G-1 | G-5 | 60.0 | 42 | Reverse | 8.5 | B | 4.5 |
| Example 15 | | | | | | | | taper | | | |
| Comparative | W-1 | 0.05 | 4.0 | G-2 | None | 58.0 | 46 | Reverse | 8.8 | B | 4.8 |
| Example 16 | | | | | | | | taper | | | |
| Comparative | W-3 | 0.05 | 4.0 | G-1 | None | 62.0 | 45 | Reverse | 8.2 | B | 4.8 |
| Example 17 | | | | | | | | taper | | | |
| Comparative | W-1 | 0.05 | 4.0 | G-1 | None | 60.0 | 43 | Reverse | 8.4 | B | 4.5 |
| Example 18 | | | | | | | | taper | | | |

The concentration of each component shows the concentration (% by mass) in concentration of the entire solid content.

From the results shown in the above Tables, it is clearly seen that the actinic ray-sensitive or radiation-sensitive resin compositions in Examples 1 to 17 and 29 to 47 realize, at the same time, high sensitivity, high resolution, a good pattern profile, inhibition of pattern collapse, good line edge roughness, and good outgas performance in EB exposure and alkali development, as compared with Comparative Examples 1 to 5 not containing repeating unit (A). Further, the actinic ray-sensitive or radiation-sensitive resin compositions in which the number of atoms for constituting the main structure of the alkylene group, alkenylene group, divalent aliphatic hydrocarbon cyclic group, divalent aromatic cyclic group, or a group formed by combining two or more of these groups represented by L₁ in formula (I) is 2 to 7 can realize further good line edge roughness.

Also, it is clearly seen that the actinic ray-sensitive or radiation-sensitive resin compositions in Examples 18 to 28 and 48 to 60 realize, at the same time, high sensitivity, high resolution, a good pattern profile, inhibition of pattern collapse, good line edge roughness, and good outgas performance in EUV exposure and alkali development, as compared with Comparative Examples 6 to 8 not containing repeating unit (A).

Also, it is clearly seen that the actinic ray-sensitive or radiation-sensitive resin compositions in Examples 61 to 76 realize, at the same time, high sensitivity, high resolution, a good pattern profile, inhibition of pattern collapse, good line edge roughness, and good outgas performance even in EB exposure and organic solvent development, as compared with Comparative Examples 9 to 13 not containing repeating unit (A).

Also, it is clearly seen that the actinic ray-sensitive or radiation-sensitive resin compositions in Examples 77 to 90 realize, at the same time, high sensitivity, high resolution, a good pattern profile, inhibition of pattern collapse, good line edge roughness, and good outgas performance even in EUV exposure and organic solvent development, as compared with Comparative Examples 14 to 18 not containing repeating unit (A).

### INDUSTRIAL APPLICABILITY

According to the invention, it is possible to provide an actinic ray-sensitive or radiation-sensitive resin composition capable of satisfying high sensitivity, high resolution, good pattern profile, and good line edge roughness on a high level at the same time, controlled in pattern collapse in a rinsing process, and having sufficiently satisfactory outgas properties at the time of exposure. According to the invention, it is also possible to provide a resist film using the same composition, a pattern forming method, a manufacturing method of a semiconductor device, and a semiconductor device.

This application is based on a Japanese patent application filed on May 31, 2012 (Japanese Patent Application No. 2012-124854) and Japanese patent application filed on Apr. 30, 2013 (Japanese Patent Application No. 2013-96041), and the contents thereof are incorporated herein by reference.

1. An actinic ray-sensitive or radiation-sensitive resin composition comprising:
(P) a resin having a repeating unit (A) represented by the following formula (I) capable of generating an acid on the side chain of the resin upon irradiation with an actinic ray or radiation: 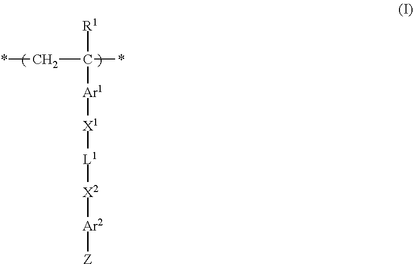
wherein R¹ represents a hydrogen atom, an alkyl group, a monovalent aliphatic hydrocarbon cyclic group, a halogen atom, a cyano group, or an alkoxycarbonyl group,
each of Ar¹ and Ar² independently represents a divalent aromatic cyclic group, or a group formed by combining a divalent aromatic cyclic group and an alkylene group,
each of X¹ and X² independently represents —O— or —S—,
L¹ represents an alkylene group, an alkenylene group, a divalent aliphatic hydrocarbon cyclic group, a divalent aromatic cyclic group, or a group formed by combining two or more of these groups, two or more groups combined in the group formed by combining two or more of these groups may be the same with or different from each other, and two or more groups combined may be linked via —O— or —S— as a linking group; and
Z represents a site capable of becoming a sulfonic acid group, an imidic acid group or a methide acid group upon irradiation with an actinic ray or radiation.

2. The actinic ray-sensitive or radiation-sensitive resin composition as claimed in claim 1,
wherein each of X¹ and X² is —O—.

3. The actinic ray-sensitive or radiation-sensitive resin composition as claimed in claim 1,
wherein in formula (I), the number of atoms for constituting the main structure of the alkylene group, the ankenylene group, the divalent aliphatic hydrocarbon cyclic group, the divalent aromatic cyclic group, or the group formed by combining two or more of these groups represented by L₁ in formula (I) is 2 to 7.

4. The actinic ray-sensitive or radiation-sensitive resin composition as claimed in claim 1,
wherein the resin (P) is a resin further having (B) a repeating unit having a group capable of decomposing by an action of an acid to generate a polar group.

5. The actinic ray-sensitive or radiation-sensitive resin composition as claimed in claim 4,
wherein the repeating unit (B) is a repeating unit represented by the following formula (b): 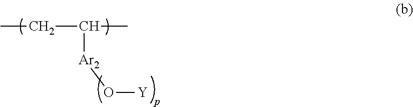
wherein Ar₂ represents a (p+1)-valent aromatic cyclic group,
Y represents a hydrogen atom or a group capable of leaving by an action of an acid, and when a plurality of Y are present, the plurality of Y may be the same with or different from every other Y, provided that at least one of Y's represents a group capable of leaving by the action of an acid, and
p represents an integer of 1 or more.

6. The actinic ray-sensitive or radiation-sensitive resin composition as claimed in claim 5,
wherein Y in formula (b) is a group represented by the following formula (c): 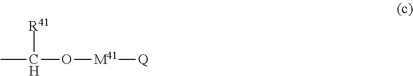
wherein R⁴¹ represents a hydrogen atom, an alkyl group, a cycloalkyl group, an aryl group, or an aralkyl group,
M⁴¹ represents a single bond or a divalent linking group,
Q represents an alkyl group, an alicyclic group, or an aromatic cyclic group which may contain a heteroatom, and at least two of R⁴¹, M⁴¹ and Q may be bonded to each other to form a ring.

7. The actinic ray-sensitive or radiation-sensitive resin composition as claimed in claim 4,
wherein the repeating unit (B) is a repeating unit represented by the following formula (II): 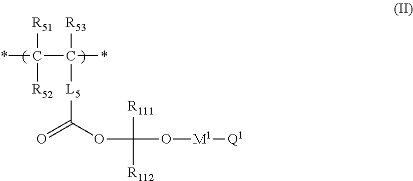
wherein each of R₅₁, R₅₂ and R₅₃ independently represents a hydrogen atom, an alkyl group, a cycloalkyl group, a halogen atom, a cyano group, or an alkoxycarbonyl group,
R₅₂ and L₅ may be bonded to each other to form a ring, and R₅₂ represents an alkylene group in that case,
L₅ represents a single bond or a divalent linking group, and L₅ represents a trivalent linking group when L₅ is bonded to R₅₂ to form a ring,
R₁₁₁ represents a hydrogen atom or an alkyl group,
R₁₁₂ represents a hydrogen atom, an alkyl group, a cycloalkyl group, an aryl group, an aralkyl group, an alkoxy group, an acyl group, or a heterocyclic group,
M¹ represents a single bond or a divalent linking group,
Q¹ represents an alkyl group, a cycloalkyl group, an aryl group, or a heterocyclic group, Q¹, M¹ and R₁₁₂ may be bonded to each other to form a ring,
when M¹ represents a divalent linking group, Q¹ may be bonded to M¹ via a single bond or a different linking group to form a ring.

8. The actinic ray-sensitive or radiation-sensitive resin composition as claimed in claim 1, which is exposed with an electron beam or an extreme ultraviolet ray.

9. A resist film formed with the actinic ray-sensitive or radiation-sensitive resin composition as claimed in claim 1.

10. A pattern forming method comprising:
exposing the resist film claimed in claim 9, and
developing the exposed resist film.

11. The pattern forming method as claimed in claim 10,
wherein, as the development, development by using a developer containing an organic solvent is performed to form a negative pattern.

12. The pattern forming method as claimed in claim 10,
wherein the exposure is performed by electron beam or extreme ultraviolet ray.

13. A method for manufacturing a semiconductor device, containing the pattern forming method as claimed in claim 10.

14. A semiconductor device manufactured by the manufacturing method of the semiconductor device as claimed in claim 13.
